(19) United States
(12) Patent Application Publication
(10) Pub. No.: US 2008/0144493 A1
(43) Pub. Date: Jun. 19, 2008

(54) Method of interference management for interference/collision prevention/avoidance and spatial reuse enhancement

(76) Inventor: Chi-Hsiang Yeh, Kingston (CA)

Correspondence Address: Prof. Chi-Hsiang Yeh;Dept. of Electrical and Computer Eng., Queen's University, Kingston, ON, K7L 3N6, omitted

(21) Appl. No.: 11/295,428

(22) Filed: Dec. 8, 2005

Related U.S. Application Data
(63) Continuation-in-part of application No. 10/881,414, filed on Jun. 30, 2004.

(30) Foreign Application Priority Data
May 11, 2005 (CN) 200510072404.2

(51) Int. Cl. G01R 31/08

(52) U.S. Cl. 370/230

(57) ABSTRACT

Interference, collisions, power control, and spatial reuse constitute important issues that need to be resolved urgently in multihop wireless networks such as ad hoc networks, single-hop/multihop wireless LANs, sensor networks, and mesh networks. A method called the evolvable interference management (EIM) method is disclosed in this patent for avoiding/preventing interference and collision and increasing network throughput and energy efficiency in wireless networks. EIM employs sensitive CSMA/CA, patching approaches, interference engineering, differentiated multichannel, detached dialogues, and/or spread spectrum techniques to solve the interference and QoS problems. Also, EIM embodiments based on collision prevention without dialogues are capable of collision reduction/control and can resolve several important problems encountered in previous MACP or RTS/CTS-based protocols, while improving/retaining their important advantages.

### CROSS-REFERENCE TO RELATED APPLICATIONS

This is a continuation-in-part of application Ser. No. 10/881,414, filed 2004 Jun. 30 by the present inventor, herein incorporated as reference.

This application claims the priority to China patent application Ser. No. 200510072404.2, filed 2005 May 11 by the present inventor, herein incorporated as reference.

This application claims the benefit of the provisional patent application No. 60/522,972, filed 2004 Nov. 29 by the present inventor, herein incorporated as reference.

Yeh, C.-H., “Method of Interference Control for Interference/Collision Avoidance and Spatial Reuse Enhancement,” China patent application Ser. No. 03145296.5, filed 2003 Jun. 30, herein incorporated as reference. (Note: The parent U.S. patent application Ser. No. 10/881,414 claimed the priority to this China patent application.)

### FEDERALLY SPONSORED RESEARCH

Not Applicable

### SEQUENCE LISTING OR PROGRAM

Not Applicable

### BACKGROUND OF THE INVENTION

1. Field of the Invention

The present invention relates generally to communication networks and systems, including, but not limited to, wireless ad hoc networks, sensor networks, single-hop/multihop wireless LANs, 4th/5th generation wireless systems and beyond, heterogeneous wireless networks, as well as networks with wired communication devices or a combination of both wireless and wired communication devices, especially to such closures which are used for medium access control (MAC).

2. Prior Art

### A. Relevant Prior Art Includes

IEEE 802.11 defines the MAC and physical layer standards for the license-free industrial, scientific, and medical (ISM) bands allocated by the Federal Communications Commission (FCC) in the U.S. Currently IEEE 802.11b products have been widely deployed, while 802.11a/11g products with speed up to 54 Mbps (or 108 Mbps when two PHY channels are used as in some products) are emerging.

IEEE 802.11b/a/g are currently the most popular standards for commercial WLAN products, and CSMA/CA of IEEE 802.11 is the most commonly assumed MAC protocol for ad hoc networks in the literature. Due to the importance of real-time applications, including voice over IP/WLAN, video call/conferencing, and video on-demand, Internet and wireless QoS is currently intensely investigated in both academia and the networking industry. IEEE 802.11, however, can not support QoS since DCF of 802.11 is designed for best-effort traffic, while PCF of 802.11 is never implemented in any commercial products due to its inefficiency and several other drawbacks. As a result, IEEE 802.11e, an extension to the MAC protocol of IEEE 802.11 for QoS enhancements in WLAN, is currently under standardization. IEEE 802.11e is poised to become the next-generation MAC protocol for WLANs.

In what follows, we focus on the MAC mechanisms of the IEEE 802.11 family that are related to the disclosed invention.

### A.1 The Distributed Coordination Function (DCF)

The MAC protocol of IEEE 802.11 consists of the distributed coordination function (DCF) based on carrier sense multiple access with collision avoidance (CSMA/CA) and the point coordination function (PCF) based on polling. In both functions, there are control messages associated with data 56 packets to be transmitted. Although IEEE 802.11b allows three simultaneous physical (PHY) channels and IEEE 802.11a allows eight simultaneous PHY channels, the data 56 packets and their associated control messages are transmitted on the same PHY channel.

For a transmission based on DCF, the intended transmitter first sets its counter to a random integer within its current contention window (CW) (i.e., a uniformly distributed random integer in [0, CW]). The intended transmitter then listens to the channel, and starts decreasing its counter by one for every idle slot time after it finds the channel idle for a duration of DCF interframe space (DIFS). If the intended transmitter finds that the channel is busy, it does not start (or halts) decreasing its counter, while keeps sensing the channel. When it finds the channel idle for a duration of DIFS again, it starts (or restarts) decreasing its counter.

When the counter reaches 0, there are two options for transmitting the data 56 packet. In the basic mechanism, the intended transmitter transmits the data 56 packet right away. In the optional mechanism, the intended transmitter first transmits a request-to-send (RTS 60) message to the intended receiver. The intended receiver then senses the channel, and replies with a clear-to-send (CTS) message if it finds the channel idle for a duration of short interframe space (SIFS). After receiving the CTS 62 message, the intended transmitter senses the channel for a duration of SIFS, and transmits the data 56 packet if the channel is idle. Finally, for both basic and optional mechanisms, the receiver sends an acknowledgement (ACK) back to the transmitter if it receives the data 56 packet correctly and senses the channel to be idle for a duration of SIFS again, which completes the RTS 60/CTS/data/ACK 4-way handshaking of the optional DCF mechanism or the data/ACK 2-way handshaking of the basic DCF mechanism.

When a nearby node receives an RTS 60 or CTS 62 message or overhears a data 56 packet transmission, it sets its network allocation vectors (NAVs) to the time required for the RTS 60/CTS/data/ACK 58 handshaking or the data/ACK 58 handshaking to complete. Since the node is not allowed to transmit anything on the channel before its NAV counts down to 0, it will not transmit anything to collide the on-going transmission. Note also that SIFS is smaller than DIFS. In particular, in the IEEE 802.11a physical-layer specification, a slot time has a duration of 9 μsec, SIFS has a duration of 16 μsec, and DIFS has a duration of 34 μsec. As a result, if every node can hear the transmission of every other node, no nodes will send RTS 60 messages (based on the optional mechanism) or data 56 packets (based on the basic mechanism) before the 2-way or 4-way handshaking is completed once the signal of an RTS 60 or CTS 62 message or data 56 packet reach them, even if their NAVs are not appropriately set due to collisions to the associated RTS 60 and/or CTS 62 messages.

If an intended transmitter does not receive a CTS 62 message or ACK before it times out, it will double its CW value, and repeat the above handshaking process. If the node succeeds in the intended transmission, it resets its CW to CWₘᵢₙ. On the other hand, if the intended transmission is still unsuccessful after a certain number of retrials the associated data 56 packet will be discarded.

### A.2 The Point Coordination Function (PCF)

In a wireless LAN, an access point (AP) can act as a point coordinator (PC) to initiate a contention-free period (CFP) based on PCR The PC first senses the channel, and then starts sending a beacon frame to announce the CFP if it senses the channel idle for a duration of PCF interframe space (PIFS). The beacon frame sets the NAVs of all nodes receiving it to the end of the CFP, and no node covered by the AP is allowed to transmit anything (on the PHY channel in use) during CFP unless it is polled by the PC. As a result, transmissions during CFP are collision free. Note that the length of PIFS is larger than that of SIFS. In particular, PIFS has a duration of 25 μsec in IEEE 802.11a. Therefore, PCF transmissions will not interfere with the transmissions of DCF control messages that are required for immediate response such as CTS 62 and ACK, or the transmissions of data 56 packets after their successful RTS 60/CTS 62 dialogues. Note also that the length of PIFS is smaller than that of DIFS. As a result, PCF transmissions have higher priority for channel access than DCF transmissions, and may be used for real-time packets. However, PCF has not been implemented in any commercial 802.11b or 802.11a products as this paper is written.

### A.3 Enhanced DCF (EDCF) of 802.11e

IEEE 802.11e is currently being standardized to enhance IEEE 802.11 for QoS provisioning. 802.11e is backward compatible with the 802.11 MAC protocol and supports all the current PHY-layer specifications including IEEE 802.11, 11a, 11b, and 11g, but augments the MAC protocol with the enhanced distributed coordination function (EDCF) and the hybrid coordination function (HCF). In what follows, I briefly present some key techniques of IEEE 802.11e based on an older draft. Note that some changes in the newest standard document are not updated in the following description.

There are several major differences between EDCF and DCF. First, in DCF, there is only one queue for all packets at a node, while in the current draft version of EDCF, there are eight separate queues at a node, each for a different traffic category. In such a multiple stream model, The first packet in each queue counts down independently of each other. However, if the counters for more than one queue count down to 0 at the same time, a virtual collision occurs. The queue with the highest priority then has the right to send the data 56 packet or the associated RTS 60 message, while the other queue(s) backoffs and repeats the countdown process. Second, each traffic category in EDCF has an arbitrary interframe space (AIFS) in replace of the DIFS in DCF. A EDCF traffic category with higher priority has an AIFS smaller than or equal to that of a lower priority one, but all AIFSs are larger than or equal to DIFS. This, however, does not means that EDCF traffic categories have lower priority than DCF traffic due to the following reason. Third, the rule for countdown is also different in EDCF: the counter is decreased by 1 upon the channel is sensed to be idle for AIFS, rather than after an additional slot time as in DCF. In this way, EDCF transmissions may gain precedence in channel access against DCF transmissions, even though their AIFSs are not smaller. Forth, the rule for calculating new CW is different in EDCF. In particular, higher-priority traffic category can increase the CW by a persistent factor smaller than 2. This allows the CW to be increased at a slower rate, thus reducing the delay and increasing the transmission rate of the traffic category as compared to DCF.

IEEE 802.11e also supports the Hybrid Coordination Function (HCF) as an evolution to PCF for better flexibility and efficiency. We refer readers to for further details.

### B. Problems with Prior Art when Applied to Ad Hoc Networks

When IEEE 802.11 or 802.11e is applied to ad hoc networks or multihop WLANs (i.e., WLANs extended by ad hoc relaying), several problems will be introduced. In particular, the collision problems constitute a major issue that is inevitable in ad hoc networks and will degrade the throughput and QoS capability of multihop networks if they are not carefully handled. In addition to significant reduction in network throughput, this phenomenon has two important implications to QoS provisioning in ad hoc network and multihop wireless LANs. The first implication is that QoS cannot be guaranteed since packets with reservations may still be collided with high probability during the reserved slots. The second implication is that the contention window (CW) will be increased exponentially for unlock nodes that experience a number of collisions, which in turns leads to unbounded delays and lower throughput for the nodes. As a result, the collision problem also has significant implication to fairness in such multihop wireless networks since nodes that experience a number of collisions will be treated unfairly.

The interference problems constitute a major reason for collision rates in multihop networks to be high. More precisely, according to the current technologies, the interference range is typically larger than the transmission range. When there are multiple interfering sources, the additive interference will cause collisions at even larger distance. IEEE 802.11 may mitigate this problem by employing CSMA with lower sensing threshold. This, however, will introduce a new form of the exposed terminal problem in ad hoc networks. Moreover, a new form of the hidden terminal problem will exist when there are obstructions blocking the signals from senders so that CSMA with sensitive carrier sensing hardware does not work well in multihop networks. These problems (called the interference-range hidden/exposed terminal problem and the additive interference problem considerably reduce the radio efficiency in ad hoc networks and multihop WLANs when IEEE 802.11 or 802.11e is employed.

The second major issue is that the energy and spatial reuse efficiency of IEEE 802.11 or 802.11e can be considerably increased when power control and appropriate MAC mechanisms are employed. For example, if RTS/CTS messages are transmitted at power levels as low as those for data packets, the collision rate will be high since a new form of the hidden terminal problem will result. On the other hand, when RTS/CTS messages are transmitted at the maximum power level, collisions can be avoided but a new form of the exposed terminal problem will exist. As a result, power control is not well supported in ad hoc networks due to the heterogeneous hidden/exposed terminal problem. The third issue is the well known exposed terminal problem, when IEEE 802.11/11e is used in ad hoc networks and multihop WLANs.

The fourth major issue is that IEEE 802.11e is not effective in terms of differentiating discarding ratios, delay, and throughput among different priority classes, and the delays of high-priority packets are not bounded under heavy load. A reason is that a high-priority packet may be blocked by a nearby low-priority packet, and then blocked by another low-priority packet on the other side, and so on. With a nonnegligible probability, such a situation can go on for a long time when the traffic is heavy and the network is dense. As a result, high-priority packets may still experience unacceptable delay. This problem cannot be solved by the current version of IEEE 802.11e or other previous differentiation mechanisms and is referred to as the alternate blocking problem.

In what follows we present in details the heterogeneous hidden/exposed terminal (HHET) problem for power-controlled MAC protocols, and the interference-radius hidden/exposed problem and the alternate blocking problem for general ad hoc networks and multihop wireless LANs.

### B.1 The HHET Problem for Power-Controlled MAC

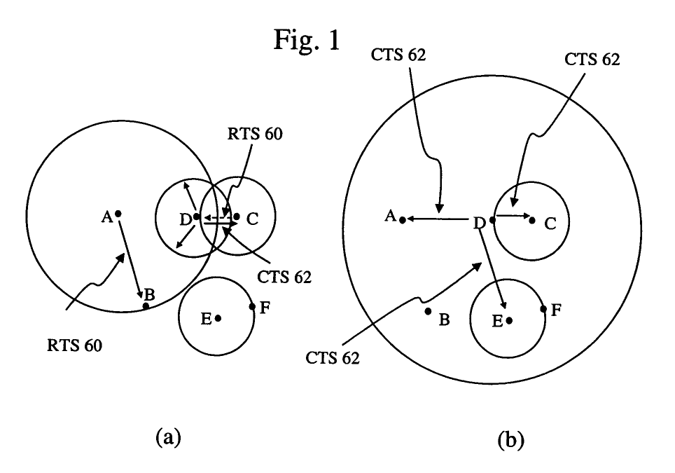

B.1.a HHET in CSMA. In a heterogeneous wireless network, different devices may have different maximum transmission power/radii. Moreover, a wireless device can transmit at different power levels according to the physical distance between the transmitter-receiver pair as well as the noise and interference level. Note that the latter is a typical capability, rather than an exception, when the IEEE 802.11 standard is concerned. In fact, the majority of 802.11-based commercial products currently available in the market can support multiple transmission power levels. In this and the following section, we illustrate the heterogeneous hidden/exposed terminal (HHET) problem that is unique in such networking environments when CSMA and/or RTS 60/CTS 62 protocols are employed and the network architecture is an ad hoc network or multihop wireless LAN. When CSMA alone (without RTS 60/CTS 62 dialogues) is employed in a heterogeneous ad hoc network, a transmission at lower power is vulnerable to nearby transmissions at higher power. The reason is that carrier for the low-power transmission cannot be detected by wireless stations at moderate distance, so those wireless stations may transmit at a higher power and collide the low-power transmission. This is the CSMA form of the heterogeneous hidden terminal problem. If the hardware for carrier sensing is made very sensitive so that a low-power transmission can be detected by wireless stations at moderate distance to mitigate or solve the aforementioned heterogeneous hidden terminal problem, then the exposed terminal problem will deteriorate considerably. More precisely, the carrier for a transmission at high power will be detected by all wireless stations within a very large area (i.e., considerably larger than the maximum transmission/interference ranges/areas) since their sensing hardware is very sensitive. All these wireless stations will then be blocked from transmissions unnecessarily, significantly reducing the network throughput in multihop wireless networking environments. We refer to this problem as the CSMA form of the heterogeneous exposed terminal problem. Clearly, CSMA alone cannot solve both the hidden and exposed parts of the heterogeneous terminal problem simultaneously, even when arbitrarily larger/smaller sensing range (relative to the transmission/interference ranges/areas) is available.
B. 1.b HHET in RTS 60/CTS 62 Protocols. In IEEE 802.11, an optional RTS 60/CTS 62 dialogue for CSMA/CA is supported. However, IEEE 802.11 or CSMA/CA cannot solve both the hidden and exposed parts of the heterogeneous terminal problem simultaneously either. The reason for the RTS 60/CTS 62 mechanism to fail in heterogeneous ad hoc networks is that an intended receiver has no way to determine whether a future transmission of a nearby wireless station will interfere with its reception and should be blocked. As a result, the CTS 62 message of the intended receiver will either block some potential transmitters unnecessarily, fail to block some potential transmitters to protect its reception, or both, no matter how the range for the CTS 62 message is chosen. For example, if the transmission radius of a wireless station is relatively small, and a wireless station only sends its CTS 62 message to wireless stations within a similar radius, then it is hidden from wireless stations outside the range (see FIG. 1a). Since these outside wireless stations do not receive CTS 62 from the on-going receiver, they will interfere with its reception if they decide to transmit data 56 packets with larger transmission radii. We refer to this problem as the RTS 60/CTS 62 form of the heterogeneous hidden terminal problem.

FIG. 1 illustrates the heterogeneous hidden/exposed terminal (HHET) problem in CSMA and RTS 60/CTS 62-based protocols. In FIG. 1a, the heterogeneous hidden terminal problem. The intended transmitter A cannot sense the transmission of the on-going transmitter C or receives the CTS 62 message from the on-going receiver D. If the intended transmitter A sends its data 56 packet to the intended receiver B, the reception at the on-going receiver D will be collided. This can be viewed as a new form of the hidden terminal problem that is unique in heterogeneous ad hoc networks. In FIG. 1b The heterogeneous exposed terminal problem. If the CTS 62 message of the on-going receiver D is sent to all wireless stations within the maximum transmission range, the intended transmitter A can be blocked successfully. However, the intended transmitter E is also blocked from transmission to its intended receiver F unnecessarily, even though its transmission will not collide with the reception at the on-going receiver D. This can be viewed as a new form of the exposed terminal problem that is unique in heterogeneous ad hoc networks. No matter what the ranges for CTS 62 messages (or the sensitivity of carrier sensing) are, either the hidden part or the exposed part of HHET will exist for CSMA, CSMA/CA, or other previous RTS 60/CTS 62-based protocols (without busy tone).

Most power-controlled MAC protocols reported in the literature thus far for ad hoc networks require all transmitters and receivers to send their RTS 60 and CTS 62 messages at the maximum power, and transmit their associated data 56 packets and ACK 58 messages at the minimum power possible. Such an approach is referred to as the BASIC scheme. From FIG. 1b, it can be seen that many wireless stations near an on-going receiver D will be blocked by its CTS 62 message. Even if these exposed wireless stations want to send data 56 packets with a smaller transmission radius that will not interfere with the reception of the sender D of the CTS 62 message, they are still blocked unnecessarily. We refer to this problem as the RTS 60/CTS 62 form of the heterogeneous exposed terminal problem. Note that the negative effect caused by the heterogeneous exposed terminal problem is significantly larger than that caused by the exposed terminal problem in fixed-radius CSMA or RTS 60/CTS 62 networks. The reason is that only wireless stations within a portion of the transmission range of a CSMA data 56 packet suffer from the conventional exposed terminal problem, while the transmission radius of a CTS 62 message transmitted at maximum power may be considerably larger that of its associated data 56 packet, and wireless stations within most part of the transmission range of the CTS 62 message will suffer from the heterogeneous exposed terminal problem.

In summary, CSMA and the RTS 60/CTS 62 mechanism together still fail to solve the heterogeneous terminal problem simultaneously, no matter how the sensitivity and CTS 62 message ranges are chosen. Although this problem does not exist in single-hop wireless LANs, which are currently the main application of IEEE 802.11, ad hoc networks in conferences, meetings, classrooms, concerts, etc., will soon become popular. Thus, an extension to IEEE 802.11 that can solve the heterogeneous hidden/exposed terminal problem is urgently demanded to support power-controlled MAC with high throughput.

B.1.c HHET in Previous Power-controlled MAC Protocols. Several power controlled MAC protocols were proposed to conserve energy consumption. In all these protocols, which are based on the so-called BASIC scheme, require all transmitters and receivers to send their RTS 60 packets and CTS 62 messages, respectively, at the maximum transmission power, and send their associated data 56 packets and ACK 58 messages at the minimum power possible. As argued and simulated, none of these protocols can increase network throughput relative to the standard CSMA/CA protocol of IEEE 802.11. The authors of also concluded that their own power control MAC(PCM) protocol can reduce the energy consumption to a better degree as compared to these previous protocols based on the BASIC scheme, but the throughput of PCM is still comparable to that of standard CSMA/CA. A refinement were made to the BASIC scheme by more carefully selecting the transmission power levels of data 56 packets and ACK 58 messages according to their sizes. Although the error rates and resultant retransmissions can be reduced, the improvement in throughput is still limited. In fact, all these protocols can solve the “hidden part” of the aforementioned heterogeneous hidden/exposed terminal problem since they use the maximum possible radius for their CTS 62 messages. However, they all suffer from the “exposed part” of the heterogeneous hidden/exposed terminal problem since such CTS 62 messages block all nearby intended transmissions unnecessarily, even when these nearby intended transmitters have very small transmission/interference radii and will not collide the receptions at the senders of those CTS 62 messages. Since these MAC protocols only attempt to reduce their power consumption, rather than utilizing smaller transmission power to increase spatial reuse and thus throughput, we categorize them as power controlled MAC protocols. They do not belong to the emerging new class of variable-radius MAC protocols investigated in this document, since in these protocols no wireless devices within the maximum transmission/interference radius of a receiver are allowed to transmit packets (except for the transmitter of this receiver), so the “effective radius” is fixed to the maximum transmission radius.

### B.2 The IHET Problem in Ad Hoc Networks and Multihop Wireless LANs

In this subsection we point out the interference-radius hidden/exposed terminal (IHET) problem for general ad hoc networks and multihop wireless LANs.

In a single-hop wireless LAN, a node can employ a sufficiently sensitive CSMA hardware to make sure that it can hear transmissions from all other nodes. In this way, no hidden terminals exist (as long as there are no obstacles) and collisions will not be caused even if the interference radius is considerably larger than the transmission radius. However, this is not the case for ad hoc networks and multihop wireless LANs.

In ad hoc networks, the most commonly assumed solution to the hidden terminal problem is RTS 60/CTS 62 dialogue. In the MACA paper which employed the RTS 60/CTS 62 dialogue, it was assumed that signals decays rapidly so that the interference radius and transmission radius are similar. Under such an assumption, the hidden terminal problem can be solved based on CTS 62 messages without sensitive CSMA hardware. However, such an assumption does not hold in many ad hoc networking environments when IEEE 802.11 technologies are used. Instead, the interference radius is typically larger than the associated transmission radius (e.g., by a factor of 2). In such an environment, a node A that does not receive an CTS 62 message from a node B may transmit a packet to collide with the reception at node B, since node B may be within the interference range of node A, while node A is outside the transmission range of node B. We refer to this problem as the hidden part of the interference-radius hidden/exposed terminal (IHET) problem.

Note that IEEE 802.11/11e does not have an efficient mechanism to handle the IHET problem in ad hoc networks and wireless LANs. If we assume that the sensing radius is larger than, or equal to, the sum of the transmission radius and associated interference radius, then the hidden terminal part of IHET can be solved. However, the exposed terminal part of IHET will deteriorate in that many nearby nodes (especially those near the transmitter's side) will be blocked unnecessarily. As a result, no matter whether we assume IEEE 802.11e nodes have very sensitive hardware for CSMA, or has smaller sensing range so that frequent collisions will result from IHET, the performance of IEEE 802.11/11e will be considerably degraded in ad hoc networks and multihop wireless LANs.

Poojary, Krishnamurthy, and Dao proposed another modification to RTS 60/CTS 62 protocols to improve fairness when wireless devices with different power capabilities are mixed together in a network. This paper did not consider the issue of larger interference radius as in IHET, but the proposed mechanism may mitigate the IHET and HHET problems theoretically (i.e., when the control messages are extremely small). More precisely, the authors proposed to augment a mechanism to flood CTS 62 messages of wireless devices with lower power capabilities. They assume a device can only transmit at a constant power and fixed radius for all its lifetime, so the proposed scheme does not belong to power-controlled MAC schemes or variable-radius MAC schemes. However, their own simulations results show that the proposed modification actually reduces network throughput due to the increased overhead in relaying CTS 62 messages, even when an enhanced version with precise GPS information is used.

Monks, Bharghavan, and Hwu proposed the PCMA protocol based on busy tone. To the best of our knowledge, PCMA is the only previous protocol reported in the literature thus far that can solve IHET and both the hidden and exposed parts of the heterogeneous terminal problem. In PCMA, a device senses the channel during its reception of data 56 packets, measure the current noise and interference level at its location, and then calculate the additional interference it can tolerate. It will then send its busy tone at a certain power level, which is a function of the additional interference it can tolerate. A device that intends to transmit a data 56 packet has to gather the busy tone signals sent by all nearby on-going receivers, and determine the maximum power level it is allowed to transmit according to the strengths of the busy tone signals it just received. Although some ideas proposed are novel and interesting and PCMA can be classified as a power-controlled variable-radius MAC protocol, a main drawback of this protocol is that each device requires two transceivers. More precisely, one is needed for reception of data 56 packets, while the other is needed to measure the channel noise and interference and to transmit busy tone during its data 56 packet reception. As a result, the hardware cost and power consumption of PCMA will be increased. Moreover, the aforementioned capability required by PCMA-based mobile devices may be expensive, if not impossible, to implement.

### B.3 The Alternate Blocking Problem in IEEE 802.11e

Prioritization-based techniques as DiffServ and reservation-based techniques as IntServ are the two main paradigms for provisioning QoS in practice or in the literature. Since reservations are very difficult to maintain in mobile ad hoc networks, and it is expensive, if not impossible, to police and enforce reservations in such networking environments, we focus on prioritization-based techniques in this present invention. In IEEE 802.11e and most previous MAC protocols for ad hoc networks, prioritization is supported by employing different interframe spaces (IFS) before the transmission of control/data 56 packets with different priorities as well as different calculation rules for backoff times of different traffic classes. Although these mechanisms can differentiate the delays between different traffic classes to a certain degree in single-hop wireless LANs, they are not adequate in a multihop environment such as ad hoc networks and multihop wireless LANs. The reason is that in a single-hop wireless LAN, an 802.11e node with higher priority is guaranteed to capture the channel before lower-priority nodes due to the fact that all nodes with lower priority have to sense the channel for a larger idle time (i.e., a larger IFS) and will lose the competition. However, this is not guaranteed in ad hoc networks or multihop wireless LANs.

For example, in such networking environments, an 802.11e node (e.g., intended transmitter A) with higher priority have a good chance in losing competition to nearby lower priority nodes because the intended transmitter A may be blocked by an on-going receiver B, while a nearby lower-priority intended transmitter C may not interfere with the on-going receiver B and acquires the channel before the intended transmitter A. The receiver D of the lower-priority transmitter C may then continue to block the high-priority intended transmitter A. With a nonnegligible probability, such a situation can go on for a long time for some high-priority nodes when the traffic is heavy and the network is dense (i.e., when there are many nodes within a typical transmission range). So high-priority nodes may still experience large delay in IEEE 802.11e due to nearby low-priority nodes. This problem cannot be solved by IEEE 802.11e or other previous differentiation mechanisms and is referred to as the alternate blocking problem. In order for killer real-time applications such as voice over ad hoc networks and multihop WLAN (i.e., extended by ad hoc relaying) to become a reality, we believe that other effective mechanisms for supporting DiffServ in such multihop net-works are urgently demanded.

### OBJECTS AND ADVANTAGES

Accordingly, besides the objects and advantages of the flexible closures described in my above patent, several objects and advantages of the present invention are:

1. To solve various unique problems of MAC protocols when they are applied to multiple-hop net-works such as ad hoc networks and multihop wireless LANs.
2. To effectively differentiate service quality for different traffic categories and to support quality of service (QoS).
3. To efficiently support power-controlled MAC protocols.
4. To tackle various interference problems.
5. To control collision rate.
6. To make possible (virtually) collision-free multiple access without relying on busy tone.
7. To maximize performance and reduce consumed resources by controlling the tolerable interference and the interference generated to other nodes.
8. To utilize interference/sensing-based singling for conveying information in a robust manner.
9. To increase network efficiency in terms of radio utilization, service quality, energy consumption, and so on.

Note that these objects may not be all addressed in a particular embodiment.

This patent disclose an interference management method (IMM), called evolvable interference management (EIM) method, which can solve both the IHET, HHET, and alternate blocking problems without having to rely on busy tone. An EIM-based node only needs a single transceiver, and typically without requiring additional expensive or specialized hardware besides the standard hardware required by an IEEE 802.11-based mobile device. However, multiple transceivers may also be employed to enhance the performance. We have shown through simulations that EIM protocols can considerably increase network throughput and QoS differentiation capability as compared to IEEE 802.11e. Due to the improvements achievable by EIM, the techniques and mechanisms presented in this invention may be applied to obtain an extension to IEEE 802.11 to better support differentiated service and power control in ad hoc networks and multihop wireless LANs. New protocols may also be designed based on EIM. Some EIM mechanisms and techniques may also be combined with previous and future mechanisms/techniques for multiple access.

### C. Relationship Between this CIP Document and its the Parent US Patent Application

In the U.S. patent application Ser. No. 10/881,414 filed on 2004 Jun. 30 (i.e., the parent document for this CIP document), I have made the following two relevant claims:

1. An evolvable interference management (EIM) method for coordinating medium access among a plurality of nodes, comprising at least one of the following approaches (a)-(h):

(a) sensitive CSMA/CA or ultra sensitive CSMA/CA with sufficiently high sensing mark exceeding a predetermined value as permitted by the sensing hardware;
(b) a prohibition-based patching approach coordinating potential hidden terminals or mutually interfering/destructing terminals to transmit at nonoverlapping times and/or channels for avoiding collision and interference when combined with other coexisting MAC approaches, including, but not limited to, CSMA, sensitive CSMA, ultra sensitive CSMA, CSMA/CA, sensitive CSMA/CA, and/or ultra sensitive CSMA/CA;
(c) an interference engineering approach, comprising the following steps:
(c.1) employing an MAC approach such as, but not limited to, CSMA, sensitive CSMA, ultra sensitive CSMA, CSMA/CA, said sensitive CSMA/CA, and/or said ultra sensitive CSMA/CA;
(c.2) adjusting a transmission's attributes including, but are not limited to, required power used, spreading factor, interference generated, and/or weights/sectors for a smart/directional antenna, and/or a reception's tolerance on interference, such that the transmitter can avoid colliding/interfering other receptions and the receiver can avoid being collided by other transmissions and/or interferences, when coexisting with other nodes using this approach or other coexisting MAC approaches, including, but not limited to, CSMA, sensitive CSMA, ultra sensitive CSMA, CSMA/CA, said sensitive CSMA/CA, and/or said ultra sensitive CSMA/CA, possibly combined with the said prohibition-based patching approach;
(d) an interference/sensing-based signaling approach comprising the following steps:
(d.1) a node transmitting intermittent signals in a channel the same as or different from that of associated data;
(d.2) other nearby nodes sensing the channel to understand the conveyed information or instructions according to the pattern of the signals, using information including, but not limited to, the timing, length, and/or power levels of the signals;
(d.3) nodes successfully sensing the signals optionally following the instructions and/or utilizing the conveyed information if there are any and the said nodes know the corresponding instructions and/or information, or simply reacting according to the protocol they are running, such as deferring for a predetermined time as in IEEE 802.11; thereby achieving desired purposes such as avoiding collision of an associated reception while other nearby nodes are running other coexisting MAC approaches;
(e) a differentiated multichannel approach allocating transmissions to different channels according to a predetermined policy and the attributes associated with the transmission; including, but not limited to, transmission power, generated interference, traffic load, network density, and/or receiver's tolerance to interference;
(f) a spread spectrum scheduling approach sending control messages including, but not limited to, RTS, CTS, SI, RI, OTS, and/or TPO, with a spread spectrum technique using sufficiently large spreading factor to achieve sufficiently high coverage mark without exceeding legitimate transmission power levels, interference, and/or penalties associated with the generated interference, with the said mark and thresholds for power, interference, and/or penalties calculated or controlled using a predetermined policy;
(g) a spread spectrum data approach sending data packets with a spread spectrum technique using sufficiently large spreading factor to achieve sufficiently high coverage mark for associated control messages when the said control messages, including, but not limited to, RTS, CTS, SI, RI, OTS, and/or TPO, are transmitted using legitimate transmission powers and generating legitimate interference;
(h) a detached dialogue approach separating control messages and their associated data packet for scheduling an associated transmission;
(i) the said predetermined values including, but not limited to, said sensing mark and coverage mark, and the said predetermined policies optionally being controlled and adapted to environmental factors and/or traffic class requirements, possibly through fixed rules in protocols or through learning.

6. A method of conveying information to another node or a plurality of nodes to achieve robust signaling or dialogues according to claim 1, comprising: intermittent short signals that use a pre-determined pattern according to a code or to convey information corresponding to the code; the information can be understood through sensing the intermittent signals and the idle time between them;

receiving nodes can optionally react according to the conveyed information.

In this document, I first include the description of the invention disclosed in the parent document, then disclose some additional embodiments or improvements to the invention. I amend claim 1 of the parent document by changing “(d.1) a node transmitting intermittent signals” to “(d.1) a node transmitting intermittent signal(s)” as in claim 1 of this CIP document, and make some claims additional to the ones in the parent document.

### D. Motivations and Advantages of the Additional Embodiments

In what follows I present the motivations and advantages of the additional embodiments disclosed in this CIP document.

Due to the importance of QoS and security, lots of efforts have been devoted to the enhancements to the MAC protocol of IEEE 802.11 recently. QoS provisioning in the Internet is mainly modelled by Differentiated Service and Integrated Service, based on differentiation/prioritization and reservation/QoS-guarantees, respectively. The differentiation mechanisms of IEEE 802.11e and previous QoS MAC protocols are mainly based on different persistent factors (PFs) for the control/increase of backoff time and different arbitrary interframe space (AIFS) for the required idle detection time before counting down. These mechanisms work reasonably well in single-hop wireless LANs with well partitioned frequency bands.

However, in ad hoc networks, mesh networks, multihop WLANs, and single-hop WLANs with competing APs, the collision rates tend to be higher than conventional single-hope WLANs when some unique issues in multihop networking are not appropriately addressed. Such collision problems constitute a major issue in multihop networks, and may considerably degrade the network throughput, QoS capability, and fairness. In particular, the delays for a traffic category of a node may increase exponentially if a couple of packets from that node experience a number of collisions and are eventually dropped. A main reason for the increased delays is the doubling of its contention window (CW) after a collision. Also, QoS cannot be guaranteed in multihop networks if the collision rate is not sufficiently low or under control. A reason for the uncertainty is that packets with reservations may be collided during the reserved slots, and then be repeatedly collided with nonnegligible probability. As a result, most previous MAC protocols cannot always provide small/bounded delay and QoS guarantees in a multihop wireless environment.

To solve the collision problems, dual busy tone multiple access (DBTMA) proposed to employ busy tone at both transmitters and receivers to achieve 100 its control messages may be collided and will thus still cause unbounded delay for repeatedly colliding nodes. Also, several important issues such as interference and power control have not been addressed in DBTMA. Moreover, busy tone requires additional overhead in power consumption, hardware complexity, and frequency band. Another direction in reducing the collision rates is based on the multiple access collision prevention (MACP) paradigm, which adapts binary countdown to distributed multihop environments. The resultant protocols can control the collision rates for both data packets and control messages to satisfactory/acceptable levels. However, the prohibitive range for previous MACP protocols may be large, and may require higher power for transmission.

In this CIP document, I provide more details concerning the dual prohibition multiple access (DPMA) method and the random ID countdown with ACK (RICK) protocol based on DPMA. DPMA can support efficient power control, and solve hidden/exposed terminal problems without relying on RTS/CTS dialogues. These properties as well as their collision control capability are acquired from a novel collision prevention technique based on dual prohibition. By appropriately assigning unique IDs to active nodes, RICK can achieve 100 collision-free control/data packet transmissions in a fully distributed manner (under certain mathematic models).

DPMA is different from previous prohibition-based protocols such as CSMA/IC or black burst in the competition stage. Moreover, DPMA can efficiently support power control without having to employ group scheduling or complex group competition (which is needed by CSMA/IC) and can thus achieve more compact spatial reuse. Unlike DBTMA no busy tone is required in DPMA. Also, DPMA-based devices only require one transceiver (while DBTMA needs dual transceiver per node) so that they may be implemented more cost-effectively. However, dual transceivers per node can improve the performance by avoiding the turn-around time during competition as well as by using both transceivers for data packet transmissions in dual channels.

### D.1 Objects for the Additional Embodiments

To solve various unique problems of MAC protocols when they are applied to single-hop networks such as wireless LANs, and multiple-hop networks such as ad hoc networks, multihop wireless LANs, mesh networks, sensor networks, as well as other networking technologies for ubiquitous computing, pervasive computing/networking, consumer electronics, home networking, smart building/environments, smart tag or location tracking systems such as RFID.

To efficiently support power-controlled MAC protocols.

To effectively differentiate service quality for different traffic categories and to support quality of service (QoS).

To tackle the interference-range problems.

To tackle the additive interference problems.

To control collision rate. To make possible (virtually) collision-free multiple access without relying on busy tone.

To maximum performance and reduce consumed resources by controlling the tolerable interference and the interference generated to other nodes.

To utilize interference/sensing-based singling for conveying information in a robust manner.

To increase network efficiency in terms of radio utilization, service quality, energy consumption, and so on.

To support unicast, multicast, and broadcast.

Note that these objects may not be all addressed in a particular embodiment.

### D.2 Problems Solved by the Additional Embodiments

In this document, we disclose the dual prohibition multiple access (DPMA) method that can solve the IHET, HHET, and alternate blocking problems without having to rely on busy tone. We summarize some potential/possible problems of previous protocols as follows:

Previous MACP protocols using single prohibition (without RTS/CTS dialogues), such as CSMA/IC, may not support power control well or as effectively/efficiently.

Previous MACP protocols using single prohibition (without RTS/CTS dialogues), such as CSMA/IC, may suffer from the exposed terminal problem.

The RTS and CTS messages of previous RTS/CTS-based protocols may not reach nodes within the interference/protection ranges due to maximum power limitation, unless special mechanisms are employed.

The RTS and CTS messages of previous RTS/CTS-based protocols may suffer from collisions, which in turns lead to collisions of data packets.

Previous MACP protocols using single prohibition (without RTS/CTS dialogues) may not use the prohibiting signals to as effectively and/or efficiently replace RTS and CTS messages as in some additional embodiments in this CIP document.

Suitably designed DPMA may solve the additive interference problem elegantly, without relying on busy tone or complex calculation based on received RTS/CTS messages.

The required prohibiting radii/ranges do not need to be the sum of two radii (as in single-prohibition MACP). The latter may require prohibitively high power levels for transmissions or high sensibility for the sensing hardware when the pass loss is high.

Suitably designed DPMA may have strong differentiation capability for QoS supports.

It is possible to employ single channel for data packet and their associated control messages, even without relying on synchronization and fixed packet length.

A DPMA-based node only needs a single transceiver without requiring additional expensive or specialized hardware besides the standard hardware required by an IEEE 802.11-based mobile device. However, multiple transceivers may also be employed some embodiments to enhance the performance.

### SUMMARY OF THE INVENTION

It should be noted that the terms “comprises” and “comprising” when used in this specification, specify the presence of features, procedures or techniques, and so on, but the use of these terms does not preclude the presence or addition of one or more other features, procedures, or techniques, and so on, or groups thereof.

In this document, a method of interference management to be referred to as the evolvable interference management (EIM) method, and the associated techniques and mechanisms are disclosed. EIM employs (ultra) sensitive CSMA/CA, prohibition-based patching approach, interference engineering, differentiated multichannel discipline, and so on, to enable CSMA/CA-type of approaches to address the interference problems in multihop wireless networks. EIM techniques can also be combined into various advanced MAC protocols such as GAP or GAPDIS that are well suited for to address the interference problems in multihop networking environments.

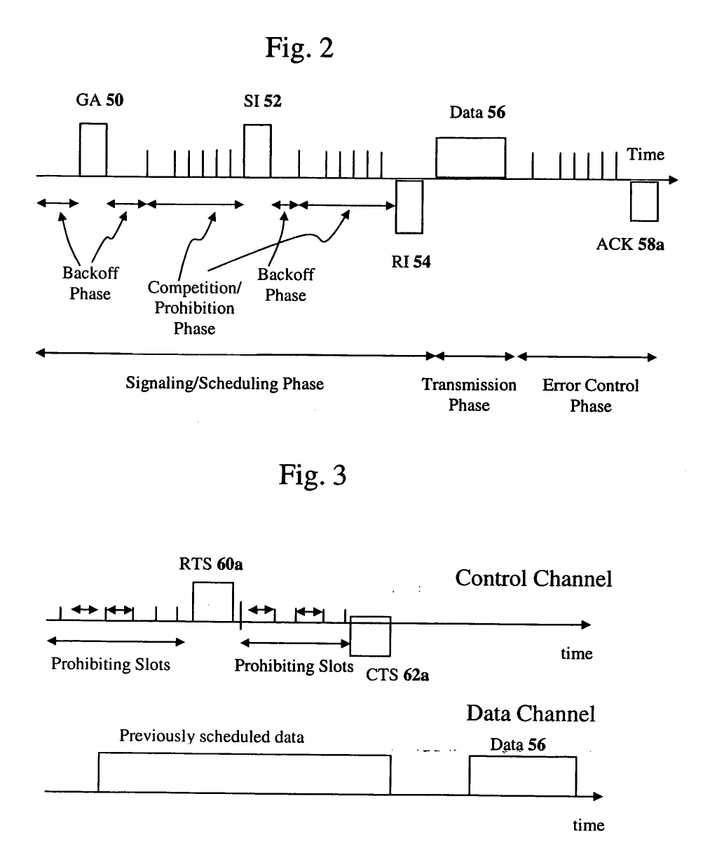

FIG. 2 illustrates the timing diagram for an advanced EIM protocol such as GAPDIS. In such protocols, a node may go through several stages comprising of a signaling/scheduling phase, a trans-mission phase, and an error control phase. The signaling/scheduling phase may overlap with other phases with multiple transmitters is available for the node. A signaling/scheduling phase typically comprises of one or several backoff phases, one or several control messages, and optionally one or several competition/prohibition phases. The backoff phase may employ an area-based backoff control mechanism and/or other backoff control mechanisms. The competition/prohibition phase may employ a prohibition-based signaling mechanism and/or other signaling mechanisms. The detached dialogue approach may be optionally employed in the signaling/scheduling phase for distributed scheduling based on control messages. The error control phase may employ passive, implicit, aggregate, group, and/or other acknowledgement mechanisms.

Group action techniques may be employed to reduce overhead and increase efficiency, while signaling techniques based on spread-spectrum and interference/power control/engineering may have to be employed for protection purpose against interference and/or collision, or may be employed on an optional basis for enhancement in performance.

The presented method allows some of the presented techniques and/or mechanisms to be optional in that they do not need to be employed in some or any of the nodes. However, it is possible for a presented technique/mechanism to require other accompanying techniques/mechanisms in order to function correctly, to avoid problems and achieve better efficiency, and/or to achieve the objects of the presented method. In other words, they may compensate, support, or enhance each other for the purpose of interference control. The presented method may be embodied in a way that different combinations of the presented or new processes, mechanisms, and techniques can coexist. However, a relatively inflexible embodiment of the presented method (i.e., with fewer options) is also possible in order to reduce the complexity and implementation cost of the resultant embodiment.

In summary, the present invention include, but not limited to, the following method and associated mechanisms/techniques:

1. An evolvable interference management (EIM) method for coordinating medium access among a plurality of nodes, comprising at least one of the following approaches (a)-(h):

(a) sensitive CSMA/CA or ultra sensitive CSMA/CA with sufficiently high sensing mark exceeding a predetermined value as permitted by the sensing hardware;
(b) a prohibition-based patching approach coordinating potential hidden terminals or mutually interfering/destructing terminals to transmit at nonoverlapping times and/or channels for avoiding collision and interference when combined with other coexisting MAC approaches, including, but not limited to, CSMA, sensitive CSMA, ultra sensitive CSMA, CSMA/CA, sensitive CSMA/CA, and/or ultra sensitive CSMA/CA;
(c) an interference engineering approach, comprising the following steps:
(c.1) employing an MAC approach such as, but not limited to, CSMA, sensitive CSMA, ultra sensitive CSMA, CSMA/CA, said sensitive CSMA/CA, and/or said ultra sensitive CSMA/CA;
(c.2) adjusting a transmission's attributes including, but are not limited to, required power used, spreading factor, interference generated, and/or weights/sectors for a smart/directional antenna, and/or a reception's tolerance on interference, such that the transmitter can avoid colliding/interfering other receptions and the receiver can avoid being collided by other transmissions and/or interferences, when coexisting with other nodes using this approach or other coexisting MAC approaches, including, but not limited to, CSMA, sensitive CSMA, ultra sensitive CSMA, CSMA/CA, said sensitive CSMA/CA, and/or said ultra sensitive CSMA/CA, possibly combined with the said prohibition-based patching approach;
(d) an interference/sensing-based signaling approach comprising the following steps:
(d.1) a node transmitting intermittent signals in a channel the same as or different from that of associated data;
(d.2) other nearby nodes sensing the channel to understand the conveyed information or instructions according to the pattern of the signals, using information including, but not limited to, the timing, length, and/or power levels of the signals;
(d.3) nodes successfully sensing the signals optionally following the instructions and/or utilizing the conveyed information if there are any and the said nodes know the corresponding instructions and/or information, or simply reacting according to the protocol they are running, such as deferring for a predetermined time as in IEEE 802.11; thereby achieving desired purposes such as avoiding collision of an associated reception while other nearby nodes are running other coexisting MAC approaches;
(e) a differentiated multichannel approach allocating transmissions to different channels according to a predetermined policy and the attributes associated with the transmission; including, but not limited to, transmission power, generated interference, traffic load, network density, and/or receiver's tolerance to interference;
(f) a spread spectrum scheduling approach sending control messages including, but not limited to, RTS, CTS, SI, RI, OTS, and/or TPO, with a spread spectrum technique using sufficiently large spreading factor to achieve sufficiently high coverage mark without exceeding legitimate transmission power levels, interference, and/or penalties associated with the generated interference, with the said mark and thresholds for power, interference, and/or penalties calculated or controlled using a predetermined policy;
(g) a spread spectrum data approach sending data packets with a spread spectrum technique using sufficiently large spreading factor to achieve sufficiently high coverage mark for associated control messages when the said control messages, including, but not limited to, RTS, CTS, SI, RI, OTS, and/or TPO, are transmitted using legitimate transmission powers and generating legitimate interference;
(h) a detached dialogue approach separating control messages and their associated data packet for scheduling an associated transmission;
(i) the said predetermined values including, but not limited to, said sensing mark and coverage mark, and the said predetermined policies optionally being controlled and adapted to environmental factors and/or traffic class requirements, possibly through fixed rules in protocols or through learning.

2. A method of interference management for coordinating medium access among a plurality of nodes to achieve interference/collision avoidance and spatial reuse enhancement according to claim 1, comprising a distributed and detached dialogue for coordinating between a sender, one or several receivers, as well as optionally nearby nodes, given that they exist within a reachable range through one or several hops, with an advance access time between control messages of the dialogue and an associated data packet around a couple of typical data packet durations, larger than a small number of typical data packet durations, or very small value close to zero or the turn around time, while nearby nodes may or may not be deferred by the dialogues heard during the advance access time.

3. The method as set forth in claim 2, wherein: the said dialogue is initiated by the said sender and replied by the said receiver if and only if the said receiver successfully receives the said control message from the said sender, and is available to transmit its said control message using a power level and spreading factor agreed between the said sender and the said receiver

4. A method of interference management for coordinating medium access among a plurality of nodes to achieve smaller collision rate according to claim 1, comprising distributed dialogues for coordinating between a sender, one or several receivers, as well as nearby nodes given they exist approximately within the maximum interfering range for sender information message or approximately within the maximum interfered range for a receiver information message

5. A method of interference management for coordinating medium access among a plurality of nodes to achieve smaller collision rate and spatial reuse enhancement according to claim 1, comprising distributed dialogues for coordinating between a sender, one or several receivers, as well as nearby nodes given they exist within a range or using corresponding power and spreading factor that can be dynamically controlled according to environmental factors and specific requirements, comprising the traffic conditions, application requirements, agreements among nodes within a certain local region, instructions from some control units such as access points or clusterheads, as well as other reasonable factors.

6. A method of conveying information to another node or a plurality of nodes to achieve robust signaling or dialogues according to claim 1, comprising: intermittent short signals that use a pre-determined pattern according to a code or to convey information corresponding to the code; the information can be understood through sensing the intermittent signals and the idle time between them;

receiving nodes can optionally react according to the conveyed information.

7. A method of interference management for coordinating medium access among a plurality of nodes to achieve interference/collision avoidance and spatial reuse enhancement according to claim 1, comprising the following steps for sensitive CSMA/CA or ultra sensitive CSMA/CA: (a) an intended transmitter sensing a predetermined frequency band of the medium to determine whether received signals have attributes conform to predetermined criteria, where the said criteria estimate whether penalties for the intended transmissions of RTS message if transmitted and/or data packet are lower than predetermined values; a counter with a randomly selected backoff value counting down when the criteria is met at a speed that is a predetermined function of the said penalties; when (b) the said intended transmitter optionally transmitting an RTS message or a data packet; (c) an intended receiver sensing a predetermined frequency band of the medium to determine whether received signals have attributes conform to predetermined criteria, where the said criteria estimate whether penalties for the intended transmission of CTS message if transmitted and/or the intended reception of data packet are lower than predetermined values;

(d) if an RTS/CTS dialogue was used, the said intended transmitter transmitting its data packet in this step;
(e) the receiver employing an error control mechanism to optionally acknowledge the transmitter or implying/asking for retransmissions.

### D.3 Summary for Additional Embodiments in this CIP Document

In this document, I disclose embodiments for a collision prevention method that coordinate medium access among a plurality of nodes. The embodiments are based on a general interference/sensing-based signaling approach disclosed in the parent document for this CIP document (i.e., the U.S. patent application Ser. No. 10/881,414 filed by the present inventor on 2004 Jun. 30), where a node may transmit intermittent signals in a channel to coordinate with its neighboring nodes and its partner in its intended transmitter-receiver pair. The channel can use the same or different frequency band(s) as compare to that used by the associated data or information. Other nearby nodes senses the channel to understand the conveyed information or instructions according to the pattern of the signals, using information including, but not limited to, the timing, length, and/or power levels of the signals. Nodes successfully sensing the signals optionally follow the instructions and/or utilizing the conveyed information if there are any and if these nodes know the corresponding instructions and/or information. These nodes (including nearby legacy nodes such as those based on IEEE 802.11/11e) can also simply react according to the specific protocol they are running, such as deferring for a pre-determined time (e.g., for EIFS as in IEEE 802.11 when a bad frame is sensed). The purposes for such signaling or coordination include, but are not limited to, avoiding collision of an associated reception while other nearby nodes are running other coexisting MAC approaches such as IEEE 802.11/11e. This may make the resultant devices more robust against other legacy devices.

In a protocol based on the disclosed method such as earlier MACP protocols, we may have the (intended) transmitters as the only ones transmitting such a signal or intermittent signals; in another protocol embodiment such as RPMA, we may have the (intended) receivers as the only ones transmitting such a signal or intermittent signals; or we may have both the transmitter and receiver in an intended transmitter/receiver-pair involved in transmitting such signals. In the last type of protocols, we may have the intermittent signal(s) sent by the intended transmitter and the intermittent signal(s) sent by the intended receiver interleaving at least once, or typically for several times. An example for interleaving several times is DPMA when multiple bits/digits are employed in their CNs, where the intended transmitter and the intended receiver take turns in transmitting signals corresponding to each bit or digit in the common CN they use. As for the former case, where they only interleave once, we essentially have the intermittent signal(s) sent by the intended transmitter and the intermittent signal(s) sent by the intended receiver sent in sequence (i.e., one after another). For example, in CSMA/BC or other protocols based on transmitter-oriented dual prohibition, the intermittent signal(s) sent by the transmitter in an intended transmitter/receiver-pair may precede the intermittent signal(s) sent by the intended receiver. In a different protocol embodiment for the former case, the intermittent signal(s) sent by the receiver in an intended transmitter/receiver-pair may precede the intermittent signal(s) sent by the intended transmitter. For example, we can modify RPMA by augmenting acknowledgement and/or declaration signals from the intended transmitter of a winning receiver candidate to obtain a protocol based on receiver-oriented dual prohibition. In some embodiments for such dual prohibition MACP, the intermittent signals sent by the intended transmitter and receiver use the same frequency band but different time slots or durations. However, in other embodiments such as asynchronous DPMA, they may also use different frequency bands for signals from the intended receivers and signals from intended transmitters.

In some embodiments for the aforementioned method based on a general interference/sensing-based signaling approach, an intended receiver can send a signal or several signals that use the same frequency band as the one used by the associated data/information to be received, or use a frequency band or several frequency bands within the one used by the associated data/information to be received. An example for the latter case is to employ multiple UltraNarrowBands (M-UNB) for such signaling purpose. Advantages for such embodiments include the same or similar propagation characteristics between the data packets and the signals for interference/sensing-based signaling. Note that such signals are different from control messages such as RTS and CTS in IEEE 802.11/11e. A node that is not the intended transmitter but receives such a signal or signals defers from transmitting for at least a predetermined period of time, such as EIFS in IEEE 802.11. Inband busy tone is a disclosed mechanism falls into this category. MACP can also have embodiments in this category.

In the aforementioned method based on a general interference/sensing-based signaling approach, a node can also send a signal or several signals corresponding to a numerical value such as, but not limited to, a ID associated with the transmitter-receiver pair, or its competition number (CN). A node that is not the intended receiver or transmitter associated with the preceding node but receives such a signal or signals will defer from transmitting data/signals above a corresponding power level for at least a predetermined period of time, if the strengths for one or some of the received signals are above corresponding predetermined levels according to the power level of the data/signals to be transmitted, and rules set forth by the protocol, and if its own corresponding numerical value is smaller than that of the received signal(s) by at least a predetermined value (which can be equal to zero) according to the rules set forth by the protocol. Of course, we can also replace the rule of being smaller to being larger, or other equivalent or similar but applicable rules, according to the protocol employed. MACP is a disclosed paradigm falls into this category. DPMA, CSMA/BC, and RPMA are special cases of MACP without RTS/CTS-type dialogues. In such an approach, the node(s) sending a signal or several signals can be intended transmitters, intended receivers, or both. For example, we may have the intended transmitter as the only node transmitting such a signal or signals as in earlier MACP protocols; we may also have the intended receiver as the only node transmitting such a signal or signals as in RPMA. Moreover, as in DPMA and CSMA/BC, we may have both intended transmitters and receivers participating in sending such a signal or signals.

In some other embodiments for the aforementioned method based on a general interference/sensing-based signaling approach, the signal(s) can also be sent using a frequency band or frequency bands different from the one(s) used by the associated data/information. The advantages for this type of embodiments is to avoid interference with reception of data packets or information, and to achieve better spatial reuse when power control is employed. For example, some MACP embodiments disclosed in this document fall into his category.

In what follows, I briefly present embodiments for MACP, DPMA, and CSMA/BC.

It should be noted that the terms comprises and comprising when used in this specification, specify the presence of features, procedures, or techniques, and so on, but the use of these terms does not preclude the presence or addition of one or more other features, procedures, or techniques, and so on, or groups thereof.

Multiple Access Collision Prevention (MACP)

In MACP, we can employ an additional level of channel access competition to guarantee collision-free transmissions of RTS and CTS messages, or to reduce the probability of collisions for such control messages. As a result, RTS and CTS messages can be received successfully with a high probability, preventing collisions of data packets at the first place; hence the name multiple access “collision prevention”. In an ideal mathematical model where RTS/CTS are received correctly when there are no collisions, collisions can be considerably reduced or even eliminated. However, when in a more realistic model where RTS/CTS may still be received in error due to the wireless channel, collisions may still occur in MACP relying on RTS/CTS dialogues.

In CSMA/IC-type protocols, RTS/CTS messages are not employed and data packets are protected directly through the aforementioned channel access competition. Since the prohibiting signals used in such competitions do not suffer from collisions, and collided transmissions of data packets can usually be prevented by the competition, several problems of IEEE 802.11 and other RTS/CTS-based protocols can be avoided naturally. However, even though CSMA/IC can achieve collision freedom after incorporating the hidden terminal detection mechanism, it has several disadvantages such as exacerbated prohibition-range exposed terminal problem and inability of power control.

Dual Prohibition Multiple Access (DPMA)

DPMA employs dual prohibition signals to replace the RTS and CTS messages in MACAW or IEEE 802.11. In DPMA, transmitters and receivers send their prohibiting signals in different but adjacent prohibition slots. As shown in FIG. 5, the slots for transmitters and receivers are interwoven for the entire competition round. A transmitter slot and a receiver slot corresponding to the same bit/digit are next to each other.

DPMA solves most of the problems encountered in previous MACP protocols such as CSMA/IC. In particular, power control supports can be naturally incorporated by applying appropriate trans-mission power levels. Also, the hidden and exposed terminal problems can be solved without relying on collision-prone RTS/CTS messages. Moreover, DPMA does not rely on the hidden terminal detection mechanism or group competition to resolve such problems as in previous MACP protocols. Other important advantages includes that the prohibitive range/radius is considerably reduced as compared to CSMA/IC and MACP/HTD. This is particularly important when the path loss factor is high.

An important advantage of DPMA is that it has very good property when supporting power control. However, the nodes in an intended transmitter-receiver-pair have to negotiate in advance in order to compete simultaneously. This can be resolved by CSMA/BC.

CSMA with Binary Countdown (CSMA/BC)

CSMA/BC employs transmitter-oriented dual prohibition. More precisely, it uses competition between transmitters only to select at most one winner within a prohibiting range. This is different from DPMA, which requires competition between transmitters and receivers. As a result, the competition/control overhead for CSMA/BC is roughly half that of DPMA.

Intended transmitters use receiver-ID-based competition numbers (CNs) for competition. This is different from CSMA/IC, which uses transmitter-only single prohibition with sender-ID-based CNs. Such receiver-ID-based CNs are essential to the important strength of CAMS/BC since they are needed to trigger intended receivers to declare the channel using declaration signals (similar to the function of CTS messages). This way intended transmitters who just lost a competition can join the next competition right away as long as they do not receive valid declaration signals from nearby receivers. This resolves the prohibition-range exposed terminal problem of CSMA/IC.

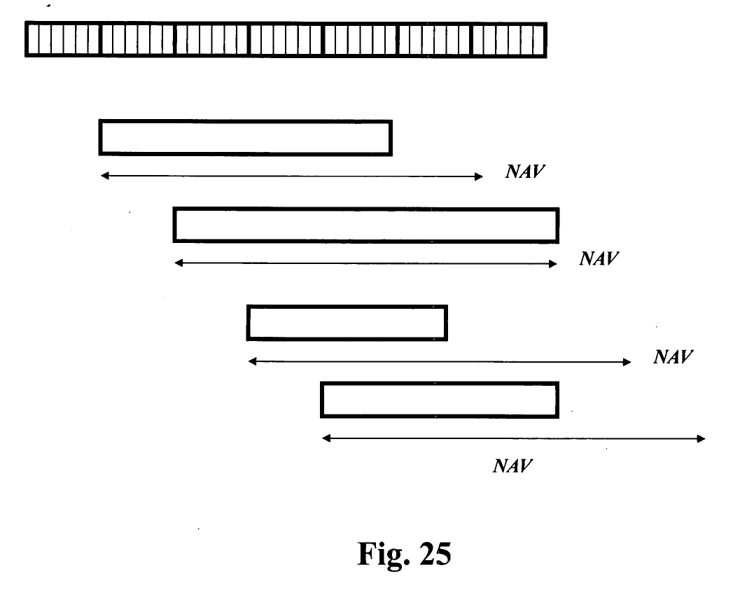

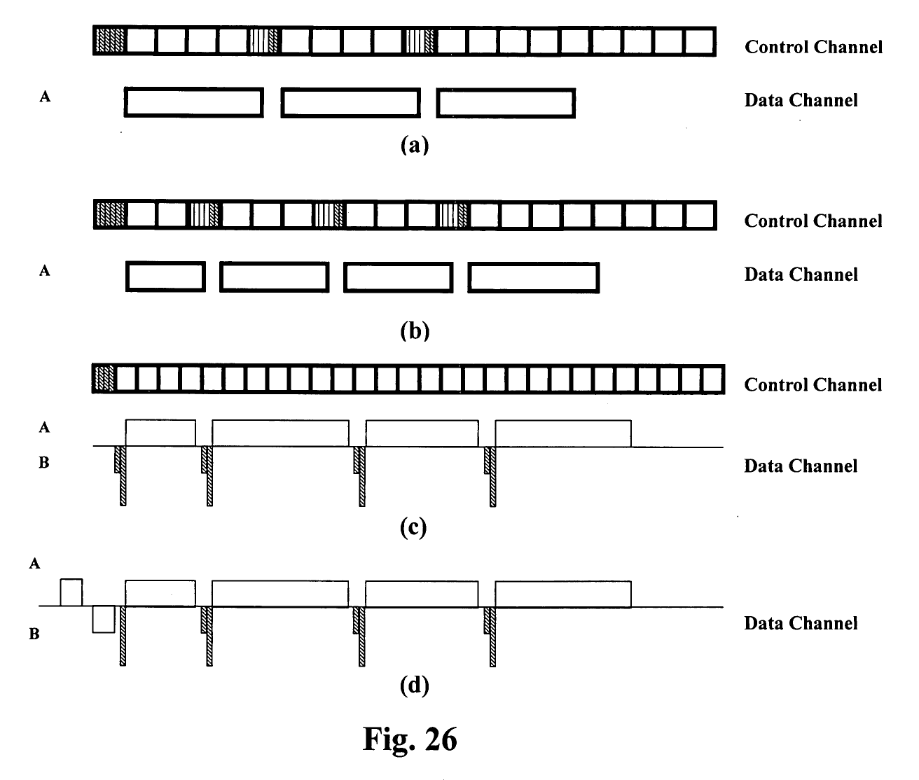

The prohibiting signals of CSMA/BC replace, but retain the functionality of, RTS/CTS dialogues in IEEE 802.11, which solves the vulnerability problem of virtual carrier sensing in IEEE 802.11/11e and BROADEN. Also, the interference-range hidden terminal problem is resolved naturally since, unlike control messages, prohibiting signals can reach interference ranges easily without requiring any special techniques or increased power level. Moreover, power control is supported in CSMA/BC, which cannot be done in CSMA/IC. FIGS. 25, 26a, and 26b provide several examples for CSMA/BC embodiments.

I also disclose additional embodiments and techniques to be referred to as RPMA and inband busytone. FIGS. 26c and 26d provide examples for embodiments of inband busytone.

### BRIEF DESCRIPTION OF THE DRAWINGS

### Drawings—Figures

FIG. 1—The heterogeneous hidden/exposed terminal (HHET) problem in CSMA and RTS/CTS-based protocols.

FIG. 2—An examplenary timing diagram for handing shaking in EIM.

FIG. 3—The timing diagram for a successful handshaking in GAPDIS.

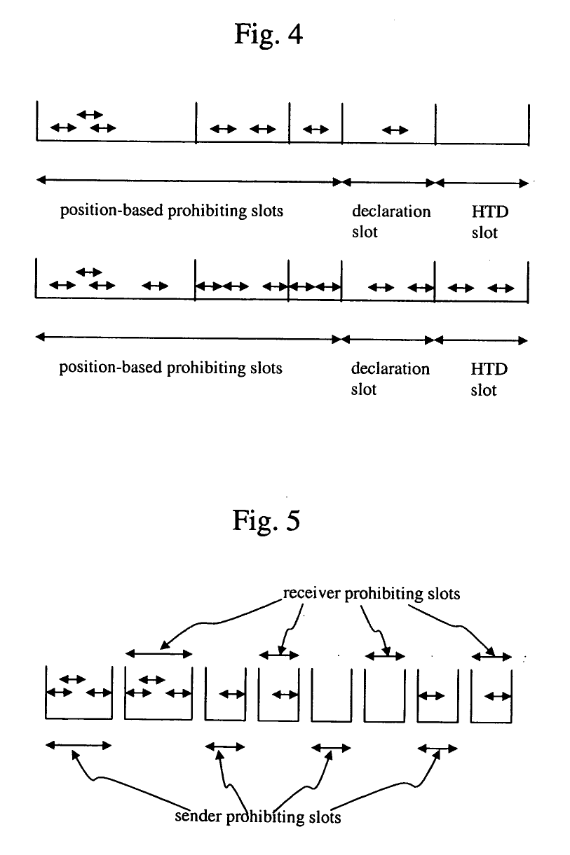

FIG. 4—The prohibiting slots, declaration slot, and HTD slot for position-based prohibition.

FIG. 5—The prohibiting slots for dual prohibition.

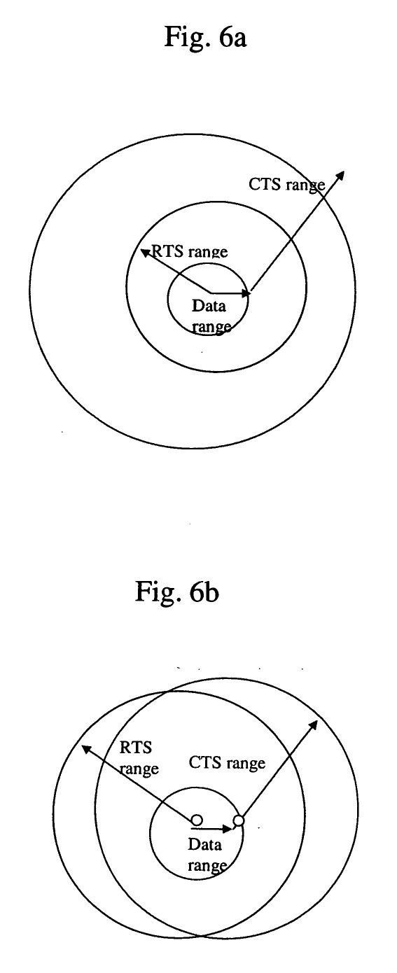

FIG. 6—The coverage ranges for data, RTS messages, and CTS messages. (a) When the minimum required power level is used for transmitting data. (b) When power level higher than the minimum required power level is used for transmitting data.

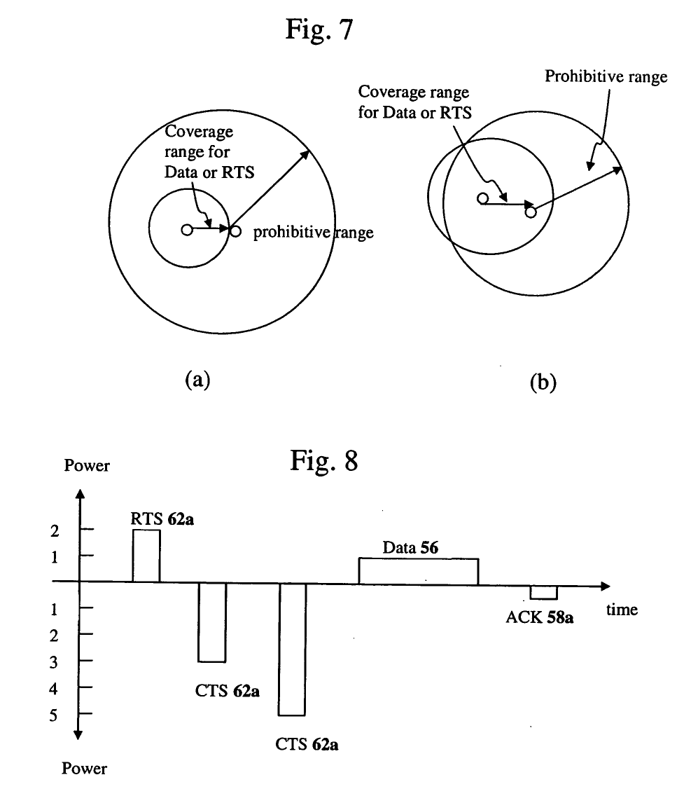

FIG. 7—The coverage ranges for data or RTS messages and the prohibitive ranges for competition before sending CTS messages. (a) When the minimum required power level is used for transmitting the data or RTS message. (b) When power level higher than the minimum required power level is used for transmitting the data or RTS message.

FIG. 8—The timing diagram for handshaking using the detached dialogue approach. The triggered-CTS mechanism is employed. The transmission power level for the second CTS message is increased since the tolerable interference level is reduced so that the coverage range for the second CTS message has to be increased.

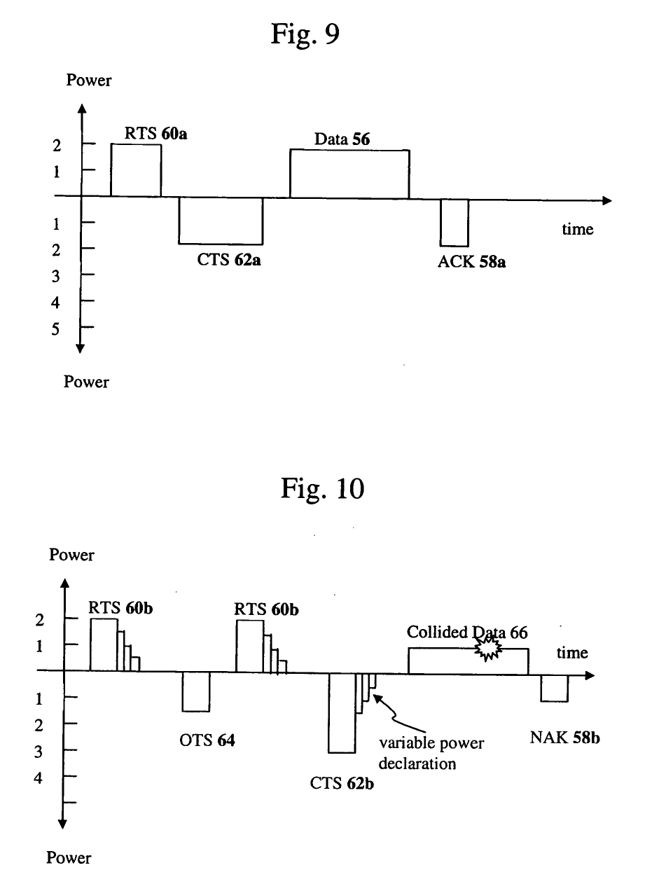

FIG. 9—The timing diagram for handshaking using spread spectrum scheduling (S³) techniques. The detached dialogue approach is not employed.

FIG. 10—An unsuccessfully handshaking where variable-power declaration is employed.

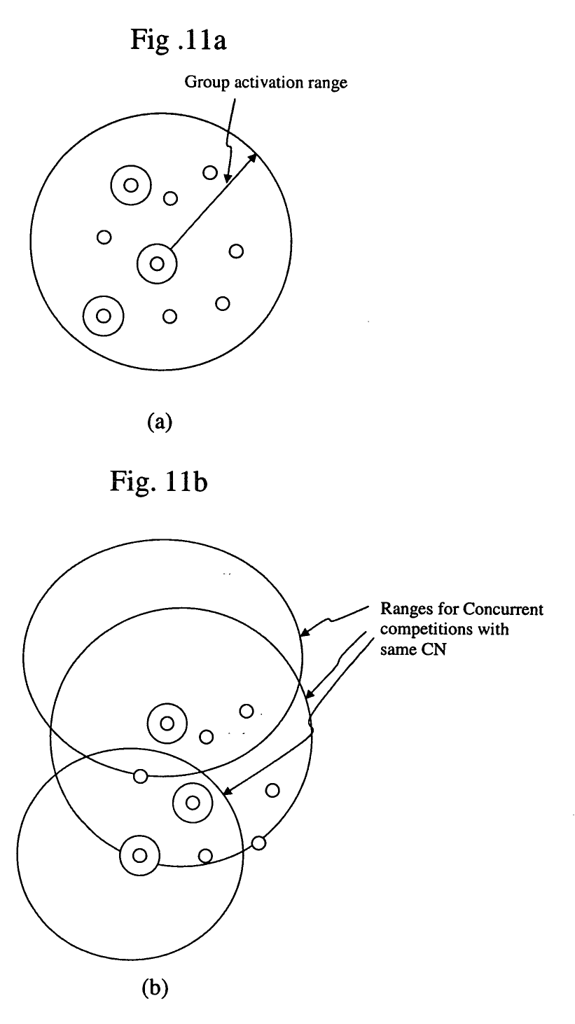

FIG. 11—Two stages of group competition. (a) Group activation. (b) Group competition using the same competition numbers.

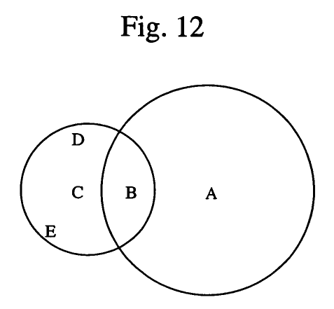

FIG. 12—Several nearby nodes in an ad hoc network. Node A intends to transmit to Node B, while node C intends to transmit to Node E.

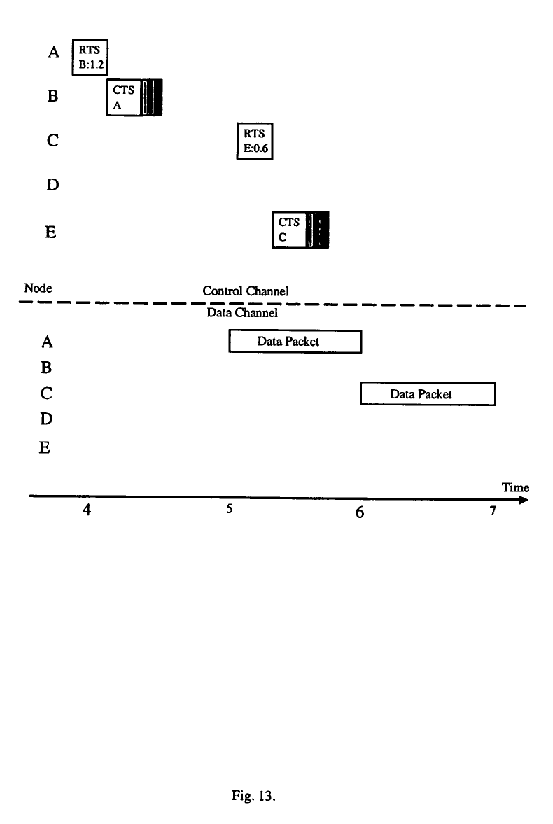

FIG. 13—Timing diagram for example DDMDD dialogues. The relative locations between Nodes A, B, C, D, and E are presented in FIG. 12. In this example, the control channel and data channel are separated, but a node only has a single transceiver so it cannot receive and transmit at the same time. The RTS, TPO, and CTS messages are transmitted in the control channel, where the letters in the squares are the addresses of the intended receivers, and the numbers are the postponed access spaces (PASs).

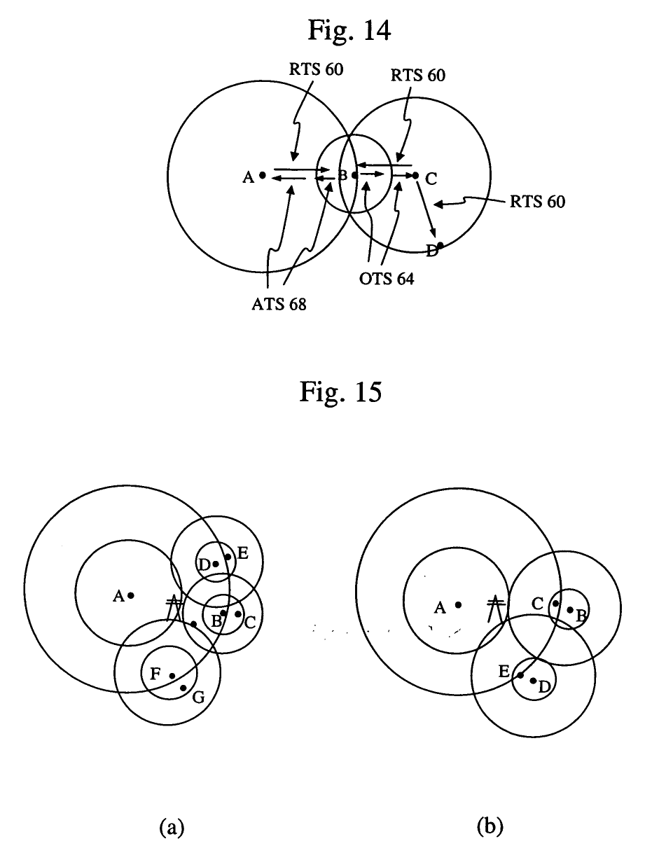

FIG. 14—Operations of DDMDD based on TPO. The intended transmitter A sends an RTS message via the control channel to the intended receiver B. The intended receiver B replies to A with an ATS message if the channel will be available. Consider another node C that is not blocked by the DTR message of the scheduled receiver B. If node C intends to send a packet to D, it sends an RTS message to all the nodes within its interference or protection area. The scheduled receiver B then replies to C with an TPO (or called OTS) message via the control channel, if the request conflicts with its scheduled reception. Therefore, the reception scheduled for receiver B will not be collided even if C does not receive the DTR message from B.

FIG. 15—An example for additive interference at the center node, even though it is outside the ranges of all other transmissions.

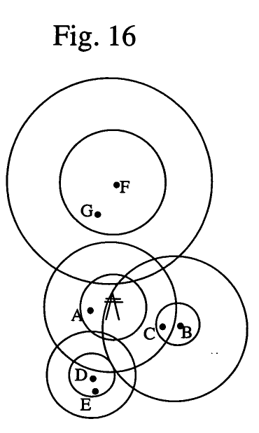

FIG. 16—An example for power engineering when the center node is the transmitter. The power level for the transmission from node B to node C or other transmissions toward nodes close to the BS should be raised.

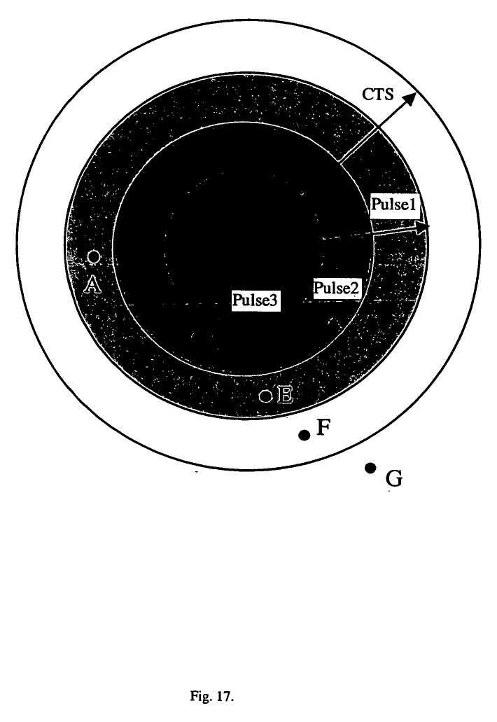

FIG. 17—The DTR mechanism for a transmission from node A to node B. A CTS message is transmitted by node B at the power level p_{P} required for reaching a radius of P_{CTS}. Follow-up declaration pulses are transmitted at power levels ¾p_{P}, ½p_{P}, and ¼p_{P}, respectively. A nearby node can count the declaration pulses it receives to determine the maximum power level it can transmit without colliding the data packet reception at node B. For example, node C receives all 3 declaration pulses, so it cannot transmit during a packet slot overlapping with the one specified in the CTS message. Node D (or E) receives 2 (or 1, respectively) declaration pulses, and can transmit at power ¼p_{T} (or ½p_{T}, respectively) or lower during an overlapping packet slot, where p_{T} is the maximum power level allowed for data packet transmissions. Node F only receives the CTS message without any follow-up declaration pulses, and can thus transmit at power ¾p_{T} during an overlapping packet slot. Node G is outside the protection area from node B, and can transmit data packets at any allowable power level (e.g., P_{T}) during an overlapping period of time. Note that no specialized hardware is required by these nodes (e.g., for measuring signal strength to determine physical distance as in previous busy-tone-based power-controlled MAC protocols).

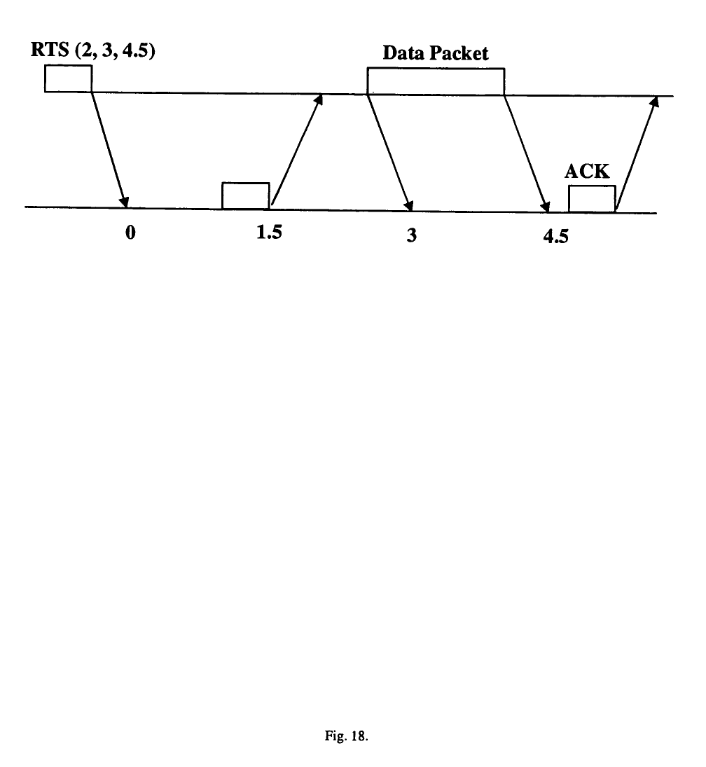

FIG. 18—Illustration of the detached dialogue approach with a single shared channel for both control messages and data packets. All the RTS, CTS, data packet, and ACK messages can be detached as the example. The RTS message specifies the dialogue deadline as 2 time units, the relative reception starting time as 3 time units, and the relative reception ending time as 4.5 time units.

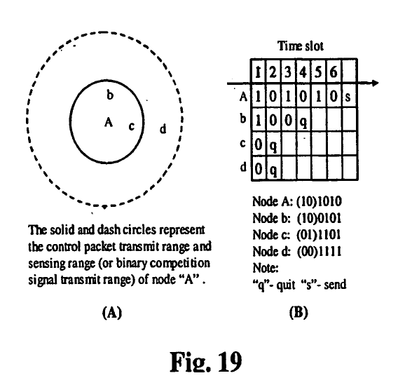

FIG. 19—An example for binary countdown competition.

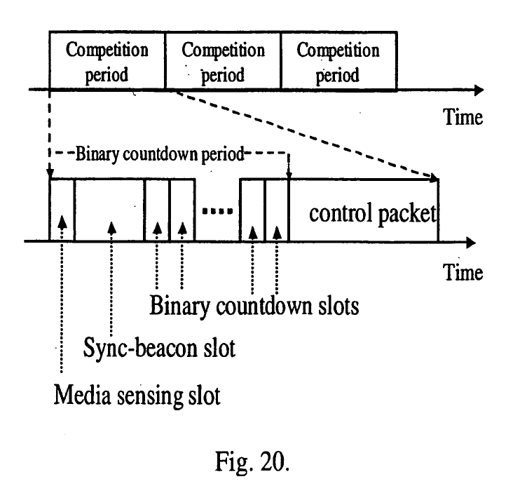

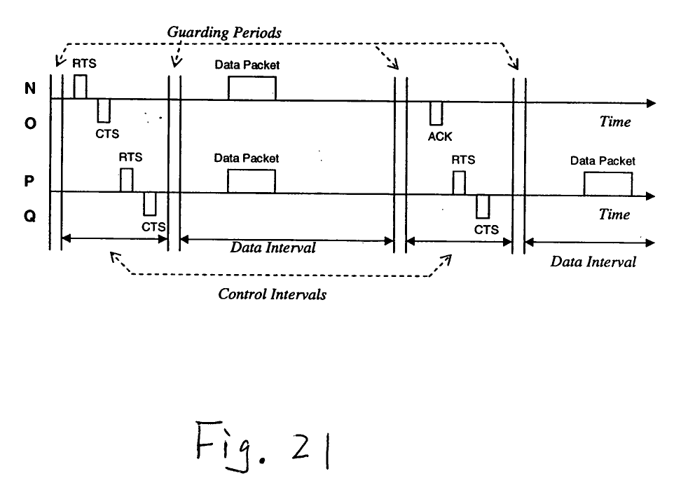

FIG. 20—The frame format for the control channel of BROADEN.

FIG. 21—The timing diagram for semi-asynchronous advanced access (AA) (an example of the detached dialogue (DD) approach) that uses a single shared channel for control messages and data packets.

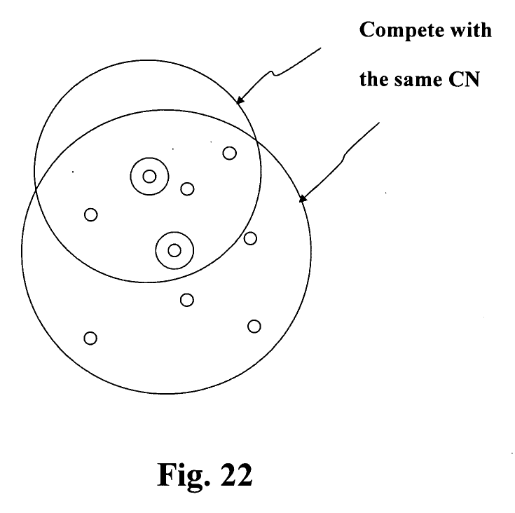

FIG. 22—An example for operations of pairwise group competition.

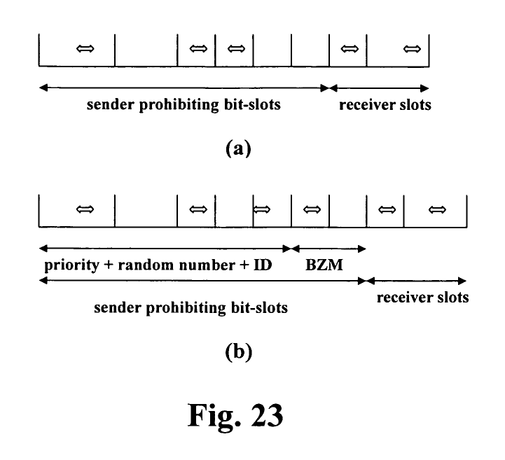

FIG. 23—An example for CSMA/BC.

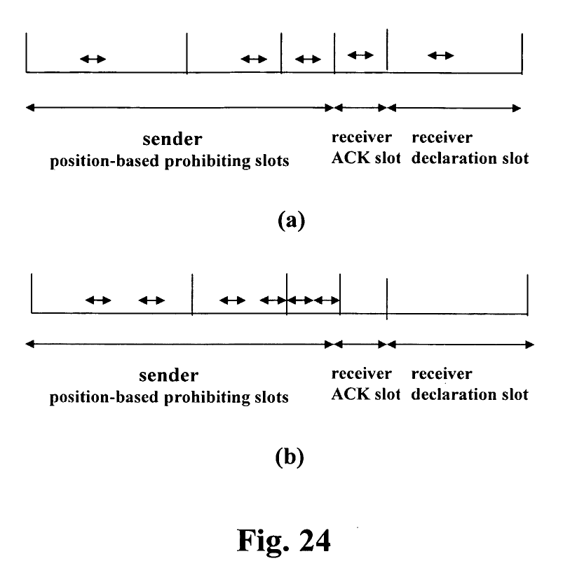

FIG. 24—An example for CSMA/BC with position-based prohibition.

FIG. 25—An example for dual-channel fixed-length MACP without dialogues.

FIG. 26—Example for MACP without dialogues and inband busytone. (a) Variable-length MACP with periodical prohibition. (b) Variable-length MACP with adaptive periodical prohibition (APP). (c) Variable-length MACP with inband busytone. (d) Inband busytone with RTS/CTS dialogues.

### REFERENCE NUMERALS

50—Group Activation (GA) message
52—Sender Information (SI) message
54—Receiver Information (RI) message
56—Data
58a—ACKnowledgement (ACK)
58b—Negative AcKnowledgement (NAK)
60a—Request-To-Send (RTS)
60b—Request-To-Send (RTS) with variable-power declaration
62a—Clear-To-Send (CTS)
62b—Clear-To-Send (CTS) with variable-power declaration
64—Objective-to-sending (OTS)
66—Collided Data
68—Agree-To-Send (ATS)

### DESCRIPTION OF THE INVENTION AND THE PREFERRED PROCEDURES FOR EMBODIMENTS

In what follows, various aspects of the invention will be described in greater detail in connection with a number of exemplary embodiments. To facilitate better understanding of the invention, several components of the invention are described in terms of sequences of actions to be performed by elements in a plurality of communication devices. In each of the presented embodiments, the various actions could be performed by specialized circuits, by program instructions executed on one or more processors, or by a combination of both. We generally refer to such an element as a node.

An appropriate subset of these components and embodiments can be optionally employed and combined with other components/embodiments to realize the objectives and achieve respective advantages for the presented interference control method. Such combinations can be adaptive to the conditions of the environments, and changed through time based on optimization, heuristics, or other policies. Moreover, different nodes can utilize different combinations due to their limitations, available resources, preferences, current status, and the respective environment conditions where they are located. As a result, the various aspects of the invention may be embodied in many different forms, and all such forms are contemplated to be within the scope of the invention. However, to facilitate coexistence among a plurality of nodes, certain rules apply to restrict the permissible combinations, which can be very strict (e.g., almost uniform among all nodes) or relatively relaxed. Such rules are typically specified in the protocols, standards, regulations, or other policies the nodes follow, and can be further coordinated in a distributed manner as the efforts of a group of nearby nodes, in a centralized manner coordinated by clusterheads, elected coordinators, or a unit governing a wider range of other nodes.

### I. THE PHILOSOPHY OF THE EIM METHOD

In this patent we disclose the evolvable interference management (EIM) approach for next-generation wireless networks. EIM is particularly designed to tackle the interference problems in multihop wireless networking environments. The philosophy for the present invention is that it is not a MAC/routing/QoS protocol or scheme optimized for present or a given future time frame, but a framework that can generate MAC/routing/QoS protocols optimized for future advanced/mature technologies (such as OFCDM, multi-carrier CDMA, and VLSI), newly emerged technologies (such as UWB and smart antennas), new application environments or needs (such as sensor networks), and so on. As a result, EIM is developed to be capable of adapting to, and taking advantages of, the evolution of technologies, and to prevent forseenable problems and leaves rooms/flexibility for their possible solutions in advance. The most important and unique goal and characteristic of all are that the series of optimized MAC, routing, and QoS protocols/mechanisms generated from EIM for a networking environment have to be able to co-exist, at least for adjacent generations.

EIM can solve various unique problems in multi-hop wireless networks including ad hoc networks, multihop WLANs, and sensor networks, but may also be applied to conventional single-hop networks. A unique feature of EIM is its capability to enable an evolutionary path from current IEEE 802.11/11e-based single-hop WLANs to future multihop WLANs, ad hoc networks, and 4G/5G heterogeneous wireless networks. EIM is also developed with emerging and potential future technologies in mind, by developing a flexible, extensible, and consistent framework that can incorporate various possible advancements in the future and tolerate the co-existing of new and legacy devices.

EIM employs several techniques and mechanisms as “components” or “tools” to resolve various problems or to obtain certain advantages. These techniques and mechanisms include, but are not limited to, spread spectrum-based interference control techniques, detached dialogues-based interference signaling techniques, patching-based interference avoidance techniques, sensitive CSMA-based interference avoidance techniques, busy-tone or interference/sensing-based signaling techniques, group action-based techniques, and so on. Some of these techniques and mechanisms can support or enhance each other, or compensate each other, while some of them can be alternatives to each other. Some EIM subschemes need to employ multiple techniques/mechanisms in order for them to work correctly, effectively, and/or efficiently. However, typically, all of them do not need to be employed at the same time. Devices based on different but consistent subschemes (e.g., developed for a certain viable evolutional path) can co-exist as long as certain rules are followed appropriately.

### II. THE EIM METHOD AND ASSOCIATED TECHNIQUES

In this section, we present several scenarios and promising EIM techniques along possible evolutionary paths for future wireless MAC protocols. We start with techniques that can work in combination with, or on top of, IEEE 802.11/11e standards without requiring any dramatic changes. We then continue with advanced EIM techniques that can be used to extend IEEE 802.11/11e protocols or lead to new MAC protocols for next-generation mobile wireless networks.

### A. Sensitive CSMA/CA: A Simple Solution to Interference Problems

When the CSMA/CA protocol of IEEE 802.11/11e is applied to ad hoc networks and multihop wireless LANs, wireless devices can mitigate the interference-range/additive-interference hidden terminal problems by employing carrier sensing hardware that is more sensitive (i.e., being able to detect the carrier with lower threshold). We refer to this approach as sensitive CSMA (S-CSMA).

In conventional wisdom, S-CSMA is frequently viewed as an alternative to the RTS/CTS dialogues to resolve the hidden terminal problem in multihop environments. However, sender-based S-CSMA cannot completely eliminate the hidden terminal problem in such networking environments. One such scenario is introduced when obstructions block the signals between some active transmitters, resulting in hidden terminals. Another kind of hidden terminals (for CSMA) exist in environments where the path loss is high. When power control is employed, this problem becomes even more severe since low-power transmissions tend to be hidden from (far away) high-power transmitters so that the latter may collide the former with a high probability. To mitigate these problems, we may employ RTS/CTS dialogues to eliminate some hidden terminals that otherwise exist in “pure” S-CSMA. We refer to this approach as sensitive CSMA/CS (S-CSMA/CA). It is desirable to tuen on RTS/CTS dialogues when the collision rate is not low and the data packets are large enough to justify the associated overheads.

Note that S-CSMA is not effective in environments with high path loss since the signals of a transmitter may not be picked up by potential interferes far away from it but closer to its receiver. This problem may also be mitigated by using ultra sensitive carrier sensing hardware, and the resultant approach is referred to as ultra sensitive CSMA (US-CSMA) or US-CSMA/CA when RTS/CTS dialogues are (optionally) employed. However, there is a limit on the sensitivity of the sensing hardware, and such adaptive mechanism may require higher complexity and overhead. Fortunately, RTS/CTS will perform more effectively in such environments, thus complementing the weakness of S-CSMA. This is another reason why, in multihop networking environments, it is desirable for S-CSMA to work in combination with RTS/CTS dialogues as in S-CSMA/CA, rather than working alone as in pure S-CSMA. Since S-CSMA/CA does not require changes at the MAC layer and hardly any changes at the PHY level, it is the scenario that will most likely happen first in ad hoc networks and multihop WLANs. Note that in S-CSMA/CA or especially US-CSMA/CA, it is desirable for the sensing threshold to be adjustable and controllable since path loss can considerably differ in different environments or at different times. Such capacity will then require a few more changes at the PHY level and possibly a mechanism for MAC-PHY cross layer interaction.

However, when the interference range of data packets is larger than the coverage range of RTS/CTS messages, RTS/CTS dialogues (on top of S-CSMA) still cannot eliminate all hidden terminals. The reason is that a CTS message may not be decodable within a large portion of the associated maximum interfering range when the signal received at the associated receiver is not high. As a result, irrelevant transmitters or receivers within that portion of the region may collide the associated reception by transmitting data packets or control messages at maximum or sufficiently high power levels. Similarly, if an RTS message is transmitted at the same power level as the associated data packet, it is also undecodable within a large portion of the maximum interfered range unless appropriate accompanying mechanisms are employed.

One way to solve this problem is to try to transmit the RTS and CTS messages to most nodes within the associated protection ranges. This may be done by transmitting the RTS messages at power levels sufficiently at higher power levels transmitting the RTS/CTS messages at power levels sufficiently at higher power levels

A simple but less efficient remedy (in terms of radio utilization) is to employ a relatively conservative algorithm for backoff control after collisions. This can be implemented by selecting larger persistent factor (PF) for the associated traffic category in IEEE 802.11e. To avoid unnecessary latency and channel idleness, a hidden terminal detection mechanism may be employed to detect, identify, and/or verify such potential hidden terminals. The relatively conservative algorithm can then be applied to such vulnerable transmitters or transmissions only, rather than to all colliding nodes in the network. Note that when power control is employed, whether a pair of nodes are hidden terminals depend on the associated transmission power levels and the received signal strengths. Note also that hidden terminals may be unidirectional, rather than bidirectional or mutual, when one of them is transmitting at a higher power level. We categorize this accompanying mechanism to the reactive hidden terminal resolution paradigm, which typically requires additional mechanisms at a level higher than MAC, and may or may not require some (simple) changes at the MAC level.

Another important issue is that when the path loss is high, sensitive CSMA is not effective since the signals of a transmitter may not be picked up by potential interferes to its receiver. This problem can be mitigated by using ultra sensitive carrier sensing hardware, and adaptively adjusting the sensing threshold according to the environments. We refer to this approach as ultra sensitive CSMA (US-CSMA), and is called US-CSMA/CA when RTS/CTS dialogues are employed. However, there is a limit on the sensitivity of the sensing hardware, and such adaptive mechanism may require higher complexity and overhead. Fortunately, RTS/CTS will perform more effectively in such environments, thus complementing the sensitive CSMA mechanism. This is another reason why it is desirable for sensitive CSMA to work in combination with the RTS/CTS dialogues in multihop networking environments as sensitive CSMA/CA, rather than working alone.

### B. Prohibition-Based Patching: A Transparent Approach on Top of MAC

The prohibition-based patching approach (PPA) can increase spatial reuse at the expense of higher control overhead. MAC protocols in this category require higher processing complexity and thus more expensive hardware, so they are more likely to be adopted after the low throughput of S—CSMA/CA or US-CSMA/CA (without appropriate modifications) become intolerable to users. Note, however, that MAC hardware can be integrated with CPU (e.g., as the Intel Centrino Mobile Technology™. As a result, such processing requirements are feasible in laptop/PC-based ad hoc networks and WLANs.

Under the reactive patching paradigm, nodes involved in collisions will go through a procedure to determine whether they are hidden terminals to each other. A threshold can be set for the procedure to be invoked. When another (higher) threshold is reached, a regional detection procedure can be invoked to detect active hidden terminals within that region. Then detected mutual/unidirectional hidden terminals will negotiate with each other to work out mutually exclusive schedules for assisting hidden terminal resolution in S-CSMA/CA-based protocols. These nodes will then avoid transmitting during overlapping times (at forbidden power levels). As a result, collisions caused by interference-range hidden terminals can be prevented through a scheduling-based patch without modifying the MAC or PHY layer.

Under the proactive patching paradigm, the regional or global hidden terminal detection procedure is provoked when appropriate (e.g., periodically or semi-periodically with the period adaptive to the traffic conditions and collision rates). Then mutually exclusive schedules can be set up to prevent collisions at the first place, at the expense of higher control overhead and more complex schedules as compared to the reactive patching paradigm. Since such techniques do not need to modify the MAC/PHY protocol standard but can be implemented at a higher level as a patch, we refer to them as the patching approach. Since collisions or other types of inefficiency are prevented by prohibiting mutual/unidirectional hidden terminals from scheduling during overlapping times, we refer to this subclass of the patching approach as the prohibition-based patching approach. The patching approach also has other subclasses such as the encouragement-based patching approach (EPA). Note that PPA, EPA, and other subclasses may work together for different pairs or groups of nodes and maybe in a hierarchical manner, rather than being mutually exclusive. The aforementioned approaches rely on individual hidden nodes to negotiate for mutually exclusive schedules and are thus referred to as node-oriented PPA.

In what follows we present group-oriented PPA in combination with S-CSMA/CA. The proactive patching paradigm is followed where a hidden terminal detection procedure is provoked whenever appropriate. Group scheduling is then employed to assign the detected mutual/unidirectional hidden terminals to different groups. Only nodes (possible with associated power limitations) that can “attempt” to transmit during overlapping time without causing unacceptable collision rate (or other performance degradation) are assigned in the same group. In other words, nodes belonging to the same group can usually attempt to transmit based on S-CSMA/CA without causing collisions due to the interference-range problems. Note that for this kind of groups, called harmonic groups, the members of a group typically cannot all transmit at the same time; otherwise a lot of collisions will be resulted. Instead, after some of them initiate their transmissions (possibly, but not necessarily, through RTS/CTS dialogues), many other group members will be blocked from transmitting or receiving (based on received RTS/CTS messages, carrier sensing, NAVs, or schedules). Note also that a node can be affiliated with multiple groups, and a node that does not have any hidden terminals may be affiliated with every such group if so desired. Group-oriented PPA has many other important applications. In particular, it can enable differentiated group channel by grouping transmissions of data packets or control messages at the same power range. Power-controlled/variable-range multiple access can then be efficiently supported in a way similar to differentiated PHY channel and differentiated code channel. Such a strategy can be expanded to assign nodes, transmissions, receptions, competitions, etc., with similar features into a birds-of-a-feather (BOF) group to achieve respective advantages.

PPA may be applied to achieve various other important objectives or to fix other problems. In what follows we use link-oriented PPA as an example to explain how it works. Consider a network that has some links, though existing, cannot provide communication quality, reliability, and/or efficiency that are satisfactory. Such links may be resulted from far-away transmitter/receiver-pairs that can barely hear each other, or suffer from multipath effects, mobility, obstructions, interference, noise, and so on, including the one caused by the interference-range or additive interference problems. These links, if used, may consume too much resources (e.g., due to retransmissions, dropping, etc.). They may also considerably degrade the performance or quality of TCP-based or real-time applications, or even prevent them from working properly. As a result, it may be beneficial to prohibit these problematic links from being used in some applications or environments. This can be implemented in a variety of ways. For example, “iptables” can be used to disable undesirable links/neighbors. Also, the protocol stack may be modified so that such problematic links are flagged and disabled for any uses or when associated with certain traffic categories or applications. Moreover, scheduling-based approach similar to the aforementioned node-oriented PPA or group-oriented PPA mechanisms may also be applied to the transmitter/receiver-pairs of such links.

Link-oriented PPA can be applied to transform conventional routing protocols into protocols with desirable new features without having to modify the protocols or their implementations. Consider an ad hoc network using a minimum-hop-based routing protocol (such as AODV or an evolved version) due to its popularity. However, in some environments or certain regions a power-controlled routing protocol is actually favored due to energy or throughput concerns. To satisfy or adapt to the needs, we can simply discourage/disable the use of high-power links through link-oriented PPA or group-oriented PPA. The conventional minimum-hop routing protocol will be magically trans-formed into a power-controlled/variable-radius routing protocol in an automatical and transparent manner. Among the PPA mechanisms, node-oriented and link-oriented PPA are more likely to be adopted first. A variety of other PPA variants are also possible, and can achieve different objectives. The details are omitted in this book chapter.

When PPA is applied to RTS/CTS-based protocols without CSMA The rational is that if the RTS/CTS coverage ranges/areas are smaller than interference ranges/areas, then nodes that cannot be protected from each other through RTS/CTS messages should avoid transmitting and/or receiving at the same time, while nodes that are farther away can transmit at the same time. (This may be viewed as a kind of “interleaving approach” over the space (rather than over the time).) We refer to this type of strategies as the prohibition-based patch approach (PPA). mutually exclusive group action-based interference avoidance techniques mutually exclusive group action-based interference avoidance techniques by associating nearby nodes that are allowed to transmit at the same time (based on CSMA, RTS/CTS dialogues, or sensitive CSMA techniques) as a group, and organize the groups in such a way that, for example, different groups should avoid transmitting at the same time to avoid collisions. The rational is that if the RTS/CTS coverage ranges/areas are smaller than interference ranges/areas, then nodes that cannot be protected from each other through RTS/CTS messages should avoid transmitting and/or receiving at the same time, while nodes that are farther away can transmit at the same time. (This may be viewed as a kind of “interleaving approach” over the space (rather than over the time).) We refer to this type of strategies as the prohibition-based patch approach (PPA).

RTS/CTS, but isolated regions (for high-power transmissions)

More details will be provided later.

### C. Interference Engineering for Power-Controlled Multihop Networking

When power control is employed, sensitive CSMA (without interference engineering or differentiated multichannel) will not work for transmissions at very-low power levels. The reason is that such low-power signals (e.g., at 1 mW) cannot be picked up by potential interferes that are relatively far away and will transmit at high power levels (e.g., at 1 W). This problem can be mitigated by RTS/CTS messages transmitted at maximum power, but cannot be completely resolved when the interference-range is larger than the coverage range. Also, when a data packet is not large, the control overhead in terms of the consumed energy may not be acceptable. Moreover, the spatial reuse cannot be increased when CTS messages are transmitted at the maximum power level as power-controlled protocols based on the Basic scheme. To solve these problems for reduced collision rate and increased throughput, we may emply interference engineering, which does not require much change to the MAC protocol of IEEE 802.11/11e, except for simple estimation of the appropriate power levels for transmissions.

Power engineering can enable interference engineering, which appropriately control the interference generated for other nearby nodes (and thus changing the maximum interfered range for a given interference threshold) or the interference tolerable at the receiver (and thus changing the maximum interfering range for a given interference threshold). For example, by increasing the transmission power beyond the minimum required power level the required coverage area for the CTS message of the receiver can be considerably reduced. The significance of this capability is that for close by transmitter/receiver-pairs, the CTS message can be transmitted to cover the entire protection range without exceeding the maximum transmission power level allowed by the FCC regulations. As a result, for transmissions that originally require lower power levels, the collision rate can be significantly reduced due to the appropriate protection from their CTS messages that reach the appropriate ranges. Other advantages including that the power required and the blocked area (for other nodes to transmit or receive) can be better balanced, reaching a considerably better spatial reuse and energy consumption.

### D. Interference/Sensing-based Signaling: A Robust Signaling Approach

In the previous subsections we introduced several EIM techniques that can mitigate the interference problems without or with only minor changes to the IEEE 802.11/11e standard. However, to fully utilize the radio resources and harvest the power of multihop networking, a new MAC protocol or an extension to the MAC protocol of IEEE 802.11/11e is needed. In this and the next subsections, we introduce several powerful EIM techniques for tackling the interference, power-control, and QoS problems. In the following section, we will provide an example implementing several techniques and illustrating how they may work together.

### D.1 Collision Prevention (CP)

In this subsection, we first present a the CP paradigm for multiple access based on a special case of interference/sensing-based signaling.

The central idea of CP is simple yet powerful. In CP, we simply employ an additional level of channel access competition/allocation to reduce the probability of collisions, when desired, for control messages such as RTS, CTS, NAK, ACK, and OTS. As a result, RTS and CTS messages can be received by most or all nodes that should receive them so that most/all nodes can schedule appropriately and collision of data packets can be prevented; hence the name “collision prevention”. When the resultant protocol is appropriately designed, collision-free transmissions of control messages and data packets can be (virtually) guaranteed.

If centralized control is feasible (e.g., with the availability of access points or clusterheads), the additional level of channel access may be implemented based on reservation Aloha, polling (e.g., PCF-like mechanisms), or splitting algorithms. Adoption of these mechanisms is relatively straightforward and the details are omitted here. However, when fully distributed MAC protocols are desired as expected in typical networking environments, the protocol design becomes more challenging. In what follows, we briefly present such a fully distributed mechanism based on distributed multihop binary countdown (DMBC). More details for DMBC and the prevention of collisions due to hidden terminals can be presented in Section ??.

In DMBC, a node participating in a new round of DMBC competition selects an appropriate k-bit competition number (CN). To simplify the protocol description, we first assume that all competing nodes are synchronized and start competition with the same bit slot, and can sense the status of every bit-slots when they are not transmitting. In bit-slot i, i=1, 2, 3, 4, . . . , k of the DMBC competition, only nodes that survive all the first i-1 bit-slots participate in the competition. Such a surviving node whose i^{th} bit of its CN is 1 transmits a buzz signal to all the nodes within an appropriate range (e.g., radius R). A surviving node whose first bit is 0 keeps silent and senses whether there is any buzz signal during bit-slot i. If it finds that the bit-slot i is not idle, then it loses the competition; otherwise, it survives and remains in the competition. If a node survives all k bit-slots, it is a winner and can transmit its RTS, CTS, or other control messages. When there are no obstructions between nodes, then prioritized, almost fair, and collision-free/collision-controlled control/data packet trans-missions can be achieved based on the proceeding procedure. More precisely, when the ID numbers of nodes are unique among all their possible competitors and all competitors within a radius of R can hear each other, there can be at most one winner within a radius of R from the winner. As a result, none of the control messages to be transmitted will interfere with each other at any nodes within their transmission ranges.

Various other ways to utilize prohibitive signals for competition and collision prevention are possible. FIG. 5 illustrates such an alternative based on dual prohibition. Transmitters are prohibited by receivers with higher competition numbers (CNs) through prohibition signals in receiver prohibition slots; while receivers are prohibited by transmitters with higher CNs through prohibition signals in transmitter prohibition slots. Transmitters sense prohibition signals in receiver prohibition slots in order to know whether its intended receiver survived the competition; while receivers also sense prohibition signals in transmitter prohibition slots in order to know whether its intended transmitter survived the competition. The thresholds for sensing can change with slots to improve the performance. A unique feature of this subclass of collision prevention is that RTS/CTS messages may be omitted (and replaced) by dual prohibition without sacrificing performance much. When the transmission is in multicast or broadcast mode, the transmitter can also act on behalf of its receivers for sending all the prohibitive signals, while using different power levels in the two slots corresponding to the same bit in order to facilitate power control. Such an approach also works for the unicast mode, except that the efficiency for this combination can be improved.

### D.2 Coded Interference/Sensing-based Signals

In this subsection we transform the interference, which was considered as among the worst enemies for wireless communications, to be a novel and power tool for wireless communications.

Intermittent interference signals, possibly transmitted at appropriate power levels with other appropriate characteristics can be used to convey some information at the MAC layer even though they may not be decoded using the PHY-layer modulation hardware. For example, the prohibitive signals used in CP (or part of them) can be viewed as such “coded interference/sensing-based signals” where the CN (or part of it) is the code or information to be extracted. Such signals can then be used with functions similar to those of RTS, CTS, ACK, NAK, OTS, and other control messages.

This approach may be considerably more robust as compared with other approaches when the environment is hostile (e.g., with severe multipath fading while the transceivers in use do not have the capability to overcome its negative effects). As a result, control messages as well as the information contained in them may be replaced or conveyed by this kind of coded interference/sensing-based signals when those control messages do not work (well) or are not employed in the protocol. Moreover, RTS/CTS messages can be transmitted to sufficiently large “protection ranges/areas” (e.g., through spread-spectrum-based techniques), such interference/sensing-based signaling techniques may be employed to tackle the interference-range problems. However, whether this approach will be actually be deployed depends heavily on its performance and cost relative to its competitors, as well as whether other competing technologies such as spread-spectrum-based MAC techniques can mature in time and be implemented at low hardware cost.

### D.3 Interference/Sensing-based Signaling for Deferring

Interference/sensing-based signals can be used preceding the transmission of a data packet to replace the energy-consuming busy tone that lasts the entire data packet transmission duration. A receiver or transmitter can also periodically or semi-periodically (e.g., with random variation of the periods) transmit such interference/sensing-based signals to acknowledge the correct or erroneous reception of the previous data fragment and to defer nearby intended transmitter by EIFS or a prolonged deferring time (recognized or signified by the coded interference/sensing-based signals if supported). When such a technique is employed, the last piece of the interference/sensing-based signals should be appropriately placed so that other nodes will not stay idle unnecessarily. For example, it can be positioned around EIFS (or the prolonged deferring time) before the end of the data packet transmission so that other nodes may continue to transmit or receive almost right after the end of the reception/transmission of the data packet. As compared to conventional busy tone, the reduction in energy is pronounced in this technique when the data packet is large and power control is employed. Moreover, this technique only requires a single transceiver per node though dual transceivers can improve the performance.

In addition to the usages introduced in this chapter thus far, the interference/sensing-based signaling approach can also enable service differentiation, wireless collision detection with single transceiver per node, power control without signal strength measurements, as well as various other capability and services such as jamming a room or region.

### E. Advanced Techniques for Next-Generation MAC Protocols

In the previous subsections we introduced several EIM techniques that can mitigate the interference problems without or with only minor changes to the IEEE 802.11/11e standard. However, to fully utilize the radio resources and harvest the power of multihop networking, a new MAC protocol or an extension to the MAC protocol of IEEE 802.11/11e is needed.

In this subsection, we introduce several powerful EIM techniques for tackling the interference, power-control, and QoS problems. In the following section, we will provide an example implementing several techniques and illustrating how they may work together.

Differentiated Multichannel for Power Control, Quality, and Efficiency. To reduce control overhead for lower-power transmissions, we can limit the range of power levels that are allowed to be used for each channel in a multichannel environment. We refer to this strategy as the differentiated multichannel scheme.

In this scheme, medium/low-power transmissions are guaranteed to be protected by CTS messages. Moreover, this scheme does not rely on interference engineering or high-power CTS messages, considering reducing the control overhead. As a result, better link quality can be supported for such medium/low-power transmissions. This scheme can be combined with TDMA-like phasing, group scheduling or patching. Interference engineering may also be employed to enable CSMA-based transmissions of smaller data packets with RTS/CTS dialogues turned off.

Detached Dialogues: A Panacea to Shared-channel MAC Problems. In the detached dialogues approach (DDA), the reserved data packet duration is postponed by postponed access space (PAS) after the associated RTS/CTS dialogue or interference/sensing-based signaling. Moreover, all the control messages and the associated data packet can be detached from each other.

An example for detached RTS/CTS dialogue is shown in FIG. 18. This figure illustrate the detached dialogue approach with a single shared channel for both control messages and data packets. All the RTS, CTS, data packet, and ACK messages can be detached as the example. The RTS message specifies the dialogue deadline as 2 time units, the relative reception starting time as 3 time units, and the relative reception ending time as 4.5 time units.

When the detached dialogues-based technology is mature, this approach may become a desirable means for signaling since it naturally avoids some difficult problems or efficiently supports other mechanisms/approaches. It may also become a powerful tool, for example, for effectively differentiating service quality and quantity or providing QoS guarantees in a distributed manner.

MAC-layer Spread Spectrum Techniques for Interference Problems. Spread spectrum techniques may be optionally employed when appropriate in order to increase the coverage areas of the associated control messages and data packets/bursts for a given power level, or reduce the generated interference to other nodes for a required coverage area. Moreover, by appropriate employing spread spectrum techniques, the tolerance of a receiver (for a control message or data packet/burst) to interference from nearby nodes can be increased. This increases the robustness of the network, connectivity, quality of (TCP or real-time) applications, and so on. Combined with power control, spread spectrum techniques can enable effective interference engineering. There are also many other advantages for incorporating spread spectrum techniques at the MAC layer. For example, power control can be efficiently supported by grouping transmissions with similar power levels into a code channel as a special case of the differentiated multichannel scheme. This way the coverage areas for CTS message can be considerably reduced for lower-power transmitter/receiver-pairs.

When the hardware for supporting spread spectrum with adaptive spectrum factors and coding be/come reasonably cheap and mature, spread spectrum-based techniques can also solve various problems, even without requiring detached dialogues. However, spread spectrum-based techniques and detached dialogues-based techniques are not mutually exclusive. They can in fact work together and combine into an effective and strong scheme for multiple access in multihop wireless networks.

Higher-layer Techniques to Interference Prevention. Routing-based techniques, such as radius-oriented ad hoc routing (ROAR), selective table-driven routing, embedded routing, and other routing techniques, can be employed to avoid links with low quality or suffer the interference problems or high collision rates for any reason. This strategy is in spirit similar to the link-oriented prohibition-based patching approach, but is different in that no additional PPA-like coordination or special operations like iptable are required, and problematic links are avoided naturally using appropriate routing metrics and policy.

Similarly, mobile wireless-MPLS can also avoid problematic links and solve the interference problems naturally. A difference from the routing-based techniques is that desirable links and routing paths are maintained through wireless LSP to maintain based on local label without having to rely on IP addresses or global IDs. Clustering-based techniques that partition the space for dynamic and adaptive TDMA or negotiate between nearby clusterheads for polling schedules or group (i.e., cluster) schedules can also achieve similar effects. Such an approach is particularly desirable if clustering is also in place for other purposes such as routing or maintaining a hierarchical architecture.

### F. Future Use of the EIM Method and Techniques

The preceding evolutionary path is simply an example to give a flavor of the EIM MAC technology and the dynamics of MAC protocols in next-generation wireless networks. Various other scenarios or evolutionary paths are also possible.

We envision that the wireless MAC protocols will continue evolving with the maturity and emergence of technologies and user needs. The following is some possible scenarios. In 4^{th}-generation (4G) wireless systems (to be launched possibly in around 5-10 years in some countries) it is likely that wireless devices will be able to roam between wireless LANs and MANs based on IEEE and IETF standards and their extensions and cellular networks based on CDMA and OFDM (or multi-carrier CDMA). In 5^{th}-generation (5G) mobile systems (to be launched possibly in around 15-20 years), an integrated but extensible MAC protocol may be developed so that many important wireless platforms, including (multihop) cellular networks, wireless LANs/MANs, and ad hoc networks, can be efficiently accessed using a single wireless card at relatively low cost. In such environments, a consistent framework that allows various MAC and other techniques to coexist some time along the road will be desirable, and will be able to achieve better performance in the long run as compared to MAC protocols optimized for each stage of technologies without such visions in mind and then extended upon necessarity, as is done in current practice based on the conventional wisdom.

In the following sections, I disclose an EIM-based MAC scheme that employs a rich set of EIM features as an example to show how these techniques may work together to support and/or enhance each other. We explain in more details concerning the ranges/areas a control message should be transmitted, which will be associated with a sufficient power level rather than having to rely on a simplified mathematical model (such as free space propagation). We will also provide more details concerning the innovative detached dialogues approach.

### III. A MAC SCHEME BASED ON ADVANCED EIM TECHNIQUES

In this section, we present an advanced EIM-based MAC scheme called GAP to illustrate how some of the EIM techniques work in combination with each other.

GAP employs Group action, Area-based backoff control, and Prohibition-based competition; hence the name GAP. Detached dialogues, spread spectrum techniques, and individualized error control mechanisms are employed on a recommended, but optional, basis. FIG. 2 provides a timing diagram example for handshaking between a transmitter/receiver-pair A and B. As shown in FIG. 2, a successful handshaking in GAP typically consists of the signaling/scheduling phase, transmission phase, and error control phase.

### A. Detached Dialogues

In IEEE 802.11/11e and most previous RTS/CTS-based protocols, the RTS message, CTS message, data packet, and acknowledgement are transmitted continuously without being separated (except for the short interframe space (SIFS) in-between for turnaround between the receiving and transmitting modes). In GAP, however, we advocate to use detached dialogues, where the RTS message, CTS message, data packet, and acknowledgement associated with the same data packet transmission can all be optionally separated with or within specified/default times. When combined with appropriate accompanying mechanisms, detached dialogues can solve various problems including all the issues identified in Section ??.

In GAP, an RTS message either implies the use of a default dialogue deadline or specifies a desired dialogue deadline, where the specified relative dialogue deadline (DD) time T_{DD} is the maximum time allowed for the CTS message from the intended receiver to be received completely by the intended transmitter (since the last bit of the RTS message is received by the intended receiver). The RTS message requests for a data packet duration starting at packet lag (PL) time T_{PL} after the dialogue deadline plus a turnaround time for the intended transmitter. That is, the requested “relative” duration (at the receiver's and other nearby nodes' side) for the data packet transmission and reception is

(T_{DD}+T_{T}+T_{PL},T_{DD}+T_{T}+T_{PL}+T_{PT}),

after reception of the last bit of the RTS message (ny the receiver or a nearby node, respectively) where T_{T} is the turnaround time and T_{PT} is the requested packet transmission (PT) time. Note that relative times are specified so that synchronization is not required and the number of bits required for such specifications is reduced as compared to the use of absolute times. Moreover, the required duration for the receiver to be available and the duration for other third-party nodes to be interfered can then be specified with exactly the same relative time duration.

For example, if the CTS reply is not allowed to be detached for the requested packet scheduling, then the dialogue deadline is T_{DD}=T_{T}+T_{CTS}+2T_{UP}, where T_{CTS} is the transmission time for the CTS message and T_{UP} is the upper bound on the propagation delay between the transmitter-receiver pair. When the exact propagation delay between the transmitter-receiver pair is known, the exact value is used for T_{UP}; otherwise, the maximum propagation delay for the maximum coverage radius of the network or for the maximum transmission radius at the intended transmission power level is used for T_{UP}. The lengths of RTS, CTS, and acknowledgement messages are flexible in GAP. When the extension flag of a control message is set to 1, a larger-size format for the message will be used. The message size may be further extended by setting another extension flag within the extended format, and so on. As a result, when a default value is used, smaller control message formats are used, and appropriate extended formats are used only when necessary. In particular, when the CTS message is allowed to be replied till the last moment, then only one relative time (i.e., the time for the first bit of the packet transmission) needs to be specified. In this way, the control channel overhead can be reduced.

The rational for detaching these control messages and the associated data packet are five-folds. First, detached CTS messages allow the intended receivers to reply at a later time if they are available during the requested duration but are currently not allowed to reply with a CTS message. This avoids unnecessary RTS/CTS dialogue failures and thus reduce control overhead and channel access delay. Second, the flexibility resulted from (optionally) detached data packets naturally avoids the exposed terminal problem from existing. Similarly, it also supports efficient power-controlled transmissions and interference-aware medium access, which considerably improves radio channel utilization. Third, differentiating maximum/minimum allowed packet lag times for different traffic classes leads to a novel and effective tool for prioritization in ad hoc networks and multihop WLANs. This enables effective and efficient MAC-layer supports for differentiated service (DiffServ) and fairness. Fourth, by detaching acknowledgement messages, multicasting, power control and the exposed terminal problem can be supported or resolved without compromising reliability. Fifth, the third-party opinion (TPO) mechanism is enabled by detached dialogues without requiring dual transceivers per node or dual channels. It can in turn be used to enable the preemptive mechanism. combined with other differentiation mechanisms, almost independent hierarchical prioritization can be realized. Sixth, detaching the messages/packets during a handshaking and specifying the (postponed) packet transmission duration are necessary for reasonable radio utilization when propagation delays are nonnegligible relative to packet transmission times. Such situations may occur in future high-speed wireless networks with small packets or in wireless networks with large coverage ranges such as satellite networks and future mobile wireless MANs.

There are also various other advantages that may be achieved through the detached dialogues. In particular, spreading irrelevant RTS/CTS dialogues (requesting for an overlapping packet duration) over a longer time period may reduce the collision rate for control messages, mitigates the negative effects of control message collisions, and enables novel mechanisms such as the triggered CTS mechanism for achieving interference awareness without relying on busy tone or dual transceivers per node.

### B. Group Activation, Scheduling, and Competition

In the timing diagram example illustrated in FIG. 2, the first control message in the signaling/scheduling phase is a group activation control message transmitted by the intended transmitter A. Node A first employs a backoff control mechanism to count down to 0, and then gains the right to send the GA message. The backoff control mechanism in use can be based on area-based interactive backoff control (AIBC) or ARAB the backoff control mechanism for IEEE 802.11 or 802.11e, an appropriate backoff control mechanism proposed in the literature, or a future appropriate backoff control mechanism.

This GA message coordinates all active group members within the coverage area of the GA message by recommending a common schedule for data packet transmission/reception (e.g., between times t₁ and t₂ in the figure or with an overlapping time period). These group members should be able to (attempt to) transmit and/or receive concurrently without collisions (with reasonably high probability) as long as several ground rules are followed, such as conforming to the power levels or ranges of transmission power associated to the group and the individual group members or employing appropriate mechanisms like (sensitive) CSMA/CA or interference engineering, assuming that interference from nodes outside the group does not exceed their safety margin. Note that a node may also transmit the GA message after it successfully scheduled for a transmission or reception. However, in many cases, we prefer to have a larger postponed access space (PAS) between GA and the associated coordinated starting time t₁.

In a different scenario, the GA message may be initiated by nodes other than the first transmitter A, while node A may schedule for a coordinated time (t₁, t₂) (or a subset of it, a superset of it, or simply an overlapping period of time, depending on the policy) after receiving such a GA message. The information and instruction in a GA message may also be combined into an RTS or CTS message, especially when RTS and/or CTS messages are allowed to have flexible length. Such a GA message or an RTS/CTS message carrying the GA information can be relayed within certain limit such as before a certain deadline or a certain number of hops, if its coverage range can not be sufficiently large through other more efficient techniques such as spread spectrum. Although flooding is most robust, its overhead may not be tolerable. Alternatively, a spanning tree can be used to execute the required geocast relaying. This is especially desirable when such spanning trees have already been made available for higher layer functions such as routing or clustering. Note, however, that it is not mandatory for a node belonging to a group to schedule around the recommended time period. Note also that backoff time equal to 0 is allowed, especially when an optional prohibition-based competition mechanism is employed before the transmission of the GA message.

### C. RTS/CTS and Multiparty Dialogues

Following the GA message, GAP employs one or several RTS messages and one or several CTS messages to schedule for the transmission/reception. An RTS message may also announce the trans-mission schedule, the interference to be generated (at other nodes' locations) and/or other information so that other nodes can avoid reception during overlapping time, or estimate the additional interference to receive during the announced schedule. Note that the additive effect of multiple interfering signals is not linear so that some accompanying mechanisms or precautions need to be employed or made for the estimation.

An CTS message may also declare the reception schedule, the interference that it can tolerate (and the power levels allowed at other nodes' locations), and/or other information so that other nodes can avoid transmitting during overlapping time, or can estimate the power levels they are allowed to transmit during the announced schedule. Note that control messages and the associated data packets/bursts can be detached and separated by certain time between them. Note also that typically the NAV is only set for the scheduled period (possibly with some extension as safe margins for better protection). Otherwise, when the time between the first CTS message (and/or the first RTS message) and the scheduled transmission (reception) starting time is large, the radio resources will be considerably wasted.

In some scenarios, an additional third-party opinion (TPO) control message may be sent. For example, consider a nearby (irrelevant) intended transmitter C that requests (using an RTS message) for a transmission duration overlapping with the scheduled transmission from nodes A to B, at a power level that will collide with the scheduled reception. Then the receiver B may send object-to-sending (OTS) (a TPO message), to node C to block its transmission. Node C will then reschedule the transmission or lower the requested transmission power level. Some additional CTS messages may follow the first CTS message to update important information such as the new tolerable interference level. As a result, successful handshaking in GAP may requires more control messages, such as RTS, CTS, and TPO messages, during the signaling/scheduling phase. Also, after a number of unsuccessful RTS and CTS messages for the same packet, the handshaking may back off or be aborted.

By allowing such PAS to be relatively large, various advantages can be achieved, such as strong service differentiation capability, better supports for power control and interference-aware multiple access, as well as better scheduling. Such larger PAS also enables the group action approach to more efficiently coordinate many group members (e.g., through relaying or spanning-tree forwarding) and/or in larger region to react (such as scheduling, competing, or negotiating) at the same time or during overlapping times. Moreover, enabled by detached dialogues, TPO or OTS messages can be sent and received appropriately even when a node only has a single transceiver. On the other hand, for simplicity, setting NAV from the beginning may also be allowed, especially when the associated PAS is relatively small, for simpler devices, and/or when the traffic load is light.

### D. Prohibition-Based Collision Prevention

In GAP, control messages can be preceded with a prohibition-based competition phase. Such a mechanism when employed can reduce the collision rate of the associated control messages, and in turn reduce the collision rate of the data packets and bursts.

Prohibition-based collision prevention can take on many different forms and formats for the competition phase. Several examples are presented in FIGS. 2, 4, and 5. FIG. 2 illustrates the timing diagram for a successful handshaking in GAP where a separate control channel and a separate data channel are employed. The detached dialogues can considerably improve the spatial reuse when the prohibitive ranges/areas are considerably larger than the interference ranges/areas for data packets and bursts. FIG. 4 illustrates the prohibiting slots, declaration slot, and hidden terminal detection (HTD) slot for position-based prohibition. If a node receives a prohibiting signal before its own position for transmitting the prohibiting signal in a slot, it loses the competition. Candidate winners (a survivor that survived all prohibition slots) will transmit a declaration signal in the declaration slot. When there are mutually hidden terminals, there is a good chance that other nodes will detect multiple declaration signals that are not likely to be from the same source (according to certain criteria such as separation in time and the received signal strength). These nodes will then send an OTS signal to block the transmissions so that the candidates fail to become winners. FIG. 4a represents a scenario where there is only one candidate so that it successfully becomes a winner and gain the right for transmissions. FIG. 4b represents a scenario where there are two candidates within the prohibitive range/area of each other. Mutually hidden terminal detectors (which can be the receiver(s) or some irrelevant nodes within appropriate ranges) send an OTS signal in the HTD slot to block their transmissions.

Various other ways to utilize prohibitive signals to avoid collisions are possible. We can also use the CN (or part of it) represented by the prohibitive signals as “coded interference/sensing-based signals” to convey some useful information. For example, RTS, CTS, TPO, OTS messages, busy tone, and other messages and information may be replaced or conveyed by this kind of coded intermittent signaling when those control messages do not work (well) or are not supported.

### E. Other Accompanying Techniques

Individualized selective segmented (ISS) error control can be employed in GAP. In ISS, the acknowledgements are not necessarily made on the per-packet basis. Instead, during the error control phase, negative acknowledgement (NAK)-based implicit acknowledgement mechanism is employed in combination with other appropriate acknowledgement mechanisms, such as group acknowledgement, passive acknowledgement, and group-coordinated acknowledgement (based on the group action approach).

The acknowledgement mechanism used in ISS is adaptive to the QoS requirements of the associated packet/session, and can be adaptive to the traffic conditions and past history. A large data packet can be segmented, with each segment accompanied with an error control code such as CRC, possible also with an error correcting code. The only collided/unrecoverable segments are requested by the receiver for retransmissions selectively, rather than retransmitting the entire packet as in conventional error control schemes.

Other techniques from the previous section may also be employed. In particular, spread spectrum and power-control should be employed, if available, to better balance the resources consumed by different messages. Moreover, they may enable the control messages be transmitted to sufficiently large range to resolve the interference-range problems.

### F. Alternative Embodiments

There are lots of alternative embodiments possible. For examples, we can use single channel, dual channel, 3-channel or multichannel for the control and data channels with lots of different combinations. We can utilize interference/sensing-based signaling, sensitive CSMA with group action, spread spectrum-based techniques, wireless collision detection based on interference/sensing-based signaling such as an NCK code, and so on, to embody the presented method for respective advantages.

Also, prohibition mechanisms and detached dialogues can be optional or removed. The network can be synchronized or asynchronous, and so on. To reduce the overhead for prohibition-based competition, the group action may be employed. For example, in FIG. 11a, a group activation message is first transmitted by some node. Other group members may rebraodcast such a group activation message, possibly with modifications for the timing information etc. Group members that have something to transmit can then compete at the same time if so desired using the same group competition number (CN) (see FIG. 11b). In the following sections, we present more possible embodiments and more details for the invention.

### G. Description of an Additional Preferred Embodiment

In what follows, various aspects of the invention will be described in greater detail in connection with an exemplary embodiment. To facilitate better understanding of the invention, several components of the invention are described in terms of sequences of actions to be performed by elements in a plurality of communication devices. In the presented embodiment, the various actions could be performed by specialized circuits, by program instructions executed on one or more processors, or by a combination of both. We generally refer to such an element as a node. An appropriate subset of these techniques and mechanisms can be optionally employed and combined with others to realize the objectives and achieve respective advantages for the presented interference control method. Such combinations can be adaptive to the conditions of the environments, and changed through time based on optimization, heuristics, or other policies. Moreover, different nodes in a particular embodiment may utilize different combinations, if so desired, due to their limitations, available resources, preferences, current status, and the respective environment conditions where they are located. As a result, the various aspects of the invention may be embodied in many different forms, and all such forms are contemplated to be within the scope of the invention. However, to facilitate coexistence among a plurality of nodes, certain rules apply to restrict the permissible combinations, which can be very strict (e.g., almost uniform among all nodes) or relatively relaxed. Such rules are typically specified in the protocols, standards, regulations, or other policies the nodes follow, and can be further coordinated in a distributed manner as the efforts of a group of nearby nodes, in a centralized manner coordinated by clusterheads, elected coordinators, or a unit governing a wider range of other nodes.

### G.1 DPMA

In what follows, more details about an embodiment for DPMA and several associated techniques and mechanisms are presented. The central idea of DPMA is simple yet powerful. We mainly employ collision-free dual prohibition to replace the RTS and CTS messages in MACAW or IEEE 802.11 (as well as OTS messages if so desired). Since the prohibiting signals used in such competitions do not suffer from collisions, and collided transmissions of data packets can usually be prevented by the competition, several problems of IEEE 802.11 and other RTS/CTS-based protocols can be avoided naturally.

In DPMA, the keys (or called competition numbers) used for countdown competition may be composed of two optional parts: random part and ID part, hence the name random ID countdown. The random part is selected randomly but according to appropriate probability distributions (possibly taking into account priority and fairness requirements). When the ID part is absent, DPMA can trade off between control overhead and collision rate by appropriately selecting the length for the random part. Note that other types of keys may also be employed if so desired.

The ID part for the key uses one of the appropriate IDs maintained by the transmitter-receiver pair. When unique IDs are available, the collision rate of appropriately designed DPMA can be reduced to 0 under ideal mathematical models. Note that overlapping IDs should be avoided among all the competing pairs and groups in the vicinity. However, when the overhead for maintaining uniqueness or the required length for unique IDs cannot be justified, such IDs do not have to be absolutely unique all the time. Since the collision rate for data packets can be reduced and controlled to a probability very close to zero, DPMA is a multiple access method capable of collision control. Due to the characteristics of wireless channels and mobile networks, damage to data packets is still possible in reality so that an appropriate acknowledgement mechanism should be incorporated. However, since DPMA can reduce the collision rate to sufficiently low levels when desired, we may employ ACK mechanisms with lower overhead such as negative/implicit ACK, PING, or individualized selective segmented (ISS) error control. The hybrid, modifications, or other ACK mechanisms may also be used. A resultant embodiment changes the dialogues of RTS/CTS-based protocols from RTS/CTS/data/ACK to RIC, data, and ACK in DPMA, and will be referred to as random ID countdown with ACK (RICK).

### G.2 Collision Prevention in DPMA

DPMA is a power-controlled MAC method based on multiple access collision prevention (MACP) with group competition. Although complex group competition features are optional in DPMA, it is mandatory for each active transmitter/receiver-pair that uses dual prohibition to form a pairwise group. The various operations of group activation, group competition, as well as group scheduling can then be optional employed in DPMA when applicable and desirable. More details concerning such group operations will be presented in the following section. A transmitter or receiver may also use previous MACP mechanisms (with the required modifications for the new frame format) to access the channel without using dual prohibition if so desired. Protocols requiring all transmitters and receivers to use dual prohibition for unicasting are just a special subclass of DPMA.

A unique feature of DPMA is that transmitters and receivers send their prohibiting signals in different prohibition slots, which enable them to replace RTS and CTS messages while retaining the main functionality of the latter. The order for the corresponding slots for transmitters and receivers can be switched during the same competition round, but the same order must be used by all DPMA-based nodes. Different from BROADEN and CSMA/IC, the prohibiting signals of a transmitter do not have impacts on other transmitters, and the prohibiting signals of a receiver do not have impacts on other receivers. Instead, the prohibiting signals of DPMA transmitters are used to kill nearby receivers with smaller competition numbers, while the prohibiting signals of receivers are used to kill nearby transmitters with smaller competition numbers. In DPMA, the slot sizes and the safe margins within a competition round do not have to be the same. The prohibitive ranges (and thus the associated transmission powers and/or spread spectrum factors etc.) for transmitters are set to be the maximum interfered ranges for the associated data transmissions, while the prohibitive ranges for receivers are set to be the maximum interfering ranges in the network or at the current location. When power control and appropriate energy-aware routing protocols are employed, the typical prohibitive ranges for receivers are significantly larger than those for transmitters. To mitigate the additive prohibiting signal strength problem, the slot sizes for receivers can be set considerably larger than those for transmitters.

Also, the energy required for sending the prohibiting signal of a receiver may be significant as compared to that for sending the data packet (unless the differentiated channel scheme is employed). To mitigate this problem as well as the preceding problem for receivers, we can employ interference engineering to raise the transmission power and/or spreading factor for such data packets so that the prohibitive ranges for the associated receivers can be considerably reduced (see FIG. 7). Other approaches to mitigate the additive prohibiting signal strength problem including spreading spectrum techniques and higher safe margin for the first few competition slots.

Note that in a different embodiment for DPAM, the prohibiting signals from a receiver or transmitter can also be used to prohibit both nearby transmitters and receivers. Other combinations are also possible. For example, only the prohibiting signals from an intended receiver are used to prohibit both nearby intended transmitters and receivers, or only the prohibiting signals from an intended transmitter are used to prohibit both nearby intended transmitters and receivers.

### G.3 Advantages of Dual Prohibition

Based on the dual prohibition mechanism, power control supports can be naturally incorporated by applying appropriate transmission power levels. Also, the hidden and exposed terminal problems can be solved without relying on collision-prone RTS/CTS messages. Moreover, RICK does not rely on the hidden terminal detection mechanism or group competition to resolve such problems (so that the minimum pairwise form of group competition suffices). An important advantage of RICK is that the prohibitive range/radius is considerably reduced as compared to previous MACP protocols such as CSMA/IC and MACP/HTD. This is particularly important when the path loss factor is high. For example, the prohibitive radius for previous MACP protocols is typically the sum of two radii (i.e., the coverage radius and interference radius). When the path loss factor is 4, the required power level is increased by a factor of 81, assuming the same receiving threshold is required and an interference radius approximately doubles the associated data coverage radius. Such power levels may be prohibitively high even if somewhat lowered by employing certain techniques.

### G.4 Fairness and Prioritization in RICK

In DPMA, a transmitter/receiver-pair that has been treated unfairly or has a higher-priority packet will use more favorable probability distributions to select the random parts of their CNs (i.e., which tend to generate a larger value). Retrial with a new

CN does not need to invoke a new (pairwise) group competition. Instead, a single group competition dialogue can schedule several possible rounds to participate in, and the CNs to use. This way the overhead can be reduced. Multiple IDs may also be used in DPMA, and higher-priority packets and unfairly treated transmitter/receiver-pairs will use a policy to select IDs with larger values when appropriate. A feedback mechanism and a dynamic control algorithm are typically employed for prioritization and fairness control. For DPMA based on prohibition-based dual prohibition (see a following subsection), the priority and improvement to fairness can be implied by the probability distribution used to randomly select the positions for prohibiting signals. However, the random selection is redone for every slot-pair, possibly with different probability distribution to optimize the performance.

### More Description of the Invention and More Preferred/Alternative Procedures for Embodiments

In the following sections, more details or aspects for the description of the invention and more preferred or alternative procedures for embodiments (of various phases, mechanisms, or aspects of the invention) will be presented.

### IV. GAPDIS: A RICH-FEATURED EIM SCHEME

In the embodiment described herein, we consider a MAC protocol followed by all nodes in a plurality of wireless communication devices. For simplicity, this exemplary protocol is relatively restricted in terms of the flexibility to optionally use an optional mechanism.

This protocol embodiment comprises of Group action, Area-based backoff control, Prohibition-based competition, Detached dialogues, Implicit acknowledgement, and Spread spectrum techniques; hence the name GAPDIS. FIG. 2 provides a timing diagram example for handshaking between a transmitter/receiver-pair A and B. In some scenarios, an additional third-party opinion (TPO) control message may be sent by the receiver to a nearby (irrelevant) intended transmitter C if node C used a sender information (SI 52) control message to request for a transmission duration at a power level that will collide with the scheduled reception at node B. Some additional receiver information (RI 54) control message may also be added to update the sender information such as tolerable interference level. As shown in FIG. 2, a successful handshaking in GAPDIS comprises of the signaling/scheduling phase, transmission phase, and error control phase. A successful handshaking in GAPDIS may requires more SI 52 messages, RI 54 messages, and TPO messages during the signaling/scheduling phase. Also, unsuccessful handshaking may be aborted.

In the timing diagram example illustrated in FIG. 2, the first control message in the signaling/scheduling phase is a group activation (GA 50) control message transmitted by the intended transmitter A. Node A first employs a backoff control mechanism to count down to 0, and then gains the right to send the GA 50 message. The backoff control mechanism in use can be the presented area-based interactive backoff control (AIBC) or ARAB mechanism, the backoff control mechanism for IEEE 802.11 or 802.11e, an appropriate backoff control mechanism proposed in the literature, or a future appropriate backoff control mechanism. This GA 50 message coordinates all active group members within the coverage area of the GA 50 message by recommending a common schedule for data 56 packet transmission/reception (e.g., between times t₁ and t₂ or with an overlapping time period). These group members should be able to transmit and/or receive concurrently without collisions (with reasonably high probability) as long as their transmissions conform to the power levels or ranges of transmission power associated to the group and the individual group members, assuming that interference from nodes outside the group does not exceed their safety margin. Note that a node may also transmit the GA 50 message after it successfully scheduled for a transmission or reception. However, in many cases, we prefer to have a larger postponed access space (PAS) between GA 50 and the associated coordinated starting time t₁. In a different scenario, the GA 50 message may be transmitted by nodes other than A, while node A may schedule for a coordinated time (t₁, t₂) (or a subset of it, a superset of it, or simply an overlapping period of time, depending on the policy) after receiving such a GA 50 message. Such a GA 50 message may also be combined into an SI 52 or RI 54 message, especially when SI 52 and/or RI 54 messages are allowed to have flexible length. Note that it is not mandatory for a node belonging to a group to schedule around the recommended time period. Note also that backoff time equal to 0 is allowed, especially when an optional prohibition-based competition mechanism is employed before the transmission of the GA 50 message. More details, alternative embodiments, as well as more specialized embodiments concerning the presented group action mechanism and alternatives/options for the mechanism can be found in later sections.

Following the GA 50 message, GAPDIS employs one or several SI 52 messages and one or several RI 54 messages to schedule for the transmission/reception. An SI 52 message may also announce the transmission schedule, the interference to be generated (at other nodes' locations) and/or other information so that other nodes can avoid reception during overlapping time, or estimate the additional interference to receive during the announced schedule. An RI 54 message may also declare the reception schedule, the interference that it can tolerate (and the power levels allowed at other nodes' locations), and/or other information so that other nodes can avoid transmitting during overlapping time, or estimate the power levels they are allowed to transmit during the announced schedule. Note that control messages and the associated data 56 packets/bursts can be detached and separated by certain time between them. Note also that typically the NAV is only set for the scheduled period (possibly with some extension as safe margins for better protection). Otherwise, when the time space between the first RI 54 message (and/or the first SI 54 message) and the scheduled transmission (reception) starting time is large, the radio resources will be considerably wasted. By allowing such postponed access space (PAS) to be relatively large, various advantages can be achieved, such as strong service differentiation capability, better supports for power control and solving interference problems, as well as better scheduling. Such larger PAS also enable the group action approach to more efficiently coordinate many group members and/or in larger region to act (such as schedule or compete) at the same time or during overlapping times. Moreover, enabled by DDA, TPO or OTS 64 messages can be sent and received appropriately even when a node only has a single transceiver. On the other hand, for simplicity, setting NAV from the beginning may also be allowed, especially when the associated PAS is relatively small and/or when the traffic load is light. Our approach allowing detached control messages and the associated data 56 packet, burst, or its fragments is referred to as the detached dialogues approach (DDA). An embodiment of DDA will be presented in the following subsection. More details, alternative embodiments, as well as more specialized embodiments and alternatives/options for the mechanism can be found in later sections.

In GAPDIS, control messages are preceded by a prohibition-based competition mechanism. Such a mechanism can reduce the collision rate of the associated control messages, and in turn reduce the collision rate of the data 56 packets and bursts. Several examples and embodiments are presented in FIGS. 3, 4, and 5. FIG. 3 illustrates the timing diagram for a successful handshaking in GAPDIS when a separate control channel and a separate data channel are employed. The detached dialogues can considerably improve the spatial reuse when the prohibitive areas are considerably larger than the interference areas for data 56 packets and bursts. FIG. 4 illustrates the prohibiting slots, declaration slot, and HTD slot for position-based prohibition. If a node receives a prohibiting signal before its own position for transmitting the prohibiting signal, it loses the competition. Candidate winners (that survived all prohibition slots) will transmit a declaration signal in the declaration slot. When there are mutually hidden terminals, there is a good chance that that other nodes will detect multiple declaration signals that are not likely to be from the same source. These nodes will then send a signal to block the transmissions so that the candidates fail to become winners. The upper figure represent a scenario when there is only one candidate and it successfully becomes a winner and gain the right for transmissions. The lower figure represent a scenario when there are two candidate within their prohibitive areas, and some other nodes send a signal in the HTD slot to block their transmissions. Various other ways to utilize prohibitive signals to avoid collisions are possible. FIG. 5 illustrates the prohibiting slots for dual prohibition. Transmitters are prohibited by receivers with higher competition numbers (CNs) through prohibition signals in receiver prohibition slots; while receivers are prohibited by transmitters with higher competition numbers (CNs) through prohibition signals in transmitter prohibition slots. Transmitters sense prohibition signals in receiver prohibition slots in order to know whether its intended receiver survived the competition; while receivers also sense prohibition signals in transmitter prohibition slots in order to know whether its intended transmitter survived the competition. The thresholds for sensing can change with slots to improve the performance. RTS/CTS messages may be omitted (and replaced) by dual prohibition without-sacrificing performance much. We can also use such “interference-based signaling” to convey some useful information. For example, SI 52, RI 54, TPO, RTS 60, CTS 62, OTS 64, messages, busy tone, and other messages and information so on may be replaced or conveyed by this kind of interference-based signaling when those control messages do not work (well) or are not supported. More details, alternative embodiments, as well as more specialized embodiments and alternatives/options for the mechanism can be found in later sections.

In GAPDIS, the acknowledgements are not necessarily made on the per-packet basis. Instead, during the error control phase, NAK 58-based implicit acknowledgement is employed in combination with other appropriate acknowledgement mechanisms, such as group acknowledgement, passive acknowledgement, and group-coordinated acknowledgement (based on the group action approach). More details, alternative embodiments, as well as more specialized embodiments and alternatives/options for the mechanism can be found in later sections.

In GAPDIS, spread spectrum techniques may be optionally employed when appropriate in order to increase the coverage areas of the associated control messages and data 56 packets and bursts for a given power level, or reduce the generated interference to other nodes for a required coverage area. Moreover, by appropriate employing spread spectrum techniques, the tolerance of a receiver (for a control message or data 56 packet/burst) to interference from nearby nodes can be increased. This increases the robustness of the network, connectivity, quality of (TCP or real-time) applications, and so on. Another important advantage is to enable interference engineering, which appropriately engineer the interference generated for other nearby nodes (and thus changing the maximum interfered range for a given interference threshold) or the interference tolerable at the receiver (and thus changing the maximum interfering range for a given interference threshold). This way the coverage area for control messages and/or the prohibitive area for competition can be considerably reduced if so desired. As a result, the power required and the blocked area for other nodes to transmit or receive can be better balanced, reaching a considerably better spatial reuse and energy consumption. Power control may be incorporated for engineering such parameters. We refer to this approach as interference/power control/engineering. FIG. 6 illustrates the change of required coverage area for RTS 60 and CTS 62 messages (which are special cases of SI 52 and RI 5 messages, respectively) when the transmission power or spread factor for a data 56 packet is increased. FIG. 7 illustrates the change of required prohibitive area for a receiver-initiated competition mechanism when the transmission power or spread factor for a data 56 packet or RTS 60 message is increased. Other appropriate techniques may also be incorporated for engineering interferences. There are many other advantages for incorporating spread spectrum techniques at the MAC layer. For example, power control can be efficiently supported by grouping transmissions with similar power levels into a code channel. This way the coverage areas for RI 54 message can be considerably reduced for lower-power transmitter/receiver-pairs. More details, alternative embodiments, as well as more specialized embodiments and alternatives/options for the mechanism can be found in later sections.

### V. BASIC OPERATIONS FOR A DDA-BASED SICF

In this section we describe an EIM-based Sender-initiated Interference Coordination Function (SICF) which employs distributed differentiated multiparty detached dialogues (DDMDD), a special case of the detached dialogues approach (DDA).

SICF employs the RTS/CTS 62 dialogue to schedule the intended transmissions in ad hoc networks and multihop wireless LANs as in MACA, MACAW, and CSMA/CA or IEEE 802.11. The main difference in SICF is that the RTS 60 and CTS 62 messages contain additional timing information concerning the requested or approved time slot. Note that in DDMDD the time axis is not required to be slotted though we use the term “packet slot”. When different PHY channels are used for a data 56 channel and the associated control channel(s) (based on frequency division control channel (FDCCH)), wireless stations (nodes) are not required to be synchronized; when the same PHY channel is used for the data 56 channel and the associated control channel(s) (based on time decision control channel (TDCCH)), nodes only need to be roughly synchronized so that control messages are transmitted within the boundary of an appropriate control interval.

There are a set of DDMDD parameters T_{MP,i}, which are the maximum postponed-access (MP) space for class i packets, where typically 0≦T_{MP,i}_{₂}≦T_{MP,i}_{₁} if i₁ has priority higher than i₂ (i.e., i₁<i₂). Before a node transmits an RTS 60 message associated with a class-i packet, it chooses an appropriate postponed access space Tₚₐ, Tₚₐ≦T_{MP,i} for the intended transmission, according to its schedule as well as the time slots available at the receiver if this information is known. The node then transmits its RTS 60 message in the control channel requesting to reserve a packet slot starting at Tₚₐ time units after the expected completion time of this RTS/CTS 62 dialogue.

FIGS. 13 and 14 illustrate an example for RTS/CTS 62 dialogues with the presented postponed access mechanism. FIG. 13 illustrates a timing diagram for example DDMDD dialogues. The relative locations between Nodes A, B, C, D, and E are presented in FIG. 12. In this example, the control channel and data channel are separated, but a node only has a single transceiver so it cannot receive and transmit at the same time. The RTS, TPO, and CTS messages are transmitted in the control channel, where the letters in the squares are the addresses of the intended receivers, and the numbers are the postponed access spaces (PASs).

FIG. 14 illustrates an operations of DDMDD based on TPO. The intended transmitter A sends an RTS message via the control channel to the intended receiver B. The intended receiver B replies to A with an ATS message if the channel will be available. Consider another node C that is not blocked by the DTR message of the scheduled receiver B. If node C intends to send a packet to D, it sends an RTS message to all the nodes within its interference or protection area. The scheduled receiver B then replies to C with an TPO (or called OTS) message via the control channel, if the request conflicts with its scheduled reception. Therefore, the reception scheduled for receiver B will not be collided even if C does not receive the DTR message from B.

There can also be a set of DDMDD parameters T_{mP,i}, which are the minimum postponed-access (mP) space for class i packets, where typically 0≦T_{MP,i}_{₁}≧T_{MP,i}_{₂} if i₁ has priority higher than i₂ (i.e., i₁<i₂).

All active nodes within the protection area or called protection area of the intended transmitter that receive the RTS 60 message record the temporary reservation in their local scheduling tables. Note that the protection area for a control message is the area (not necessarily in a round shape or even continuous) within which nodes are supposed to receive the associated message (typically in a best-effort manner) according to the policy in use. For example, the protection area for an RTS message may be defined as the area (or locations) within (at) which a node with a certain hardware requirement (such as typical or minimum sensitivity) will sense the interference of the associated data packet with strength above a certain threshold (decided by the protocol or the intended transmitter that transmits the RTS message). As another example, the protection area for a CTS message may be defined as the area (or locations) within (at) which a node with certain antenna that transmit at a certain power level (e.g., the maximum power level the node may transmit for its data packets) will generate interference with strength above a certain threshold (decided by the protocol or the intended receiver that transmits the CTS message). Assuming a free space, for RTS 60 and CTS 62 messages associated with unicasting (i.e., single receiver), the protection areas have radii P_{RTS}≧I_{TRP}+(S_{T}+S_{R}+Sₘₐₓ)×Tₚₐ, and P_{CTS}≧Iₘₐₓ+(S_{R}+Sₘₐₓ)×Tₚₐ, respectively, where Iₘₐₓ is the maximum interference radius for data 56 packet transmissions in the network, I_{TRP} is the interference radius (e.g., twice the current distance between the transmitter-receiver pair), S_{T} is the average moving speed of the intended transmitter from transmission of the control message to the associated data 56 packet transmission, S_{R} is the average moving speed of the intended receiver from transmission of the control message to the associated data 56 packet transmission, and Sₘₐₓ is the maximum moving speed of potential receivers in the network. Note that we use the interference radii I_{TRP} and Iₘₐₓ instead of the associated transmission radii in order for EIM to be interference aware and solve the IHET problem. Note also that the above notions are provided to better visualize the protection areas/ranges required for a control message. In general propagation model, an interference or protection area may not be a circle. In such cases, we simply use an appropriate power level that covers all/most positions of the corresponding protection area. When the remaining tolerable interference level is reduced below a threshold, the receiver may have to retransmit a CTS message. We refer to such a mechanism as the triggered CTS mechanism. The protection range/area for the triggered CTS message may be increased so that the required power level is increased. FIG. 8 shows a timing diagram for handshaking using the detached dialogue approach. It indicates the different power levels for RTS and CTS messages due to their different protection ranges/powers in order to satisfy sufficient coverage marks (e.g., cover 95% of nodes within their maximum interfering range and maximum interfered range, respectively). The triggered-CTS mechanism is employed when the change exceeds a certain threshold according to a policy. Although optimization of such threshold or policy is nontrivial, heuristic approaches can be used for such purposes as well as the selection or adaptation of parameters for various other mechanisms. Note that the transmission power level for the second CTS message is increased since the tolerable interference level is reduced so that the coverage range for the second CTS message has to be increased.

As an alternative or an accompanying technique, spread spectrum with larger spreading factor may be used to reduce the required power level and the interference to be generate (see FIG. 9). FIG. 9 illustrates a timing diagram for handshaking using spread spectrum scheduling (S³) techniques. The detached dialogue approach is not employed. By using appropriate power levels and spreading factors, the tolerable interference and generated interference can be engineered so that radio efficiency can be increased and various problems naturally do not exist. In fact, using such an approach, various problems can be resolved without having to rely on detached dialogues. This is a reason why DDA is also optional in EIM. To enable other nodes to estimate the interference to be generated by the sender of an RTS message or the tolerable interference for the sender of an CTS message, the variable-power declaration mechanism may be employed (see FIG. 10). Some issues associated with larger transmission radii for control messages have also been discussed in the cited China patent application.

The maximum postponed access spaces can be limited to the time required for several data 56 packet transmissions so that the delay of DDMDD will not be considerably increased and the throughput will not be degraded in the presence of mobility. Note that the postponed access space may be used to schedule the next data 56 packet only, rather than reserving for packet slots periodically as in MACA/PR, so we do not assume constant-bit rate traffic and DDMDD can work efficiently in the presence of bursty traffic and high mobility. However, multiple packet durations and possibly periodical packet durations may also be scheduled in DDMDD.

Note that when there are available slots with small PASs, they can be chosen so that the delay of DDS will not be increased and the throughput will not be degraded in the presence of mobility. Also, when large PAS is not desirable in a networking environment, the nodes can simply set it to zero or a small value. Moreover, the maximum PASs can be limited to the time required for several data 56 packet transmissions. DDS enables the prior scheduling mechanism and the multiple scheduling mechanism to avoid queuing delay accumulation along a multihop path. Such effect and the higher success rate for RTS/CTS 62 dialogues of high-priority packets can in fact reduce the end-to-end delay in ad hoc networks and multihop wireless LANs.

In the prior scheduling mechanism, a probe can be sent from the source to the destination for a high-priority packet or session to request for data 56 packet slots at intermediate nodes. As soon as the data 56 packet slot is reserved successfully at an intermediate node A (e.g., from t₁ to t₂), the probe can be forwarded to the downstream node B to request for another data 56 packet slot that immediately follows the data 56 packet slot at the upstream node (e.g., from t₂ to t₃). As a result, the effective delay at the downstream node B can be as small as 0 (or a very small value for the turn-around time etc.). Since a packet slot can be scheduled before the node receives the data 56 packet to be transmitted, we refer to this mechanism as “prior scheduling”.

In the multiple scheduling mechanism, the j^{th} packet in the class-i queue can start its scheduling before the first j-1 packets ahead of it are all scheduled and transmitted. Supports for this mechanism is important for DDS-based networks. Otherwise, a large PAS will block the scheduling of packets behind it in the same queue, leading to large delay and low throughput.

When an intended receiver receives an RTS 60 message from its intended transmitter, it looks up its local scheduling table to determine whether it will be able to receive the intended packet. If so, the intended receiver sends a CTS 62 message to the intended transmitter and all nodes within the protection area P_{CTS}. If the intended transmitter receives the CTS 62 message from its intended receiver, it transmits the data 56 packet during the scheduled data 56 packet slot. Finally, an implicit acknowledgement is employed for low-overhead reliable unicasting.

In order to support power control and efficient spatial reuse, we may employ the variable-power compact spatial reuse (VPCSR) scheme for EIM. VPCSR is based on the variable-power CTS 62 (VP-CTS) mechanism, where an intended receiver send mini-messages, declaration pulses, or other signals at decreasing power levels following its initial Agree-to-send (ATS) message. More details concerning VP-CTS and implicit acknowledgement mechanisms will be presented in subsections VIII-C.2 and VIII-D, respectively.

### VI. PAS-BASED DIFFSERV SUPPORTS IN DDMDD

By allowing larger maximum allowed PAS for higher-priority traffic, the service quality and quantity for higher-priority traffic can be considerably improved. We can also allow smaller minimum allowed PAS for higher-priority traffic to enhance service differentiation. Other advantages may be achieved, for example, by virtually avoiding lower-priority traffic to compete with higher-priority traffic, especially when preemption is allowed (e.g., based on TPO or OTS 64 message). More details, alternative embodiments, as well as more specialized embodiments and alternatives/options for the mechanism can be found in other sections.

### VII. PRIORITIZED kᵢ-ARY COUNTDOWN (PKC)

In this section we present more details for PKC, which is a possible embodiment for (part of) the prohibition part of MACP, GAPDIS, DDMDD, EIM, and the interference/sensing-based signaling approach.

To facilitate successful delivery of packets for admitted reservation or to provide timely delivery of packets for real-time traffic, the MAC protocol in use should make sure that RTS/CTS 62 dialogues (or CTS/RTS 60 dialogues in RICF) can be completed in time and data 56 packets are not collided repeatedly. Differentiation between the access rights of different traffic categories and control of the collision rates for RTS/CTS 62 messages and data 56 packets are useful tool to achieve these goals.

The central idea of PKC is simple yet powerful. We simply employ an additional level of channel access to reduce the collision rate of RTS/CTS 62 messages. The collision rate for data 56 packets can in turn be controlled. In this section, we employ such a distributed PKC mechanism.

PKC is an optional mechanism for EIM to facilitate distributed collision control, where the collision rate and overhead can be controlled by choosing several parameters. Note that low collision rate through collision control is critical to the interference awareness of DDMDD under heavy load since DDMDD requires most control messages to be recorded for the calculation of interference levels and tolerance to be sufficiently accurate in most cases.

A. The kᵢ-ary Countdown Mechanism

In PKC, a node participating in a new round of kᵢ-ary countdown competition selects an appropriate competition number (CN). A CN may comprise of 3 parts: (1) priority number part, (2) random number part (for fairness and collision control), and (3) ID number part (for collision-free trans-missions if so desired). To simplify the protocol description in this application, we assume that all CNs have the same length and all competing nodes are synchronized and start competition with the same digit-slot.

PKC can be realized with segmented black burst (SBB) or location-based coding (LC). At the beginning of the distributed kᵢ-ary countdown competition, a node whose CN has value x₁>0 for its first digit transmits a “pulse signal” to be detectable by all the nodes within the competition range. during the first k₁-slot competition segment of the PKC competition period. The radius for the competition range is equal to R_{protection}+R_{interference,max}, where R_{protection} is the protection radius for the associated control message and R_{interference,max} is the maximum interference radius in the network. In SBB, the pulse signal lasts from the first unit (if x₁>0) till the x₁^{th} unit; while in LC the pulse signal always has length equal to one unit (if x₁>0) and is inserted in the x₁^{th} slot of the first competition segment. If a node detects a pulse signal after it becomes silent, then it loses the competition and retry in a future competition period. Otherwise, it survives and remains in the competition.

In kᵢ-slot competition segment i, i=2, 3, 4, . . . , n, only nodes that survive all the first i-1 competition segments participate in the competition, where n is the number of digits in the CN. Such a surviving node whose i^{th} digit is xᵢ>0 transmits a pulse signal of length xᵢ in SBB or during the i^{th} slot in LC. If a node detects a pulse signal after it becomes silent, then it loses the competition; otherwise, it survives and remains in the competition. If a node survives all n competition segments, it becomes a winner and can transmit its RTS, CTS, and/or other control message(s) in the time slot and channel corresponding to the competition period. When the CNs are unique within the competition range of the winner, it is guaranteed that it is the only winner within the range so that all nodes within its protection area can receive the transmitted control message(s) without collision; by controlling the probability for the largest CN within a typical competition range to be unique, the collision rates for control messages and data 56 packets are controllable.

### B. PKC Supports for Differentiated Service

In PKC, prioritization is supported in two ways. The first approach simply uses different values for the priority number parts of CNs; while the second is realized by using different distributions for the assignment of the random number parts of CNs. The prioritization capability of PKC is then utilized to support effective service differentiated and adaptive fairness. In PKC, the priority number part of a CN should be assigned according to the type of the control message and the priority class of the associated data 56 packets, as well as other QoS parameters (if so desired), such as the deadline of the data 56 packet, the delay already experienced by the control message or data 56 packet, and the queue length of the node. For example, a CN in prioritized random countdown (PRC) can be composed of two 3-ary digits for the priority number part and four 3-ary digits for the random number part. Then all CTS 62 messages and acknowledgement messages of RTS/CTS 62 dialogues can be assigned (22)₃ for the priority number parts of their CNs (i.e., the highest priority). An RTS 60 message for a class-i data 56 packet is assigned (x₁, x₂)₃=8−i for the priority number part.

### C. PKC Supports for Adaptive Fairness

In PRC and prioritized random ID countdown (PRIC), we need to pick a random number for a CN. To achieve adaptive fairness, nodes piggyback in Hello messages their own recent history concerning the bandwidth they uses, the collision rates for RTS/CTS dialogues, their data 56 packet collision rates, the current queue lengths, discarding ratios, and so on. All nodes gather such information from their neighboring nodes through Hello messages. If a node finds that the bandwidth it recently acquired is below average and its queue length is relatively large, it will tend to select larger random values for the random number parts of its CNs for the next few RTS 60 messages; otherwise, it will select relatively small values. In this way, nodes that happened to have bad luck and experienced more collisions, failure RTS/CTS 62 dialogues (e.g., due to blocking by transmitters near its intended receivers), or larger backoff can latter on acquire more slots to compensate its recent loss. On the other hand, nodes that have consumed more resources than its fair share will “thoughtfully yield” and give priority to other neighboring nodes. Note that when neighbors have nothing to send, such yielding nodes can still gain access to the channel so that the resources are not wasted unnecessarily. As a comparison, if we increase the sizes of contention windows (and thus backoff time) for such nodes, fairness may also be achieved, but resources will sometimes be wasted unnecessarily. Therefore, PKC can achieve fairness adaptively and efficiently for both short-term fairness and in the long round. As a comparison, IEEE 802.11/11e can achieve long-term fairness, but some nodes may starve for a short period of time.

More priority classes can be created based on the values of the random number parts. For example, the lowest priority class 8 can devote the first digit of the random number part for further prioritization so that is creates 9 additional priority subclasses, leading to 16 priority classes in the preceding example. Packets belonging to these new priority subclasses will experience higher priority for collisions due to their shorter “real” random number parts. But this is acceptable for lower priority classes.

### VIII. DETAILS FOR AN EMBODIMENT OF INTERFERENCE MANAGEMENT

Enabled by the detached dialogues approach, we can augment the conventional RTS/CTS 62 dialogue with a third-party opinion (TPO) mechanism without requiring dual or multiple transceivers per node (though dual or multiple transceivers per node may also be employed to enhance the performance or channel utilization).

An example for operations of the resultant dialogues is illustrated in FIG. 14. The intended transmitter A sends an RTS message via the control channel to the intended receiver B. The intended receiver B replies to A with an ATS message if the channel will be available. Consider another node C that is not blocked by the DTR message of the scheduled receiver B. If node C intends to send a packet to D, it sends an RTS message to all the nodes within its interference or protection area. The scheduled receiver B then replies to C with an TPO (or called OTS) message via the control channel, if the request conflicts with its scheduled reception. Therefore, the reception scheduled for receiver B will not be collided even if C does not receive the DTR message from B. DDMDD-based EIM can solve various problems and enable various functions in ad hoc mobile wireless networks, including interference-aware multiple access.

### A. The Request-to-send Message and Associated Mechanisms

In SICF, an intended transmitter first sends a Request-To-Send (RTS) message to all nodes (e.g., mobile hosts (MHs), access points (APs), and/or base stations (BSs)) within its interference range/area or a (possibly) enlarged region to be referred to as its protection range/area, rather than its coverage area/area only. The purposes of RTS 60 messages in SICF are (1) to inquire the receiver whether the interference at its current location (and possibly at its predicted future locations) will be low enough to receive its packet, possibly through the RTS 60 messages it has recently received and (2) to inquire other wireless stations (nodes) within its interference/protection area whether the intended transmission will collide with the packets that they are, or will be, receiving.

To reduce the delay and/or overhead for channel access, an intended transmitter can request for multiple packet slots, either in the same PHY channel or several different PHY channels. Also, in a multichannel ad hoc network, different PHY channel may have different transmission rates; even for the same PHY channel, the intended transmitter is also allowed to request for packet slots with different transmission rates (which have different error rates and transmission power requirements). For example, based on the specifications of IEEE 802.111a, there can be 8 PHY channels concurrently used, so that we can have 1 control channel and 7 data 56 channel. Note, however, that an SICF-based node only need a single transceiver since it does not need to listen to both the control channel and the data 56 channel(s) at the same time. As a result, in an RTS 60 message, the intended transmitter should specify the receiver ID(s), the requested duration(s) (possibly as an enlarged window for flexibility), and the PHY channel(s), so that the intended receiver and nearby nodes can response accordingly. Note that the intended transmitter can request for appropriate slots and channels according to the reception schedules of nearby nodes (see Subsection IX-C.2). There are limitations on the number, durations, and postponed access spaces for requested packet slots. Typically, a higher-priority session/packet has larger maximum allowable number, lengths, and postponed access spaces for the requested slots.

Note, however, that if the requested packet slots have different protection areas, they should be requested either in different RTS 60 messages, in an RTS 60 message sent to all the nodes within the maximum protection area among them, or in a multirange RTS 60 message (similar to a VP-CTS 62 message to be presented in Section IX-C.2. When more than one packet slot or an enlarged window is requested for one packet, it is mandatory for the intended transmitter to send another RTS 60 message (or sometimes more than one RTS 60 message) to announce the result of its request and release all the resources requested but not used, including the unused slots/channels and the slots that require a protection area or duration smaller than those originally used or requested by the first RTS 60 message. In addition to canceling unused reservations, such follow-up RTS 60 messages also serve the purpose of reconfirming the reserved resources to be used. If a nearby node did not receive the first RTS 60 message (possibly due to collisions of control messages), it then has a second chance to record the RTS 60 message, and more importantly, to send an TPO message if it has an intended reception with a conflicting schedule (see Subsection IX-B). An RTS 60 message also defers the transmission of control messages from nearby nodes when desired in order to facilitate the successful transmission/reception of follow-up control messages in response to its request.

Note that the RTS 60 message is only used to defer the control messages of nearby nodes and the intended reception of nearby nodes that receive the RTS 60 message, but is not used to defer the intended transmission of any nearby nodes. Note that if the interference/protection area of an intended transmission is larger than the maximum transmission radius of the transmitter, we may use a relayed geocasting mechanism to forward the RTS 60 message to all the nodes within its interference/protection area. We may also use other alternative mechanisms such as spread spectrum techniques or interference/sensing-based signaling to send the control messages to a larger range or area

### B. The Third-Party Opinion Message and Interference Awareness

To be interference aware, a node cannot rely on CTS 62 messages alone to determine whether a packet can be transmitted. In fact, any dialogue between the transmitter and receiver alone is not adequate. The reason is that a nearby third-party node outside may have a possibly conflicting scheduled reception. Even though the node is outside the transmission range (or an enlarged interference area) of the requested transmission, the additional interference caused by the requesting transmission may lead to collision for the scheduled reception (see FIG. 15). As a result, some kind of third-party dialogue is necessary for interference-aware multiple access. To solve this problem, we may employ the third-party opinion (TPO) mechanism to block such interfering request from nearby third-party nodes.

If a node has only one transceiver, as expected for ordinary nodes, the node listens to the control channel except when it is transmitting or receiving data 56 packets or is currently in a dormant mode. If the node receives an RTS 60 message but will be receiving a packet during a period of time that overlaps with at least one of the requested slot(s) and the estimate interference to be caused by the requested transmission is not tolerable, it informs the intended transmitter with an TPO message, and the intended transmitter has to backoff and request to send again at a later time. Since the intended transmitter is mostly likely unaware of the schedule of this node, the node can provide (the possibly missing part of) its local schedule along with the TPO message. The intended transmitter can specify its preference in its RTS 60 message indicating whether it chooses not to receive/record RTS 60 messages or does need such information when an unexpected conflict occurs.

Note that relayed unicasting is less expensive than relayed multicasting and is inevitable for the relay of TPO messages in some scenarios, so we do not discourage usage of this mechanism. If the intended receiver is not available to receive the packet or does not have buffer space, it can also inform the intended transmitter with an TPO message, although this is optional for unicast transmissions. Such TPO messages from an intended receiver can include a recommended schedule, part of its local schedule, and/or its buffer space. If the packet to be transmitted has reserved bandwidth at the network layer or has a higher priority and/or an approaching deadline (with relatively large penalty for dropping), the backoff time is increased relatively slowly after an additional failure attempt; otherwise, the backoff time is increased exponentially. If the reason for the intended receiver to reply with an TPO message is the lack of buffer space, it can initiate the dialogue by inviting the intended to transmit when the buffers become available.

Note that the implementation of TPO and associated mechanisms are optional for some/all nodes in SICF. Such nodes, however, are weaker in terms of the capability for them to protect their intended receptions/transmissions and to provide QoS guarantees.

There are several levels of supports for the TPO mechanism. If a node only has a transceiver, as expected in most future nodes, the node can only utilize TPO to block requests that conflicts with its scheduled reception, rather than its on-going reception. But this will still be effective as long as the postponed access spaces are sufficiently long. Otherwise, an on-going receiver should utilize a mobile agent residing at a neighboring buddy node to send TPO messages on its behalf. Also, a node with a single transceiver cannot stop transmission when its receiver detects a collision and sends it an TPO message, unless special mechanism is supported such as intermittent transmission or CDMA techniques.

### C. The Clear-to-Send (CTS) Mechanism

The Clear-To-Send (CTS) mechanism in SICF consists of two components: the Agree-To-Send (ATS) message and the Declare-To-Receive (DTR) mechanism. It is very different from the CTS 62 message and associated mechanisms in previous RTS/CTS 62-based protocols in order to tackle the heterogeneous terminal problem, where different nodes may have different maximum transmission radii and a node can transmit with different transmission radii according to the networking environments and the application requirements. ATS and DTR messages can be transmitted separately at different power levels, but can also be combined into a single message to reduce the control-channel overhead. In the follow subsections, we present the associated operations for ATS and DTR.

### C.1 Interference Awareness and Power Engineering

For a unicast transmission, the intended receiver replies the intended transmitter with an Agree-To-Send (ATS) message when it expects that it will be available to receive the packet during the requested packet slot. When multiple packet slots are requested in the RTS 60 message it receives, it should indicate the slots that will be available. More precisely, when an intended receiver receives the RTS 60 message from its intended transmitter, it looks up its local database for the RTS 60 messages it recorded (and/or using carrier sensing to check whether the channel is idle) to determine whether it will be able to receive the intended packet. If the data 56 channel will be available, the intended receiver sends an ATS to the intended transmitter and activate a DTR mechanism (see Subsection IX-C.2) announcing the territory (i.e., range and duration) within/during which other intended transmitters are forbidden to transmit. Otherwise, it sends an TPO to the intended transmitter (or simply ignores the intended transmitter as a multicast intended receiver if this is allowed in the SICF-based protocol in use).

Note that to be interference aware, a node cannot rely on individual RTS 60 and CTS 62 messages to determine whether it can receive or transmit a packet. The reason is that it is possible that a receiver is outside the transmission ranges (or enlarged interference areas) of all the other scheduled transmissions, but the additive interference caused by other scheduled transmissions will collide the intended reception (see FIG. 15). As a result, an RTS 60 message should be multicast to all nodes within a sufficiently large protection area, and these receiving nodes record the associated interference that will be caused by the requested transmission so that the interferences generated by different scheduled transmitters can be added together to determine whether an ATS can be sent.

For a unicast transmission, if the intended transmitter receives an ATS from the receiver and does not receive any TPO messages, the intended transmitter can start its unicast transmission at the scheduled time. Note that the transmitter can specify a short period of time for objecting nodes to send their TPO messages in the control channel, so that as long as that period is not idle (e.g., either a successful transmission or a collision), the transmitter knows that there may be a nearby node that objects to its transmission. FIG. 14 provides an example for the basic operations of DDMDD for unicasting.

For a multicast transmission, intended receivers do not reply with ATS messages when it thinks it is available to receive; instead, for reliable multicast, it is mandatory for an intended receiver to reply with an TPO message when it is not available to receive the intended packet. Then if the intended transmitter does not receive any TPO messages, it can then safely start its multicast trans-mission at the scheduled time.

When the estimated signal-to-noise/interference ratio (SNIR) for signal at the intended receiver is below the threshold, the RTS 60 request should either be rejected or the signal strength of the intended transmission must be increased. Such a strategy helps combat the noise, interference, and blocking by obstacles and can considerably increase the quality of wireless communications. Moreover, more packets may be transmitted than what is possible with a single transmission power level. We refer to this strategy as power engineering. Note, however, that higher transmission power means higher cost in terms of both energy and the interference generated by the intended transmission, so the allowed power level is limited by the cost affordable by the intended transmission. Moreover, for an intended transmission to be eligible for a new allocation, it should not cause the SNA of any other allocated receivers to drop below the associated thresholds. Otherwise the newly allocated transmission should be canceled in typical scenarios. Mechanisms for interference awareness become particularly important since power-engineered transmissions may generate larger interference, and the conventional RTS/CTS 62 dialogue will fail even for a single power-engineered transmission. FIG. 15b and FIG. 16 give several examples for power engineering.

### C.2 The Declare-to-receive (DTR) Mechanism

In this subsection, we employ the Variable-Power Clear-To-Send (VP-CTS) mechanism, which is the default DTR mechanism for DDMDD.

In VP-CTS, there are multiple protection areas/ranges (or power levels). A CTS 62 message is first sent by the intended receiver to all nodes within the largest protection area among them, and then several follow-up mini-messages are sent one-by-one to all nodes within the second largest protection area, the third largest protection area, and so on. This can be done by controlling the power levels carefully for these mini-messages. The first CTS 62 message and the follow-up mini-messages are collectively called an VP-CTS 62 message, which is a kind of DTR messages.

We may use the radius of the maximum interference/protection area allowed for data 56 transmissions as the largest protection area, but this is not mandatory. In each of the mini-messages, the radius for the corresponding protection area can either be recorded or implied (as specified in the standard). As a result, if a node receives mini-messages for protection areas 1, 2, 3, . . . , i, but does not receive mini-messages for the remaining protection areas i+1, i+2, . . . , k, then the node knows that it should not transmit a packet with interference/protection area larger than the radius for protection area i, but can transmit a packet with a protection area smaller than protection area i+1. If the node happens to be transmitting a packet that requires a protection area between protection areas i and i+1, it can either request for a nonoverlapping slot, or send an RTS 60 message to this intended node and ask for its agreement for using an overlapping slot and PHY channel. In the latter case, the node can transmit only when it receives an ATS message from this intended receiver, which referred to as the multi-ATS mechanism.

In the SR-CTS 62 mechanism, only a CTS 62 message is sent while no follow-up mini-messages are required. Such an SR-CTS 62 message may use the radius of the maximum allowed interference/protection area as the protection area, which is similar to previous RTS/CTS 62-based protocols. A major difference, however, is that a node that receives the CTS 62 message may still transmit during an overlapping period of time after confirmed by a multi-ATS mechanism. Another difference is that SR-CTS 62 may also use a certain radius that is larger than the protection areas required for the majority of transmissions from nearby nodes, or a protection area that is equal to or somewhat larger than the protection area required for the intended transmission. In both the VP-CTS 62 and SR-CTS 62 mechanisms, the ATS message can be combined with the CTS 62 message into a single message, if so desired, to reduce the control-channel overhead.

Similar to the TPO mechanism, the implementation of the DTR mechanism is optional for nodes if the TPO mechanism is mandatory, since its main functionality can be replaced by the TPO mechanism. DTR, however, may improve the network throughput by reducing the number of RTS 60 and TPO messages from repeated requests and objections, as well as reducing the probability for the collisions of data 56 packets caused by the collisions of RTS 60 and/or TPO messages. As a result, a node that implements DTR can better protect its receptions and improve its QoS-provisioning capability.

An example for the DTR mechanism is illustrated in FIG. 17. In this figure, the DTR mechanism is employed for a transmission from node A to node B. A CTS message is transmitted by node B at the power level p_{P} required for reaching a radius of P_{CTS}. Follow-up declaration pulses are transmitted at power levels ¾p_{P}, ½p_{P}, and ¼p_{P}, respectively. A nearby node can count the declaration pulses it receives to determine the maximum power level it can transmit without colliding the data packet reception at node B. For example, node C receives all 3 declaration pulses, so it cannot transmit during a packet slot overlapping with the one specified in the CTS message. Node D (or E) receives 2 (or 1, respectively) declaration pulses, and can transmit at power ¼p_{T} (or ½P_{T}, respectively) or lower during an overlapping packet slot, where P_{T} is the maximum power level allowed for data packet transmissions. Node F only receives the CTS message without any follow-up declaration pulses, and can thus transmit at power ¾p_{T} during an overlapping packet slot. Node G is outside the protection area from node B, and can transmit data packets at any allowable power level (e.g., p_{T}) during an overlapping period of time. Note that no specialized hardware is required by these nodes (e.g., for measuring signal strength to determine physical distance as in previous busy-tone-based power-controlled MAC protocols).

### D. The Implicit Acknowledgement (I-ACK) Mechanism

In DDMDD, a regular acknowledgement mechanism like the one in MACAW or IEEE 802.11 can be used for higher-priority packets. However, most packets in DDMDD have to use the implicit acknowledgement (I-ACK) mechanism or a at least the group acknowledgement (group-ACK) mechanism. The reason is that we want to solve the exposed terminal problem. We need an acknowledgement mechanism different from the conventional per-packet positive acknowledgement mechanism as in MACAW and IEEE 802.11. Otherwise, the acknowledgement messages for two nearby concurrent transmitters will collide with a high probability (which has been proved by our simulation programs). An additional advantage for I-ACK is that the control-channel overhead can be considerably reduced as compared to conventional per-packet acknowledgement mechanisms.

In DDMDD the I-ACK 58 mechanism is used for reliable unicasting and multicasting. The receiver in a transmitter-receiver pair replies to the transmitter with a negative acknowledgement (NAK) when it fails to receive the scheduled packet correctly; otherwise, it remains silent. When the intended transmitter receives the NAK, it sends RTS 60 within a time limit to schedule for a retransmission. If the intended transmitter with a reception in error does not receive an RTS 60 message for retransmission of that packets, it sends another NAK 58 with its transmitter ID and packet sequence number, until it receives the rescheduling RTS 60 message or until it timeouts.

If an intended transmitter does not receive any NAK within a specified period of time, it times out and discard the transmitted packet. Note that I-ACK 58 works correctly due to the fact that a receiver with erroneous reception will keep sending NAK 58 messages; hence silence from a receiver can be safely viewed as an “implicit acknowledgement”.

In group-ACK the receiver in a transmitter-receiver pair can reply to the transmitter with an ACK after one or more than one packet received, possibly in a piggyback manner. Moreover, acknowledgements for multiple packets may be piggybacked in a data 56 packet or included in a single control message if so desired.

### IX. AREA-BASED BACKOFF CONTROL

Before an RTS 60 message (or a CTS 62 message in RICF) can be initiated, the intended transmitter of the associated data 56 packet has to first count down to zero to gain its right for the transmission attempt. Control of the backoff times for countdown is critical to the network throughput and service quality.

In enhanced distributed coordination function (EDCF) of IEEE 802.11e, there are up to eight separate queues at a node, each for a different traffic category. The first packet in each queue counts down independently of each other. In the presence of a collision, the contention window (CWᵢ) for the associated traffic category i of the involved node is increased by its persistent factor (PFᵢ), while the CWⱼ, j≠i, for other traffic categories of the node is not affected, and the CWs of other nearby nodes that are not involved in the collision are not affected either. Although in IEEE 802.11e higher-priority traffic categories can have PFᵢ's smaller than 2, these PFs cannot be small. The reason is that the CWs of other traffic categories of a node and the CWs of other CWs in the vicinity are not increased, so the network will become unstable if the PFs are too small.

In this section, we present the area-based return-to-normal attempt-rate-control backoff (ARAB) scheme for differentiated backoff control in ad hoc MAC protocols. In ARAB, the CWs are controlled on a regional basis, rather than on a node-by-node basis or even on a per-class per node basis as in IEEE 802.11e. Higher-priority traffic can therefore has smaller PFs and be better protected from excessive lower-priority traffic.

### A. Regional Distributed Flow Control Enabled by ARAB

In ARAB, CWs are controlled based on a combination of estimated collision rate and attempt rate in the vicinity of a node. A node estimates the vicinal attempt rate (VAR) and the collision-to-attempt ratio (CAR), as well as the dropping ratio and other QoS parameters for each of its traffic classes. For example, VAR can be estimated as the percentage of time the channel is busy with control messages (excluding the time for data 56 transmissions if single channel is employed for both control and data 56 packets). As another example, CAR can be estimated as the collision rate of its recent CTS 62 receptions. Such CAR for CTS 62 messages, to be referred to as CTS 62-CAR, can be counted as the number of CTS 62 retrials recorded in the CTS 62 messages it successfully receives as in MACAW. CAR can also be approximated by the percentage of its failure RTS/CTS 62 dialogues if the number of CTS 62 retrials is not available in the CTS 62 messages.

If the observed VAR, CAR, and/or a composite measure are higher than the associated thresholds and the node has packets to transmit or receive, it will inform nearby nodes the need to increase their CWs. On the other hand, if the observed VAR and CAR are lower than the associated thresholds, a node may keep silent or indicate the possibility for nearby nodes to decrease their backoff times in its control/Hello messages. Note that the suggested adjustments can be associated with appropriate intensity and weights for different traffic categories and by different nodes. For example, if the current VAR for a node is considerably higher then the desirable value, it can indicate the need for nodes in the vicinity to considerably increase their backoff times, especially for lower-priority traffic categories. The adjustment can also be suggested in the form of “quota,” which indicates the reduction in the aggregate attempt rate for nearby nodes, while the relative increases for the CWs of different traffic categories is the jurisdiction of the node.

If a node receives many strong indications for considerably increasing the backoff times, it can suggest a larger adjustment for CWs, and associate a larger weight with its suggestion. If a node only receives prohibitive indications from nodes that are relatively far away, it can associate a smaller weight with its suggestion. A node will then decide how to adjust the CWs for its future and/or current intended transmissions based on its own opinion and the received suggestions from nearby nodes, hence the name “area-based”. A node calculates the average backoff time for its recent transmissions, and broadcasts it to nearby nodes. A node then determines its normal CWs according to its own and the received average CWs (e.g., as their weighted average).

The reasons that ARAB can in effect enable distributed and automatic flow control in the control channel or for control messages is twofold. The first obvious reason is that larger backoff times in a congested area lower the injection rates in that vicinity. The second reason is that larger backoff times for the first RTS 60 attempt reduce the probability for collisions. This in turn leads to a smaller number of RTS/CTS 62 dialogues required for a successfully transmitted data 56 packet, thus smaller attempt rate for control messages. As a comparison, the backoff times in IEEE 802.11 start with a small value and increase to an appropriate value exponentially after a few collisions. However, some radio resources would have been wasted due to the collisions and the delay is increased due to repeated RTS/CTS 62 dialogues.

### B. Interaction Between Different Traffic Categories

A node calculates the CW_{i,normal} for each of its traffic categories i according to its recent CWs and the respective queue lengths. In addition to responses to the preceding suggested adjustments, the unsuccessful RTS/CTS 62 dialogues of a node and other events in the vicinity also trigger the adjustment of its CWs. For example, for a low-priority traffic category i, an unsuccessful RTS/CTS 62 dialogue of the node will increase its CWᵢ by a factor of PF_{i,i} until it reaches CW_{i,max}, and increase its CWⱼ by a factor of PF_{i,j} for lower-priority categories j. A successful RTS/CTS 62 dialogue of the node decreases its CWᵢ to CW_{i,normal} rather than CW_{i,min}; hence the name “return-to-normal”. Additional successful RTS/CTS 62 dialogues of the node or nearby nodes can further decrease its CWᵢ and CWⱼ till CW_{i,min} and CW_{j,min} but at relatively slow rates, while an unsuccessful RTS/CTS 62 dialogue will increase its CWᵢ back to CW_{i,normal} if CWᵢ is smaller than CW_{i,normal}.

An unsuccessful RTS/CTS 62 dialogue of a node may increase the backoff times of other packets that are currently counting down by Δ_{i,j}. Furthermore, weighted fair countdown can be employed by suppressing the countdown of lower-priority packets when there is a collision for a higher-priority packet at the same node, or whenever there are higher-priority packets that are counting down. An unsuccessful RTS/CTS 62 dialogue of a nearby node may also increase the CWⱼ of the node by a factor of PF_{i,j}′ for j≧i, or increase the backoff times of packets that are currently counting down by Δ_{i,j}′, while a successful RTS/CTS 62 dialogue of a nearby node may decrease CWⱼ, if such information is available (e.g., indicated in RTS/CTS 62 messages as in MACAW). When the condition of a certain node k is considerably different from other nearby nodes (e.g., having more nearby competitors, near a source of noise, interfered by a Bluetooth device, equipped with an insensitive transceiver, or having less residual energy), a receiver-specific CW, CWᵢ(k), may be employed by nearby nodes for transmissions to this node k. By suppressing transmission attempts of lower-priority packets or nearby nodes, the backoff time for a high-priority packet may be decreased (instead of being increased) when the packet encounters a collision or when the node observes high CAR, high dropping ratio, or large queue length for its high-priority traffic categories. Moreover, a real-time packet with urgent deadline (e.g., to be dropped t time units later) can use a smaller CWⱼ(t), especially after a few retrials. However, for stability reason, the CWⱼ values will bounce back and increase if its CAR or nearby CARs become too high due to special traffic patterns and correlation.

### X. OTHER DDMDD DIFFERENTIATION MECHANISMS

### A. Differentiated QoS Parameters

Various other MAC-level parameters or mechanisms can also be differentiated as long as the benefit gained can justify the increased implementation cost (if any). For example, the CW_{i,min} and CW_{i,max} for traffic category i, the maximum frame size allowed for a class-i packet, can also take different values if so desired. Another QoS parameter differentiated in ARAB is the minimum backoff time MBTᵢ, where a class-i packet randomly select a backoff time between [MBTᵢ, CWᵢ]. For high-priority traffic categories, MBTᵢ can be 0.

### B. Controllable Interframe Space (CIFS)

Interframe space (IFS)-based differentiation is employed in IEEE 802.11, IEEE 802.11e, and several other previous MAC protocols for ad hoc networks and wireless LANs. In CIFS, the IFS value is a function of the current backoff time value and the number of fragmented periods during the countdown of the associated packet. This is helpful in some situations since the number of fragmented periods is a good indication of the traffic load. For different traffic categories, the values and functions for CIFSs are different. For different nodes, the slot times may also be different when legacy and emerging technologies coexist.

### C. Differentiated Discarding/Retransmissions

The criteria to discard packets constitute another set of parameters that should be differentiated among different traffic categories. A higher-priority packet is allowed to retry for a larger number of failure RTS/CTS 62 dialogues and a larger number of data 56 packet collisions. We refer to such a strategy as the differentiated discarding discipline, which is applicable to both the MAC and transport layers. When this discipline is employed in a MAC protocol, the head-of-line problem may become severe since the first packet of the queue may not be scheduled in time and block other real-time packets in the queue. To solve this problem, semi-FIFO queues can be used where the first few packets can be transmitted out of order. Such queues are particularly important for higher-priority traffic categories that have a higher threshold for discarding.

Instead of discarding, a (higher-priority) packet can also be moved to a lower-cost but larger memory (e.g., with larger latency) for later rescheduling/retransmissions when the network inter-face card supports it. To meet different discarding ratio objectives, different traffic categories should have different maximum queue lengths. Note, however, that a higher-priority traffic category does not necessarily have a larger maximum queue length, since it may have smaller arrival rate and considerably smaller queueing delay when the traffic is heavy. Moreover, when a high-priority queue is full, packets of the associated traffic category may be optionally stored in the low-cost memory (if available) or in a lower-priority queue with space.

### D. Other Differentiation Mechanisms

In Section IX-D, we have presented the group acknowledgement mechanism and the negative/implicit acknowledgement mechanism. For low-priority packets, the negative/implicit acknowledgement mechanism can be used since it requires the least control channel overhead. Medium-priority packets can employ the group acknowledgement mechanism, while high-priority packets can employ the conventional per-packet acknowledgement mechanism as in MACAW and IEEE 802.11/11e.

Various other criteria can also be differentiated in the MAC protocol. For example, different traffic classes may be blocked by VP-CTS 62 messages with different thresholds for the generated interference. Packets with different priorities or attributes can also be allocated to different PHY channels. Power control/management mechanisms can also easily incorporate the notion of service differentiation. For example, a user who is expecting interactive traffic from another user at a remote site should have its mobile device wake up more frequently.

### XI. SPREAD SPECTRUM-BASED DDMDD PROTOCOLS

In this section we present the spread-spectrum version of DDMDD-based MAC embodiments.

### A. SOCF

The synchronous orthogonal-code coordination function (SOCF) is based on a slotted version of the DDMDD scheme. The orthogonal codes used in SOCF are allocated by a centralized control unit covering the area. It is allowed for different codes to have different spreading factors, differentiating the amounts of resources and service quality for different traffic classes. All SOCF trans-missions during the same time slot use the same scrambling code to maintain orthogonality among these transmissions, in contrast to WCDMA where different nodes use different scrambling codes for separation.

VPCSR can be well supported in SOCF in a novel way different from the VP-CTS 62 or other mechanisms for signal strength estimation. In SOCF, we employ differentiated orthogonal-code channels (DOCH) to effectively support VRMA with low control-channel overhead. In DOCH, an orthogonal-code channel i is allowed to transmit data 56 packets with transmission radius no larger than Rᵢ. A CTS 62 message in the orthogonal-code channel i is transmitted to all nodes within radius R=Rᵢ when the interference radius is the same as the transmission radius. However, if the interference radius is larger, an enlarged protection radius (e.g., R=2Rᵢ or 3Rᵢ) should be used in order for SOCF to support interference awareness. The latter can be done by using higher transmission power for CTS 62 messages than that for data 56 packet. This will not consume much power due to their shorter message length. However, if higher power is not feasible or allowed, other strategies such as a larger spreading factor should be employed. Following the notion of differentiated CDMA, a TSD-CDMA base station (BS) can also provide some privileged orthogonal-code channels for sessions with higher QoS requirements. For example, less congested orthogonal-code channels lead to smaller queuing delays. If more channels are desired, the centralized control unit such as a TSD-CDMA BS can further distinguish the maximum radii for different intervals. of the same orthogonal code. Rᵢ's can be dynamically controlled by TSD-CDMA BSs for load balancing between code channels and DiffServ supports, while nodes can choose to transmit in an orthogonal-code channel with larger Rᵢ if the orthogonal-code channel they are waiting for is congested.

The RTS/CTS 62 dialogues of SOCF are transmitted in a time-division control channel (TDCCH) (during the contention interval for each code), in a common control channel for all orthogonal-code channels based on code-division control channel (CDCCH), or an additional CDCCH (with a larger spreading factor) for every orthogonal-code channel. An RTS 60 message carries with it the requested code-time-slot(s), rather than requesting to transmit immediately after the RTS/CTS 62 dialogue as in IEEE 802.11 and other previous RTS/CTS 62-based protocols except for the presented DDMDD. Since the data 56 packet transmissions in SOCF are slotted, fragmentation will not happen and PASs can be specified using a small number of bits. The acknowledgement for successful reception of a data 56 packet can be transmitted during the contention interval of the next frame, possibly piggybacked in the next CTS 62 message. When a node is not transmitting or receiving, it can listen to the common CDCCH in order to be informed of the transmission requests to come. A node should listen to the TDCCH to be used for sufficiently long time before it can request to transmit or agree to receive. Another way to know previously allocated transmissions/receptions and to be informed of transmission requests is to have nonoverlapping TDCCHs so that a node can listen to all TDCCHs. Strategies similar to DOCH can be applied to IEEE 802.11a or other multichannel ad hoc networks by replacing an orthogonal-code channel with a PHY channel, leading to VPCSR based on differentiated PHY channels (DPCH).

The area surrounding a BS may be the bottleneck part of a cell. These and other congested areas should be given higher priority for packet-slot allocation. Also, real-time and interactive traffic should be given higher priority than background traffic. One way to differentiate service is to use DOCH and to employ the strategy of differentiated CDMA by limiting the access right to some intervals. However, such strategies will typically lead to lower utilization for these privileged intervals or orthogonal-code channels.

### B. Code Assignment Techniques

### B.1 Code Assignment Schemes

Previous code assignment schemes for CDMA-based ad hoc networks or packet radio networks can be classified into the common code, transmitter-based, receiver-based, and pairwise-based schemes. In this section, we employ another scheme, called the transmission-based code assignment scheme, for multiple access with spread spectrum (MASS).

The presented transmission-based scheme is fully distributed in nature, and is particularly designed for multihop mobile networks including ad hoc networks, multihop WLANs, and multihop mobile wireless MANs. In the per-packet transmission-based (PPT) subscheme, the codes to be used for packet transmissions are determined on a packet-by-packet basis. In the transmitter-persistent transmission-based (TPT), receiver-persistent transmission-based (RPT), or link-persistent transmission-based (LPT) subscheme, the previously used transmitter-specific, receiver-specific, or link-specific code can be (optionally) reused again if it has been working well, until some conflict or high cross-correlation is detected or “suspected”, or when a certain renew threshold is reached for using the same code.

In the following subsections, we employ three fully-distributed code assignment algorithms that are particularly developed for highly mobile ad hoc networks. They will be used by different sub-classes of MASS as described in the following sections. Previous code assignment algorithms/mechanisms may also be employed or incorporated into MASS if so desired. Details for their adaptation are omitted in this application.

### B.2 Announcement-based Conflict Avoidance (ACA)

In this subsection we present a proactive code assignment algorithm called ACA.

In ACA, all nodes (roughly) periodically announce the codes they are using or will use when the channel is idle or (relatively) lightly loaded. Such information can be piggybacked in regular Hello messages if so desired. A node records in its code table the codes that have been announced by other nearby nodes and deletes the aged codes. When a new code is needed, the node checks its code table and selects a code that is not used and/or will not cause high cross-correlations with other codes when used concurrently. It then announces the code to be used and nearby nodes will record the code in their code tables. A conflict resolution procedure will be invoked when there is a conflict or high cross-correlation detected (e.g., due to mobility or temporary deafness during the associated announcement). A simple way to resolve conflict or high cross-correlation is for the node that detects the conflict or encounters a collision to select a new code. There will not be problems caused when multiple nodes detects the conflict or high cross-correlation and select new codes concurrently. Note that the set of codes to be used may be appropriately chosen so that the cross-correlation between any pair of the codes with any relative delay may be sufficiently low so that only code conflict (i.e., the same code assigned to multiple transmissions, links, or transmitters) needs to be considered. But we still indicate the requirement of low cross-correlation in this section so that the descriptions of the code assignment mechanisms are applicable to a wider class of codes. If no codes are available anymore, the node in need of a new code can optionally negotiate with neighbors to borrow or share a code, or simply select the least-used or oldest code recorded in the table. Various other approaches are also possible. For example, the node may generate a new longer code to increase resilience to interference from nearby transmissions, and transmit at lower power to reduce the interference it will cause to other nearby receptions.

### B.3 The ROC Code Verification (ROCCV) Scheme

In this subsection we present several classes of reactive code assignment algorithms based on RTS/Object-to-sending (OTS)/CTS 62 (ROC) code assignment. The procedure for the ROC code assignment mechanism is similar to that of the ROC scheme for distributed multiple access in ad hoc networks, but the purpose of the presented ROCCV scheme is fully-distributed code request, approval, and assignment.

The ROC code assignment mechanism is invoked only when a new code is required. For PPT, LPT, and pairwise-based code assignment schemes, the transmitter-initiated ROC code assignment mechanism or the receiver-initiated ROC code assignment mechanism may be employed. In the transmitter-initiated ROC mechanism, a transmitter that needs a new code first randomly selects a code or a set of codes that will not conflict with the codes concurrently in use by other nodes in the vicinity or cause high cross-correlations (e.g., according to the codes recorded from previous RTS/CTS 62 or Hello messages it overheard). Note that for PPT, only the codes that are/will be used by transmissions/receptions with overlapping durations need to be avoided, but in LPT and pairwise-based code assignment schemes, all the codes that are recently assigned should be avoided. It then includes the requested code(s) in the RTS 60 message, and the intended receiver checks whether the requested code(s) conflicts with the codes used by nearby transmissions, and/or the (estimated) cross-correlations are too high. Note that such code information and decision can be piggybacked in RTS/CTS 62 messages that precede the data 56 packet transmission, especially for PPT, but can also be exchanged in special messages devoted to ROCCV.

If the requested code(s) passes the test, then the intended receiver replies with a CTS 62 message; otherwise, the intended receiver either keeps silent (as an implicit negative response) or replies with an explicit negative response indicating the inappropriate code(s) and possibly suggesting codes to be used. Due to the desirable similarity between the ROC code verification mechanism and the ROC MAC scheme, such code request and response information can be piggybacked in regular RTS/CTS 62 messages for MASS packet scheduling dialogues. especially when PPT is employed. However, such code information and decision can also be exchanged in special messages devoted to ROCCV. Also, similar to the ROC MAC scheme, a nearby third-party node that receives an RTS 60 message will check for possible conflict and estimate cross-correlation with the codes it is/will be using. If the node detect conflict or intolerable cross-correlation (especially for codes of the node as a receiver) the node sends an OTS 64 message to the intended transmitter to express its negative response. A nearby third-party node that receives a CTS 62 message will also check for possible conflict and estimate cross-correlation. If the node detect conflict or intolerable cross-correlation (especially for codes of the node as a transmitter) the node sends an OTS 64 message to the intended receiver. The node will also send an OTS 64 to the intended receiver directly if it is reachable and is not expensive; otherwise, it will ask the intended receiver to forward the OTS 64 message to the intended transmitter. In PPT, LPT, and pairwise-based code assignment schemes, an intended transmitter can use a code only when it receives the CTS 62 message from the intended receiver and receives no OTS 64 messages against it.

For the receiver-initiated ROC mechanism, the code negotiation is initiated by a CTS 62 message with codes suggested by the intended receiver, and verified by the RTS 60 message from the intended transmitter. Similar to the transmitter-initiated ROC mechanism, third-party nodes in the vicinity will send an OTS 64 message to the intended transmitter or receiver if the suggested code(s) is not appropriate. For TPT and transmitter-based code assignment schemes, an intended transmitter sends an RTS 60 with the requested code(s) to nearby nodes. Since there are no specific receivers in such schemes, no CTS 62 replies are required for code approval, and all nodes in vicinity function as third-party nodes in the preceding transmitter-initiated ROC code verification mechanisms. For RPT and receiver-based code assignment schemes, an intended receiver sends a CTS 62 with the requested code(s) to nearby nodes. Since there are no specific transmitters in such schemes, no RTS 60 replies are required for code approval, and all nodes in vicinity function as third-party nodes in the preceding receiver-initiated ROC code verification mechanisms.

Note that ACA can be incorporated into all the aforementioned subclasses of the ROC code verification mechanisms. The advantages of such announcement-enhanced ROC (AE-ROC) mechanism over the preceding pure ROC code verification mechanisms include smaller probability for failed ROC dialogue (due to code conflict). This reduces repeated code requests and thus control overhead. The advantages of AE-ROC over the preceding pure ACA mechanism include early detection of code conflict (enabled through the ROC verification mechanism) and possible reduction in the required frequency for announcement messages. This reduces the delay resulted from code assignment and negotiation, and reduces control overhead.

### B.4 Randomly-initiated Code Hopping (RICH)

In this subsection we employ randomly-initiated code hopping (RICH) where a node can decide the codes to be used by itself without negotiation with nearby nodes.

In RICH, one or several extremely long sequences of codes are selected. The same code may reappear in a selected sequence many times. As long as the (short to medium) subsequences within the entire sequence rarely repeat themselves, no problems will be caused in RICH. One way to generate such a sequence is to employ a pseudorandom number generator with extremely large period. A generated pseudorandom number is then used to derive the actual code(s) to be used through certain functions (e.g., pseudo-randomly/deterministically selecting several bits from a pseudorandom number) or through mapping/conversion by a table exchanged between the transmitter-receiver pair to enhance security. Since the sequence is extremely long, a transmitter can simply randomly select a starting point from the sequence(s) to transmit its PPT packet without worrying conflict with the starting points of any other nearby transmissions/receptions.

In per-bit randomly-initiated code hopping, different codes are used for different bits, while in per-segment code hopping, different codes are used for different segments. Note that even though nearby transmissions/receptions are not likely to use exactly the same subsequence of codes, “hits” between their codes for some concurrent bits or segments are bound to happen, whose frequency depends on the length of codes for a bit or segment. As a result it is desirable for RICH-based MASS to be able to request for retransmissions on a segment basis so that some hits between the codes will not collide the entire data 56 packet. Moreover, appropriate error-correcting code and/or redundancy should be employed to improve the efficiency of RICH-based MASS. Also, hierarchical CRC may be employed to detect errors on both the segment level and packet level.

An important advantage for RICH is that the codes used do not need to be assigned or approved in advance, making it particularly suitable for highly mobile networks. Other subschemes for RICH with slower or faster code hopping may also be used in MASS. In particular, when the same code is used for an entire packet, we obtain per-packet RICH, while and transmitter-persistent RICH or link-persistent RICH are obtained when the same code is used for a number of packets by a certain transmitter or link, respectively. Other approaches for generating the long sequence(s) are also possible. For example, a transmitter (and/or receiver) may generate one or several sequences by flipping a coin in any viable way, and then the sequences are exchanged through very secure encryption. These sequences can then be composed into considerably longer sequence(s) or used to map a long sequence generated by conventional approaches into a secure sequence. Previous hopping sequences/approaches such as those developed for Bluetooth or IEEE 802.11 may also be adapted or used as component subsequences for the composition of long sequences. Note that in any RICH approach, an accompanying mechanism is required for the transmitter to announce the rule of sequence generation. Moreover, when the receiver(s) loses track of the sequence, it should inform the transmitter and/or the transmitter should be able to detect the situation so that the accompanying mechanism for announcing the current sequence position can be invoked.

### C. Spread Spectrum Scheduling Techniques

In this application, we employ to use spread spectrum with large spreading factors in RTS/CTS 62 dialogues to solve the MAC-layer interference problems that are unique in ad hoc networks and multihop wireless LANs. We refer to this approach as spread spectrum scheduling and the resultant MASS as multiple access with spread spectrum scheduling (MASSS).

C.1 The Interference Problems and presented Solutions

In some popular wireless technologies such as IEEE 802.11, 802.11b, and 802.11a, the data-data 56 interference area is typically larger than the associated data 56 coverage area. For example, when the required SNR is at least 4 for data 56 packet receptions with acceptable quality (for a certain modulation technique) and the path loss exponent is around 2, then the data-data 56 interference area is approximately twice larger than the associated data 56 coverage area. For a MAC protocol to solve or mitigate the interference problems in ad hoc networks, RTS/CTS 62 messages have to be sent to all nodes within the associated protection areas. However, such protection areas are even larger than the associated data-data 56 interference areas so that the achievable SNR for RTS/CTS 62 messages may be considerably smaller 4. For example, if (1) a data 56 packet is already transmitted at the maximum allowed power level, (2) the associated RTS 60 message is to be transmitted to the associated data-data 56 interference area, and (3) the RTS 60 message will be transmitted at the same maximum allowed power level, then the achievable SNR for the RTS 60 message is approximately 1. As a result, a means capable of receiving the RTS 60 message with SNR equal to 1 or smaller is necessary for ad hoc MAC protocols to solve the interference-range problem.

When additive interference is considered, the maximum data-data 56 interfering range is even larger than twice that of data 56 coverage area. Our simulation results show that protection areas at least 3 times larger than the associated coverage area are required to achieve reasonable collision rate and throughput, while increasing it to 4 times or more can further increasing the network performance. As a result, a means to receive the control messages with SNR no more than 4/9 or even ¼ is needed or useful.

In this section, we employ to use spread spectrum techniques to transmit control messages in order to increase the reachable control coverage area to solve the interference problems. Data 56 packet transmissions, on the other hand, do not need to be transmitted using additional spread spectrum techniques in this approach (except for the modulation technique such as DSSS in use). Since spread spectrum scheduling does not use spread spectrum to multiplex concurrent data 56 packet transmissions to avoid collisions, the motivations, objectives, and procedure of the presented approach are very different from those of previous CDMA-based ad hoc MAC protocols that intend to channelize an ad hoc network and transform it into a multichannel network to achieve concurrent code division multiple access between nearby transmitters.

### C.2 The Spread Spectrum Scheduling (S³) Scheme

In S³, direct sequence spread spectrum techniques with a larger spreading factor is employed to transmit control messages. The default code assignment scheme for transmitting control messages in S³ is common code. When they are not transmitting or receiving data 56 packets, all active nodes tune to the common code to receive control messages. The data-to-control interference areas are considerably reduced as compared to the associated data-to-data 56 interference areas, where the “X”-to-“Y” interference area is the interference area for the transmission of “X” (packets or messages) to the reception of “Y” (packets or messages). This considerably reduces the probability for control messages to be collided by data 56 packets. Employing spread spectrum techniques with a larger spreading factor can reduce the power levels required for transmitting control messages (i.e., to be smaller than the power level for the associated data 56 packet). As a result, the probability for data 56 packets to be collided by control messages (due to loss of their associated CTS 62 messages or additive interference) can also be considerably reduced. Increase in the spreading factor (and thus reduction in the control message power) and increase in control message lengths should be balanced to improve network performance. Moreover, for control messages that are not transmitted at almost identical time, the interference and thus probability for collision between control messages may be reduced when appropriate error-correcting codes and spread spectrum techniques (e.g., long common code sequence with small auto-correlation) are used.

When the transmitter-based or pairwise-based code assignment scheme (instead of the common code scheme) is employed, CDMA with multiuser detection should be used, which will further reduce the collision rate of control messages, but the required hardware is relatively complex. Such reduction in control message collision rate is particularly important to interference-aware protocols that estimate interference based on information in RTS/CTS 62 messages, since accurate estimation for the interference level at the node's location requires that all/most RTS 60 messages are received successfully, while a scheduled reception can be better protected when its CTS 62 message(s) is received by all/most nearby active nodes successfully.

MASSS is flexible in changing the coverage area for control messages. As a result, MASSS is more flexible than protocols that use spread spectrum techniques at the PHY layer alone but not at the MAC layer. One way to support this capability is to employ the over-spreading discipline by using a spreading factor that is larger than required, and reduce the power level for transmitting the associated control messages. When the collision rate for data 56 packets or other performance/quality measures becomes too high or too poor (which can be estimated by local exchange of collision information), nodes can increase the power levels for control messages in order to increase their control coverage areas. Another potential way to increase control coverage area is to double or triple the number of chips used per bit. The same long code sequence for the entire control messages should be used. A node that detects many duplicate bits and/or fails to decode the control message correctly when using fewer chips per bit but decodes a correct control message when using more chips per bit then automatically adopts the latter as the received control message.

An important application of MASSS is MAC for ad hoc networks with directional antenna. Since control messages can be transmitted to sufficiently large ranges in MASSS, nodes that do not beamform toward an intended transmitter or receiver can still receive its RTS 60 or CTS 62 message. As a result, the directional-antenna deafness problem or the directional-antenna heterogeneous terminal problem for MAC protocols with direction antenna can be solved naturally by employing the presented S³ approach.

### D. Spread Spectrum Data Techniques

In multiple access with spread spectrum data 56 (MASSD), the purposes for employing spread spectrum techniques include: (1) increasing transmission radius for higher connectivity, (2) reducing data-to-data 56 interference area for spread spectrum-based interference control, (3) supporting power control by (optional) differentiated code channel, (4) utilizing “virtually free transmissions” that uses sufficiently low power levels, and (5) enabling interference engineering through flexible transmission power levels and receiving SNR requirements.

### D.1 Orthogonal-Code MASSD (OC-MASSD)

In OC-MASSD, a set of (approximately) orthogonal codes with low cross-correlation is employed. Each code is viewed as a code channel, where transmissions within the same code channel have to be coordinated using collision avoidance techniques such as RTS/CTS 62 dialogues or ROC dialogues. Depending on the spreading factor, the cross-correlation between different codes, and the requirement for collision rate, transmissions between different code channels may or may not need to be coordinated using information contained in RTS/CTS 62 messages. When different code channels do not need coordinations, the default of MASSD is to use different and (approximately) orthogonal codes with low cross-correlation for the RTS/CTS 62 dialogues in different code channels. The codes for RTS/CTS 62 dialogues typically use spreading factors larger than those of data 56 packets. Such default settings can reduce the collision rate of control messages. However, it is also allowed for alternative MASSD protocols to use the same common code for scheduling in all code channels so that a node can record the schedules in all channels. The presented transmission-based code assignment scheme is appropriate for OC-MASSD.

An important strength of OC-MASSD is that it can employ the differentiated code channel discipline to support efficient power-controlled transmissions. More precisely, each code channel is assigned a maximum allowed power level. For code channels with small or moderate maximum power levels, the interference areas between data 56 packets of the same code channel are relatively small due to their smaller transmission power. Moreover, the interference areas between data 56 packets of different code channels are typically small due to their small cross-correlation. As a result, the protection areas for CTS 62 messages in code channels with small or moderate maximum power levels are considerably smaller that in a network without differentiated channels. Thus, control overhead is considerably reduced in orthogonal-code MASSD with the differentiated code-channel discipline.

The advantages of OC-MASSS with the differentiated code channel discipline over the differentiated physical channel discipline include that there can be considerably more code channels than physical channels, providing finer-grain differentiation and thus lower control overhead. Also, OC-MASSS is more flexible and it is easier to adapt the number of code channels to the number of trans-missions within certain power ranges. Moreover, underutilization of certain code channels will not degrade the throughput and radio resource utilization as long as other code channels are well utilized. As a result, overprovisioning of code channels is possible. As a comparison, underutilization of any physical channels will considerably degrade the throughput and radio resource utilization so that overprovisioning of physical channels is not a viable strategy. Note, however, that it is desirable to employ multiple physical channels, each with multiple code channels, in OC-MASSD.

### D.2 Random-Code MASSD (RC-MASSD)

In RC-MASSD, a very large set of codes is needed. The transmission-based code assignment scheme combined with RICH (using large spreading factors) may be employed so that no coordination between different nodes are required, simplifying the protocol and reducing the control overhead. The transmitter-based, receiver-based, and pairwise-based code assignment schemes may also be employed, while a viable code assignment algorithm such as the ROC code verification scheme is needed to work in combination with them to avoid conflict between nearby nodes. The transmission-based code assignment scheme combined with the ROC code verification scheme may also be used in RC-MASSD.

In RC-MASSD, both the data-to-data 56 interference areas and the control-to-data 56 interference areas will be considerably reduced as compared to protocols without employing the spread spectrum data 56 techniques (when the same interfering sources and strengths are considered). As a comparison, in OC-MASSD, the data-to-data 56 interference areas will not be reduced within the same code channel, while the control-to-data 56 interference areas will be reduced when the RTS/CTS 62 dialogues and data 56 packets use different codes. As a result, MASSD can solve the interference-range problems. On the other hand, the data-to-control interference areas will be reduced for the same transmitter-receiver pairs (or the same physical distance) due to the lower transmission power levels required. As a result, the collision rate of control messages caused by data 56 packets may be reduced, leading to performance improvements. However, the maximum data-to-control interference area will not be reduced when the maximum power for data 56 remains the same.

When the spreading factor is large, RTS/CTS 62 dialogues may also be omitted in these protocols. This is particularly useful for small data 56 packets, and can be optionally used for packets with sizes under certain thresholds. The rationale is that when many chips are used per bit, the data-to-data 56 interference areas between different nodes is reduced considerably so that collisions become less likely even without such dialogues. However, when the spreading factor is not sufficiently large or when a node has neighbors with very short distance, RTS/CTS 62 or ROC dialogues should be employed as other MASS protocols, at least among those very close neighbors. A special application of this property is for nodes to find out the maximum allowed power levels for them to transmit without interfering nearby nodes (in most situations). A node can then transmit with power equal to or lower than an appropriate level by using sufficiently large spreading factor (e.g., not interfering the second closest active node when transmitting to the closest active node, or not interfering the most vulnerable node that sent out a CTS 62 message with an overlapping duration). As long as the associated data 56 packets and other packets waiting in queue can tolerate the (possibly) increased transmission durations, then these transmissions are “virtually free” in that they virtually do not waste any radio resources.

Another application of the spread spectrum data 56 techniques is to change the code and spreading factor before or during the transmissions. Such changes may be beneficial when the transmitter finds that the original code and spreading factor will collide/interfere nearby receptions or the receiver finds that the reception cannot be recognized with the original code and spreading factor (e.g., due to unexpected or increased noise/interference). With this technique, transmitters can reduce the power level when required (e.g., after receiving a CTS 62 or OTS 64 message) so that their transmissions can continue while avoiding colliding/interfering other receptions. This is a special case of power engineering. On the other hand, when the power level remains the same and the spreading factor is increased, the required SNR can be reduced so that receptions can be correctly demodulated when the noise/interference level is increased. Therefore, transmissions do not need to be aborted under these situations and the previously scheduled transmission/reception slots can be salvaged. We refer to these techniques that manipulate the interference areas and tolerance as interference engineering. Although interference engineering is applicable to both OC-MASSD and RC-MASSD, the required mechanisms are less complex in RC-MASSD.

### E. Other Spread Spectrum Techniques

### E.1 Spread Spectrum-based Busy Tone

Receiver busy tones can be employed to prevent inappropriate transmissions of control messages (as well as data 56 packets) from colliding on-going data 56 packet receptions. To reduce power consumption, enable interference awareness, and mitigate the moving terminal problem, we may use adaptive periodical busy tone (APBT).

APBT is similar to the busy tone scheme proposed in PCMA, but has two important differences. The first difference is to make the last short busy tone burst ends around an AIFS time or an appropriate period before the data 56 packet reception ends. This way an intended transmitter only needs to detect the channel idle for that period of time before it can send its RTS 60 message and/or data 56 packet. Since a time duration equal to the period is guaranteed between the last busy tone burst and the end of the reception, the RTS 60 message and/or data 56 packet will not collide with the reception protected by the busy tone. Moreover, due to the fixed duration overlapping the end of data 56 packet reception, other nodes can start transmissions upon the completion of the reception. As a result, the radio channel does not need to stay idle for an additional period after the reception is completed, avoiding unnecessary wastes of radio resources.

Another (optional) change is to employ spread spectrum techniques for transmitting busy tone in APBT. This can reduce the energy consumption for such busy tone bursts, which may need to be sent to a range larger than the associated data 56 packet coverage area when power control is employed or when the interference area is larger than coverage area. The presented techniques for APBT can also be applied back to PCMA and PCM.

When APBT is used in a more conservative way (i.e., with bust tone transmitted to larger ranges to reduce the chance of collisions), it is desirable to combine it with the detached dialogue approach. Otherwise, such a conservative use of busy tone will suffer from the busy-tone exposed terminal problem. With detached RTS/CTS 62 dialogues, only RTS/CTS 62 messages are blocked when a node is “exposed,” while data 56 packets with legitimate concurrent transmissions or receptions could have been scheduled previously, solving the busy-tone exposed terminal problem.

### E.2 Multichannel Sensitive-CSMA (MS-CSMA)

When power-control is not employed, sensitive CSMA (i.e., CSMA with lower sensing threshold) may also be employed to mitigate the interference-range hidden terminal problem. More precisely, in sensitive CSMA, an intended receiver senses the media and defers from transmissions even if the sensed signal strength is low as long as it is above the low sensing threshold. For example, intended transmitters that sense a carrier with signal strength at least, say, one ninth that of typical received signals (at receivers) will defer from transmissions. Then nodes within three times the data 56 coverage area from the on-going transmitter will keep silent (assuming that there is no obstruction and the path loss factor is 2) so that none of the nodes within twice the data 56 coverage area from the on-going receiver will transmit. This way the on-going reception can be protected from all nodes within the interference area that sense the signal.

This approach is less complex to implement so that it has the potential to be deployed in practice before other more complicated approaches become mature (e.g., MASS, the detached dialogue approach, and busy-tone-based implementations). However, the hidden terminal problem still exists in MS-CSMA when there are obstruction between an on-going transmitter and potential interferers. Another severe problem is that when power control is employed, it is typically impossible for potential interferers to sense an on-going transmissions with very low power levels, even when the sensing threshold is set to very low value. Moreover, the lower the sensing threshold is, the worse the exposed terminal problem will become. So sensitive CSMA alone is not applicable to power-controlled ad hoc networks.

In this subsection, we present MS-CSMA that utilizes multiple physical or code channels to support power control. The differentiated physical channel discipline or the differentiated code channel discipline is employed in MS-CSMA. As a result, the latter of the aforementioned problems will not occur within any of the physical channels or code channels, respectively, since the same or similar power levels are used. When multiple code channels are employed (which is enabled by the presented OC-MASSD), the sensed signals from different code channels should not defer intended transmissions except when the received signal is very strong.

In such multiple code channel sensitive CSMA (MCCS-CSMA), the signals may be sensed using two or more mechanisms with different thresholds. To avoid interference within the same code channel, a lower threshold is needed and the received signal should be demodulated using the code of the channel before determining its strength. To avoid interference between different code channels, one or several thresholds with considerably higher values suffice (depending on the cross-correlation between the codes) and the received signal strength is determined without demodulation. An alternative is to use a single low threshold and the received signal is demodulated using the code of the channel before determining its aggregate strength. The implementation for this alternative approach is less complex but the performance will be degraded.

### E.3 Scrambled Sequence Spread Spectrum (S⁴): An Embodiment for Diversity Engineering

To increase the diversity of a bit, we employ the S⁴ scheme that places the chips for a bit at distant positions in a transmission. The rational for doing so is to avoid fading for all chips of the same bit so that most bits can be decoded correctly even when many bits are faded for some of their chips.

In intra-segment S⁴, the chips of the same bit are confined within a segment of bits. Error detection, correcting, and retransmission are relatively easy in intra-segment S⁴. A CRC code is added for each segment of bits, and a segment is corrected or retransmitted when errors are detected. Note that the CRC code is calculated according to the bits (rather than chips) so that the CRC is verified at the receiver side after all the bits in that segment obtaining and reordering. Hierarchical CRC scheme can be employed to enhance the error control capability.

In inter-segment S⁴, the chips for a segment of bits will be mixed with those from different segments. The principle for error detection, correcting, and retransmission are similar to that of intra-segment S⁴. Each segment of bits also has a dedicated CRC code, and error correcting and retransmission are performed accordingly. The main difference is that the CRC code for a segment will be verified after all the bits in that segment in obtained, which typically requires multiple segments of chips. As a result, more buffering space and relatively complex sorting of the bits are required in inter-segment S⁴.

### XII. INTERFERENCE-AWARE MULTIPLE ACCESS (IAMA)

### A. Detached Dialogues in IAMA

In IEEE 802.11/11e and most previous RTS/CTS 62-based protocols, the RTS 60 message, CTS 62 message, data 56 packet, and acknowledgement are transmitted continuously without being separated (except for the short interframe space (SIFS) in-between for turnaround between the receiving and transmitting modes). In IAMA, however, we advocate to use detached dialogues, where the RTS 60 message, CTS 62 message, data 56 packet, and acknowledgement associated with the same data 56 packet transmission can all be optionally separated with or within specified/default times. An example is provided in FIG. 18. When combined with appropriate accompanying mechanisms, detached dialogues can solve various problems including all the issues identified in this application.

In IAMA, an RTS 60 message either implies the use of a default dialogue deadline or specifies a desired dialogue deadline, where the specified relative dialogue deadline (DD) time T_{DD} is the maximum time allowed for the CTS 62 message from the intended receiver to be received completely by the intended transmitter (since the last bit of the RTS 60 message is received by the intended receiver). The RTS 60 message requests for a data 56 packet duration starting at packet lag (PL) time T_{PL} after the dialogue deadline plus a turnaround time for the intended transmitter. That is, the requested “relative” duration (at the receiver's and other nearby nodes' side) for the data 56 packet transmission and reception is (T_{DD}+T_{T}+T_{PL}, T_{DD}+T_{T}+T_{PL}+T_{PT}), after reception of the last bit of the RTS 60 message (ny the receiver or a nearby node, respectively) where T_{T} is the turnaround time and T_{PT} is the requested packet transmission (PT) time. Note that relative times are specified so that synchronization is not required and the number of bits required for such specifications is reduced as compared to the use of absolute times. Moreover, the required duration for the receiver to be available and the duration for other third-party nodes to be interfered can then be specified with exactly the same relative time duration.

For example, if the CTS 62 reply is not allowed to be detached for the requested packet scheduling, then the dialogue deadline is T_{DD}=T_{T}+T_{CTS}+2T_{UP}, where T_{CTS} is the transmission time for the CTS 62 message and T_{UP} is the upper bound on the propagation delay between the transmitter-receiver pair. When the exact propagation delay between the transmitter-receiver pair is known, the exact value is used for T_{UP}; otherwise, the maximum propagation delay for the maximum coverage radius of the network or for the maximum transmission radius at the intended trans-mission power level is used for T_{UP}. The lengths of RTS, CTS, and acknowledgement messages are flexible in IAMA. When the extension flag of a control message is set to 1, a larger-size format for the message will be used. The message size may be further extended by setting another extension flag within the extended format, and so on. As a result, when a default value is used, smaller control message formats are used, and appropriate extended formats are used only when necessary. In particular, when the CTS 62 message is allowed to be replied till the last moment, then only one relative time (i.e., the time for the first bit of the packet transmission) needs to be specified. In this way, the control channel overhead can be reduced.

The rational for detaching these control messages and the associated data 56 packet are five-folds. First, detached CTS 62 messages allow the intended receivers to reply at a later time if they are available during the requested duration but are currently not allowed to reply with a CTS 62 message. This avoids unnecessary RTS/CTS 62 dialogue failures and thus reduce control overhead and channel access delay. Second, the flexibility resulted from (optionally) detached data 56 packets is very important for solving the exposed terminal problem and supporting efficient power-controlled transmissions and interference-aware medium access. This considerably improves radio channel utilization. Third, differentiating maximum allowed packet postponed access spaces for different traffic classes leads to a novel and effective tool for prioritization in ad hoc networks and multihop WLANs. This enables effective and efficient MAC-layer supports for differentiated service (DiffServ) and fairness. Fourth, by detaching acknowledgement messages, the exposed terminal problem can be resolved without compromising reliability. Fifth, detaching the messages/packets during a handshaking and specifying the (postponed) packet transmission duration are necessary for reasonable radio utilization when propagation delays are nonnegligible relative to packet transmission times. Such situations may occur in future high-speed wireless networks with small packets or in wireless networks with large coverage areas such as satellite networks and future mobile wireless MANs.

There are also various other advantages that may be achieved through the presented detached dialogues. In particular, spreading irrelevant RTS/CTS 62 dialogues (requesting for an overlapping packet duration) over a longer time period may reduce the collision rate for control messages, mitigates the negative effects of control message collisions, and enables novel mechanisms such as the triggered CTS 62 mechanism (to be presented in Subsection XIII-B) for achieving interference awareness without relying on busy tone or dual transceivers per node.

### B. Accumulative Interference Estimation and Triggered CTS

In sender-initiated coordination function (SICF) of IAMA, an intended transmitter first observes the channel it plans to send an RTS 60 message for a sufficiently long time to record the RTS 60 and CTS 62 messages of nearby nodes. Consider an ad hoc network that has multiple PHY channels. If one of them is used for the public control channel for transmissions of all RTS/CTS 62 control messages, then the intended transmitter should listen to it. If the PHY channel to be used for sending data is shared by both data 56 packets and their associated RTS/CTS 62 messages, then the intended transmitter should first employ a certain paging or searching mechanism to inform the intended receiver the PHY channel to use, and then both listen to the PHY channel to be used for sufficiently long time. If directional antenna is used, the intended transmitter should first inform the intended receiver (e.g., through multihop unicasting or spread spectrum techniques to tune to the right PHY channel, beamform toward each other, and then both listen to the channel in the direction to be used for sufficiently long time. We refer to this method as the observe before transmit approach, which can tackle deafness problems introduced by multichannel, directional antennas, and power-saving modes. Other irrelevant active nodes may also beamform toward the intended transmitter (or toward its own intended transmitter when they have scheduled a reception with a duration overlapping with the requested transmission time) to listen to the transmitted RTS 60 message (whose transmission duration may be specified in its notification message). They will then beamform toward the intended receiver (or toward its own intended receiver when they have scheduled a transmission with a duration overlapping with the requested reception time) to listen to the transmitted CTS 62 message (whose transmission time may be specified in its response message).

Then both the intended transmitter and intended receiver have to listen to the PHY channel to be used for a sufficiently long time. Let t time units be the time for the intended transmitter to listen to the channel for t time units (no matter whether the channel is idle or busy). Then the intended transmitter is eligible to request for a class-i packet duration with starting time no smaller than T_{min,dd,i}+T_{T}+T_{min,i} and maxⱼ(T_{Maz,dd,j}+T_{T}+T_{Max,j})+T_{Max,d,j}−t plus a few control messages and turn-around times, and no larger than T_{Max,dd,i}+T_{T}+T_{Max,i}, where T_{min,j} and T_{min,dd,j} are the minimum allowed values for packet postponed access spaces and dialogue deadlines, respectively, T_{Max,j} and T_{Max,dd,j} are the maximum allowed values for packet postponed access spaces and dialogue deadlines for class-j data 56 packets, respectively, and T_{Max,d,j} is the maximum allowed data 56 packet transmission time. Note that a higher priority class j typically has a larger maximum allowed postponed access space T_{Max,j}. Then the intended transmitter can send an RTS 60 message to all nodes within the protection area for the associated data 56 packet power level. The RTS 60 message carries with it the transmitter and receiver IDs, the sequence number, duration, and priority for the associated data 56 packet, as well as transmission related information such as the employed power level, modulation technique, and code (when spread spectrum data is used). The protection area is enlarged from the maximum interfered range, in which a node will receive interference strength higher than a interference notification threshold. Note that a transmitter-receiver pair in IAMA should negotiate a transmission power level that can tolerate aggregate interference at least equal to the minimum tolerable interference threshold for the associated packet class, which is typically considerably larger than the interference notification threshold.

An active node records all the RTS 60 and CTS 62 messages it received when it listens to the appropriate channel and direction. When direction antenna is available, they are typically used for the transmissions of data 56 packets and the declaration short signals/pulses (see Subsection XIII-C for more details). While inactive nodes (different from nodes in sleeping or dormant mode) only need to pay attention to activation messages addressed to them (possibly transmitted using spread spectrum with their specific codes) so that the consumed power can be reduced. The intended transmitter should only request for a packet duration at a power level not exceeding the maximum allowed power for that duration (according to the triggered CTS 62 messages it has received thus far, and the default maximum allowed power for the PHY channel to be used). A third-party (irrelevant) node that has a scheduled reception should record sufficient information from the RTS 60 messages it receives so that it can calculate or estimate the maximum (aggregate) interference strength during its data 56 packet reception. If it finds that an RTS 60 message requesting for an overlapping duration will add interference to a level higher than what its reception can tolerate, it will send an object-to-sending (OTS) message to the intended transmitter. We refer to this paradigm as accumulative interference estimation,

An intended receiver should record sufficient information from the RTS 60 messages it receives. If it receives an RTS 60 message from its intended transmitter requesting for a postponed access space T_{PL} but has not listened to the channel for at least maxⱼ(T_{Max,j})−T_{PL} time units, then it should defer replying with a CTS 62 message (unless it is willing to risk its packet being collided) till that amount of time is reached. If the intended receiver has listened to the channel for at least that amount of time, then it estimates the maximum (aggregate) interference strength for the requested packet duration. If the estimated SNR is sufficiently high, it can reply with a CTS 62 message informing the intended transmitter that it is available to receive the packet. The CTS 62 message also serves to inform all nodes within the protection area (enlarged from the associated maximum interfering range) that it will receive a data 56 packet during the specified duration, where the maximum interfering range is the range in which a node transmitting at the maximum allowed power in the associated PHY channel will generate interference higher than the interference notification threshold at the receiver (that sends the CTS 62 message). The CTS 62 message should also include the information required for these nodes to determine the maximum power allowed for them to transmit during the packet reception duration. Such information can be implied by the signal strength for transmitting the CTS 62 message (which is applicable when all network nodes have the hardware for measuring the signal strength of CTS 62 messages). However, if some network nodes are not equipped with hardware for signal strength measurement, the variable-power CTS 62 mechanism can be employed by attaching to the end of a CTS 62 message power-decreasing pulses or short signals (possibly transmitted with spread spectrum) or pulses/signals with power dependent on time (but not necessarily decreasing). Then the interference a node is going to generate at the intended receiver (which sends the CTS 62 message) is proportional to the number or duration of pulses it receives above an appropriate threshold. Note that in both approach the intended receiver should includes the power level the CTS 62 message is transmitted at. A main difference is that the former approach requires all network nodes to be equipped with the hardware for signal strength measurement, but in the latter approach none of the network nodes require such specialized hardware. If the intended receiver is available to receive the data 56 packet but is not allowed to reply at the moment, it will wait until the channel is free and reply with a CTS 62 message, unless the dialogue deadline is passed. If the intended receiver is not available to receive the data 56 packet, it can employ the receiver-initiated coordination function (RICF) to request for a reception from the intended transmitter based on the information it obtained in the received RTS 60 message and its local schedule for channel utilization. It can suggest in the CTS 62 message the duration, power, and modulation techniques etc. to be used. A node with a scheduled reception monitors the channel to estimate the remaining interference threshold it can tolerate for its scheduled reception(s).

After successful scheduling of a reception, an intended receiver continues to monitor the channel to estimate the remaining interference tolerance it can tolerate for its scheduled reception(s). If the remaining interference tolerance drops below the next threshold (or equivalently, if the additional interference estimated by newly received RTS 60 messages exceeds a interference triggering threshold), another CTS 62 message is triggered. The triggered CTS 62 message is sent within the associated protection area, which may be larger than the previous protection area due to the increase in maximum interfering range. To reduce the required protection area, the intended transmitter-receiver pair can initially negotiate a transmission power level that is somewhat higher than that required by the target SNR. Note that protection areas can be adaptive to the performance and service quality (such as collision rate of data 56 packets). Also, when calculation of the appropriate protection area or the required power is difficult, the required power for transmitting control messages can be adaptively controlled to increase the protection areas adaptively when needed.

Finally, a (possibly) detached acknowledgement (ACK) can be sent back to the transmitter when the data 56 packet is correctly received. The acknowledgement scheme for IAMA may employ passive acknowledgement, implicit/negative acknowledgement, and group acknowledgement leading to the PING-ACK 58 scheme In particular, segment-based NAK that indicates the erroneous segments in a packet/burst requests for their retransmissions only instead of the entire packet/burst. This is particularly useful for large packets and bursts, spread spectrum-based MAC, or more aggressive transmission policy with higher bit error rates.

Note, however, that when RTS/CTS 62 messages are transmitted in the same channels used by data 56 packets, they should not be transmitted before listening to the channel for maxⱼ(T_{Max,dd,j}+T_{T}+T_{Max,j})+T_{Max,d,j} time unless appropriate mechanisms for protecting data 56 packet receptions from control message transmissions are employed. Possible mechanisms for this purpose include using sensitive-CSMA before transmitting RTS/CTS 62 messages (but not required for transmitting scheduled data 56 packets), possible with segment-based ARQ retransmissions or short “dummy signals” or disposable signals/information (e.g., declaration short signals) at the beginning of data 56 packets.

### C. Enabling Techniques for Power and Interference Control/Engineering

When an intended receiver has the hardware to measure received signal strength, it can estimate the path loss and then inform the intended receiver an appropriate power level to use. This can be done by measuring the received signal strength divided by the transmitted power level specified in the RTS 60 message. However, to enable power control without such specialized hardware for signal strength measurement, an appropriate accompanying mechanism is required.

One way to do it is for a transmitter-receiver pair to negotiate an appropriate power level through repeated trial and error. More precisely, when a transmitted control message can be recognized by the intended receiver, the intended transmitter can either suggest the currently used power level, or reduce the power level (e.g., by a factor of 2) and retry for a possibly better power level. If the newly transmitted short control message can still be recognized, the intended transmitter can continue to reduce the power level(s) until the transmitted short control message cannot be recognized anymore. Then the transmitter may decide to use the lowest recognizable power level known thus far, or continue to refine the range. For the latter the intended transmitter will transmit at a power level that is smaller than the lowest recognizable power level so far, while larger than the highest unrecognizable power level so far. This process is repeated until a sufficiently small range is obtained. Note that even though this process is relatively time-consuming and will consume considerable communication resources, it only needs to be conducted once until the relative positions, angles of antennas, and/or environment factors (such as obstruction, reflector, noise level, or interference level) are considerably changed. So the same process can be conducted again after a preset timer is reached and/or triggered when such changes are detected (e.g., after a number of transmission failures). We refer to this approach as logarithmic trial power control.

The logarithmic trial power control mechanism may introduce higher or even unacceptable delay. Equally importantly, the radio resources consumed by the mechanism may be prohibitively high when the moving speeds of the transmitter, receiver, obstructions, and/or reflectors are high or the angles of antennas and other environment factors are affecting the path loss frequently. Moreover, it is relatively unreliable, inaccurate, and expensive for nearby irrelevant nodes to estimate the interference generated by the intended transmitter using this approach, making it less effective in supporting interference awareness.

To solve these problems, we employ the variable-power RTS 60 (VP-RTS) mechanism that can facilitate power control using a single RTS/CTS 62 two-way hand-shaking, without relying on specialized hardware for signal strength measurement. The presented VP-RTS 60 mechanism is similar to the variable-power CTS 62 (VP-CTS) mechanism. More precisely, the intended transmitter first transmits the main information part (called declare-to-send (DTS)) of the VP-RTS 60 message using a power level that is sufficiently high to be recognized by most active nodes within the protection area of the associated transmission. When spread spectrum is employed, an appropriate spreading factor should be used and the appropriate power level depends on the spreading factor in use. The DTS submessage is then followed by an encoded short signal (possibly with information bits transmitted with spread spectrum) or pulse transmitted by the intended transmitter at power level p₁ that is sufficiently high for the intended receiver to recognize it and for most active nodes within the protection area to detect it. Then DTS and the first short signal/pulse is followed by n-1 encoded short signals or pulses transmitted at power levels p₂, p₃, . . . , pₙ, where pᵢ are a fraction of p₁, and the value of n and the ratios pᵢ/pᵢ are known by default or specified in the DTS submessage. A nearby irrelevant node can then estimate the interference it is going to receive due to the intended transmission by counting the number of pulses/signals it can detect above an appropriate threshold (that can be controlled locally according to the basic interference unit it is interested in). Similar to VP-CTS, the intended receiver can then inform the intended transmitter an appropriate power level according to the number of pulses/signals it can recognize. Note that pulses can be used to replace short signals in VP-RTS 60 messages only when the intended receiver can estimate the appropriate power level for transmission through received signal strength alone even when the multipath effects are not negligible. Note, however, that this is possible (e.g., through learning from previous transmissions and outcomes).

The presented variable-power declaration approach for VP-RTS 60 and VP-CTS 62 mechanisms can be applied to other control messages and/or data 56 packets for power control and interference estimation. For example, variable-power short signals/pulses (plus essential information) can be attached to the end of some data 56 packets (e.g., roughly periodically between a transmitter-receiver pair). The receiver then piggybacks the appropriate power level in the ACK 58 message (or data 56 packets in the reverse direction) to facilitate adjustment of power level for subsequent packet transmissions. Such a path loss declaration mechanism can also be implemented in a proactive manner for active nodes and between active transmitter-receiver pairs by attaching variable-power short signals/pulses to other control messages such as Hello messages. Optimization for the presented variable-power declaration approach (including the number of short signals/pulses, the relative power levels for the group of short signals/pulses, and the frequency for attaching them to control messages and/or data 56 packets) is currently being investigated and will be reported in the future.

Note that for all the aforementioned power control mechanisms, the receiver should not use the minimum power level that happens to make the signals recognizable. It should add sufficient safe margin to the power level so that it can tolerate at least the minimum tolerable interference threshold. When the safe margin is larger, the protection area for its reception will become smaller since it can tolerate higher interference. As a result, for low-power transmissions, the receiver can request for a power level with a larger safe margin so that the power required to transmit its CTS 62 message can be considerably reduced. This way the overhead for the RTS/CTS 62 dialogue (including consumed energy and radio spacial resources) will be considerably reduced. This is a special application of interference engineering.

When directional antennas are employed by at least some of the network nodes, the variable-direction variable-power declaration approach can be employed. The presented approach is an extension to the variable-power declaration approach. In this approach, an intended transmitter transmits its RTS 60 message in several directions to facilitate the intended receiver to determine the best direction for the transmitter to use. The intended receiver can use the reverse direction for its reception when it also has a directional antenna, but it can also transmits its CTS 62 message in several directions to facilitate the intended transmitter to determine the best direction for the receiver to use. The intended transmitter-receiver pair can then beamform to the appropriate directions and use variable-power declaration short signals/pulses to determine the power level to use.

Note that variable-direction declaration and variable-power declaration can be combined by transmitting variable-power short signals/pulses for each direction. This way only a two-way RTS/CTS 62 handshaking is required. However, variable-direction declaration may be needed less frequently than variable-power declaration so that variable-power declaration alone will sometimes be performed separately in typical environments. Moreover, for nearby nodes to better estimate the interference they are going to receive or generate, they can beamform to appropriate directions. For example, when the declaration short signals/pulses are to be transmitted by the intended transmitter, a nearby node can beamform toward the direction it is going to use to receive its packet during a slot that overlaps with the one requested by the RTS 60 message. Also, other nearby nodes may beamform toward the direction of the intended transmitter or receiver when it transmits to make sure they can detect the declaration short signals/pulses. To do so they will need separate variable-direction declaration and variable-power declaration. Note also that the variable-direction declaration approach may be replaced by algorithms for optimizing the direction (e.g., through changing weights of individual array antennas or switching between different antennas). But such a mechanism is still needed if a receiver will receive interference from a wider range of angles than the recognizable range of angles for a single CTS 62 message from it, both under the directional antenna mode.

Another major issue concerning the accumulative interference estimation mechanism of IAMA is that loss of RTS 60 messages will cause inaccurate estimation of interference strength, while loss of CTS 62 messages will cause failure in protecting a scheduled reception. The OTS 64 mechanism provides a second chance for intended receivers to protect their scheduled receptions, while the triggered CTS 62 mechanism also mitigate the negative effects of losing CTS 62 messages. However, reduction in control message collision rate is still very important for IAMA to work efficiently. In Section XVI, we present collision prevention with hidden terminal detection (CP/HTD) to address this issue. By choosing appropriate CP/HTD techniques, collision rate for control messages can be controlled so that collision rate for data 56 packet can in turn be controlled or even avoided completely, solving the hidden terminal problem.

### D. Other Accompanying Mechanisms

A third issue that must to be solved for IAMA to work is that a means is needed to send control messages to distance considerably larger than the maximum coverage area for data 56 packets (to be referred to as data 56 coverage area in what follows). The simplest way is to allow larger maximum transmission power for control messages. Since control messages are considerably smaller, the energy consumed by them may be tolerable. However, in order to conform to the maximum power regulation, the power required by the first approach may not be allowed. Another simple approach is to limit the maximum power allowed for data 56 packets so that the associated control coverage areas (i.e., the protection areas for the associated data 56 packet transmissions or receptions to be used to transmit the associated control messages) are reduced to be reachable by the allowed power levels. However, when the required control coverage areas are considerably larger than the associated data 56 coverage area, many links that were originally possible will have to be given up in such an approach.

The third approach is to use very robust modulation techniques (at the PHY layer) for control messages so that they can reach larger ranges. However, the maximum control coverage areas may still be unreachable. Another type of solutions is to utilize multichannel variable-radius multiple access that transmit data 56 packets belonging to different power ranges in different PHY channels. Then only the channels that use higher power levels are not able to transmit RTS/CTS 62 messages to their appropriate protection areas. However, the above approaches all have their limitations. We can also utilize spread spectrum techniques for transmitting control messages that require larger control coverage areas, which require relatively complex hardware but do not have the aforementioned drawbacks. The last approach considered in this application is to employ multihop geocasting to relay RTS 60 and CTS 62 messages to the appropriate protection areas. Note that even though limited flooding is a viable approach to implement multihop geocasting, a considerably more efficient approach is to maintain a multicasting tree that covers the maximum protection area to be used for each active node. Limited flooding should then be used only as a backup or when a new multicast tree needs to be generated. Other solutions are possible and will be reported in the future.

Other mechanisms useful for IAMA include mobile wireless MPLS that aggregates packets into larger bursts to reduce control overhead, utilizes the control messages and the ROC mechanism for interference-aware reservations to provision QoS guarantees and reduce control overhead (through (limited-lifetime) periodical slots without RTS/CTS 62 dialogues), and employing multiple channels (for neighboring hops) and (optionally) bifurcated paths to support maximum-speed connections (e.g., at 54 Mbps based on IEEE 802.11g/a).

### XIII. M-VRMA: A MULTICHANNEL VRMA PROTOCOL

In this section, we present details for the scheme, control messages, and their associated mechanisms for variable-radius supports in the ROV protocol.

### A. The Multichannel VRMA (M-VRMA) Scheme

ROV supports variable-radius transmissions based on a combination of two approaches, the M-VRMA scheme and power-decreasing declaration based on the variable-power CTS mechanism. The efficiency for variable-radius transmissions in ROV is also enhanced by its OTS mechanism. In this subsection, we describe the M-VRMA scheme for ROV.

M-VRMA is based on the differentiated PHY channel discipline, where the maximum allowable power levels for data packet transmissions are different for different PHY channels. When there are m PHY channels that can be used concurrently in ROV, one of them will be used as the public control channel, while the other m-1 channels will be used as the data channels. The control channel is used to coordinate between all nodes in ROV. The RTS and CTS messages should be sent in the control channel to select a data channel that allows the power level they require, and schedule for an data packet duration in it. Adequate postponed access space should be employed to separate the RTS/CTS dialogue and the starting time for data packet transmissions in order to allow the intended transmitter and receiver to turnaround their receivers and to tune their receivers to the frequency of the selected PHY channel. An important advantage of M-VRMA is that the required transmission ranges can be considerably reduced for CTS messages associated with data packets that require lower power levels. This significantly reduces the control overhead for ROV.

To coexist with IEEE 802.11/802.11e, an ad hoc network can allocate one PHY channel to simpler nodes based on the single-channel MAC protocol of IEEE 802.11/802.11e, while allocate the remaining PHY channels to ROV-capable nodes. On the other hand, the M-VRMA techniques may be applied to IEEE 802.11 and 802.11e to obtain multichannel extensions with efficient VRMA supports. For example, such an extension can utilize an RTS/CTS dialogue or a small data packet in the public channel to select a data channel for actual data packet transmissions. They will then both tune to the PHY channel they agreed on, countdown and observe the channel for sufficiently long time (e.g., at least for the duration of a maximum-size data packet plus the maximum allowed postponed access space for that channel minus the chosen postponed access space for the packet duration to be requested). Finally the intended transmitter initiate a transmission by sending its RTS message as in ordinary IEEE 802.11/802.11e. An advantage for the disclosed IEEE 802.11/802.11e extensions is that a data packet will experience propagation characteristics similar to those of its associated control messages so that the reserved “floor” may be more accurate. An additional flexibility is that the intended receiver may initiate a reception in the selected PHY channel, if so desired, since it knows that the intended transmitter has a packet to send. The RTS message can then be omitted as in MACA/BI, if so desired, to reduce the control overhead.

A problem for applying the preceding techniques to ROV is that the power levels required to transmit control messages may be considerably higher than those of the associated data packets so that they should avoid being mixed together. To fix this problem, control messages can be grouped together in the control intervals as in semi-synchronous advance access or TDCCH MAC protocols. When the control intervals for different PHY channels do not overlap in time, the public control channel can even be removed. Another approach that allows the public control channel to be removed is to employ a paging procedure by sending RTS or paging messages to find the PHY channel the intended receiver currently listening to. All the approaches disclosed in this subsection can solve the multichannel heterogeneous terminal problem.

### B. The Request-to-send (RTS) Messages

In ROV, an intended transmitter first sends in the control channel a Request-To-Send (RTS) message to all nodes (e.g., mobile hosts) and/or access points within its protection range. The purposes of RTS messages in ROV are (1) to inquire the receiver whether the interference at its predicted future locations will be low enough to receive its packet and (2) to inquire other nodes within its protection range whether the intended transmission will collide with the packets that they will be receiving. For RTS and VP-CTS messages, the protection ranges have radii

P_{RTS}=I_{TRP}+M_{RTS}

and

P_{CTS}=Iₘₐₓ+M_{CTS}

respectively, where Iₘₐₓ is the maximum interference radius for data packet transmissions in the network, I_{TRP} is the interference radius (e.g., twice the current distance between the transmitter-receiver pair), M_{RTS} and M_{CTS} are safe margins for RTS and CTS messages, respectively. M_{RTS} and M_{CTS} can vary for different messages, but should be larger than (S_{T}+S_{R}+Sₘₐₓ)×Tₐₐ and (S_{R}+Sₘₐₓ)×Tₐₐ, respectively, plus some additional safe margins to mitigate the additive interference problem. Note that the advance access time can be limited to the duration of several data packet transmissions so that the resultant performance of ROV will not be degraded in the presence of mobility. A packet with higher priority i has larger maximum allowable advance access time 0≦Tₐₐ≦T_{aa,i}, while a packet with lower priority j has more limited maximum advance access time 0≦Tₐₐ≦T_{aa,j}≦T_{aa,i}. Also, the advance access time is the advance access scheduling time for the next data packet, and we do not assume constant-bit rate traffic as in MACA/PR. As a result, ROV can work efficiently in ad hoc networks with bursty traffic and high mobility.

Since the interference radius and thus protection range may be considerably larger than that of transmission radius (e.g., by a factor of 2), some accompanying mechanism is required. The simplest yet practical approach is to limit the data packet transmission radius to half that of the maximum transmission radius. We may also employ relayed unicasting and relayed geocasting to relay control messages through multihops to the intended receiver, transmitter, or other nodes within the associated protection ranges. Other possible approaches include using spread spectrum techniques to increase the transmission ranges of control messages.

### C. The Object-to-Sending (OTS) Messages

FIG. 14 provides an example for OTS operations. Node B is scheduled to receive a packet from node A. If a nearby node C sends an RTS message to request for transmission to node D during an overlapping time at a power level that will collide Node B's reception, then node B will send an OTS message to node C to block node C's transmission. Since node B has not started data packet reception, only one transceiver is required for node B.

A ROV-based node only has a single transceiver. All node that have a scheduled packet reception listens to the control channel except when they are transmitting or receiving data packets or are currently in the dormant mode. If a node receives an RTS message but will be receiving a packet during a period of time that overlaps with the requested slot, it informs the sender of the RTS message with an OTS message. Then the sender objected by the OTS message has to backoff and request to send again at a later time.

Note that the OTS mechanism and message are very different from the Not Clear To Send (NCTS) mechanism and message disclosed by Bharghavan. The most distinguishing difference is that NCTS is sent by an intended receiver while our OTS message is sent by a third-party node that receives an RTS message, which is neither the intended receiver nor the intended transmitter of the associated RTS message. Another important difference between OTS and NCTS is the different purposes they serve. NCTS is sent by an intended receiver to inform its intended transmitter about its unavailability, in order to speed up their negotiations and quickly release the resources blocked by the unsuccessful RTS message, while OTS is sent by third-party nodes to express their objection to a nearby ongoing RTS/CTS dialogue to protect their own “interests”. In our opinion, it is important to allow third-party nodes to express their opinions about the schedule of a nearby data packet transmission. The rationale is that in ad hoc networks nearby nodes share the same medium (i.e., the air) but may transmit/receive at the same time, so scheduling a transmission is not just an issue between its intended transmitter and receiver, but an issue concerning all nearby active nodes.

Other differences include several other functionality of third-party OTS mechanism that cannot be replaced by the second-party NCTS mechanism. For example, OTS can be used by a node to protect its scheduled packet reception or to enforce its reservation that would otherwise be collided by nodes that just move to the nearby area and are unaware of the scheduled reception or reservation. This is important for provisioning QoS guarantees in mobile ad hoc networks since we need an effective mechanism to maintain, police, and enforce legally made reservations. As another example, OTS can effectively support VP-CTS and variable-radius transmissions, while NCTS does not have such a function. Moreover, OTS is critical in supporting fully distributed interference aware multiple access in multihop ad hoc networks. It is straightforward to extend ROV to solve the additive interference problem. The details are out of scope of this paper.

We allocate a single message slot for all OTS messages against the same RTS requests, the associated control channel overhead can be significantly reduced, making OTS a practical mechanism. Thus, we believe that OTS is a revolutionary new concept for multiple access in multihop ad hoc networks. Moreover, our simulations have proved that such an augmentation can considerably improve the network throughput. As a comparison, NCTS cannot increase throughput to a comparable degree.

### D. The Variable-Power Clear-to-Send (VP-CTS) Messages

In order to tackle the heterogeneous terminal problem, the VP-CTS message of ROV is very different from the CTS message in previous RTS/CTS-based protocols. In short, VP-CTS consists of a declaration packet followed by a number of declaration signals. These declaration signals are transmitted sequentially at different power levels. As a result, VP-CTS is not a conventional message that is transmitted to the same group of receivers, but a message with a packet and several follow-up declaration signals that are destined to different receiving groups (according to the respective power levels). In what follows, we present detailed operations for VP-CTS.

When an intended receiver receives an RTS message from its intended transmitter, it looks up its local scheduling table to determine whether it will be able to receive the intended packet. If so, the intended receiver replies to the intended transmitter with a declaration packet. The declaration packet is sent by the intended receiver to all nodes within the VP-CTS protection range (see Subsection XV-B).

If an intended transmitter receives a declaration packet from the receiver and does not receive any OTS messages, the intended transmitter knows that it can start its transmission at the scheduled time. Note that in ROV an intended transmitter specifies a single declaration/OTS slot following its RTS message transmission for its intended receiver to send the declaration packet as well as for all nearby nodes to send their OTS messages if they have objections. This will considerably reduce the overhead for OTS messages. If the intended transmitter finds that the specified slot is idle (in the control channel), it knows that the intended receiver did not receive its RTS message or does not agree with the requested schedule; if the intended transmitter find that the specified slot is successful but the received message is OTS, or find that the specified slot is collided (in the control channel), it knows that there is at least a nearby node that objects to its schedule. In the last scenario, the intended transmitter will reschedule for the packet very shortly so that the intended receiver can release the resources blocked by the VP-CTS message (if any). Only when the intended transmitter find that the specified slot is successful and the received message is a declaration packet, it will regard its request as success.

The declaration packet is followed by several declaration signals, which are very short and may or may not contain information or coding. One way to implement VP-CTS is to utilize n declaration signals, these short signals will be transmitted at 100%,

$$\frac{n - 1}{n} , \frac{n - 2}{n} , … , \frac{1}{n}$$

of the power required by the VP-CTS protection radius. By counting the number of declaration signals received, a nearby node can easily estimate the maximum power level it can transmit without interfering with the reception of the sender of the associated VP-CTS message. In this way, variable-radius transmissions can be effectively supported without relying on busy tone or other expensive hardware that measures the signal strength of CTS messages to estimate the distance between it and the sender of the CTS message.

Note that the estimation of physical distance based on VP-CTS, signal strength measurement, or GPS are bound to have nonnegligible errors. In ROV, we mitigate this problem by equipping it with an OTS mechanism for protection against estimation errors. As a result, ROV can support VRMA more efficiently while requiring lower hardware cost at the same time as compared to previous approaches based on busy tone, signal strength measurement, or GPS information alone.

### E. The PING Acknowledgement Scheme

In ROV, a group acknowledgement (G-ACK) mechanism can be used for reliable unicasting. In G-ACK, the receiver in a transmitter-receiver pair can reply to the transmitter with an ACK in the control channel after one or more than one packet received, possibly in a piggyback manner. The former degenerates into the per-packet acknowledgement mechanism of MACAW or IEEE 802.11, while the latter can reduce the control-channel overhead.

Other mechanisms such as Passive, Implicit, and Negative acknowledgement mechanisms may also be combined with G-ACK as optional components of the resultant PING-ACK scheme.

### XIV. MACP

### A. Basic Operations for MACP

For a transmission based on MACP, the intended transmitter first sets its counter to a random integer within its current contention window (CW) (i.e., a uniformly distributed random integer in [0, CW]). The intended transmitter then listens to the channel, and starts decreasing its counter by one for every idle slot time after it finds the channel idle for a duration of DCF interframe space (DIFS). If the intended transmitter finds that the channel is busy, it does not start (or halts) decreasing its counter, while keeps sensing the channel. When it finds the channel idle for a duration of DIFS again, it starts (or restarts) decreasing its counter. The mechanisms disclosed for IEEE 802.11e or other previous MAC protocols may also be employed by MACP, but the details are omitted in this application.

When the counter reaches 0, the intended transmitter enters the competition status and send prohibiting signals and listen to the channel as described in the following subsection. If it wins the competition, it will transmits a request-to-send (RTS) message to the intended receiver. It loses the competition, it either backoff or participates in the next round of competition, depending on the priority class and policy for the associated data packet, the number of failed competitions, and an associated threshold specified in the protocol. When the intended receiver received the RTS message, it will senses the channel, and prepare to replies with a clear-to-send (CTS) message if it finds the channel idle for a duration of short interframe space (SIFS). To send the CTS message, the intended receiver still needs to enter the competition status, but its competition number has the highest priority. If there are no other competitors for sending CTS or ACK messages, the intended will win the competition, and transmits a CTS message. It loses a competition, it does not backoff and will persistently compete for the channel until it wins the channel or timeout. After receiving the CTS message, the intended transmitter will transmit the data packet at the scheduled time, which may be detached from the RTS/CTS dialogue when the detached dialogue approach is employed. Finally, the receiver enters the competition status with the highest priority to send an acknowledgement (ACK) message back to the transmitter if it receives the data packet correctly. This completes the RTS/CTS/data/ACK4-way handshaking of MACP. Negative/implicit ACK or group ACK mechanisms are also suitable for MACP since transmissions of data packets typically have considerably higher success rate as compared to previous MAC protocols.

When a nearby node receives an RTS message, it sets its network allocation table (NAT) to be unavailable for reception for the time durations requested by the overheard RTS message; when a nearby node receives a CTS message, it sets its NAT to be busy for transmission for the time durations requested by the overheard CTS message. When a cancellation message is received (possibly piggybacked in a resent RTS or CTS message), the NAT is updated accordingly. Since virtually all RTS messages can be received without collisions and the node is not allowed to receive data packets when NAT is specified as unavailable for reception, it will not schedule a reception that will be collided by other transmissions; since virtually all CTS messages can be received without collisions and the node is not allowed to transmit anything on the data channel when NAT is specified as unavailable for transmission, it will not transmit anything to collide other nodes' receptions.

If an intended transmitter does not receive a CTS message or ACK before it times out, it will double its CW value, and repeat the above handshaking process. If the node succeeds in the intended transmission, it resets its CW to CWₘᵢₙ. On the other hand, if the intended transmission is still unsuccessful after a certain number of retrials the associated data packet will be discarded. Other mechanisms for backoff control may also be employed by MACP if they match.

### B. Central Ideas for MACP and its DiffServ Supports

The central idea of MACP is simple but powerful. In MACP, we simply employ an additional level of channel access competition to guarantee collision-free transmissions of RTS and CTS messages, or to reduce the probability of collisions for such control messages. As a result, RTS and CTS messages can be received by all nodes that should receive them with 100% probability or at least a high probability, collision of data packets can be prevented; hence the name multiple access “collision prevention”.

If centralized control is feasible (e.g., with the availability of clusterheads), the additional level of channel access can be implemented based on Aloha, polling (e.g., PCF-like mechanisms), or splitting/tree algorithms. Adoption of these mechanisms is relatively straightforward and the details are omitted here. However, when fully distributed MAC protocols are desired as expected in typical networking environments, the protocol design becomes considerably more challenging. In what follows, we briefly present such a fully distributed mechanism based on distributed multihop binary countdown (DMBC). More details for DMBC and the prevention of collisions due to hidden terminals will be presented in Section XVI-C.

In DMBC, a node participating in a new round of DMBC competition selects an appropriate k-bit competition number (CN). The procedure for competition in DMBC is similar to that in BROADEN and PICK, except that DMBC has more fields in its CNs (including the optional random number part for fairness and the extension part for hidden terminal detection (HTD), and that ID is an optional field in DMBC. The details are provided in Section XVI-C. If a node has the largest CN among all competitors within its prohibiting range and no nearby nodes object to its candidacy, it will become a winner and acquire the privilege to transmit its RTS, CTS, or other control messages. When there are no obstructions between nodes and the ID numbers of nodes are unique among all their possible competitors, there can be at most one winner within its prohibiting range. As a result, control messages are collision free (without considering wireless channel transmission errors) since none of the control messages to be transmitted will interfere with each other at any nodes within their trans-mission ranges. Also, prioritized, almost fair, and collision-free/collision-controlled control/data packet transmissions can be achieved based on the proceeding procedure. DMBC can also be extended to distributed multihop kᵢ-ary countdown (DMKC) by incorporating kᵢ-ary countdown or its asynchronous version. Both DMBC and DMKC should be further equipped with the hidden terminal detection mechanism (see Section XVI-C) when there are obstructions that cause collisions. MACP-based nodes can function correctly with single transceiver per node. However, when dual transceivers are available per node, durations for bit-slots may be considerably reduced since the turn-around time do not need to be included in the bit-slot duration anymore. Both transceivers can also double the maximum speed per node by transmitting a data packet using different physical channel.

With DMBC, prioritization can be guaranteed even in multihop networks. We simply assign higher priority values to the first few bits of CNs for data packets with higher priorities, then they are guaranteed to gain access before nearby lower-priority packets. By combining such competition-based prioritization for transmissions of control messages, and the distributed differentiated scheduling (DDS) discipline for transmissions of data packets, a higher-priority packets will not be blocked by any other lower-priority packets. The resultant MACP scheme is the first and only distributed MAC reported in the literature thus far that has such prioritization capability in multihop wireless networks. Furthermore, by utilizing the strong differentiation capability of MACP, fairness can also be guaranteed and maintained adaptively. For example, nodes that experience more collisions than their neighbors can optionally raise the priorities for their packets. This way short-term fairness can be achieved in addition to long-term fairness. Similarly, nodes that were treated relatively unfairly can also optionally use a different probability density function (pdf) that lets them choose larger CNs with higher probability. We can also add a bit in CN (e.g., between priority bits and random (or ID) bits) called the continuation bit, where only nodes that lost the last (or a previous) competition are eligible to set it to one. Nearby nodes will then be able to take turn automatically, in a distributed manner, for packets belonging to the same priority class.

C. MACP with Hidden Terminal Detection (HTD)

FIG. 23 illustrates collision prevention with hidden terminal detection (CP-HTD). In FIG. 23a, the CN is 101100 based on the n-choose-k codes where n=6 and k=3. In FIG. 23b, the binary ID is 10101 and the extension is 10, based on the binary 0-count mapping (BZM) extension where IDs with 0, 1, and 5 1-bits are not allowed in the codewords.

In DMBC with HTD (DMBC/HTD), a node that intends to transmit a control message (possibly after binary backoff countdown to 0) competes with other nodes within its prohibiting range based on their competition numbers (CNs), where the radius of the prohibiting range is equal to or somewhat larger than that of the protection range of the associated control message to be transmitted plus that of the maximum control-to-control (C2C) interfering range for potential interfering sources in the neighborhood, and a control-to-control (C2C) interfering range is a range within which a nearby node will receive, from an interfering control message, interference above certain threshold (nonnegligible for the reception of control messages). (For hoc networks with directional antennas, the shape of a prohibiting range is composed of two major parts in the direction of transmission and its opposite direction, but with smaller distance for all other directions.) In general MACP protocols, the CNs do not need to be unique. However, for MACP to achieve collision freedom for both control messages and data packets, the CN used by a node must be unique among all the nodes that are competing at the same time within its prohibiting range. In the resultant collision-free MACP(CF-MA CP) protocols, the purpose for the competition is to elect at most one winner within its prohibiting range in a fully distributed manner. Note, however, that it is not required for the competition to elect a winder for “every” prohibiting range.

A CN in CF-MACP consists of an optional priority part, followed by an optional random number part and a unique competition ID. All the unique competition ID in the ad hoc network should be based on the same set of additive error detectable codes (AEDC). In particular, a binary AEDC is a binary codeword that is guaranteed to be changed to a non-codeword as long as any 0-bit is changed to 1, given that none of the 1-bits are changed to 0. For example, n-choose-k codes that have exactly k 1-bits and n-k 0-bits constitute a possible set of n-bit AEDC. Typically k can be selected as └n/2┘ or ┌n/2┐. An example for the 5-choose-3 codes is provided in FIG. 23a.

For simplicity, we first describe the competition procedure for time-division synchronous MACP, where all participating nodes are synchronized (e.g., to the GPS clock signal) and start the competition round at the same time. In this simplified version, a node whose CN has value 1 for its i-th bit, i=1, 2, . . . , n, transmits a short prohibiting signal during bit-slot i at power level sufficiently high to be detected by other nodes within its prohibitive range during bit-slot i with strength above the minimum required SNR for detection. We refer to this received signal strength for detection as the prohibiting threshold. On the other hand, a node whose i-th bit is 0 keeps silent and senses whether there is any prohibiting signal that has strength above the prohibiting threshold during bitslot i. If the silent competing node finds that bit-slot i is not idle (i.e., there is at least one competitor whose i-th bit is 1), then it loses the competition and keeps silent until the end of the current round of competition. Otherwise, it survives and remains in the competition. If a node survives all the n bit-slots, it becomes a candidate for the winner within its prohibitive range.

All active nodes that require to receive RTS/CTS control messages but are not in the competition can serve as mutually hidden terminals detectors to eliminate mutually hidden candidates that will transmit collided control messages to them. A hidden terminal detector listens to the channel to determine whether the prohibiting signal strength received during each bit-slot is above the control coverage threshold and the C2C interference threshold. It counts the number of bit-slots with received strength above the control coverage threshold during the current competition round. If the number is at least k, then the node becomes a valid mutually hidden terminals detector. It also counts the number of bit-slots with received strength above the C2C interference threshold during the current competition round, including the bit-slots with received strength above the control coverage threshold. If a valid mutually hidden terminals detector hears more than k such bit-slots, then there are mutually hidden nodes involved in the competition and the candidate(s) whose range(s) covers the valid mutually hidden terminals detector must be one of them. Even though other mutually hidden node(s) might have lost the competition, the valid mutually hidden terminals detector will send an OTS short signal during the following mutually hidden terminals detection slot to prevent such candidate(s) from transmitting their control messages. The candidate(s) then has to backoff before participating in competition again.

Note that different thresholds should be used in the preceding procedure for correctness and efficiency of the protocol. Note also that the duration for bit-slots should be selected to be sufficiently large so that multipath signals and echoes will not cause mistakes in such detecting and counting procedures. Moreover, the durations for bit-slots can be larger than that for the prohibiting signals, especially for the first few bit-slots. A competitor with CN bit value equal to 1 for the corresponding bit-slot will then randomly select an appropriate time instant within the bit-slot to start its prohibiting signal transmission. This can mitigate the additive prohibiting signal exposed terminal problem. If the short signals are transmitted with spectrum, the additive prohibiting signal exposed terminal problem can be further mitigated. An appropriate flow control mechanism should also be employed to reduce the number of competitors at the first place in order to reduce the required durations for bit-slots. Similarly, the duration for the mutually hidden terminals detection slot should be even larger, especially in a dense network, since many nearby valid mutually hidden terminals detectors may decide to transmit their detection signal during the same slot.

When these bit-slots are sufficiently large, an additional elimination mechanism can be employed to further reduce the collision probability between control messages when CNs are not unique for different nodes. More precisely, a competitor should give up the competition if it detects a prohibiting signal above the prohibiting threshold before it attempts to transmit its prohibiting signal during the same bit-slot. This, however, may cause nodes with smaller CN to win the competition against nodes with larger CN. Moreover, the number of available CNs can in fact be increased when such longer competition slot are appropriately utilized. A possible approach is to use DMKC with HTD where kᵢ-ary codes instead of binary codes are employed for CNs. The competitor whose i^{th} CN digit is equal to d then transmits its prohibiting signal during the (kᵢ−d+1)-th segment of the competition slot. This approach can also effectively mitigate the additive prohibiting signal exposed terminal problem.

### D. Collision-Free MACP(CF-MACP) Protocols

In MACP with HTD (MACP/HTD), we incorporate DMBC/HTD before transmitting control messages that require collision freedom or collision control. Although a single competition before an entire RTS/CTS dialogue is possible, it is typically more efficient to employ dedicated competition for the transmission of each control message. A rule to follow is that a node should not participate in a competition round if it is not allowed to transmit the intended control message after wining the competition. Such information can be known according to the CTS messages it received and the required power level for sending its the control message. In MACP/HTD whose competition bitslots, control messages, and data packets are mixed together in the same physical channel, spread spectrum techniques such as the spread spectrum scheduling S³ scheme needs to be employed so that the required power levels for sending the prohibiting signals and detection signals are not higher than the maximum allowed power (for not colliding data packets). Higher-priority control messages such as CTS and OTS messages are assigned higher priority in the CNs used for competition. Note that such priority can be obtained by partitioning the legitimate AEDC codes into appropriately-sized groups, and then use the group with the largest values for the highest priority messages, and so on. Since all control messages can be received without collisions, all schedules are know by nearby nodes so that no nodes will request for conflicting schedules or send control messages when nearby nodes are receiving data packets. By combining interference-aware mechanisms MACP/HTD protocols based on appropriate coding can then provide collision freedom for both control messages and data packets (when the corruption of control messages caused by bit errors rather than control message collisions and the resultant data packet collisions are not considered).

In addition to n-choose-k codes, we can employ other AEDC codes to obtain different classes of MACP/HTD protocols. In particular, binary 0-count mapping (BZM) is a general scheme that can convert any binary codes into AEDC that can be used in DMBC/HTD for achieving collision freedom. This approach is convenient since binary IDs may have been assigned to nodes for routing and other tasks. A node can then simply convert its ID or part of its ID (e.g., the locally unique part) as the ID part of its CN. The idea for BZM is simple and easy to implement: we simply attach a binary number corresponding to the 0-bit count of the original binary code as its extension. More precisely, we count the number of 0-bits in the binary code. We then encode that count into a nonzero binary number with strictly increasing mapping, and use it as a BZM extension. For example, if all values from (00 . . . 0)₂ to (11 . . . 1)₂ are allowed in the original binary code, we can simply use the binary representation of the count plus 1 for the BZM extension to be attached. As another example, if some counts do not exist in the codes to be converted, then we can map the smallest possible count to 1, the second smallest possible count to 2, . . . , the i^{th} smallest possible count to i+1, and so on, till the largest count. We then use the binary representation of the mapped value as the BZM extension. An example for DMBC/HTD based on BZM coding is given in FIG. 23b.

MACP/HTD based on BZM is similar to that based on n-choose-k codes. A difference is the definition for valid mutual hidden terminal detectors due to the differences in the codes. In BZM or any scheme with an error-detection extension, a node becomes a valid mutual hidden terminal detector when it received signals with strength above the control coverage threshold during the (BZM) extension bit-slots. The remaining procedure is similar to that for n-choose-k codes. In short, when a valid mutual hidden terminal detector finds that the received prohibiting signals above the C2C interference threshold do not constitute a legitimate codeword, it will send an OTS short signal. For some codes, more complicated rules or policy may improve performance by avoiding unnecessary blocking by OTS short signals. The details are omitted in this application.

E. The MACP with n-choose-k (MACP/NCK) Protocol

In MACP protocols, we incorporate distributed multihop binary countdown before transmitting control messages that require collision freedom or collision control. In single-channel MACP, prohibiting slots (e.g., CN bit-slots and detection slots), control messages, and data packets are mixed together in the same physical channel. If all nodes are synchronized to the same types of slots, then it will not cause problems. However, if the network is asynchronous, then certain accompanying mechanisms are required to avoid collisions and/or interference between different types of signals. Spread spectrum techniques such as the spread spectrum scheduling S³ scheme are possible solutions that can reduce the power levels for sending the prohibiting and detection signals (and/or control messages) so that data receptions protected by CTS messages will not collided by them. Other techniques are possible and will be reported in the future. In particular, group competition (see Section XVII-D) may be employed to partition nodes (or transmissions of nodes with specified power levels) into appropriate groups so that nodes/transmissions of the same group can avoid causing such interference/collision problems. In the rest of the paper, we only describe the competition procedure for separate-channel synchronous MACP for simplicity, where all participating nodes are synchronized and start the competition round at the same time, and the prohibiting signals, control messages, and data packets are transmitted in different physical channels.

In separate-channel synchronous MACP/NCK, the simplest version of MACP/NCK, an intended transmitter (for control messages or small data packets) uses a binary number that have exactly k 1-bits and n-k 0-bits as its competition number (CN). Typically k can be selected as └n/2┘ or ┌n/2┐. An example for CNs based on the 5-choose-3 coding is provided in FIG. 23a. During prohibiting bit-slot i, i=1, 2, . . . , n, the intended transmitter that has value 1 for its i-th bit transmits a short prohibiting signal at power level sufficiently high to be detected by (most/all) other nodes within its prohibitive range. We define the prohibiting threshold as the signal strength required for the received strength to be detected and recognized as a prohibiting signal. Note that there is a lower bound on the prohibiting threshold for all transmissions in any nodes, but the prohibiting threshold can be adjusted when interference control (see Section XVI-G.3) is employed. On the other hand, a node whose i-th bit is 0 keeps silent and senses whether there is any prohibiting signal that has strength above its prohibiting threshold during bit-slot i. If the silent competing node finds that bit-slot i is not idle (i.e., there is at least one nearby competitor whose i-th bit is 1), then it loses the competition and keeps silent until the end of the current round of competition. Otherwise, it survives and remains in the competition. If a node survives all the n prohibiting bit-slots, it becomes a candidate for the winner within its prohibitive range.

All active nodes that require to receive RTS/CTS control messages but are not in the competition can serve as mutually hidden terminals detectors to eliminate mutually hidden candidates that will transmit collided control messages (and/or small data packets) to them. A hidden terminal detector listens to the channel to determine whether the prohibiting signal strength received during each bit-slot is above the control coverage threshold and the control-to-control (C2C) interference threshold, where the control coverage threshold is the minimum signal strength required for a control message to be received successfully, and the C2C interference threshold is the minimum signal strength required for a control message to be collided by the signal. The hidden terminal detector counts the number of bit-slots with received strength above the control coverage threshold during the current competition round. If the number is at least k, then the node becomes a valid mutually hidden terminals detector. It also counts the number of bit-slots with received strength above the C2C interference threshold during the current competition round, including the bit-slots with received strength above the control coverage threshold. If a valid mutually hidden terminals detector hears more than k such bit-slots, then there are mutually hidden nodes involved in the competition and the candidate(s) whose coverage range(s) cover the valid mutually hidden terminals detector must be one of them. Even though other mutually hidden node(s) might have lost the competition, the valid mutually hidden terminals detector will send an objecting-to-send (OTS) short signal during the following mutually hidden terminals detection slot to block such candidate(s) from transmitting their control messages (or small data packets). The candidate(s) then has to backoff before participating in competition again. The contention windows for such candidates are exponentially increased whenever they are blocked by OTS short signals, but will be reduced the minimum value or a normal value when the transmission is successful. If a candidate winner does not receive any OTS short signals, then it becomes a winner and will be eligible to transmit its control message (or small data packet).

When the competition numbers are unique, there can only be at most one winner within the prohibitive range of the winner. As a result, the control message to be transmitted will not be collided. Since all control messages can be received by all active nodes without collisions, all schedules are known by nearby nodes so that no one will request for conflicting schedules. Hence, collision freedom can be achieved in MACP/NCK (when transmission errors due to unreliable wireless channels are negligible). Note that to enforce such collision-free property, a node lost a competition has to remain silent and observe the control messages for a sufficiently long time according to the observe before transmit discipline. However, when collision-freedom is not necessary, this requirement can be relaxed in MACP/NCK. Note also that the requirement for CN format can also be relaxed by choosing k 1-bits from n′≦n positions in CNs only (e.g., the last n′ bit positions).

Note that different thresholds should be used in the preceding procedure for correctness and efficiency of the protocol. Note also that the duration for bit-slots should be selected to be sufficiently large so that multipath signals and echoes will not cause mistakes in such detecting and counting procedures. Moreover, the durations for bit-slots can be larger than that for the prohibiting signals, especially for the first few bit-slots. A competitor with CN bit value equal to 1 for the corresponding bit-slot will then randomly select an appropriate time instant within the bit-slot to start its prohibiting signal transmission. This can mitigate the additive prohibiting signal exposed terminal (APSET) problem that may block far-away nodes unnecessarily when the density of competitors is high. If the short signals are transmitted with spectrum, the APSET problem can be further mitigated. An appropriate flow control mechanism should also be employed to reduce the number of competitors at the first place in order to reduce the number of concurrent competitors at the first place, reducing the required durations for such bit-slots and thus competition overhead. Similarly, the duration for the mutually hidden terminals detection slot should be even larger, especially in a dense network, since many nearby valid mutually hidden terminals detectors may decide to transmit their detection signal during the same slot.

In addition to the n-choose-k codes used in MACP/NCK, we can employ other codes for CNs to obtain different classes of MACP protocols. In particular, binary additive error detectable codes (AEDC) are binary codewords that are guaranteed to be changed to a non-codeword as long as any 0-bit is changed to 1, given that none of the 1-bits are changed to 0. n-choose-k codes are a special class of AEDC, while binary 0-count mapping (BZM) represents a general scheme that can convert any binary codes into AEDC (see FIG. 23b for an example). Various other codes may also be used to achieve respective advantages. For example, a binary code can be extended with a CRC code, another type of error detection codes, or a short n-choose-k code. The resultant protocols are not collision-free, but can reduce the length of CNs to reduce the associated control overhead. We can also cascade several codes of the same and/or different types to gain their combined strengths. For example, a CN can start with a PP-slot (see Subsection XVI-G.1) for mitigating APSET, followed by a binary code for higher efficiency in competition, and then ended with a short NCK code plus a HTD slot for further competition and to prevent the rare occurrence of mutually hidden winners. The MACP protocols resulting from these codes are usually similar to MACP/NCK, except that the required hidden terminal detection mechanisms may need to be modified. As another example, a declaration slot or encoded collision detection slot can be added for candidate(s) to transmit a single short declaration signal. If a valid mutual hidden terminal detector detects multiple declaration signals that are not multipath signals or echoes, it will send an OTS signal to prevent control message collisions at its location. When CNs are not guaranteed to be unique, the PP mechanism (see Subsection XVI-G.1) can be employed to improve the performance. Also, if a valid mutually hidden terminals detector can recognize the ID of the candidate to be blocked, it can send coded OTS signal to block that candidate alone if such a capability is supported. Another approach, to be referred to as the parrot approach, is to have active nodes or mutual hidden terminal detectors repeat the prohibiting signals they received or send a short signal at the end of competition with the CN they appear to have heard. Some of these subclasses of MACP will be investigated in details in the future.

### F. Other MACP/HTD Protocols

FIG. 3 provides an example for code division or frequency division DMBC/HTD.

Various other MACP protocols can be obtained by using different codes to achieve respective advantages. For example, a binary code can be extended with a CRC code, another type of error detection codes, or a short n-choose-k code. The resultant protocols are not collision-free, but can reduce the length of CNs to reduce the associated control overhead. Another potential approach is for valid mutual hidden terminal detectors to determine whether there are sufficiently strong signals in different bit-slots that are transmitted at different power levels (indicating the existence of mutually hidden terminals in the competition round). Another approach is to add a declaration slot or encoded collision detection slot for candidate(s) to transmit a single short declaration signal. If a valid mutual hidden terminal detector detects multiple declaration signals that are not echoes, it will send an OTS signal to prevent control message collisions at its location.

When the transmission rate becomes higher, the durations for control messages become relatively short. In such networking environments, time-division collision prevention such as the examples in FIG. 21 becomes inefficient when the competition duration is larger than those for control messages. An approach to this problem is to utilize code division collision prevention (CDCP) or frequency division collision prevention (FDCP). In CDCP or FDCP, several code channels (with a large spreading factor) or PHY channels (with narrow band) are employed. Each channel is partitioned into continuous competition subintervals that have size equal to that of a control message. Note that different competition subintervals may have different numbers of bit-slots. In particular, the first few bit-slots may have larger durations. A node enters the competition by starting with the i^{th} slot of channel 1, and then compete in the (i+1)^{th} slot of channel 2, and so on. The last slot of the last channel is devoted to the detection slot, while the winner sends its control message in the following slot for regular control messages, either in the control channel or in the channel shared by both control messages and data packets. The sender of CTS messages should stay alert for a sufficient number of subsequent control messages to detect RTS messages that request for a conflicting duration and power level.

F.1 Asynchronous MACP with Variable-Length CNs

Asynchronous MACP protocols can be obtained by adding an initialization slot to the beginning of competition rounds in synchronous MACP and employing the observe before transmit discipline. Under such a discipline, a node has to have listened to the channel for at least an observation duration, before can participate in a competition, where an observation duration is the time for a complete competition round (plus the maximum transmission time for control messages if the same channel is shared by competition signals and control messages). Note, however, that the channel does not need to stay idle during the observation duration for the node becomes an eligible competitor. As long as no initialization signals are heard during the observation duration, the node will become eligible for initiating or participating in a competition. This way the node can make sure that no other nodes are currently in competition. If a node hears an initialization signal after it becomes an eligible competitor, it can participate in the competition without sending the initialization signal. Instead, it starts its competition from the first competition bit-slot. If this chance is missed, the node loses its eligibility as a competitor and has to wait for another observation duration without hearing any initialization signals. To increase the number of nodes competing at the same time, the group competition approach can be employed. An alternative is to postpone the starting time for the first competition bit-slot and for participating nodes to relay coded initialization signals (e.g., coded with length or spread spectrum). However, such an alternative is relatively more expensive in terms of the communication overhead, and less effective in terms of the increase in the competition ranges.

Asynchronous MACP protocols can also be obtained by adding completion signals at the end of competition rounds. The observation duration can be reduced to the time required for a completion signals plus the maximum transmission time for control messages if the channel is shared. We also need to insert additional detection bit-slots in the competition round. The duration for completion signals must be longer than the period between detection bit-slots. When a node detects the existence of completion signals (or any signals when they are not coded or distinguishable), it will lose the competition. Such a node can either backoff or initiate a new competition at the end of the current competition round and control message slot. An important property for this approach is that CNs with variable lengths can be used without problems. However, in this scheme, nodes that start competition later may kick out nodes that initiate or participate in a competition earlier. By incorporating carrier sensing in addition to the observe before transmit discipline, nodes that still get kicked out usually have relatively lower priorities or CNs so that the resultant negative effects can be mitigated. To completely solve the aforementioned problem, initialization slots may be combined with this approach.

When a dedicated channel is available for competition signals, we can use another way to solve the preceding problem by inserting prohibiting signal bit-slots in the competition round periodically. In such an approach, a node first senses whether the channel is idle for at least the period between the inserted prohibiting signal bit-slots. If the channel is busy, the node waits for the channel to be idle for a sufficiently long time; otherwise, it starts the competition by sending its first periodical prohibiting signal. By inserting a sufficiently long sensing slot at the end of a competition round, this approach also allows MACP to use variable-length CNs. To reduce the communication overhead of this approach, we can use its variant by employing special coding for CNs where 1-bits (and thus prohibiting signals) are not allowed to be separated by too many 0-bits.

A problem with asynchronous MACP is that its differentiation capability will be compromised. With CDCP or FDCP, this problem can be solved by allowing higher-priority nodes to enter channel 2, 3, or another channel directly.

### G. Accompanying Mechanisms for MACP

### G.1 The Position-Based Prohibiting (PP) Mechanism

In BROADEN and the MACP protocols presented in this application thus far, we utilized binary countdown with the on/off prohibiting mechanism. To mitigate the APSET problem, we can insert one or several larger competition slots based on position-based prohibition. We can also design MACP with position-based prohibition (MACP/PP) protocols that rely on position-based prohibition for all its competition slots. When the PP-slot is sufficiently large, we can also use a single PP-slot for competition, possibly followed by a yield period (with sensitive carrier sensing) before transmitting a control message or data packet.

The position-based prohibiting mechanism is similar to the on/off prohibiting mechanism except that we use position-based prohibiting slots (PP-slots) with durations larger than bit-slots, and there are competitions for signals within the same PP-slot. More precisely, there is one or multiple PP-slots in a competition round, where the durations typically decrease (or sometimes remain the same). There is a guarding period (lower bounded by the maximum-allowed propagation delay) at the end of a PP-slot (as in a bit-slot) so that the prohibiting signal transmitted in a PP-slot will not be heard with non-negligible strength in the subsequent PP-slots or bit-slots by any nodes in the network. The prohibiting signals can then be transmitted at any desirable position in the remaining part of a PP-slot, according to the viewpoint of the transmitter.

A competitor first decides whether it is preparing to send a prohibiting signal in the following PP-slot. If it does, it selects an appropriate position in the PP-slot either randomly according to an appropriate probability distribution or following certain rules (e.g., according to its priority, urgency, and/or ID). It will then listen to the channel before its time to turn around for transmitting its own prohibiting signal. (As a result, if there is an additional receiver for sensing, the turn-around time can be avoided and considerably increasing the efficiency of MACP/PP.) If it did not hear anything above the appropriate prohibiting threshold, it will transmit a short prohibiting signal at the selected position according to its own clock and viewpoint of the competition frame; however, if it detects any prohibiting signals before the selected position, it loses the competition and will wait for the next competition round or back off for a longer time. A competitor that survives all the prohibiting slots become a candidate, and will become a winner eligible transmitting a control message (or small data packet) if it does not receive any OTS short signals from valid mutual hidden terminal detectors.

When the PP-slot(s) is/are followed by NCK bit-slots the hidden terminal detection mechanism for NCK can be applied to the NCK part. For MACP/PP, we can augment several special NCK bit-slots, called HTD-code bit-slots, for the purpose of hidden terminal detection. Such HTD-code bit-slots may be considerably smaller than typical PP-slots or bit-slots since the former do not need to be lower bounded by the maximum-allowed propagation delay. Instead, as long as the prohibiting signal can decay below the threshold for HTD in the subsequent HTD-code bit-slots, the duration is acceptable. HTD-code bit-slots based on AEDC can also be used alone as a means for wireless collision detection. Some special requirements include that the total duration for these bit-slots should be lower bounded by twice the maximum-allowed propagation delay (plus some additional time). Also, at least one of the first few bits and one of the last few bits must be equal to 1. The approach based on an additional declaration slot or coded collision detection slot (see the end of Section XVI) may also be employed for hidden terminal detection. Note that in MACP/PP, the declaration slot will also employ the PP mechanism for competition, in addition to the purpose of mutually hidden winners detection.

Note that we can use backoff control (similar to IEEE 802.11/11e) as a means to conduct flow control in order to mitigate the APSET problem. However, when backoff control is the only mechanism to reduce the attempt rate, radio resources cannot be efficiently utilized because the radio channel will typically stay idle for a non-negligible portion of time. However, in MACP/PP or other MACP protocols augmented with position-based prohibition, backoff control can be employed to reduce the typical number of competitors to a constant number considerably greater than 1, and then use the first or first few PP-slots to eliminate most of the competitors. This way the APSET problem can be resolved without noticeable idle times for the ratio channel, considerably increasing the radio efficiency.

### G.2 Fairness and Prioritization in MACP

We develop several strategies that can improve fairness and prevent starvation in MACP networks based on its strong differentiation capability. A directly applicable approach is to allow nodes or packets that have been treated unfairly to climb up one or a couple of priority levels when desired, or to use a more favorable probability distribution to select the random number part of CNs. To assess the unfairness or the urgency, we can either exchange the performance information locally with nearby nodes, or use one or the composite measure of several performance metrics, such as delay, queue length, granted bandwidth, discarding ratio, blocking rates, the status of last attempt, service quality, and the number of trials, collisions, or failed transmissions. We then calculate the urgency index and the efficiency index, and determine the CN in combination with other parameters such as priority by either mapping to the urgency part of CNs (with one to typically several bits) or to choose an appropriate probability distribution to randomly select CNs. By appropriately combining the delay or countdown time with the location information, we can in fact generate unique CNs without having to rely on other ID assignment mechanisms. We can also set the continuation bit to 1 when a node lost a competition (possibly under with certain accompanying conditions) as a simple mechanism to achieve fairness, especially under the single-hop environments.

To enhance fairness and QoS in an efficient and economic manner, we propose to utilize the multiple ID scheme (MIS) that assigns multiple IDs to a node. The IDs for a node are typically spread all over the possible domain so that there will not be nodes that only have smaller IDs and suffer from unfairness or even starvation. As a result, MIS naturally solves the inherent unfairness problem of binary countdown and CSMA/IC. To support prioritization in the disclosed MIS approach, a node simply uses larger IDs for higher-priority transmissions, and smaller IDs for lower-priority transmissions. Similarly, to support adaptive fairness in MIS, a node can choose to use a relatively large ID after it has been treated unfairly, or randomly select a smaller ID as a courtesy to yield to other nodes when it has been well treated. In MACP, several additional bits typically need to be reserved for IDs just in case some prohibitive ranges become very dense. As a result, there will be many unused IDs that can be well utilized in MIS without additional competition overhead in typical operating environments, Thus, in contrast to previous approaches that requires additional bits for prioritization and fairness, MIS can support fairness and QoS without increasing CN lengths, leading to economic implementations. Moreover, this scheme will experience smaller collision rate as compared to CSMA/IC, PIC and PRIC when there are duplicate IDs, since multiple concurrent competitors that possess the same ID(s) may not choose the same ID at the same time. When a region becomes denser, a node can release some IDs to other newcomers. If variable-length CNs are supported, a node typically owns several ranges of IDs, and can split a range and release part of it to other newcomers. The MIS approach also works well with E-MACP/GC and power control (see Subsection XVI-G.3).

For MACP/PP and MACP protocols augmented with position-based prohibition, the priority can be implied by the probability distribution used to randomly select the positions for prohibiting signals in a way similar to the random selection of the random number part of CNs. However, in MACP/PP, the random selection is redone for every PP-slot, possibly with different probability distribution to optimize the performance.

### G.3 Interference/Power-Control in MACP

When power control is employed the coverage ranges for many RTS control messages may be orders of magnitude smaller than the maximum control coverage range, given sufficient density and appropriate power-controlled routing and MAC protocols. When interference control is employed, the coverage ranges for CTS control messages associated with low-power transmissions may also be considerably smaller than the maximum control coverage ranges by allowing higher tolerance to interference. However, in naive implementations of MACP, the prohibitive ranges for those control messages can only be slightly smaller than the associated maximum prohibitive ranges, leading to unacceptable overhead in terms of spacial usage and power consumption for competition.

In this application, we extend the disclosed interference control to the transmissions of prohibiting signals. By allowing a higher tolerance threshold for reception of control messages, the prohibitive ranges can be considerably reduced, thus reducing the transmission power for the associated prohibiting signals and allowing more winners to transmit control messages or data packets within the same area. Note that competitors that employ interference control need to adjust their prohibiting thresholds accordingly so that they will not be prohibited unnecessarily by far away nodes that use higher transmission power levels for prohibiting signals. The disclosed approach can also be combined with the differentiated channel discipline for power control supports to make it even more efficient. When both power control and interference control are employed, the size of prohibitive ranges will change considerably from transmission to transmission. As a result, the optimized lengths for the random parts of CNs (for collision control) or minimum lengths for IDs (for collision freedom) are considerably different for different transmissions. Thus, variable-length CNs and variable-length MIS are is particularly suitable to interference/power-controlled MACP.

Other potential mechanisms for MACP and related protocols include coded interference signaling and detached competition. In coded interference signaling, intermittent prohibiting signals will be recognized as codes to convey important information or instructions when none of the other more efficient approaches (such as spread spectrum) are working or supported. Periodic prohibiting signaling can also be used to prohibit other nodes (especially standard IEEE 802.11/11e nodes) from transmitting based on their inherent carrier sensing mechanism. This is particularly efficient when done by an MACP agent near the standard IEEE 802.11/11e node, but is also useful when radio channel characteristics (such as severe multipath effect) prevent correct decoding of signals even when interference of similar levels are not negligible. Detached competition utilizes part of the CNs or coded interference signaling to indicate the specified time for the transmissions of control messages after winning a competition. Detached competition may improve spacial reuse for trans-missions of control messages, though the same issue can also be addressed by other techniques such as group competition.

### XV. GROUP ACTION

In MACP, the required prohibiting range is very large. In particular, when power control and/or interference control are employed, the C2C interfering range for the RTS/CTS control message to be transmitted can be orders of magnitude smaller than the maximum or typical prohibiting ranges. If no appropriate accompanying mechanisms are employed, the radio spacial resources will be severely wasted for transmitting such control messages.

### A. The Group Activation Approach

An approach we propose to solve this problem and further reducing the control overhead is called group activation. In the group activation approach, transmitter-receiver pairs and/or transmitters (with specified power limits) that can transmit their control messages or data packets without colliding with each other can form a control message group or data packet group, respectively. Groups that have more transmitter-receiver pairs (or links) will typically lead to better spacial reuse if the majority of links participate in the transmissions; while groups that have more transmitters with power level specifications typically have higher participation rate. The reason for the latter is that such specifications allow transmissions to any receivers as long as the power levels used by the transmitters do not exceed the specified limit. Large numbers of such groups may need to be formed for the group activation approach to be effective, especially when power control and/or interference control are employed. Typically, frequently used active links are more valuable to be considered in such groups. These groups should be maintained dynamically and locally, where links are included or removed when they satisfy or dissatisfy the requirements and the group maintenance mechanism is provoked. In particular, a link or transmitter should be included into more groups if it does not have sufficient chance for transmissions, while a link or transmitter should be removed from some groups if its participation rate is low. Also, groups are created or deleted when the group generation mechanism is provoked. A special hardware requirement for nodes supporting group activation is that they should use buffers that are capable of out of order queuing, at least for the first few positions in each queue. These mechanisms are out of scope of this paper and will be reported in the future.

When the group activation approach is applied to DMBC or DMKC competitions, we obtain the group competition scheme; when it is applied to the scheduling of data packets (e.g., based on the detached dialogue approach or sensitive CSMA), we obtain the group scheduling scheme. For both schemes, a group coordinator or a group member (if allowed) can initiate a group synchronization process by sending a group synchronization message. Then the group becomes active. In the group competition scheme, a group synchronization message specifies the group CN to be used and the disclosed time for group members to compete for the privilege of transmissions. In the group scheduling scheme, a group synchronization message specifies the disclosed time for group members schedule or attempt for their transmissions of data packets. The specified time should be relative when there is no common reference for time, but can be a absolute time when a common reference for time (such as GPS) is available.

A node that plans to participate in an active group transmission can optionally relay the group synchronization message, possibly with essential modifications such as the reduction in the remaining time for synchronization. However, excessive relaying of group synchronization messages should be avoided, for example, by preventing nodes from relaying after they have received the same group synchronization message for a certain number of times (which can be a default or dynamically controlled threshold). Typically, it is desirable to have larger coverage ranges for such group synchronization messages. However, the allowed power level may be quite limited by regulations or the allowed interference to other data packet receptions (when a shared channel is employed). One way to resolve this problem is to employ spread spectrum-based techniques. In spread spectrum hierarchical grouping, a node first chooses a level-1 group it belongs to, where a level-1 group is composed of various nodes or dedicated to a certain physical/code channel. Each level-1 group is assigned an approximately orthogonal code for the transmissions of their group synchronization messages. There are typically many level-2 groups belonging to a level-1 group, and a level-2 group is composed of links and/or transmitters that can transmit simultaneously without interfering with each other. In the group competition scheme, a level-2 group either uses a default group CN or dynamically choose a new CN when initiating the group synchronization process. An active node listens to the spread spectrum code for its group when it has something to transmit or receive. If it receives a group synchronization message for a group it belongs to, it will participate in group competition or group scheduling, respectively, during the specified time if the requirements are satisfied. In the following subsections, we present specific details for each of the schemes.

### B. The Group Competition Scheme

In group competition, all nodes participating in the same group activity (e.g., the level-2 group in hierarchical grouping introduced in Subsection XVII-A) use the same group CN for competition at the same time. The group CN can be assigned partially randomly for every new initiation, but can also be used repeatedly until timeout. Note that when relative time is specified the propagation delay should be taken into account so that the prohibiting signals from a node must not kick out other group members participating in the same group activity. This can be easily done by ignoring prohibiting signals that arrive right before the transmission of one's own prohibiting signal. This way many group members within a typical prohibiting range may win the competition at the same time, considerably reducing the overhead for competition and significantly increasing the spacial reuse for transmitting control messages.

Different groups may avoid competing at the same time if such information is known and the traffic for competition is not heavy; however, it is acceptable for different groups to compete at the same time. The latter is desirable or even inevitable when the number of groups is large, the traffic for competition is heavy, or the typical percentage of members participating in a group competition is not high. Similarly, individual nodes may avoid competing with such groups if the information is known, but this is also allowed especially for nodes that have control messages or data packets with high priority, large delays, or long queues. When multiple groups are allowed to compete at the same time, prioritized group competition can be employed where higher-priority groups (e.g., with higher-priority transmissions or more compact spacial reuse) are assigned larger group CNs. The distributed differentiated scheduling (DDS) discipline can be applied to prioritized group competition to further enhance its differentiation capability. The resultant schemed, called prioritized group competition with DDS, simply allows larger maximum postponed access spaces for groups with higher priority. This enhancement can increase the chances and reduce delays for higher-priority groups to initiate group competition.

### C. The Group Scheduling Scheme

When the detached dialogue approach is employed, group scheduling can enable distributed but coordinated transmissions of data packets to increase spacial reuse. Transmitter-receiver pairs (links) and/or transmitters with specified power levels can form groups if their data packets will not collide with each other and it is beneficial for them to transmit together. Similar to group competition, such a link or transmitter can belong to multiple groups. MACP nodes will then try to schedule their data packet slots during the times specified by their group initiators. Since the penalty is not high when a transmission outside a group is scheduled during the time specified by the group, the scheduling of such transmissions does not need to be avoided. Otherwise, expensive radio resources may be wasted due to staying idle unnecessarily, However, to increase the effectiveness of group scheduling and thus spacial reuse, transmissions belonging to the same active group should be given higher priority to attempt for their “synchronized” scheduling. This can be effectively supported by the DDS discipline, where higher-priority packets are allowed to be scheduled further into the future (by allowing lager postponed access spaces for them). Moreover, the DDS discipline can also be applied to group scheduling by assigning larger maximum allowed postponed access spaces to higher-priority groups. We refer to the resultant scheme as prioritized group scheduling with DDS. Prioritized group competition and prioritized group scheduling are collectively called prioritized group activation.

In addition to the group synchronization process disclosed in Subsection XVII-A where a group synchronization process can be initiated by a group synchronization message and its effective range can be expanded by relaying the message, we can also initiate a group synchronization process and expand its effective range based on a series of RTS/CTS dialogues when the detached dialogue approach is employed. In such a process, the information for activating group scheduling is piggybacked in RTS/CTS messages. Nodes that receive such an RTS/CTS message with group synchronization information will check whether they have data packets that belong to the same group. If so, they use their own RTS/CTS dialogues (with small backoff times) to request for transmissions or receptions during the same or overlapping times. Such group scheduling information is also piggybacked in the new RTS/CTS messages (possibly with necessary modifications). If the scheduling attempt succeeds, other nodes that receives the new RTS/CTS messages can repeat the same process, until the scheduled time is too close. For such a group synchronization process to be effective, the initial postponed access space used should be sufficiently large.

To reduce the average per-packet overhead for group scheduling and/or group competition, we can request for periodical packets slots instead of a single packet slots. A cancellation mechanism is required in such a paradigm so that resources are not wasted when some nodes do not have appropriate packets to transmit or receive during the scheduled packet slots. Nodes can also aggregate a number of packets into a burst so that the overhead required for scheduling a burst is averaged out among multiple packets. This approach is particularly effective when combined with cluster-based or backbone-based routing protocols.

D. Extensible MACP with Group Competition

In the group competition mechanism, only nodes (or transmissions of nodes with specified power levels) belonging to the same level-3 group are allowed to compete at the same time. Nodes belonging to the same level-2 group use the same activation mechanism to invoke other nodes, while nodes (or transmissions of nodes with specified power levels) belonging to the same level-1 group use the same group CN for competition and are encouraged to compete at the same time. Note that a node may have membership in multiple groups at the same level. Note also that level-1 groups consist of members that can transmit their control messages or data packets at the same time without causing collisions. The term “group competition” mainly refers to the fact that members belonging to the same level-1 group can concurrently participate in competition with the same group CN. As a result, “groups” are referring to level-1 groups in this application if the level is not explicitly specified. Other hierarchical structures and grouping strategies are possible for group competition, but are outside the scope of the paper.

There are a number of advantages for employing the group competition mechanism. First, the typical number of winners within a typical prohibitive range will be significantly increased (e.g., considerably greater than 1). As a result, the overhead for competition is now shared by many winners and can thus be considerably reduced per winner. Second, many level-1 group members within a typical prohibitive range may win the competition and become eligible for transmissions of control messages at the same time. As a result, the spacial reuse can be considerably improved for the transmissions of RTS/CTS control messages, significantly reducing the control overhead. Third, when many level-1 group members are competing at the same time, the chance of having hidden terminals will be significantly reduced. As a result, in E-MACP/GC, the HTD mechanism becomes optional, which can reduce the competition overhead and considerably simplify the design of asynchronous E-MACP/GC protocols. Fourth, by appropriately adjusting the prohibitive ranges, both the hidden and exposed terminal problems can be resolved or at least mitigated without having to rely on RTS/CTS dialogues. This can considerably reduce the control overhead, especially when data packets are not large. Fifth, many level-1 group members within a typical prohibitive range may win the competition and become eligible for transmissions of data packets at the same time (when Data-ACK two-way handshaking is employed), solving or at least mitigating the exposed terminal problem of CSMA/IC. As a result, when RTS/CTS handshaking is replaced by, or combined with, sensitive CSMA (with lower carrier sensing threshold) or prohibition-based competition as in CSMA/IC, the spacial reuse can be significantly improved as compared to sensitive CSMA or CSMA/IC without group competition. Sixth, group competition naturally leads to effective coordination between level-1 group members, which enables effective group scheduling among nodes that are eligible to transmit data packets or control messages at the same time. This further improves the spacial reuse relative to conventional distributed MAC protocols that typically have little or no coordination.

To take advantages of the aforementioned characteristics, we develop extensible MACP with group competition (E-MACP/GC), a collision-controlled MAC protocol where the RTS/CTS dialogues and the hidden terminal detection mechanism are optional even in multihop networking environments. In E-MACP/GC, the lengths of CNs may be adaptive to traffic conditions, the tolerance to collisions for the associated transmissions, and the local history of performance. When the traffic is very light, group competition or even the competition itself can be skipped if so desired, and be reactivated when needed. A node or group can thus start with no or shorter CNs, and increases the CN length when the collision rate is high. The RTS/CTS and/or HTD mechanisms can also be turned on when found necessary (e.g., after a number of collisions or based on other observations/information). Different from IEEE 802.11/11e, however, E-MACP/GC does not suffer from the hidden or exposed terminal problem even when the RTS/CTS and HTD mechanisms are not turned on, as long as level-1 groups are sufficiently dense.

### E. Other MAC Extensions and Enhancements

E.1 (Multichannel) Sensitive CSMA with Group Scheduling

Group scheduling can be applied to MAC protocols that are not based on RTS/CTS dialogues. In particular, when group scheduling is incorporated into sensitive CSMA or multichannel sensitive CSMA, the spacial reuse can be considerably increased by solving the exposed terminal problem that originally exists in (multichannel) sensitive CSMA. Moreover, coordination between group members will also increase the compactness of spacial reuse.

In (multichannel) sensitive CSMA with group scheduling, an appropriate group synchronization process will enable members belonging to the same group to attempt for transmissions approximately synchronously. For example, when the process described in Subsection XVII-A is used, one spread spectrum code should be assigned for each physical channel. Since nodes that participate in the same group scheduling activity will not be able to sense the carrier transmitted by each other, their carriers will not block other group members. As a result, nodes that would have been blocked by each other due to the exposed terminal problem in (multichannel) sensitive CSMA, can now transmit their data packets at the same time. Note that when relative time is specified, the propagation delay should be taken into account by ignoring carriers that arrive right before the transmission of one's own data packet. Note also that different groups should schedule for nonoverlapping time durations in this scheme (unless such information is not known), and individual nodes should also attempt for transmissions at nonoverlapping times.

### E.2 The Group Scheduled Group Competition (GSGC) Scheme

The prohibiting-range exposed terminal problem is a problem caused by prohibiting ranges that are considerably larger than the associated data coverage ranges, which is similar to the interference-range exposed terminal problem. The prohibiting-range exposed terminal problem exists and reduces the achievable throughput in CSMA/IC. But the simplicity of CSMA/IC and its collision-free property may justify the loss in efficiency in some applications. However, when power control is employed, some data packets will be transmitted at low power levels corresponding to transmission/interfering ranges that are considerably smaller than typical prohibiting range. This leads to the variable-power heterogeneous exposed terminal (VP-HET) problem in CSMA/IC, lowering its achievable throughput by orders of magnitude, which is not acceptable.

In this subsection, we propose the group scheduled group competition (GSGC) scheme that can solve VP-HET without relying on RTS/CTS dialogues. This is achieved based on a completely different paradigm that combine the group scheduling and group competition techniques. In GSGC, many power-controlled data packet groups are formed for active links and/or transmitters. Such groups are used for both group scheduling and group competition. As a result, the transmissions included in a group must not collide each other. Also, the same group CN is used for the group members to compete. Group coordinators or general nodes can then initiate group scheduling in a way similar to S-CSMA with group scheduling. Group members that decide to participate will start their competitions at the scheduled time using the assigned group CN. If a node wins the competition, it becomes a candidate for transmitting its data packets. The main difference between GSGC and MACP/HTD is that only receivers serve as hidden terminal detectors in GSGC. If an intended receiver finds that the intended reception will be collided by hidden terminals (e.g., from other groups or individual nodes), it will send an OTS signal (e.g., coded with spread spectrum) to its candidate transmitter to stop it from transmitting. Such an OTS signal can also be sent to the potential interferer instead if the ID and code for the potential interferer are known.

Note that mixing transmissions from different groups or individuals is very expensive in GSGC so that this should be avoided. The reason is that no transmissions of data packets will be allowed around the boundaries between different groups and individuals. To reduce the numbers of group members required for GSGC to be efficient, the differentiated PHY/code channel discipline can be employed. Then the prohibiting ranges can be considerably reduced so that the number of low-power transmissions required to fill one or several prohibiting ranges can be significantly reduced. Interference control can also help with this issue, especially when both techniques are employed.

Wireless collision detection, the wireless counterpart for CSMA/CD, is a mechanism that has been pursued for decades but no satisfactory approaches have been found. One way to support it is to utilize dual channels and dual transceivers per node, and have the on-going receiver transmit an OTS signal to its on-going transmitter. To realize wireless collision detection with a single channel and large propagation delay, we can bit-slots that are considerably shorter than the typical propagation delay. If an intended transmitter hears prohibiting signals during its idle bit-slots, a collision is detected so that the intended transmitter should backoff and retry at a later time; otherwise, it will transmit the data packet. When the intended transmitter has dual transceivers, it may be able to use very short bit-slots since propagation delay and turn-around time do not needed to be considered for the bit-slot duration anymore. As a result, the communications overhead can be considerably reduced. The disclosed wireless collision detection, should incorporate group scheduling when power control is employed. Otherwise, VP-HET will render power reduction useful in terms of the effectiveness of spacial reuse. In wireless collision detection with group scheduling, the group synchronization process can be initiated by the transmission of CN. Other group members become eligible to transmit if they receive the group CN correctly (without detecting prohibiting signals from other groups). As a result, VP-HET can be solved and the radio spacial reuse can be significantly improved.

### E.3 The Group Coordination Function (GCF)

The disclosed group coordination function (GCF) is an extension to point coordination function (PCF), hybrid coordination function (HCF), and ad hoc coordination function (A CF) for contention free periods in multihop wireless networks.

GCF employs a valid MAC scheme such as MACP to schedule for the contention-free periods for transmissions to be polled by group coordinators or other group members. The main difference between MACP-based GCF and the pure MACP scheme described in previous sections is that the latter only schedules for the durations of packets based on competition and RTS/CTS scheduling, while the former has to consider all the potential transmissions and receptions within every basic service set. More precisely, hierarchical grouping is employed in MACP-based GCF. Level-2 groups are composed of links and transmitters with specified power limits that will be polled by each other within the same basic service set; while level-1 groups are composed of level-2 groups that can coexist without colliding with each other for any combinations of legitimate control messages and data packet transmissions. As a result, the spacial reuse for allocating such GCF basic service sets has to be conservative. To increase the utilization of the radio spacial resources, individual nodes that are not polled or are outside the successfully scheduled basic service sets are allowed to transmit if these nodes and the transmissions in nearby contention-free basic service set all use RTS/CTS dialogues for scheduling. However, a conservative policy should be used for the scheduling of such additional transmissions in order to protect the contention-free polled transmissions This approach is similar to ACF.

Note that in GCF, a basic service set is allowed to have multiple group coordinators. The polling right can be passed from one group coordinator to another using token-based techniques. Other techniques such as classifying master-slave group coordinators are also possible. Note also that even though group scheduling is employed in MACP-based GCF, different level-2 groups typically request for different durations according to their needs. The scheduled contention-free period for a basic service set may also terminate earlier than the requested duration is so desired. Since MACP can support collision-free transmissions, MACP-based GCF can acquire collision-free basic service sets. Since group scheduling can lead to more compact spacial reuse, MACP-based GCF can acquire basic service sets that utilize the radio spacial resources more efficiently. Since group competition can reduce the control overhead, the communication cost required to initiate MACP-based GCF can be reduced.

### XVI. QOS-ADAPTABLE DDMDD

### A. Penalty-Based Adaptable Reservation (PAR)

In this subsection, we present the penalty-based adaptable reservation (PAR) scheme for network-layer and MAC-layer QoS differentiation based on PARA.

### A.1 The PAR Scheme

In PARA, the reservation and allocation of bandwidth are separated. The purpose of reservations is bookkeeping, while allocation explicitly assigns the bandwidth to a session and time slots to packets and/or bursts. Resource allocation is performed according to the information in the adaptable reservation profile. The reservation made by a PARA connection may contain more than one set of QoS requirements, one for the normal mode and others for degraded modes. A node may then adapt to the traffic conditions and provide acceptable service quality to all the connections by minimizing the aggregate penalty and thus maximizing user satisfaction. This feature will be referred to as adaptable reservation.

When adaptable reservation is used for a connection (possibly after aggregation) or a QoS classes, its setup packet is required to carry with it the resource requirements under the degraded modes, and the associated session(s) has to be able to cope with such a degraded bandwidth enforced by the network when there are no sufficient network resources. Network nodes (including base stations) with such an advanced feature have to record the requirements of each connection or QoS class, including the maximum tolerable delay and delay variation, the peak, average, and/or minimum bandwidths without degradation, and the bandwidth requirements (e.g., a fixed value or a window) under degradation level 1, level 2, and so on, along with the priority of the session or QoS class and the penalty for each degradation level (e.g., a fixed value for that level or a function of the assigned bandwidth within the associated window as well as the traffic conditions and resources consumed).

When there is sufficient bandwidth available, a network node allocates the required bandwidths without degradation to all the connections/QoS class, as in ordinary reservation protocols; when there is not sufficient bandwidth left, a network node may first hold a certain amount of traffic that is time-noncritical (which typically has the smallest penalty). If this is still insufficient to accommodate the traffic for new connections, handoffs, and/or reactivating/renegotiating connections, the network node reallocates the required bandwidth under degradation to some connections/QoS classes that have lower priority and smaller penalty.

There are three types of adaptable applications: namely, survivable applications, negotiable applications, and hybrid survivable/negotiable applications. If an application is survivable, a network node can drop its packets with lower priority when necessary without having to inform the application, while the remaining higher-priority packets can still be used to regenerate multimedia signals with acceptable quality; if an application is negotiable, a network node should not drop its packets but can inform the application to reduce its transmission rate; if an application is hybrid survivable/negotiable, a network node can drop its packets with lower priority when necessary to reduce its bandwidth requirement to a certain degree (e.g., 50%), while have to inform the application to reduce its transmission rate if further degradation (e.g., to 75%) is required. To accommodate immediate resource demands, a network node can first degrade some survivable and/or survivable/negotiable sessions in a timely manner, while minimizing the aggregate penalty by upgrading some degraded survivable and/or survivable/negotiable sessions after degrading some other negotiable and/or survivable/negotiable sessions with smaller penalty at a later time.

Note that the network node should try to provide the required bandwidths without degradation to high-priority connections/QoS class if possible, while reducing the bandwidths assigned to some (or even all) of the connections/QoS classes, when necessary. A goal of the bandwidth reallocation algorithm is to minimize the aggregate penalty, and thus to maximize user satisfaction, which can be easily implemented using a standard greedy algorithm and a prioritized data structure such as a heap. Note that the possibility of such degradation is within the agreement made between the network node and the sessions when they established the connections or when they renegotiated for new bandwidth. Degrading some services while still at a tolerable level can achieve higher satisfaction to all users as a whole, as compared to degrading real-time multimedia sessions without delay guarantees as in current best-effort networks. Also, it helps prevent waste of resources due to retransmissions when the traffic is heavy and the resources are most needed.

We may employ the ready-to-adapt discipline for timely bandwidth reallocation, where the sessions that may be degraded with lower penalty are selected by a network node in advance and updated regularly at its spare time (i.e., when the network node has sufficient processing resources). When the aggregate bandwidth requirement is reduced and/or the available bandwidth is increased, we can reallocate more bandwidth to degraded sessions. This can again be performed using a standard greedy algorithm and a heap based on the penalty (per unit bandwidth) of the degraded sessions. The ready-to-adapt discipline is also applicable to the latter scenarios, though the list of sessions that should be upgraded to reduce penalty is not as critical as the list of sessions that can be degraded with smaller penalty. Since sessions are chosen to be degraded or upgraded based on their penalty, which is flexible and can be assigned to maximize user satisfaction, we refer to the disclosed mechanism as a penalty-based adaptable reservation mechanism.

To reduce the overheads associated with repeated upgrading and degrading, we may delay the upgrading of sessions until a certain threshold for the available bandwidth is reached and/or after a certain timeout. Note that the values for the preceding threshold and timeout can be adaptive and dynamically controlled by the network nodes. Also, although the penalties and the number of degradation levels are provided by network applications during connection establishment, a penalty can be specified as a function of traffic conditions so that time-noncritical data packets that have to be retransmitted after being dropped will have relatively higher penalty value when the traffic is heavy (especially if they have consumed considerable network resources).

### A.2 Penalty Assignment in PAR: A Universal Approach

The PAR mechanism is universal in that it is applicable to the optimization of allocations under various important criteria. However, what is optimized is heavily dependent on the assignment of penalties, which may not be trivial. For example, we can quantify the average degree of user's complaint caused by a certain decrease in bandwidth assignment or dropping/delaying of packets as the penalty for the associated degradation. In this way, the minimization of the aggregate penalty for all sessions also minimize the “sum” of complaint of all users (to be referred to as aggregate complaint). Similarly, we can quantify the decrease in user's satisfaction caused by a certain degradation as the penalty for the associated degradation. In this way, when the aggregate penalty is minimized, the aggregate satisfaction for all users are maximized. The penalty for a certain degradation can also be used to quantify the lost of earning by a network operator. Then the revenue of the network operator is maximized when the aggregate penalty is minimized. Another possibility is to assign the penalty for a certain degradation as the inverse of the reduction in the user's satisfaction percentage, which ranges from 0 up to 100% (e.g., 40% when the resultant user's satisfaction is 60% of the user satisfaction when the bandwidth is not degraded). With such an assignment of penalties, the fairness of users is maximized when the aggregate penalty is minimized (i.e., most users tend to have similar satisfaction percentages). Various other approaches and variants for penalty assignments are also possible but are omitted here.

In general, using lost of revenue as the penalty helps the network operator to makes more money in a short or medium term; while using user's satisfaction as the penalty makes it more enjoyable for customers of the wireless network or the Internet as a whole, which in turn helps the network operator to be more competitive and keep more customers and thus make more money in the long run. As an example, if a certain user is most likely to call again after being blocked, the penalty can be made smaller to quantify the lost of revenue, while the penalty should be made relatively large to quantify the decrease in user's satisfaction since the user may switch to a competing service provider after his/her contract ends. The last approach does not maximize the aggregate users' satisfaction as the first approach, and is somewhat counterintuitive, but fairness or its variants may still be reasonable measures of consideration. Various criteria have their respective importance, so it is advantageous to assign the penalties so that the resultant service is satisfactory under most/all of the criteria. Since penalty-based adaptable reservation is universal and is “neutral” in that it does not have to be associated with a certain criterion, it serves as a useful tool to optimize the performance under multiple constraints. As a result, our approach can lead to an adaptation and reallocation policy that is more balanced amount various important concerns.

To achieve a certain objective, we may need to take into account multiple constraints and optimize multiple measures. Maximizing service provider's revenue in both medium and long terms, under possibly strong competitors, is one of such examples. To maximize the weighted sum of aggregate revenue and aggregate satisfaction, we simply use the weighted sum of the reduction in revenue and the reduction is user's satisfaction as the penalty for the associated degradation. However, if we want to take into account fairness of other criteria, the assignment of penalties may become considerably more complicated. This requires further experiments and is out of scope of this paper. Also, to achieve this objective, we should also consider the effects of pricing for services, redeemed credits to customer when degradation occurs, and so on. For example, when there are abundant radio resources, we may consider lowering the price for bandwidth to encourage more usages to increase earning and/or users' satisfaction. We may also offer attractive prices and deals for customers who are willing to accept degraded service when necessary, especially when the resources are heavily utilized, in order to make the disclosed penalty-based adaptable reservation mechanism work better.

### B. Penalty-Based Adaptive Admission Control (PAA)

It is critical for the next-generation Internet and wireless mobile networks to have the capability for differentiated service provisioning to various traffic types, where different traffic classes may have very different QoS requirements. For example, real-time traffic such as that generated by voice or video applications is latency-sensitive, while time-noncritical data traffic such as e-mails or ftp files is not. Also, some calls may be blocked without causing problems, while the active sessions of handoff mobile stations in wireless networks or the reactivating sessions traversing the Internet core should not be rejected in order to guarantee nondisrupted QoS. Therefore, we treat different requests differently according to their attribute in PARA.

The PAR scheme naturally encompasses the capability for adaptive admission control, and the resultant reservation and admission control mechanisms work effectively and harmonically. The reason is that in PAR, blocking of a session or postponing of a packet scheduling is associated with a penalty, which can be dynamically estimated according to both the application requirements and the individual stress conditions as well as its past (absolute/relative) performance. If the blocking of a session or deferring of a packet will likely lead to greater loss than degrading existing sessions or packet receptions, its penalty will be set higher than those of the latter. Then optimization of penalty naturally leads to optimized decision for admission control in an adaptive manner. We refer to this approach as penalty-based admission control and PAR with penalty-based adaptive admission (PAA) control as penalty-based adaptable reservation admission (PARA).

When there are several traffic classes, the penalty for blocking/deferring higher-priority traffic class will be higher, and vice versa. When the current utilization of the capacity is higher, more sessions/packets will be degraded so that the penalty for accommodating a new session/packet will be higher. As a result, by associating several (bandwidth) utilization levels with appropriate penalties, the aforementioned penalty-based admission control scheme naturally degenerate to a utilization-based or bandwidth-based admission control scheme. The advantages of utilization-based admission control include simpler implementation and management. Both penalty-based and utilization-based admission control belong to the differentiated admission control (DAC) scheme. Since our penalty-based resource management approach can take into account multiple constraints and complex policies, PARA and DAC can be implemented as multiconstraint/policy-based schemes.

### C. Application of PARA to MAC Protocols in Ad Hoc Networks

In RTS/CTS/OTS with differentiated adaptation (ROC/DA) and distributed reservation multiple access (DRMA), we disclosed to combine a MAC scheme with a differentiated QoS adaptation scheme for adaptable MAC operations and distributed reservations. For ad hoc networks, conventional RTS/CTS-based protocols or ROC are possible choices, while PARA investigated in this application is an appropriate candidate for the differentiated QoS adaptation scheme.

In the resultant RTS-CTS/PARA or ROC/PARA, RTS messages are used to announce the interference and power-control information as in IAMA, while CTS messages are used to declare receptions and enable estimation of the associated tolerable interference levels for nodes within the interference range. The main innovation in ROC/PARA is that the decision about whether a packet transmission or reception can be scheduled is determined on the penalties for scheduling and not scheduling it according to the possibilities of interfering with other concurrent receptions or being interfered by other concurrent transmissions, and the penalty for not doing so and further delaying or even discarding packets.

Consider an intended transmitter that has received a CTS message from an irrelevant receiver (i.e., belonging to another transmitter-receiver pair). If the intended transmitter transmits at power level L₁ during an overlapping period of time, it is going to generate interference approximately equal to, or upper bounded by, 11 at the irrelevant receiver, where I₁ is proportional to L₁. Different interference level will cause different increase in the probability for the scheduled reception to be collided, and thus I₁ can be translated into a penalty P_{R,1} by the irrelevant receiver. The intended transmitter then estimates its loss (e.g., in terms of further delays for its packets, possible discarding, as well as reduction in its allocated bandwidth) if it does not transmit this packet during that time, and also translates it into a penalty P_{T,1}. Note that other possibilities such as scheduling at another time or transmitting a different packet and/or at a different power level should be considered in its estimation of penalty. If P_{T,1}>P_{R,1} or P_{T,1} is greater than P_{R,1} by a certain threshold, the intended transmitter will go ahead and schedule, disregarding the reception of the CTS message. Note that the threshold value can either be static or dynamically controlled, and can be different at different nodes. When P_{T,1}<P_{R,1}, the intended transmitter can wait or schedule its transmission at a different time. However, when power control and interference control are employed, the intended transmitter can also estimate the penalties for transmitting at different power levels to see whether the resultant penalty (e.g., for higher collision probability caused by the reduced transmission power and thus received signal strength) can be smaller than the resultant penalty that will cause to the irrelevant receiver. Note that out-of-order scheduling is beneficial for ROC/PARA and should be exploited, but there is no need to always schedule for the lowest-penalty transmission first due to the increased complexity and communication overhead and the limited gain for such optimization. Also, the system for penalty estimation does not need to be absolutely optimized since the translation of one's potential loss to penalty is not a trivial task. Reasonable heuristics usually do for such purposes.

In ROC/PARA, bandwidth for a session or traffic class is reserved using PTS/OTS/CTS dialogues in a distributed manner. The information for reservation, interference estimation, and penalty is provided in the associated request-to-reserve (RTR) and clear-to-reserve (CTR) messages. When signal strength measurement is not available, the interference information in RTS, CTR, and CTS messages can be provided using the variable-power declaration mechanism. Similar to SARA, the reserved bandwidth does not need to be a constant value, but can be a fluctuated function for each penalty level. When the traffic condition is light, most sessions are serviced with high quality so that the penalty level for most nodes will be relatively low. As a result, most requests for reservations will avoid generating nonnegligible interference to exiting reservations, which will otherwise cause penalty higher than those caused by postponing or degrading those reservation requests. When the traffic condition is heavy or overloaded, some sessions will experience low quality so that their penalty level will be increased and may schedule their packets and reservations more aggressively. Penalty information can be exchanged locally, if so desired, to coordinate consistent operations in vicinity, Such local penalty information may also be exploited to control various MAC parameters (e.g., the persistent factor for increasing backoff times in the presence of collisions).

### XVII. DDA SOLUTIONS/SUPPORTS TO VARIOUS PROBLEMS

The details for DDA to resolve various problems can be found in our VTC'03 paper, and its performance evaluation can be found in our PIMRC'03 paper. We include some details here for completeness. More details and associated issues can also be found from our related papers.

### A. Solutions to Efficiency Problems

AA-based MAC protocols employ RTS/CTS dialogues to schedule the intended transmissions in ad hoc networks and multihop WLANs as in MACA, MACAW, and CSMA/CA of IEEE 802.11. AA-based MAC protocols can also employ ROC dialogues as in ROC and IAMA. The unique feature of AA is that the RTS, CTS, and ACK messages are allowed to be “detatched” from the associated data packets. In other words, there can be a postponed access space with optional duration between the completion of a CTS message reception and the start of the associated data packet transmission. The value for the postponed access space should be specified in both the RTS and CTS messages. Before a node transmits an RTS message, it chooses an appropriate postponed access space T_{L} for the intended transmission, according to its schedule as well as the periods available at the receiver if this information is known. The node then transmits its RTS message requesting to reserve a packet period starting at T_{L} time units after the expected completion time of this RTS/CTS dialogue. Since a node can access the channel for RTS/CTS dialogues in advance, T_{L} time units before the associated data packets are transmitted or even before the data packets are actually received by the intended transmitter from its upstream node, we refer to this strategy as “advance access”. An example for such detached dialogues in asynchronous AA is given in FIG. 2.

Note that when there are available packet transmission periods with small postponed access spaces, they can be chosen so that the delay of AA will not be increased and the throughput will not be degraded in the presence of mobility. Also, when large postponed access space is not desirable in a networking environment, the nodes can simply set it to zero or a small value. Moreover, the maximum postponed access spaces can be limited to the time required for several data packet transmissions so that the delay of MALT will not be considerably increased and the throughput will not be degraded in the presence of mobility. Note that the postponed access space is used to schedule the next data packet only, rather than reserving for packet slots periodically as in MACA/PR, so we do not assume constant-bit rate traffic and MALT can work efficiently in the presence of bursty traffic and high mobility.

The rational for detaching the CTS and ACK messages with the associated data packets includes enabling compact special reuse and effective QoS supports in ad hoc networks and multihop WLNs. AA enables compact special reuse by solving the exposed terminal problem, the heterogeneous hidden/exposed terminal problem, and the interference-range hidden/exposed terminal problem as well as mitigating the impacts of failed RTS/CTS dialogues. AA effectively supports QoS by solving the alternate blocking problem, enabling prior scheduling, and enforcing reservations, as well as avoiding repeated RTS/CTS dialogues for higher-priority packets. The reasons are explained in the following subsections and the next section.

### B. Solving the Exposed Terminal Problem

FIG. 21 illustrates the asynchronous advance access (AA) mechanism with a single shared channel for both control messages and data packets. Even if the reception of CTS messages at node P will be collided by the data packet transmission from node N, concurrent transmissions from nodes N and P are enabled by advance RTS/CTS dialogues in AA. ACK messages can also be detached from the associated data packets or piggybacked in RTS/CTS messages or data packets.

As pointed out, in MACA (and similarly in IEEE 802.11), an exposed node cannot successfully complete an RTS/CTS dialogue. One of the reasons is that the exposed sender (e.g., node C in FIG. 1a) cannot receive the CTS message from its intended receiver (e.g., node D in FIG. 1a) when it is being “exposed” due to an on-going transmission (e.g., from node B to node A in FIG. 1a).

In AA, since RTS/CTS messages are not required to be followed by their associated data packets, concurrent transmissions from node B to node A and from node C to node D (in the topology of FIG. 1a) can be scheduled without difficulties. FIG. 1 provides such an example, where node N (corresponding to node B in FIG. 1a) and node O (corresponding to node A in FIG. 1a) completes their RTS/CTS dialogue first, and then node P (corresponding to node D in FIG. 1a) and node Q (corresponding to node C in FIG. 1a) initiate their RTS/CTS dialogue. The RTS/CTS messages contain the requested/declared packet sending/reception periods. Even though node C received the RTS message from node B, this message only prevents node C from receiving during an overlapping period, but does not prevent node C from sending during an overlapping period. As a result, node B and node C can successfully schedule for concurrent transmissions, solving the exposed terminal problem.

Another problem with the exposed terminal problem is that in IEEE 802.11 and MACAW, an ACK message has to follow a successful data packet reception. The reception of the ACK message at node B in FIG. 1a (or O) will be collided by the unfinished transmission from node C (or P) to node D (or Q) if the data packet reception and the ACK message transmission are not detached. But in AA, they can be detached so that such collisions can be avoided. The time for separating data packets and ACK messages can be suggested by the associated transmitters, or simply determined by the associated receivers. When an ACK message is collided or when a data packet is not successfully received, the associated transmitter or receiver can employ appropriate accompanying mechanisms to handle the situation. In AA, ACK can also be piggybacked in the next RTS/CTS message or data packet from the associated receiver. An implicit ACK mechanism may also be employed in replace of explicit ACK. As a result, no problems will be caused even if exposed nodes have overlapping transmission periods.

FIG. 1 illustrates the exposed terminal problem in RTS/CTS-based ad hoc networks and multihop WLANs. In FIG. 1a, node B has started sending a data packet to node A, while node C intends to send a data packet to node D. Even though a transmission from node C will not collide the reception at node A, the intended transmission cannot be initiated since the CTS message for node C will be collided by the data packet transmission from node B to node A. In FIG. 1b, node A has started sending a data packet to node B, while node D intends to send a data packet to node C. Even though a transmission from node D will not collide the reception at node B, and the reception at node C will not be collided by the transmission from node A to node B, the intended transmission cannot be initiated. Otherwise, the CTS message from node C to node D will collide the data packet reception at node B.

Similarly, in MACA and IEEE 802.11, an intended receiver (e.g., node C in FIG. 1b) cannot successfully complete an RTS/CTS dialogue when there is an on-going reception within its transmission/interference range (e.g., when node B is receiving a packet from node A), since it is not allowed to reply its intended transmitter (e.g., node D in FIG. 1b) with a CTS message. Although node D in FIG. 1b might send its data packet without an RTS/CTS dialogue, such transmissions are not approved by RTS/CTS dialogues and such receptions are not protected by CTS messages, resulting in considerably higher collision rate in ad hoc networks and multihop WLANs.

In AA, nodes B and C (in FIG. 1b) can schedule for receptions with overlapping durations simply because the CTS messages are allowed to be detached from the associated data packets. Such concurrent receptions can be scheduled by an RTS/CTS dialogue between one of the transmitter-receiver pairs first, and then scheduled by another RTS/CTS dialogue between the other transmitter-receiver pair. FIG. 1 provides such an example, where node N (corresponding to node A in FIG. 1b) and node O (corresponding to node B in FIG. 1b) completes their RTS/CTS dialogue first, and then node P (corresponding to node C in FIG. 1b) and node Q (corresponding to node D in FIG. 1b) initiate their RTS/CTS dialogue. No problems will be caused. Our detached dialogue strategy is the first approach reported in the literature that can solve the exposed terminal problem and the aforementioned problem, even when the data packets and RTS/CTS control messages are transmitted and mixed together in the same PHY channel.

### C. Supporting Power-Controlled Variable-Radius Transmissions

FIG. 1 illustrates the heterogeneous terminal problem in power-controlled RTS/CTS MAC protocols. Ideally low-power data packets from node A to node B, from node C to node D, from node E to node F; and from node G to node H can be concurrently transmitted. However, a CTS message has to be transmitted at the maximum power level. As a result, if node D, F, or H has started its reception, node B is not allowed to send its CTS message so that the intended transmission from node A to node B cannot be initiated. Similarly, if node B has started its reception, nodes D, F, and H are not allowed to send their CTS messages so that the intended transmissions from nodes C, E and G cannot be initiated. The end result is that there can only be a single reception at most within the maximum transmission/interference range of a receiver.

Detached dialogues are particularly important for power-controlled MAC protocols. In power-controlled MAC protocols, the CTS messages need to be transmitted at the maximum power level even when the data packets and control messages (as well as RTS messages in some protocols) are transmitted at the minimum possible power level. If the dialogues are not detached and a single PHY channel is shared by both data packets and control messages, then it is impossible to squeeze many nearby low-power transmissions with overlapping transmission periods, since the CTS messages will collide with the receptions of nearby nodes otherwise.

FIG. 1 illustrates such a scenario with the heterogeneous hidden/exposed terminal problem. Ideally, if only data packet transmissions are considered, all the four transmitter-receiver pairs should be allowed to transmit concurrently. However, if a transmission from node C, E, or G has started, then the transmission from node A cannot be initiated. The reason is that the CTS message from the heterogeneous exposed node B is not allowed to be transmitted due to the receptions at nearby nodes (e.g., node D, F, or H). Otherwise, its CTS message will be collide the receptions at these nearby nodes. Similarly, if the transmission from node A has started, then the transmission from node C, E, or G cannot be initiated. Otherwise, their CTS messages will collide the reception at node B. As a result, only one node will end up being able to receive within the transmission range for its CTS message (which is large/maximum due to its transmission at full power), even when many low-power data packets can be transmitted concurrently without collisions within that maximum transmission range. We refer to this problem as the heterogeneous hidden/exposed terminal problem.

If RTS/CTS dialogues are detached from the associated data packets as in AA, then the aforementioned heterogeneous hidden/exposed terminal problem can be solved as the way the exposed terminal problem is solved by AA (see Subsection XIX-B). Even when separate PHY channels are devoted to data packets and control messages, detached dialogues are still useful for increasing the efficiency of power-controlled variable-radius transmissions. The reason is that the flexibility in AA dialogues enables more compact scheduling, which is particularly important for power-controlled MAC protocols, where the overhead for control messages is considerably higher relative to the bandwidth requirement for data packets.

### D. Supporting Interference-Aware Transmissions

FIG. 15 illustrates the interference-range problem in RTS/CTS-based ad hoc networks and multihop WLANs. In FIG. 15a, node A has started sending a data packet to node B, while node C intends to send a data packet to node D. A transmission from node C will not collide the reception at node B since the interference range (i.e., the medium circle) of the data packet transmission from node C does not cover node B. However, the intended transmission cannot be initiated since the RTS message from node C (with the transmission range represented by the medium circle and the interference range represented by the large circle) will interfere the data packet reception at node B. In FIG. 15b, node A has started sending a data packet to node B, while node D intends to send a data packet to node C. A transmission from node D will not collide the reception at node B since the interference range of the data packet transmission from node D does not cover node B. However, the intended transmission cannot be initiated since the CTS message from node C (with the trans-mission range represented by the medium circle and the interference range represented by the large circle) will interfere the data packet reception at node B. The end result is that there can only be a single reception at most within a very large area (e.g., the large circles, whose radii are about 4 times the maximum transmission radius for data packets when the interference radius is twice the transmission radius).

Detached dialogues are also important in supporting interference aware multiple access in ad hoc networks and multihop WLANs. More precisely, in some wireless technologies, the interference range is considerably larger than the associated transmission range (e.g., with approximately doubled radii). RTS and CTS messages have to be send to all nodes (with best efforts) within the corresponding interference ranges or enlarged protection ranges, instead of the transmission range only, in order to appropriately announce transmissions and declare receptions in such networking environments. If the dialogues are not detached and a single PHY channel is shared by both data packets and control messages, then it is impossible to schedule nearby transmissions

The reason is that the RTS message from node C is not allowed to be transmitted due to the reception at node B. Otherwise, the RTS message will interfere with the reception at node B. Similarly, the CTS message from node C is not allowed to be transmitted due to the reception at node B. Otherwise, the RTS message will interfere with the reception at node B. As a result, no nodes are allowed to transmit or receive within the interference range of a receiver (whose radius is approximately 4 times that of a transmission rage at full power level). This is a severe waste of radio resources and we refer to this problem as the interference-range hidden/exposed terminal problem. Detached RTS/CTS dialogues as in AA are required to solve the aforementioned problem and the additive interference problem. However, when no separate PHY channel(s) for control messages is available, some additional accompanying mechanisms are required for the problems to be solved completely. One such mechanism is introduced in Subsection XIX-F.2.

### E. Other Advantages DD

Another cause of inefficiency in ad hoc networks and multihop WLANs is that when RTS/CTS dialogues fail, the channel will not be used because no data packets are successfully scheduled during that period of time. However, when detached dialogues are employed, the negative impact of failed dialogues may be mitigated since later dialogues can be used to schedule for the originally requested packet periods, instead of giving them up. Such a strategy spread the allowed duration for the RTS/CTS dialogues of a data packet period from a small duration to a considerably larger period of time (e.g., T_{L} time units in Subsection XIX-F.2), improving the channel utilization.

Detached dialogues have a variety of other important effects. For example, it enables reservations of packet periods with variable bit rates and packet arrival rates, rather than requiring the associated sessions to transmit packets periodically as in MACA/PR. When the propagation delay is large relative to the duration to control messages, detaching the RTS messages with the associated CTS messages may also increase the channel utilization. Another important reason for employing detached dialogues is its strong differentiation capability in ad hoc networks and multihop WLANs.

### F Solutions to QoS Problems

### F.1 The Alternate Blocking Problem

Illustrates the alternate blocking problem in RTS/CTS-based ad hoc networks and multihop WLANs. Node C is within the ranges of the CTS messages from nodes B and D. Transmissions from node C may be blocked for a long time even if node C has higher-priority packets and nodes A and E only have lower-priority packets. The reason is that transmissions from node A to node B can continuously overlap with transmissions from node E to node D so that node C does not have sufficient chance to countdown.

In IEEE 802.11e and the differentiation mechanisms and most previous MAC protocols for ad hoc networks, prioritization is supported by employing different interframe spaces (IFS) before the transmission of control/data packets with different priorities as well as different calculation rules for backoff times of different traffic classes. These mechanisms can differentiate delays and throughput between different traffic classes to a certain degree in single-hop WLANs. The reason is that an IEEE 802.11e node with higher-priority packets is guaranteed to capture the channel before nodes with lower-priority packets simply due to the fact that all nodes with lower priority have to sense the channel for a larger idle time (i.e., a larger IFS) and will lose the competition. Moreover, lower-priority packets are allowed smaller aggregate bandwidth when the traffic is heavy due to their larger and adaptive contention windows. However, these desirable properties are not guaranteed in ad hoc networks or multihop WLANs.

Illustrates a scenario in multihop networks where the differentiation mechanisms of IEEE 802.11e do not work. In this example, an intended transmitter C with higher-priority packets have a good chance in losing competition to nearby nodes with lower-priority packets because the intended transmitter C may be blocked by an on-going receiver B, while a nearby lower-priority intended transmitter E may not interfere with the on-going receiver B and may acquire the channel before the intended transmitter C. The receiver D of the lower-priority transmitter E will then continue to block the high-priority intended transmitter C. With a nonnegligible probability, such a situation can go on for a long time for some high-priority packets when the traffic is heavy and the network is dense (i.e., when there are many nodes within a typical transmission/interference range). So high-priority packets may still experience large delay in IEEE 802.11e due to low-priority packets at nearby nodes. This problem cannot be solved by IEEE 802.11e or other previous differentiation mechanisms and is referred to as the alternate blocking problem in this application. In order for killer real-time applications such as voice over ad hoc networks and multihop WLAN to become a reality, we believe that other effective mechanisms for supporting DiffServ in such multihop networks are urgently demanded.

### F.2 DDA-Based Solutions

FIG. 21 illustrates the semi-synchronous advance access mechanism with grouped control messages. This scheme can solve the interference-range hidden/exposed terminal problem where RTS/CTS messages have to be sent to nodes within the interference ranges of associated data packets. ACK messages are also sent during control intervals. Note that nodes only need to roughly synchronize so that control messages are transmitted during control intervals and at most extend to the guarding periods.

In addition to increasing spacial reuse as argued in the previous section, postponed access spaces also enable effective MAC-layer support for Differentiated Service (DiffServ). This can be achieved by differentiating the maximum allowed postponed access spaces for different traffic classes. More precisely, there are a set of AA parameters T_{ML,i}, which are the maximum lag (ML) time for class packets. A higher-priority class is typically assigned a larger maximum postponed access space. That is, 0≦T_{ML,i}_{₂}≦T_{ML,i}_{₁} if i₁ has priority higher than i₂ (i.e., i₁<i₂). A higher-priority packet can then avoid competing with other lower-priority transmissions by choosing a larger postponed access space when desired. For example, a higher-priority packet of class i can optionally choose a larger postponed access space T_{L} satisfying

T_{ML,i-1}<T_{L}≦T_{ML,i}.

Then no other (intended) transmitters with priority lower than i could have reserved during an overlapping packet period, so the intended receiver of this high-priority packet will most likely be available during the requested packet sending period, solving the alternate blocking problem. Note that if there is an available packet sending period smaller than T_{ML,i-1}, the sender can also request that period if desired. Note that there can also be minimum postponed access spaces T_{ml,i} that serve as the lower bound for T_{L} of class i, and the values of minimum postponed access spaces can also be differentiated among different traffic classes.

An approach to solve the interference-range hidden/exposed terminal problem and the additive interference problem is to group the control messages together within control intervals. Since AA employs detached dialogues and specifies postponed access spaces in the RTS/CTS messages, this approach is naturally supported by AA. We refer to this class of AA protocols as semi-synchronous AA since the control messages have to be confined within control intervals and guarding periods, but precise synchronization and slotted time axis are not required. FIG. 21 illustrates an example for RTS/CTS dialogues in semi-synchronous AA.

To apply DDS to semi-synchronous AA, we first correspond each time instant in the data interval to a certain time instant in the control interval. The values for time are continuous across different control intervals, and a time instant in a data interval does not necessarily correspond to a time instant in the preceding control interval. Then a higher-priority class is assigned a larger maximum postponed access space as DDS in asynchronous AA. Note that it is possible for an RTS/CTS dialogue to request for a packet sending period within the second next data interval instead of the immediately following data interval. Also, if a packet sending period remains unscheduled after the corresponding time instant in the control interval is passed, nodes are still allowed to compete for that packet sending period. An additional capability of semi-synchronous AA is to further partition a control interval into several subintervals, where the first subinterval is for the highest priority classes, the second subinterval is for the highest and second highest priority classes, and so on. In this way, the RTS/CTS dialogues not only have larger probability to successfully schedule for a packet sending period, but also have smaller probability to be collided by other RTS/CTS messages due to lighter traffic load in such higher-priority subintervals. Although data intervals may also be partitioned into subintervals with different priorities, such a differentiation strategy is not as efficient as DDS in terms of radio utilization.

### XVIII. ACCOMPANYING MECHANISMS FOR DDA

In this patent, we have pointed out various ways to incorporate DDA into a variety of MAC protocols/schemes. In this section, we pointed out several additional mechanisms/policies that are enabled by DDA, and/or may support DDA-based protocols. We also introduce a few mechanisms supporting the use of DDA. Finally, we compare our DDA with MACA-P briefly.

### A. Multiway Handshaking and Flexible Dialogues

The flexibility provided by DDA can enable a variety of functionality that was not possible (or efficient) for previous MAC paradigms. In this subsection we show a few such examples.

In EIM, the dialogues for scheduling data packet transmissions/receptions can be initiated by either intended transmitters or receivers. In some occasions, the traffic is bidirectional so that a node can be both a transmitter and receiver for a single handshaking or dialogues.

Enabled by the PAS of DDA, the dialogues for scheduling is not restricted to 2-way or 4-way as in IEEE 802.11/11e and previous MAC protocols. When the duration(s), power level(s), spreading factor(s), and/or other attributes suggested by an intended transmitter (or receiver) is not acceptable or desirable to the intended receiver (or transmitter, respectively), the latter party can suggest one or several alternatives to the former party before the suggested packet transmission/reception duration. This way the success rate for a dialogue can be considerably increased, in addition to the fact that the flexibility of packet transmission/reception duration also increase the success rate for a request (given that this property is appropriately utilized and handled). The transmitter/receiver-pair can also exchange schedule information for their locations so that other parties can request for more appropriate durations, power levels, and other attributes.

PAS also enable more flexible control message sizes so that more than one packet duration or power level can be suggested in a single RTS/CTS messages This capability again increases the success rate for the scheduling of a packet transmission/reception, thus better supporting traffic with stricter QoS requirements. As a comparison, IEEE 802.11/11e and previous MAC protocols typically backoff with larger and larger CW values after a failure dialogue, which is not desirable for QoS traffic, and is causing various problems for executing real-time and TCP applications in ad hoc networks and multihop WLANs. In addition to increasing the success rate, a single dialogue can now be used to request for the transmission/reception slots for multiple data packets or a large burst of data (with segmented mini-slots). Also, it can include more information to request for periodical slots for constant-bit-rate traffic or other appropriate scenarios. (Note that by “slots”, we do not mean the network is synchronized.) In this way, the control overhead can be considerably reduced.

In previous sections, we have introduced use of triggered CTS messages or other control messages that can better support interference awareness. We have also introduced the OTS and TPO mechanisms that can better support QoS. Such capabilities are again enabled by DDA when only one transceiver per node is available or when a single shared channel is nused for data packets and the associated control messages.

OTS or TPO mechanisms can also be used to preempt lower priority or non-legitimate packets. Such mechanisms considerably help enforcing reservations made by wireless devices when there is not centralized coordinators such as an access point or clusterhead. When combined with the differentiated PAS discipline (with appropriate upper and lower bounds for PAS of different traffic categories), and possibly other mechanisms such as prioritized random countdown or MACP, very strong prioritization may be achieved. For example, higher priority traffic classes can be almost not affected, or independent of, the competition from lower priority traffic. This property was previously considered very difficult to achieve in a fully distributed environment.

Similarly, the flexibility of PAS also enables efficient multicasting. The reasons include more efficient scheduling and acknowledgement between a transmitter and multiple receivers, especially when combined with group-ACK, implicit-ACK, or other appropriate acknowledgement mechanisms. This addresses a problem that is long considered difficult to solve.

Also some details are needed to achieve the aforementioned advantages, previous mechanisms and techniques reported in the literature, possibly with some adaptation or modification, can usually be filled in the gap without much difficulties. In the following subsection, we introduce such a mechanism developed particularly to support DDA as an example. Since developing such appropriate mechanisms or detailed implementations for DDA or other approaches introduced in this patent application are usually not challenging, we omitted the details for other mechanisms.

### B. Multiple and Prior Scheduling for DDA

The detached dialogues approach (DDA) is a revolutionary paradigm for multiple access in ad hoc networks and multihop WLANs. As a results, it is not uncommon for us to receive comments concerning the approach. However, we have not find problems that cannot be resolved and will prevent DDA from working properly or reasonably thus far. In this subsection, we introduce several mechanisms as an example to address some common concerns.

In DDA, when there are available packet transmission periods with small PASs, they can be chosen so that the delay of DDA will not be increased and the throughput will not be degraded in the presence of mobility. Also, when large PAS is not desirable in a networking environment, the node can simply set it to zero or a small value. In fact, a simple embodiment is to request for two durstion, one for the smallest possible time slot available as seen by the intended transmitter (when SICF is employed), and the other as the maximum (or close to maximum) of the PAS allowed for that traffic class. Moreover, the maximum PAS can be limited to the time required for several data packet transmissions so that the delay of DDA will not be considerably increased and the throughput will not be degraded in the presence of mobility. Note that the PAS can be used to schedule the next data packet only, rather than always reserving for packet slots periodically as in MACA/PR, so we do not have to assume constant-bit rate traffic and DDA can also work efficiently in the presence of bursty traffic and high mobility.

The postponed scheduling mechanism of DDA enables the prior scheduling mechanism and the multiple scheduling mechanism. In the prior scheduling mechanism, an intended receiver that has just finished a successful RTS/CTS dialogue with its upstream node (by replying a CTS message) can act as an intended transmitter of the same packet and initiate the next RTS/CTS dialogue with its downstream node (by sending an RTS message). The newly requested packet period (e.g., from t₂ to t₃) to the downstream node can follow immediately the previous packet period (e.g., from t₁ to t₂) for the same data packet from the upstream node. As a result, the effective delay at the downstream node B can be as small as 0 (or a very small value for the turn-around time etc.). Since a packet transmission period can be scheduled by a node before the node actually receives the data packet, we refer to this mechanism as “prior scheduling”. In the multiple scheduling mechanism, the j^{th} packet in the class-i queue can start its scheduling before the first j-1 packets ahead of it are all scheduled and transmitted. Supports for this mechanism is important for DPS-based networks. Otherwise, a large PST will block the scheduling of packets behind it in the same queue, leading to large delay and low throughput. If the hardware for such queues allows out-of-order transmissions for the first few packets in a queue, the “head of line” problem can also be solved. These mechanisms can avoid queuing delay accumulation along a multihop path. Such effect and the higher success rate for RTS/CTS dialogues of high-priority packets (so that repeated countdowns and RTS/CTS dialogues are avoided) can in fact reduce and virtually bound the end-to-end delay in ad hoc networks and multihop wireless LANs, especially for higher-priority packets under moderate and heavy loads. This claim is well supported by our comprehensive simulation results in the PIMRC'03 paper.

When an intended receiver receives an RTS message from its intended transmitter, it looks up its local scheduling table to determine whether it will be able to receive the intended packet. If so, the intended receiver sends a CTS message to the intended transmitter and all WSs within the protection range P_{CTS}. If the intended transmitter receives the CTS message from its intended receiver, it transmits the data packet during the scheduled data packet slot. Finally, an implicit acknowledgement is employed for low-overhead reliable unicasting.

In order to support power control and efficient spacial reuse, we propose the power-controlled pulse-based declaration (PPD) mechanism, where an intended receiver send declaration pulses at decreasing power levels following its CTS message.

Note that when different PHY channels are used for a data channel and the associated control channel(s) (based on frequency division control channel (FDCCH)), WSs are not required to be synchronized; when the same PHY channel is used for the data channel and the associated control channel(s) (based on time division control channel (TDCCH) intervals), WSs only need to be roughly synchronized so that control messages are transmitted within the boundary of an appropriate TDCCH interval. When TDCCH is employed, we simply correspond a point in the time axis of the control message interval to an appropriate point in the time axis of the data packet interval, and then the rest is the same as FDDCH. The time axis is not slotted in either case. The advantages of TDDCH include that data packets and their associated control messages are transmitted using the same frequency band and they are only separated by a small amount of time (relative to the moving speeds of WSs), so their propagation characteristics can be almost identical. This can solve the dual-channel pass-loss difference problem that exist in previous proposals using busy tone or a different frequency for control messages.

C. Comparison with MACA-P

There are various differences between DDA and MACA-P. We list some of them as follows. DDA does not have to block nearby nodes before the requested time slot. Other nodes within range are typically not triggered by the RTS message and data for parallel transmission. We use group scheduling to compactly scheduling more concurrent transmissions. Also, when interference range is larger than the data coverage range, we cannot rely on the RTS and data packet as in MACA-P. PAS can be considerably larger than the control gap of MACA-P without wasting resources. DDA naturally avoids the exposed terminal problem and better supports power control and interference-range problems, rather than by forcing nearby nodes to transmit at the same time. In our approach, transmissions triggered by group scheduling do not need to have smaller have data packets smaller than the first data packet. ACK messages do not have to be aligned in our DDA. We consider interference problems in DDA, so the model is very different. MACA-P does not work in our more realistic model. We can use S-CSMA/CA for RTS/CTS messages. The PAS is just more flexible and can be chosen more freely. DDA does not suffers from restrictions of any “master nodes” as in MACA-P.

### XIX. PBC: A DIFFSERV MAC SCHEME

In this section we present the basic scheme for PRC, PIC, and PRIC.

19.1 The Central Ideas for PRC

The central idea of PBC is simple yet powerful. We employ an additional level of channel access to reduce the collision rate for RTS and CTS messages. Since RTS and CTS messages can be received by nearby wireless stations (WSs) with a high probability (e.g., 95%), WSs can usually schedule their transmissions and receptions accordingly without conflict. Thus, collision of data packets can usually be prevented and the collision rate can be controlled and traded off according to the parameter values and affordable overhead. We refer to this capability as collision control. PRC can then work in combination with RTS/CTS-based protocols or new protocols such as ROC and MALT for power control and IAMA for interference awareness.

If centralized control is feasible (e.g., with the availability of clusterheads), such an additional level of channel access may be implemented based on reservation Aloha, polling, or splitting algorithms. However, when fully distributed MAC protocols are desired as expected in ad hoc networking environments, the protocol design becomes considerably more challenging. In this paper, we propose such a fully distributed scheme for collision-control based on binary countdown.

19.2 The Prioritized Binary Countdown Scheme

In the prioritized binary countdown (PBC) scheme, a WS participating in a new round of binary countdown competition selects an appropriate competition number (CN). A k-bit CN consists of at most 3 parts: (1) priority number part (for DiffServ supports), (2) random number part (for fairness and collision control), and (3) ID number part. To simplify the protocol description in this paper, we assume that all CNs have the same length and all competing WSs are synchronized and start competition with the same bit-slot.

At the beginning of the distributed binary countdown competition, a WS whose CN has value 1 for its first bit transmits a short signal at power level sufficiently high to be received by WSs within its prohibitive range during bit-slot 1, where the radius of the prohibitive range is equal to that of the protection range of the associated control message to be transmitted plus that of the maximum interfering range for all control messages in the neighborhood. On the other hand, a WS whose first bit is 0 keeps silent and senses whether there is any signal during bit-slot 1. If it finds that bit-slot 1 is not idle (i.e., there is at least one competitor whose first bit is 1), then it loses the competition and keeps silent until the end of the current round of binary countdown competition. Otherwise, it survives and remains in the competition.

In bit-slot i, i=2, 3, 4, . . . , k, only WSs that survive all the first i-1 bit-slots participate in the competition. Such a surviving WS whose i-th bit is 1 transmits a short signal to all the WSs within its prohibitive range. A surviving WS whose first bit is 0 keeps silent and senses whether there is any signal during bit-slot i. If it finds that the bit-slot i is not idle, then it loses the competition; otherwise, it survives and remains in the competition. If a WS survives all k bit-slots, it is a winner within its prohibitive range. It can then transmit its RTS, CTS, or other control messages. FIG. 20 shows the frame format for the control channel of PBC.

19.3 DiffServ and Fairness in PRC, PIC, and PRIC

In PRC, a CN is composed of two parts: the priority number part and the random number part. In PRIC, a CN is appended by an additional ID part. The ID should be unique, or at least have a high probability to be unique. In PIC, a CN has a priority number part followed an ID part. There is no random number part in the CNs of PIC.

In PRC and PRIC, prioritization is supported in two ways. The first approach simply uses different values for the priority number parts of CNs; while the second is realized by using different distributions for the assignment of the random number parts of CNs. The strong prioritization capability of PRC and PRIC is then utilized to support effective service differentiated and adaptive fairness.

In PRC, PRIC, and PIC, the priority number part of a CN should be assigned according to the type of the control message and the priority class of the associated data packets, as well as other QoS parameters (if so desired), such as the deadline of the data packet, the delay already experienced by the control message or data packet, and the queue length of the WS. For example, a CN in PRC can have the first 2 bits for the priority number part and the last 6 bits for the random number part. Then all CTS messages and acknowledgement messages of RTS/CTS-type dialogues can be assigned with the highest priority 3 (i.e., with bits “11”) for the priority number parts of their CNs. An RTS message is assigned with the second highest priority 10 if the data packet associated with it has high priority; it is assigned with the third highest priority 01 if the associated data packet has medium priority; while it is assigned the lowest priority 00 if the associated data packets has low priority. Other control messages can be assigned with appropriate priority numbers from 11 to 00. For example, Hello messages or control messages associated with background broadcasting of unimportant information can be assigned with the lowest priority 00.

In PRC and PRIC, we need to pick a random number for a CN. To achieve adaptive fairness, WSs piggyback in Hello messages their own recent history concerning the bandwidth they uses, the collision rates for RTS/CST dialogues, their data packet collision rates, and so on. The WSs also gather such information from all their neighboring WSs. If a WS finds that the bandwidth it recently acquired is below average, it will tend to select larger random values for the random number parts of its CNs for the next few RTS messages; otherwise, it will select relatively small values. In this way, WSs that happened to have bad luck and experienced more collisions or larger backoff can latter on acquire more slots to compensate its recent loss. On the other hand, WSs that have consumed more resources than its fair share will “thoughtfully yield” and give priority to other neighboring WSs. Note that when neighbors have nothing to send, such yielding WSs can still gain access to the channel so that the resources are not wasted unnecessarily. As a comparison, if we increase the contention window (and thus backoff time) for such WSs, fairness may also be achieved, but resources will sometimes be wasted unnecessarily. Therefore, PRC and PRIC can achieve fairness adaptively and efficiently for both short-term fairness and in the long round. As a comparison, IEEE 802.11/11 e may achieve long-term fairness, but WSs may starve for a relatively short period of time.

19.4 Comparisons Between PRC, PIC, and PRIC

PRC can achieve higher performance as compared to PRIC and PIC is that it can considerably reduce the control channel overhead by reducing the length of its CNs for binary countdown. By controlling the length of CNs in PRC, the collision rate of data packets and overhead caused by control messages are under the control of the network operator, so the throughput or other criteria can be optimized. The rational for augmenting this flexibility to PRC is that when CNs are not short (e.g., with about 8 bits), we find that the collision rate is so low (e.g., about 0.15%) that the throughput and other performance metrics are rarely effected by control message collisions. So in some networking environments there is no need to achieve collision-free transmissions in both control channel and data channel. In addition to smaller control channel overhead, PRC further improves the throughput of PIC by augmenting a random countdown mechanism that can achieve better fairness. As a comparison, in PIC, wireless devices with a smaller ID will starve under heavy load.

19.5 ID Assignments in PRIC and PIC

When access points are present, they can assign IDs for the CNs of WSs. When there is no such infrastructure, a clustering scheme may be used to elect clusterheads, which assign IDs within their coverage ranges. To reduce the length of CNs, a clusterhead negotiates with nearby clusterheads to get a short prefix that is unique among them (locally), but not globally. It then assigns unique intracluster IDs to members of its cluster. In this way, WSs can obtain relatively short IDs that are unique locally.

When clusterheads are not available, a fully-distributed ID assignment scheme can be used. As an example, a WS first randomly selects an ID. (If it records some of the IDs that have been used locally, it should avoid those IDs.) It then sends an ID request message it to WSs within its maximum prohibitive range. If a nearby WS receiving the ID request message happens to be using the same ID, it replies with an objection message to the sender, and the latter will randomly select another ID and repeat the proceeding process for ID uniqueness check. If duplicate IDs are detected at a later time (which is possible due to mobility or temporary deafness), the WSs with the same ID will all randomly select a different ID and perform the proceeding process.

### XX. BEOADEN: AN EMBODIMENT BASED ON BINARY COUNTDOWN

In this section, we present a scheme called Carrier Sense Multiple Access with Collision Prevention (CSMA/CP), for wireless ad hoc networks. We then present an embodiment called BROADEN.

20.1 Basic Operations for CSMA/CP

In CSMA/CP, the wireless channel is partitioned into a control channel and one to several data channels. In what follows, we assume that there is only one data channel to simplify the protocol description.

In CSMA/CP, the right to access the data channel is based on negotiation in the control channel. In such dual-channel protocols, collisions of data packets are usually caused by failed negotiation/announcements in the control channel. So, the central idea for CSMA/CP to achieve 100% collision-free operation is to prevent collisions in the control channel. In BROADEN, every node's sensing device has been adjusted to make the sensing radius at least twice the data packet transmission/interference radius. Therefore, the hidden terminal problem can be solved automatically. This approach is called sensitive CSMA (S-CSMA). Note that the resources wasted in the control channel of S-CSMA can be justified by the gain in preventing data packet collisions due smaller control message sizes.

To prevent control messages from collisions, we present to incorporate the binary countdown mechanism into MACA or ROC-type protocols. First, the system needs to be synchronized so that mobile terminals (MTs) can begin to compete for the media at the same time. The clock signal from the Global Positioning System (GPS), synchronization signals from a centralized control unit such as a base station or access points, or a distributed synchronization mechanism such as one based on mobile point coordinator (MPC) may be used for this purpose. Note that a unique characteristic for CSMA/CP is that only local synchronization between nearby competitors is required. Asynchronous CSMA/CP protocols that take advantages of this unique property are desirable in some environments.

FIG. 20 shows the frame format for BROADEN. The time axis is partitioned into equal length competition periods, each starting with a time slot for medium sensing, followed by sync-beacon sending slot, and a series of time slots used for binary countdown. A node first senses the medium during the media-sensing slot. If the medium is not idle (e.g. a neighboring node is sending a control message), it will wait for the next round and start all over again. The winner of binary countdown has right to transmit its control message during the control message slot following the binary countdown slots.

In BROADEN, a node creates a unique equal-length binary number for each control message. Such a binary number consists of a priority number followed by its unique MAC ID. The priority of function packets is created based on the differentiation of function packet type and the data packet it relates to, as well as packet waiting time. The unique MAC ID in the second part of the binary number makes the whole binary number unique so that no collision will be caused due to multiple nearby transmitters. A lower priority function packet will lose the competition and backoff. In the case of function packets of the same priority, a node with lower MAC ID will lose and backoff.

A medium competitor will start by sensing the medium, and then sends its buzz signal or senses the medium according to its binary code, where it sends buzz signal in i-th slot if the i-th bit is 1, and senses the medium otherwise. If a medium competitor senses the channel busy, it stops competing; if a medium competitor completes the competition, it becomes the only winner within the sensing range. It can then send its control message without collisions.

FIG. 19 shows an example for binary countdown in CSMA/CP. Nodes A, b, c, and d in FIG. 19A are competing for the medium. Each node creates a unique binary code as shown in FIG. 19B. The binary codes in parenthesis represent the priority of the competitor. In slot 1, node A, and b send buzz signal, while nodes c and d senses the media and decide to quit. Nodes A and b continue to compete, and both sense the media idle during slot 2. During slot 3, node A sends buzz signal, while node b senses the media and quit. So, only node A continues and finishes the whole competition period. It thus gets the right to sends its control message. Since no other nodes within twice the transmission radius of node A are allowed to transmit, all nodes within the transmission radius of node A can receive the control message of node A without collisions.

In CSMA/CP, a node sends RTS in the control channel to ask for feedback from the intended receiver and nearby nodes when it wants to acquire a transmission slot in the data channel. In BROADEN, the surrounding nodes will either keep silent or send back OTS, ATS, and DTS to express their opinion toward the sending schedule in the RTS. The intended transmitter then sends ETS to announce the final sending schedule to nearby nodes. The intended receiver sends NTS to announce this final receiving schedule to nearby nodes.

In the data channel, a node will send its data packet at the scheduled time period at the negotiated power level no matter whether its neighboring nodes are sending or not. The transmission powers for data packets are variable, depending on the distances between the transmitter-receiver pairs.

A receiver will reply with an ACK message when it receives a data packet successfully. The ACK message will be sent through the control channel. If the sender does not receive an ACK after sending the data packet, it will reschedule for the packet to transmit it again. If the sender tries several times without any response, the intended receiver is regarded as unreachable and it will not attempt to send data to this node anymore until it hears Hello messages from this node again.

20.2Scheduling in BROADEN

In BROADEN, a mobile terminal (MT) maintains three tables: an MT table, a receiving duty table, and a sending duty table. (1) MT tables: In BROADEN, an MT broadcasts a so-called “Hello message” periodically with a prescribed maximum transmission power to announce its existence and to provide its information to its neighbors. Because the sender uses a fixed transmission power to send this message, the distance between the sender and receiver can be estimated according to the strength of the received signal. The MT table of an MT is then used to record the geographical distance from a neighboring MT when it receives a Hello message from the neighbor. Other messages that have a fixed transmission power may also be used to update the MT tables. Note that other SPEED mechanisms may also be used to determine whether a transmission may interfere with another reception.
(2) Receiving duty tables: Receiving duty tables are used to record the scheduled receiving events that are currently taking place or will happen in the nearby area. For every such receiving event, the receiver ID, starting time, and packet duration are recorded.
(3) Sending duty tables: Sending duty tables are used to record the current and future scheduled sending events whose transmission range will cover this node. For every event, it also records three fields: sender ID, starting time, and packet duration.

When an MT intends to send a data packet to a single receiver, it will first search the MT table to check whether the intended receiver is in its communication range. If the intended receiver is not in the MT table, then the data packet will be discarded or will inform the higher layer to reassign a MT to relay the packet. From the MT table, the sender will determine the accurate transmission radius. If the packet has multiple receivers, the transmission radius will be set to the maximum transmission range or the transmission range that can reach the farthest receiver. The sender will search the receiving duty table to find some time periods, during which sending the data packet with this transmission radius will not interfere with other nodes' reception. After that, the sender will search the sending duty table to make sure that the intended receiver is not sending a packet at those time periods. When searching the sending duty table, all the intended receivers of a multicasting group or all the nodes surrounding the broadcasting node will be taken into account. The sender will put the information about the transmission radius and possible sending periods in the RTS function message, and broadcast the RTS with the prescribed fixed transmission power through the control channel.

The neighboring nodes, except for the intended receiver, will again check their receiving duty table to see whether the time period in RTS conflicts with their own scheduled reception. If it does conflict, the neighboring MT will send an OTS message, which may contain a suggested time period. Note that this rarely happens because the sender already checks before sending RTS, but nodal mobility may cause the RTS sender to use some inaccurate geographical information and thus lead to conflict. The intended receiver will check the receiving duty table when it receives the RTS, and the sending duty table to see whether other sending or scheduled sending will affect this requested reception. If the time period in RTS does not conflict with other transmissions and receptions, the intended receiver will respond back with ATS, otherwise, it will respond back with DTS which may also contain some suggested time periods when it will be available to receive the data packet. After collecting nearby nodes' OTS and ATS or DTS, the RTS sender determines and broadcasts ETS to announce the scheduled transmission. All the nearby nodes (including the intended receiver) will record the sending duty in their sending duty table when they receive the ETS message. The intended receiver will also broadcast NTS to announce the scheduled receiving duty when it receives the ETS. Nearby nodes (including the sender) will record the receiving duty in their receiving duty table.

20.3 Multicasting in BROADEN

AS in ROAD, the OTS mechanism is useful for multicasting or broadcasting based on BROADEN. When a node intends to schedule a broadcasting/multicasting-type of data packet, multiple nodes will regard themselves as the intended receiver of the ETS message. They all record the sender in the sending duty table, and themselves to the receiving duty table. These intended receivers can send NTS or keep silent. If all the intended receivers respond back with NTS, the traffic load may be considerably increased, but all the nodes around the destinations will know the receiving schedule and thus help to initialize an accurate sending schedule. In the second case where the intended receivers keeps silent, some neighboring nodes of these intended receivers will not record the corresponding receptions to the receiving duty table. So, in the latter case, before sending the RTS, the node scans the receiving duty table but may still miss some scheduled receptions. To solve this problem based on ROC, a node with a conflicting schedule can send OTS to block a conflicting transmission.

20.4 Additional Mechanisms for CSMA/CP

Collisions of data packets in the data channel are caused by several reasons. One of them is nodal mobility, and another is caused by concurrent transmissions of control messages from nearby nodes. In what follows, we discuss these two reasons in more detail. We then present to incorporate the binary countdown mechanism into MAC protocols, and show that the resultant protocol can achieve 100% collision-free transmissions in both the control channel and data channel.

In CSMA/CP, there is a lag time between the actual transmission of a data packet and the completion of BROADEN dialogue. The lag time is called postponed access space (PAS). Therefore, nodal mobility may cause data packets to suffer collision in the data channel even if the negotiation finishes perfectly in the control channel. More precisely, when a node announces the data packet sending schedule of the future, some nearby MTs may be outside the communication area and cannot hear the announcement. When the node sends the scheduled data packet, these nearby nodes may move closer to the node and cause collisions. This is called the moving terminal problem. To solve this problem, the nodal mobility should be considered.

When negotiating a future packet sending, the transmission radius for BROADEN dialogue messages will be enlarged to be the distance between the current location of the sender and the destination plus the maximum possible moving distance before the future sending. We also need to consider the possible movement of neighboring receiving nodes. So, the non-receiving area should be further enlarged. This enlarged range is called protection range. The radius can be calculated as follows.

R_{fixed}=R+4×S×RLT (1)

R_{fixed}: the fixed transmission radius
R: the current distance between sender and destination
S: the maximum nodal speed
RLT: the time between transmission of the RTS message and the scheduled data packet transmission.
An intended transmitter should make sure that no nodes within the protection range will receive packets during time periods conflicting with its requested schedule.
In BROADEN, ETS and NTS announce the final schedule. All nearby nodes will record the sending or receiving duty in the correspondent permanent table when hearing these messages. Other messages like RTS, OTS, ATS and DTS are used to exchange the information for making such a final schedule. To facilitate the functions of these messages, we add two other types of tables, the temporary receiving duty tables and the temporary sending tables, to record the tentative schedules indicated in RTS, OTS, ATS, and DTS. When ETS or NTS is received, the corresponding duty is deleted from the temporary duty table. Old duties in the temporary tables will also expire after timeouts and be deleted.

### X XI. DPMA

In the following sections, we elaborate on an embodiment of DPMA, called RICK, and several associated mechanisms such as dual prohibition, and present several optional accompanying mechanisms that can be incorporated to increase the performance or reduce the protocol complexity.

A. The Dual Prohibition Mechanism

In RICK, transmitters and receivers send their prohibiting signals in different but adjacent prohibition slots. Following the prohibition stage are declaration slots. As shown in FIG. 5, the slots for transmitters and receivers are interwoven for the entire competition round. A transmitter slot and a receiver slot corresponding to the same bit/digit (for either prohibition or declaration) must be next to each other, but its order can be interchanged throughout a competition round. However, the order must be known and followed by all RICK devices. As an example, transmitters can have earlier slots for bits/digits at odd positions, but later slots for bits/digits at even positions.

During the prohibition stage, transmitters are prohibited by nearby receivers with higher competition numbers (CNs) through their prohibition signals; while receivers are prohibited by transmitters with higher CNs through their prohibition signals. Note that for transmitters, the thresholds for being prohibited are determined by their transmission power levels; while for receivers, the thresholds for being prohibited are determined by their tolerance to the interference levels. Note also that the safe margin (as a component of the threshold) can change from slot to slot to improve the performance. Since transmitters do not prohibit other intended transmitters and receivers do not prohibit other intended receivers, the exposed terminal problem does not exist in RICK. Moreover, different from CSMA where on-going transmissions block nearby intended transmitters from transmitter to transmitter, on-going receptions in RICK block nearby intended transmitters from receiver to transmitter directly, and on-going transmissions discourage nearby intended receivers from transmitter to receiver directly. As a result, obstructions or hidden terminals (for CSMA systems) will not cause collisions in RICK as in CSMA. Thus, the hidden terminal problem can be resolved in RICK without relying on hidden terminal detection mechanism [37] or complex group competition or other operations [40] as in previous MACP protocols.

For a node to determine whether its partner is surviving, a transmitter checks whether a prohibition signal corresponding to the same bit/digit value (with reasonable power level) exists in receiver prohibition slots, and similarly, a receiver also sense prohibition signals in transmitter prohibition slots to make the judgement. If a node finds that the partner in its transmitter/receiver-pair has failed the competition, it will withdraw from competition immediately. Similarly, if a node cannot sense any signals in the declaration slot that may be sent by its partner, it also withdraws from the competition. In order for a node to know the status of its partner more accurately, a surviving node can encode its ID information or a shorter code in the declaration slot. For example, such information may be encoded through coded interference/sensing-based signaling [39], or by using some additional prohibition slots corresponding to the code.

If signals are detected in the declaration slots, it implies that certain nearby nodes were successful in the current competition round. If the received power levels are sufficiently high to prohibit the transmission or reception of a competing node, the node will wait for a default or specified packet duration minus the length of a competition round, before it become eligible to enter a new competition again. However, if the node can transmit data packets at lower power or receive data with higher interference tolerance (e.g., by using larger spreading factor or transmitting a different data packet out of order), it may restart earlier. In what follows, we present a simple example for implementing the dual prohibition mechanism in RICK.

To simplify the description, we consider a synchronized dual-channel RICK based on binary countdown [24]. In this simple version, all competing nodes are synchronized and start competition at the same time. The prohibiting signals are transmitted in a narrow PHY channel dedicated for control, while data packets are transmitted in a separate PHY channel. Each intended transmitter/receiver-pair employs group operations (see Subsection D) to coordinate the round of competition to participate in, and the competition number (CN) to use. In RICK based on binary countdown with CNs of the same length, the CN can be represented as a k-bit binary number.

A competing transmitter senses the status of all receiver slots, but does not sense any transmitter slots; while a competing receiver senses the status of all transmitter slots, but does not sense any receiver slots. In bit-slot i, i=1, 2, 3, 4, . . . , k of the competition, only nodes that survive all the first i-1 bit-slots participate in the competition. Such a surviving node whose i^{th} bit of its CN is 1 transmits a prohibiting signal in the appropriate bit-slot (i.e., either transmitter bit-slot or receiver bit-slot) at appropriate power level (so that it reaches most/all nodes within its prohibitive range). A surviving transmitter whose i^{th} bit is keeps silent and senses whether there is any prohibiting signal during receiver bit-slot i that has received power level above its threshold. If so, it loses the competition; otherwise, it survives and remains in the competition. A surviving transmitter whose i^{th} bit is 1 senses whether there is any prohibiting signal during receiver bit-slot i that may be sent by its receiver. If so, it survives the competition and remains in the competition; otherwise, it loses the competition. Similarly, a surviving receiver whose i^{th} bit is 0 keeps silent and senses whether there is any prohibiting signal during transmitter bit-slot i that has power above its threshold. If so, it loses the competition; otherwise, it survives and remains in the competition. A surviving receiver whose i^{th} bit is 1 senses whether there is any prohibiting signal during transmitter bit-slot that may be sent by its transmitter. If so, it survives the competition and remains in the competition; otherwise, it loses the competition. If a node survives all k bit-slots, it becomes a candidate for transmission or reception. It then employs coded interference/sensing-based signaling [39] to transmit the short code agreed upon by the transmitter-receiver pair, at appropriate power level (e.g., the same as the power levels used in the prohibition slots). If a node detects the code sent by its partner, it becomes a winner and will transmit or receive accordingly; otherwise, it loses the competition.

The appropriate power levels for prohibition signals and the appropriate threshold for being kicked out of competition are not difficult to figure out. If desired, they can even be dynamically controlled to adapt to the environments according to the propagation and traffic load etc. In what follows we present the guideline for a simple embodiment.

A transmitter may send its prohibition signal at the same power level as its intended data packet transmission. A receiver may be kicked out of competition when the sensed signal strength exceeds (or almost exceeds) its tolerance to interference for the intended reception. A receiver may transmit its prohibition signal at the maximum power level for other nodes to transmit during the requested period of time and in the requested channel, when it has a typical minimum interference tolerance for the intended reception. If the interference tolerance of the intended receiver is doubled, it may transmit its prohibition signal at a lower power level (e.g., half the maximum power level). Assuming the channel is symmetric, then an intended transmitter can estimate the maximum power level it is allowed to transmit without corrupting a nearby reception according to the received prohibition signal strength from the latter. As a result, a transmitter can calculate an appropriate threshold (for itself to be kicked out) according to the power level for its intended transmission.

Various variants to the preceding guideline are possible. For example, the power levels for prohibition signals can be proportional to the above guideline, while changing the threshold accordingly. It is also typically desirable to modify them by incorporating safe margins and considering the additive interference effects. Moreover, some sub-mechanisms can be substituted by previous techniques, possibly after some adaptation, or newly designed techniques for respective advantages. Some mechanisms such as declaration may be modified or omitted if so desired.

We can derive another variant of RICK by substituting the dual prohibition mechanism with the receiver-based prohibition mechanism. The required modifications are similar to the way MACA was modified to MACA/BI and the details are omitted in this application. Also, when the transmission is in multicast or broadcast mode, the transmitter can act on behalf of its receivers for sending all the prohibitive signals, while using different power levels in the two slots corresponding to the same bit in order to facilitate power control. Such an approach also works correctly for the unicast mode since it is a special case of the multicast mode, but the efficiency will typically be degraded.

### B. Position-Based Dual Prohibition

To mitigate the additive prohibiting signal strength problem, we can use larger competition durations, especially for receiver slots and the first few transmitter slots. To better utilize the extended slot durations, however, it is desirable to employ the position-based dual prohibition mechanism adapted from position-based prohibition (PP) [40]. This can be done by separating the prohibition slots for transmitters and receivers in a way similar to the description in the preceding subsection (except that we are not using the binary on/off prohibiting mechanism anymore). Or, equivalently, we substitute each bit-slot in RICK based on binary countdown with a position-based “digit-slot”, and follow similar rules or spirits as in the simple version in the preceding subsection. More details concerning position-based prohibition can be found in [40].

We can use position-based dual prohibition for the entire prohibition stage if so desired. When the digit-slot is sufficiently large and the number of competition is sufficiently small, we can also use a single digit-slot-pair for the prohibition stage, followed by a declaration slot-pair and possibly an additional yield period (with sensitive carrier sensing) before transmitting or receiving the data packet. An accompanying mechanism for reducing/controlling the number of concurrent competitors is presented in the following subsection.

C. Backoff Control in Combination with Collision Prevention

Backoff control is employed in RICK as a means to conduct flow control. Backoff control algorithms/schemes in previous protocols as well as their variants may be adapted. This way the number of concurrent competing pairs can be considerably reduced so that the prohibition slots in RICK do not need to be too expensive or even prohibitively large just to mitigate the additive prohibiting signal strength problem. Moreover, the number of concurrent competing pairs can be dynamically controlled according to the traffic conditions, so that the number of slots and their durations can remain fixed in RICK without compromising the performance.

Different from IEEE 802.11/11e where backoff control is the only mechanism to reduce the attempt rate, RICK employs position-based dual prohibition to further eliminate the number of competing nodes. This way the parameters as well as algorithms/schemes employed for the backoff control in RICK do not need to be as conservative as previous MAC protocols. In other words, backoff control is only utilized to reduce the typical number of competitors (e.g., to a constant number considerably greater than 1), and then the first or first few prohibition slot-pairs will effectively eliminate most of the remaining competitors to prevent collision. This way the additive prohibiting signal strength problem can be resolved without noticeable idle times for the ratio channel.

As a comparison, when backoff control is the only or main mechanism to avoid collisions (that would be frequently caused by concurrent attempts otherwise), the radio channel may stay idle for a non-negligible portion of time so that radio resources are not efficiently utilized. Thus, backoff control combined with position-based dual prohibition as in RICK can considerably increase the radio efficiency.

Note that the threshold for the first few slots may be set higher to mitigate the additive interference effects. After some nodes are eliminated, the threshold can be set to more conservative values to lower collision rates.

Note also that after a few slots, the additive effects for the prohibition signals from transmitters do not post major problems anymore. In fact, it may become an important advantage of DPMA and RICK since the additive interference effect may happen to provide more accurate signal strength for receivers to determine whether they should give up reception. As a result, the durations for transmitter prohibiting slots typically do not have to be as large as those for receiver prohibiting slots.

### D. Group Competition and Associated Operations

General group competition is optional in RICK due to its complexity and overhead as in most MACP protocols. However, pairwise group competition is helpful for RICK and DPMA. In this subsection, we briefly present the ideas for group competition [40].

An example for pairwise group competition is illustrated in FIG. 22. In pairwise group competition, the transmitter and receiver are coordinated with group activation to compete concurrently with the same CN. The prohibiting signals, however, are transmitted in different slots and typically at different power levels.

In group competition, only nodes (or transmissions of nodes with specified power levels) belonging to the same level-3 group are allowed to compete at the same time. This effectively acquires some advantages of TDMA-type of protocols, and facilitate some patching-based techniques [39] In particular, it may be useful to solve some interference problems [39]. There can be another level (i.e., level-2) where nodes belonging to the same level-2 group use the same activation mechanism to invoke other nodes. Nodes (or transmissions of nodes with specified power levels) belonging to the same level-1 group use the same group CN for competition and are encouraged to participate in competition simultaneously. A requirement for a level-1 group is that its members can transmit their data packets at the same time without causing collisions. The term “group competition” mainly refers to the fact that members belonging to the same level-1 group can concurrently participate in competition with the same group CN. Note that pairwise group is referred to a single transmitter-receiver pair that can always form a group legitimately. Note also that a node may have membership in multiple groups at the same level.

Several group operations are required for group competition to work. In particular, group activation is required for a node to invoke it partner to participate in the competition simultaneously, using the correct IDs, CNs, as well as appropriate additional codes. Also, an ID maintenance mechanism is required if the random part of CN alone is not sufficient to achieve satisfactory performance. Other hierarchical structures and grouping strategies are also possible for group competition. More details concerning several group operations and disciplines can be found in [40].

### E. Power Control and Interference Control/Engineering

When power control is employed, the prohibitive ranges for transmitters and the coverage range for data packets may be orders of magnitude smaller than the prohibitive ranges for associated receivers. This implies significant waste in the control overhead of receivers in terms of both energy consumption and spatial reuse. To mitigate this problem, we extend interference control/engineering [39] to the transmissions of prohibiting signals in RICK in this application.

An example for interference engineering in DPMA or RICK is shown in FIG. 7 (regarding data rather than RTS). FIG. 7a shows original ranges with minimum transmission power for the data packet. FIG. 7b illustrates that the tolerance to interference is increased when the transmission power for data is increased. As a result, the maximum interfering range for the receiver is reduced. Thus, the required prohibition range for the receiver is reduced.

We allow a higher tolerance threshold for data reception (through higher transmission power or larger spreading factor associated with the reception), the prohibitive ranges for receivers (with originally small-distance or low-power transmissions) can be considerably reduced, thus reducing the transmission power levels for the associated prohibiting signals. This way more winners will typically be resulted within the same region/area so that more data packets can be transmitted.

Note that competitors that employ interference control/engineering need to adjust their prohibiting thresholds accordingly so that they will not be prohibited unnecessarily by far away nodes that use higher transmission power levels for prohibiting signals. This can be calculated without much difficulty, with similar spirit and guidelines as previous approaches for calculating thresholds. The details are omitted in this application.

Note also that DPMA and RICK only requires two levels of transmissions (i.e., prohibition signals and data packets). As a result, interference engineering is more effective as compared to 3-level MACP protocols.

When both power control and interference control are employed, the size of prohibitive ranges will change considerably from transmission to transmission. As a result, the optimized lengths for the random parts of CNs (for collision control) or minimum lengths for IDs (for collision freedom) are considerably different for different transmissions. Thus, variable-length CNs [40] and multiple variable-length IDs may be useful for interference/power-controlled RICK.

### F. Differentiated Channel for Power Control and Differentiation

To further reduce the control overhead, we can incorporate the differentiated channel discipline [36] into DPMA and RICK with interference/power-control. This way the variations in prohibitive ranges will be considerably reduced so that the associated control overheads (with or without interference control/engineering) can be significantly reduced. Also, variable-length CNs or multiple variable-length IDs are not needed when the differentiated channel discipline is employed so that the complexity of the resultant protocol is simplified.

Different channels can also use CNs with different length and safe margins with different values. As a result, service quality can also be differentiated effectively among transmissions in different channels.

### XXII. CSMA WITH BINARY COUNTDOWN (CSMA/BC)

### A. CSMA/BC

### A.1 Central Ideas and Unique Features

CSMA/BC employs MACP-type competition between transmitters only to select at most one winner within a prohibiting range. This is different from DPMA, which requires competition between transmitters and receivers. As a result, the competition/control overhead for CSMA/BC is roughly half that of DPMA.

Intended transmitters use receiver-ID-based competition numbers (CNs) for competition. This is different from CSMA/IC, which uses sender-ID-based CNs. Such receiver-ID-based CNs are essential to the important strength of CAMS/BC since they are needed to trigger intended receivers to declare the channel using declaration signals (similar to the function of CTS messages). This way intended transmitters who just lost a competition can join the next competition right away as long as they do not receive valid declaration signals from nearby receivers. This resolves the prohibition-range exposed terminal problem of CSMA/IC.

The prohibiting signals of CSMA/BC replace, but retain the functionality of, RTS/CTS dialogues in IEEE 802.11, which solves the vulnerability problem of virtual carrier sensing in IEEE 802.11/11e and BROADEN. Also, the interference-range hidden terminal problem is resolved naturally since, unlike control messages, prohibiting signals can reach interference ranges easily without requiring any special techniques or increased power level. Moreover, power control is supported in CSMA/BC, which cannot be done in CSMA/IC.

In the following subsections, we present the mechanisms and examples for implementing CSMA/BC.

### A.2 Basic CSMA/BC Operations and Mechanisms

In the CSMA/BC scheme, a node that intends to transmit data packet sends prohibiting signals to other nodes within its prohibiting range (to be elaborated shortly). The purpose for the competition is to elect at most one winner within a prohibiting range in a fully distributed manner. Note, however, that it is not required for the competition to elect a winner for “every” prohibiting range.

We define the maximum interfering range for an intended receiver as the range within which the receiver will receive, from a single interfering node, interference above certain threshold (nonnegligible for the intended data reception). Note that the maximum interfering range for a transmitter-receiver pair depends on the intended reception signal strength as well as other factors associated with interference tolerance and target error rates. For example, when spread spectrum with larger spreading factors are used, the interference tolerance will be higher so that the maximum interfering ranges can be reduced. We also define the maximum interfered range for an intended transmitter as the range within which a nearby node will receive, from the intended transmitter, interference above certain threshold (nonnegligible for the data reception at the nearby node). Note that the maximum interfered range depends on the intended transmission power. Then the radius of the prohibiting range for an intended transmitter can be anything ranging from the maximum interfered radius of the intended transmitter to the sum of the sender-receiver distance, the maximum interfering range, plus safe margin. When the prohibiting range actually used is closer to the higher end, the probability of having hidden terminals during competition is lower so that the chance for canceled trans-mission by winning candidates will be lower. On the contrary, when the prohibiting range actually used is closer to the lower end, the probability of having hidden terminals is higher so that more competitions will end up with canceled transmissions, thus wasting radio resource in competition. However, anything within the legitimate range leads to correct operation of the protocol, and can achieve collision freedom when the CNs are unique locally within a prohibiting range.

Similar to RICK, a CN used for CSMA/BC composed of a priority part, a random number part, and an ID part. But different from RICK or other previous MACP protocols, the IDs used in CSMA/BC are based on the IDs of the intended receivers. Note that it is very important for such IDs to be receiver-oriented for CSMA/BC to work. The IDs have to be based on the same set of additive error detectable codes (AEDC). It is also preferred to use AEDC for the random number part to mitigate problem caused by possible occurrence of duplicate IDs (temporarily). In particular, a binary AEDC code is a binary codeword that is guaranteed to be changed to a non-codeword as long as none of its 1-bits are changed to 0 and at least one 0-bit is changed to 1. n-choose-k codes is a possible set of n-bit AEDC and have exactly k 1-bits and n-k 0-bits in any codeword. Typically k can be selected as └n/2┘ or ┌n/2┐. An example for the 6-choose-3 codes is provided in FIG. 23a. There are other possible AEDC coding. For example, the binary 0-count mapping (BZM) codes shown in FIG. 23b can transform any binary number into an AEDC code by adding an extension with logarithmic length of its original binary number. When BZM coding is employed, the priority part, random number part, and a binary-number ID can be transformed together to obtain a single BZM extension for the AEDC-based CN.

FIG. 23 provide examples for collision prevention based on AEDC codes. In FIG. 23a, the CN is 101100 based on the n-choose-k codes where n=6 and k=3. In FIG. 23b, the binary ID is 10101 and the extension is 10, based on the binary 0-count mapping (BZM) extension where IDs with 0, 1, and 5 1-bits are not allowed in the codewords.

The CSMA/BC scheme is a family of protocols that can be implemented in various ways to achieve respective advantages according to their requirements and the options made. In this subsection, we use a simpler version of CSMA/BC protocol, dual-channel time-division CSMA/BC (DT-CSMA/BC) with fixed data packet duration, to illustrate the basic operations and mechanisms of CSMA/BC. In the following subsections, we will introduce more advanced mechanisms and options and explain how to extend to other protocols in the CSMA/BC family.

In the fixed-duration DT-CSMA/BC protocol, all participating nodes are synchronized (e.g., to timing signals from GPS, WLAN APs/MPs, or WiMax/4G+base/relay stations), and start the competition round at the same time. A narrow-band control channel is used for sending prohibiting signals (including acknowledgement and declaration signals), while a data channel is used for trans-missions of data packets. Acknowledgement message can be piggybacked in the data channel (or transmitted explicitly if so desired), or replaced by prohibiting signals during the acknowledgement slot in the control channel (coded with interference-based signaling or transmitted as a small control message). The acknowledgement signals can also include information for rate and power control as well as other control such as spreading factor. An intended transmitter can then retry with higher priority in the next competition round based on the suggested rate and power if they are eligible.

During a competition round, a node whose CN has value 1 for its i-th bit, i=1, 2, . . . , n, transmits a short prohibiting signal during bit-slot i at power level sufficiently high to be detectable by other nodes within its prohibitive range during bit-slot i. The received signal strength should be above the minimum required power level or SNR for detection, and is referred to as the prohibiting threshold. On the other hand, a node whose i-th bit is 0 keeps silent and senses whether there is any prohibiting signal that has strength above the prohibiting threshold during bit-slot i. If the silent competing node finds that bit-slot i is not idle (i.e., there is at least one competitor whose i-th bit is 1), then it loses the competition and keeps silent until the end of the current round of competition. Otherwise, it survives and remains in the competition. If a node survives all the n bit-slots, it becomes a candidate for the winner within its prohibiting range.

An active intended receiver observes the ID part of the current competition for prohibiting signals with strength above its interference threshold, where a competitor sending prohibiting signals with such strengths will interfere with the reception of the intended receiver. If it finds that the heard prohibiting signals correspond to its own ID, then its intended transmitter has successfully win the competition. If it also decides that the current (and expected future) interference levels are low enough for it to receive the intended data packet, it will send an acknowledgement signal or message recognizable by the sender to acknowledge its availability, and then a short but (typically) higher-power declaration signal to nodes within its protection range to declare its scheduled reception (similar to the functionality of CTS messages).

When a winning candidate hears an acknowledgement signal, it will send its data packet after the competition round; otherwise, it backs off before entering another competition again. If a nearby node hears a declaration signal with strength above an appropriate threshold, it sets it transmission-NAV accordingly so that the associated reception can be protected. Note that the threshold is determined by the intended transmission power level for the nearby node. For example, if the received declaration signal is weaker, it implies that the receivers to be protected is farther away (or has higher tolerance to interference). As a result, a nearby node with lower transmission power level can be allowed to join competition right after the current competition round is finished. This enables power control capability in CSMA/BC, which was not possible in CSMA/IC.

Note that if the intended transmitter of an intended receiver has a hidden node (or hidden nodes) that also wins its competition, the intended receiver will not send the aforementioned acknowledgement signal and declaration signal so that no associated transmission or blocking in the associated region will occur. The reason is that the intended receiver will have observed a non-codeword for the ID part of the competition due to the prohibiting signals from the hidden node(s). As a result, the hidden terminal problem is resolved. Since an intended transmitter losing a competition can join the following competition as long as it does not receive any declaration signal (above its associated threshold), the prohibiting range exposed terminal problem of CSMA/IC is also resolved. Power control is also naturally supported with the proceeding mechanisms.

### A.3 Mechanisms for Variable-length Extensions

In this subsection we introduce two variable-length versions of CSMA/BC as well as some related optional mechanisms.

In the first simpler extension, we require the receiver to turn around at the end of the first data fragment and send another declaration signal to protect its reception of the next data fragment. More precisely, the receiver first senses the data channel after the previous data fragment is completely received, and informs its transmitter with an acknowledgement signal to send the next data fragment if the previous data fragment was received correctly and the interference level is acceptable. It also estimates the appropriate power level for its new prohibiting range according to the current interference level, and transmit a declaration signal accordingly to protect its following data fragment reception. This makes the protocol interference-aware in that it is capable of taking into account the timely change in the aggregate interference level for better protection of receptions without wasting resources unnecessarily. In particular, it does not need a very large safe margin to tolerate all new transmitters initiated during the reception of an entire data packet, as required in some previous protocols that claimed to be interference aware. Note that such an estimate does not require accurate measurement of the interference level. For example, a possible implementation is for the receiver to sense whether the interference level is below an acceptable threshold (or a small number of thresholds), and then include that threshold (or the upper-bounding threshold) into the calculation. This way the resultant variable-length CSMA/BC protocol can be interference-aware and more robust, without requiring expensive measurement hardware or duration overhead for measurement.

In variable-length DT-CSMA/BC, the acknowledgement and declaration signals are transmitted during the corresponding acknowledgement and declaration slots following the end of the data fragment. The NAV set for a received declaration signal should last till the end of the aforementioned declaration slot. An intended transmitter is eligible to compete only after the NAV ends. When the previous reception of the data fragment was not successful, the receiver will not send its acknowledgement or declaration signal and the transmission will be aborted. The rest of data fragments or the entire data packet will then have to back off randomly and be (re)transmitted after the transmitter wins another competition. This can be considered as one of the methods to implement wireless collision detection.

Note that out-of-band periodical busy tone has been used in power controlled multiple access (PCMA), but PCMA does not have dedicated signaling for acknowledgement or negative acknowledgement. However, busy tone alone as in PCMA cannot effectively support wireless collision detection. The reason is that a busy tone has to be transmitted to a relatively large range that may cover many lower-power transmissions. As a result, busy tones from other receivers will be frequently confused with those from one's own receiver, making it ill suited for the acknowledgement purpose. Another difference between busy tones in PCMA and the declaration signals in CSMA/BC is that PCMA relies on all nodes to measure the power levels of the received busy tones accurately. On the contrary, CSMA/BC only requires nodes to sense for declaration signals to see whether any of them exceeds its threshold(s) (determined by the power level(s) of the next (few) packet(s) it is going to transmit).

A possible concern is that transmissions newly initiated in the current competition round (as the acknowledgement and declaration signals) are not taken into account in the aforementioned CSMA/BC version, and might interfere with the next data fragment. However, such new trans-missions typically do not cause much threat for such continuous reception. The first reason is that the previous declaration signal is still covering the current competition round, so intended transmitters that will cause unacceptable interference will have been prohibited by it. The second reason is that the duration for a data fragment is typically equal to a large number of competition rounds so that the additive interference from the new transmissions initiated during the previous data fragment constitute a much bigger threat to the reception. The latter threat has been taken into account in this CSMA/BC version by sensing the data channel before sending out the acknowledgement and declaration signals. The former threat can be mitigated by an appropriate safe margin for the prohibiting range/power-level of the declaration signal. In fact, the additive interference from new transmissions to be initiated during the next data fragment is also mitigated by the safe margin, so the former threat is actually negligible. As a result, we typically do not observe the current round to adjust the newly estimated prohibiting range/power for the new declaration signal. Instead, most part of the competition round can still be used for transmitting the remaining bits of the previous data fragment, reducing the overhead.

Even though it is not impossible to adjust the estimated prohibiting range/power, it requires additional processing time before sending the declaration signal. Also, the adjustment may be too conservative in that the competitor corresponding to a prohibiting signal observed may eventually lose the competition or fail to receive an acknowledgement from its receiver so that the adjustment is not required. Moreover, such a mechanism requires measurement of the prohibiting signals, which may be considerably more expensive to implement in terms of the required hardware and the required duration for the prohibiting signals.

An optional mechanism of variable-length CSMA/BC is for the receiver to send a negative acknowledgement (NAK) signal or message in the control channel to request for retransmission of the previous data fragment. Such NAK signals can be transmitted in a dedicated slot, or in the same acknowledgement slot but encoded with interference-based signaling (or transmitted as a small control message) to be distinguishable and recognizable by the transmitter. The transmitter will then retry till the previous data fragment is successfully received, or after a limited number of trials. We refer to this mechanism as wireless ARQ. The aforementioned techniques can be applied to extend IEEE 802.11/11e by augmenting a mechanism for sending NAK messages and retransmissions. The details are omitted in this paper. Another optional mechanism of variable-length CSMA/BC is for a receiver to incorporate rate control in the acknowledgement slot by encoding the information in the acknowledgement signal for its transmitter using interference-based signaling. This allows the receiver to adaptively control the transmission of individual data fragments according to the new interference and propagation conditions, optimizing the performance and robustness and/or controlling the required power for its declaration signals. Adaptive control for other attributes such as transmission power level and spreading factor can also be supported in a similar way if so desired.

There are two problems with the preceding method and the periodical busy tone approach of PCMA. The first is that the data packet length may not be a multiple of fixed data fragments, wasting resources unnecessarily. The second is that some nearby receivers may transmit declaration signals or busy tones at overlapping times repeatedly, leading to the additive prohibiting signal strength problem or similarly the additive busy tone problem. The send problem can be somewhat mitigated by using larger declaration slots in CSMA/BC. However, to further resolve these issues, we modify the first extension by incorporating the adaptive periodical prohibition (APP) technique.

In CSMA/BC with APP, a receiver transmits its declaration signals in a semi-periodical manner to protect its reception. More precisely, the receiver (or transmitter) needs to estimate the end of its reception, and determines the time for the last APP signal, which must be within the maximum allowed APP period from the estimated end. It also determines the times for its APP signals throughout the reception, where any adjacent pair of APP signals must not be separated for more than the maximum allowed APP period (i.e., the duration of a maximum data fragment). The NAV set for a received declaration signal should last for a maximum allowed APP period. Under the aforementioned constraints, the determined times can be randomly or semi-randomly selected to avoid repeated overlapping with the APP signal(s) from nearby receivers. Such determined times should be predetermined or conveyed on the fly (e.g., by length indications or framing flags) between the transmitter and receiver. This way the additive prohibiting signal strength problem can be better mitigated since they only defer nearby transmitters unnecessarily once (or for a small number of times) even when overlapping does happen. Also, this is achieved without considerably enlarging the declaration slot, reducing the control overhead. In APP, it is usually advantageous for the very last data fragment to be exactly the size of a maximum data fragment (that can be protected by a declaration signal). This way nodes blocked by the reception can begin their intended transmission upon the completion of the data packet reception, without having to stay idle unnecessarily for another duration of a data fragment (or part of it) as in PCMA.

### A.4 Single-Channel CSMA/BC

A problem that has not been addressed by the proposed protocols thus far is the dual-channel path-loss mismatch problem. To avoid this problem, we need to use single-channel versions of CSMA/BC. The resultant protocol also becomes more robust against interference from legacy IEEE 802.11/11e devices or other protocols.

In single-channel time-division CSMA/BC (ST-CSMA/BC), the same frequency band is used for both prohibiting signaling and data packets. The time axis is divided into alternating control intervals and data intervals. A control interval is further divided into multiple competition rounds, while a data interval has duration equal to that of a single maximum data fragment. A competition round in ST-CSMA/BC is similar to that of DT-CSMA/BC, except that an active intended receiver may now need to accumulate the aggregate interference from all continuous data fragment transmissions (from the last data interval) and the newly requested transmissions for the next data interval. To facilitate this, we impose some special rules for the competition and augment some special slots in control intervals and possibly in data intervals.

At the beginning of a control interval, a acknowledgement slot is available for all the transmitter-receiver pairs from the previous data interval to negotiate whether they want to continue transmitting or not. Then a large declaration slot follows to let all continuing receivers to protect their receptions. After these two slots, a special additive interference slot is inserted to let all continuing transmitters to transmit a signal equal to its transmission power. An active intended receiver can then measure the aggregate interference level from existing transmitters as well as all other interference sources. After these slots, the control interval is filled with competition rounds, with a relatively small number of additive interference slots inserted among them.

A special rule for ST-CSMA/BC competition is that a CN has to have at least a 1-bit among the last few bits. An active intended receiver can then accumulate the aggregate interference level by listening to the last few bits in each competition round to estimate the interference to be generated by the new winner if any. Since such estimations may not be accurate, and will be more expensive if relatively accurate measurement is required, active intended receivers can roughly estimate the aggregate interference level in a more conservative manner. To refine the estimation, an additive interference slot can be inserted after a few competition rounds for all the transmitters so far to transmit at their intended power level. An active intended receiver can then discard previous estimation and use the new measure of the aggregate interference level. Note that it is possible to adaptively control the durations of control intervals in WLANs and WLAN meshes, but controlling them in infrastructureless ad hoc networks is more complicated and incur larger overhead. Also, it is not impossible to also augment some large declaration slots for scheduled receivers to resend their declaration signals with more accurate power, but such a mechanism is relatively complicated or expensive to support and is thus not recommended in ST-CSMA/BC.

To make ST-CSMA/BC backwards compatible with IEEE 802.11/11e, we need to make sure that the declaration signals can appropriately serve as busy tone to protect ST-CSMA/BC receptions when desired. First of all, the power level for declaration signals need to be sufficiently high, which is relatively easy to support. Secondly, legacy devices need to be deferred for sufficiently long time (until current data fragment reception is completed). If, for example, the duration of a data fragment is greater than EIFS, then we can insert large declaration slots during a data interval. These declaration slots should be closely spaced so that the duration from the beginning of a declaration slot to the end of the next declaration slot does not exceed EIFS. Then a receiver randomly selects a position for transmitting its declaration signal in each of the declaration slot, and changes its position in every declaration slot. Note that the shared-channel exposed terminal problem does not exist among ST-CSMA/BC devices since their declaration signals are confined within declaration slots and will not collide with data receptions. To fine tune the power levels for declaration signals, a transmitter-receiver pair can optionally select one or a small number of short periods randomly for the receiver to measure the sampled interference level(s) from all the other concurrent transmitters and interference sources. It will then use the highest measured value to estimate the required power level for its declaration signal. This way, new changes in the interference level can be incorporated in a timely manner, making the resultant protocol interference-aware and leading to more effective spatial reuse.

### B. Other CSMA/BC Extensions

FIG. 24 provides an example for the prohibiting, acknowledgement, and declaration slots in position-based prohibition. In FIG. 24a, there are no hidden terminals so the intended receiver sends an acknowledgement signal and a declaration signal. In FIG. 24b, there are hidden terminals so the intended receiver keeps silent.

To mitigate the additive prohibiting signal strength problem, we can use larger competition durations, especially for the declaration slot and the first few prohibiting slots. To better utilize such extended slot durations, however, it is desirable to adapt the position-based prohibition mechanism for the prohibiting slots for transmitter competition, leading to CSMA with position-based prohibition (CSMA/PP). This can be done by substituting each bit-slot in CSMA/BC with a position-based prohibiting slot in CSMA/PP, and following similar rules or spirits as in CSMA/BC. The main difference between CSMA/PP and CSMA/BC is that in CSMA/PP, if a node receives a prohibiting signal before its own position for transmitting the prohibiting signal in the same position-based prohibiting slot, it loses the competition. A special requirement for the position-based prohibition mechanism in CSMA/PP is that a competitor needs to transmit exactly one prohibiting signal per slot before losing the competition, and cannot stay silent in a slot. FIG. 24 illustrates the prohibiting slots and declaration slot for position-based prohibition. Single-channel CSMA/PP (ST-CSMA/PP) can be obtained by adapting DT-CSMA/PP in a way similar to extending DT-CSMA/BC to obtain ST-CSMA/BC. The details are omitted in this paper.

Similar to ST-CSMA/BC, we can use inband busy tone (IBT) in addition to, or to replace, the declaration signals in CSMA/BC or CSMA/PP. This way the resultant protocol can be more robust against interference from legacy IEEE 802.11/11e devices. More precisely, IBT is transmitted by the receiver intermittently, using the same frequency band as its data packet reception. The APP technique can be applied to such IBT transmissions. CSMA/BC (or CSMA/PP) with IBT can then become compatible with legacy or future CSMA-based protocol. For example, we can make the data fragment duration no greater than the EIFS of IEEE 802.11/11e. Then data fragment receptions in CSMA/BC with IBT can be well protected from interference of legacy IEEE 802.11/11e devices. However, since IBT signals are not synchronized or confined, a receiver has to avoid transmitting IBT with power high enough to collide nearby receptions. As a result, if IBT is mandatory for all CSMA/BC-IBT (or CSMA/PP-IBT) receptions, the availability of intended receivers may be greatly limited by nearby lower-power receptions. This might lead to poor spatial reuse if not carefully handled, even when power control is employed. This is a special case of the shared-channel exposed terminal problem. A mitigation for this problem is to employ interference-engineering to increase the interference tolerance of a receiver when needed, reducing the required power level for its IBT. Also, a realistic implementation of CSMA/BC-IBT (or CSMA/PP-IBT) is to make IBT optional for a data packet that does not need perfect protection from legacy devices, and to allow a lower power level for IBT when the ideal power level cannot be reached.

IBT can also be applied to other types of protocols. For example, receiver dominance multiple access with APP (RDMA/APP) is an RTS/CTS-based protocol with IBT. RDMA/APP employs the receiver dominance mechanism, where longer CTS messages (relative to RTS) are used as in FAMA. However, the deterring times in RDMA/APP are considerably shorter than those in FAMA. More precisely, the duration for a CTS message is longer than that for an RTS message by at least the maximum propagation delay plus the minimum time for carrier sensing. An intended transmitter that transmits an RTS message almost concurrently with an irrelevant CTS message in the vicinity will then be able to detect the signal corresponding to the end of the CTS message and yield. Different from FAMA, the intended transmitter will defer only for the maximum APP period, rather than the maximum data packet duration (which is considerably larger) as in FAMA. If the intended transmitter hears APP signals during the deferred time, it will keep deferring; otherwise, it becomes eligible for retrial, but may subject to a backoff time. When a node hears signals that are possibly resulted from collisions of a CTS message (possibly between RTS and CTS messages, CTS and CTS messages, or CTS messages and data packets), it will also defer for the maximum APP period. If the node hears APP signals during the deferred time, it will keep deferring; otherwise, it becomes eligible for initiation of transmissions. In this way, IBT can be used to prevent collisions, improving transmission efficiency and quality.

### XXIII. INBAND BUSYTONE (IB)

A. CSMA with Inband Busytone (CSMA/IB)

In this section, we propose carrier sense multiple access with inband busytone (CSMA/IB) based on CSMA, optional inband busytone, and optional RTS/CTS dialogues.

In CSMA/IB, an intended transmitter listens to the channel before transmitting anything, and the required observation time is at least equal to the maximum allowed inband busytone period. The same as CSMA, the transmitter does not transmit when it detects signals or carriers above a certain threshold. But different from conventional CSMA, the threshold can be higher due to the use of inband busytone from CSMA/IB receivers, resolving the exposed terminal problem and thus leading to better spatial reuse. When collision rates are high (for the transmitter, its receiver, or nearby nodes), the transmitter may reduce the threshold to make its carrier sensing more sensitive. If the detected signal or carrier strength is below the threshold, the transmitter can transmit its data packet, possibly after appropriate backoff as in IEEE 802.11/11e or other backoff schemes.

When the size of a data packet to be transmitted is over a fragmentation threshold and the packet requires better protection from other (CSMA) devices, the transmitter transmits it in fragments. The durations for the fragments can be fixed or variable in different CSMA/IB versions. For the latter type of CSMA/IB protocols, the fragment lengths need to be made known to the receiver. This may be implemented by utilizing framing techniques such as indicating the length(s) or attaching a frag at the end of a fragment. The rules for the fragment lengths can also be made known between the transmitter and receiver pair in advance, possibly with some parameters conveyed on the fly during the transmission. If a data fragment (other than the last one) is received correctly, a receiver with single transceiver turns around and transmits an short signal (to be referred to as inband busytone (IB)) using the same frequency channel as the data packet transmission. When the last fragment is received, the receiver sends an acknowledgement (ACK) message when a per packet acknowledgement mechanism is employed. However, if a different acknowledgement mechanism (such as group acknowledgement or PING) is employed, the receiver sends an acknowledgement or negative acknowledgement message only when needed (according to the respective rules) and allowed to do so.

An inband busytone signal can be a short pulse at appropriate power level (that can reach at least most parts of its protection range) with sufficient length to be detectable by other (CSMA) devices in the vicinity. When an IB signal is received by a nearby node, the node will set its network allocation vector (NAV) for a duration equal to the maximum allowed IB period. An intended transmitter or receiver is eligible to transmit data fragments, control messages, and/or inband busytone only after its NAV ends. The next data fragment reception can then be protected from being collided by nearby intended transmitters. To make CSMA/IB backward compatible with IEEE 802.11/11e or future CSMA-based protocols. we can make the maximum allowed IB period smaller than or equal to the EIFS of IEEE 802.11/11e (which are hundreds of microseconds). Then data fragment receptions in CSMA/IB can be well protected from interference of legacy IEEE 802.11/11e devices.

If the environment and technology permit, the inband busytone signal may also serve as an ACK signal to inform the transmitter that the previous data fragment was received successfully; otherwise, in other CSMA/IB versions a separate ACK signal/message is transmitted. Note that if the receiver has an extra transceiver for sending busytone, it can transmit the inband busytone upon receiving the fragment completely and successfully, without requiring the turnaround time and thus reducing the overhead.

If the transmitter does not receive the expected ACK signal/message (which may be the inband busytone if so used), it can cease its transmissions (when wireless ARQ is not employed), lending to a means for mobile wireless collision detection. When wireless ARQ is employed in the CSMA/IB version, an option is for the receiver to send a negative acknowledgement (NAK) signal or message to request for retransmission of the previous data fragment. Such NAK signals can be encoded with interference-based signaling to be distinguishable from ACK/inband busytone signals and recognizable by the transmitter. The transmitter will then retry till the previous data fragment is successfully received, or after a limited number of trials.

When the data fragments are fixed in duration, the corresponding intermittent inband busytone signals will be transmitted periodically; otherwise, they are not transmitted with a fixed period. We refer to the latter approach as the adaptive periodical prohibition (APP) mechanism. In APP, a receiver transmits inband busy signals in a semi-periodical manner (see FIGS. 26c and 26d). More precisely, the transmitter first estimates the end of its transmission (or the end of its ACK message reception), and then determines the time for the last IB signal required. The last IB signal should be within the maximum allowed IB period from the estimated end. to protect the transmission(s). It then determines the times for their IB signals throughout the transmission, which must not be separated by more than the maximum allowed IB period between any pair of adjacent IB signals. Under the aforementioned constraints, the determined times can be fixed or variable. For the former case, the period can be equal to the maximum allowed IB period or the remaining part of transmission (excluding the last fragment) divided by the number of data fragments. For the latter case, the “periods” or durations of data fragments may be randomly or semi-randomly selected to avoid repeated overlapping with the IB signal(s) from nearby receivers. The latter is more suitable if the employed error correcting code can typically fix the transmission errors caused by short signals (e.g., the additive effects from inband busytone signals and other transmissions). When CSMA/IB with wireless ARQ is employed, and there are no legacy IEEE 802.11/11e devices nearby, the latter may also be beneficial. The reason is that the latter may mitigate the additive bsusytone signal problem since they only defer nearby transmitters unnecessarily once (or for a small number of times) even when overlappings of IB signals do happen. The determined times should be conveyed to the receiver and the transmitter will not transmit any signal during the selected times, and will listen to the channel instead.

When received IB signal is received by a nearby node, it will set its network allocation vector (NAV) for a duration equal to the maximum allowed IB period. An intended transmitter or receiver is eligible to transmit data fragments, control messages, and/or inband busytone only after its NAV ends.

A.1 CSMA/IB with Dialogues

Similar to IEEE 802.11, CSMA/IB allows optional RTS/CTS dialogues. For backward compatibility, exactly the same format and transmission requirements may be used as legacy IEEE 802.11/11e. A transmitter-receiver pair employing RTS/CTS dialogues in CSMA/IB may reduce or completely prevent collision for their reception, no matter whether there are other concurrent transmissions from legacy IEEE 802.11/11e devices or CSMA/IB devices that are not using RTS/CTS dialogues.

In CSMA/IB with dialogues, an IB signal is augmented after the CTS message (see FIG. 26d). The duration for CTS message plus the augmented IB signal should be longer than that for an RTS message by at least the maximum propagation delay plus the minimum time for carrier sensing. The resultant CSMA/IB protocol becomes receiver dominant, which is similar to FAMA where longer CTS messages (relative to RTS) are used. However, a very important difference is that the deterring times in CSMA/IB are considerably shorter than those in FAMA. More precisely, an intended transmitter in FAMA has to defer for the maximum data packet duration after it received the ending part of a CTS message. On the contrary, in CSMA/IB, an intended transmitter only needs to defer for the maximum IB period, which is considerably smaller than the maximum data duration. As a result, better channel utilization can be achieved in CSMA/IB.

In CSMA/IB, an intended transmitter that transmits an RTS message almost concurrently with an irrelevant CTS message plus an IB signal in the vicinity will be able to detect at least the IB signal and yield. If an intended transmitter hears IB signals or other undecodable signals during the deferred time, it will keep deferring. When a node hears signals that are possibly resulted from collisions of a CTS message (possibly between RTS and CTS messages, CTS and CTS messages, or CTS messages and data packets), it will also defer for the maximum IB period. When a node does not hear any signals for a maximum IB period, it becomes eligible for initiation of transmissions, but subject to a backoff time or countdown. The receiver dominance property accompanied with the preceding rules may lead to collision-free property in CSMA/IB, if FAMA is collision free in the same environment.

B. DPMA with Inband Busytone (DPMA/IB)

FIG. 26 provides examples for the prohibiting slots in MACP without dialogues and examples for MAC protocols with inband busytone. FIG. 26a provides a transmission example for CSMA/BC with periodical prohibition. FIG. 26b provides a transmission example for CSMA/BC with adaptive periodical prohibition (APP). FIG. 26c provides a transmission example for CSMA/BC with inband busytone (CSMA/BC-IB). FIG. 26d provides a transmission example for CSMA/IB with dialogues.

DPMA and RPMA can also be modified to obtain variable-length versions corresponding to FIGS. 26a, 26b, and 26c, in a way similar to variable-length CSMA/BC, where periodical prohibition and adaptive periodical prohibition (APP) are also sent by receivers as in CSMA/BC.

The central idea of dual prohibition multiple access with inband busytone (DPMA/IB) is simple yet powerful. We essentially employ the dual prohibition mechanism (see FIG. 5 and Subsection ??) to replace the RTS and CTS messages in CSMA/IB, while retaining its collision-free property. Since the prohibiting signals used in such competitions do not suffer from collisions, and collided transmissions of data packets can usually be prevented by the competition, several problems of IEEE 802.11 and other RTS/CTS-based protocols can be avoided naturally. Moreover, DPMA/IB has the advantage of stronger differentiation capability as compared to IEEE 802.11e and CSMA/IB, at the expense of an additional control channel, and the additional requirement for synchronization. The differentiation capability of DPMA/IB is similar to those of DPMA and other MACP protocols. Since extensive performance evaluation results have been reported in our previous MACP papers, we omit them in this work in progress paper due to the page limitation. In what follows, we briefly explain how DPMA can incorporate the inband busytone mechanism as in CSMA/IB, and why it can achieve the collision free property.

In DPMA/IB, the “keys” used for “countdown competition” are composed of two optional parts: random part and ID part. The random part is selected randomly but according to appropriate probability distributions (possibly taking into account priority and fairness requirements). When the ID part is absent, we can trade off between control overhead and collision rate by appropriately selecting the length for the random part.

The ID part for the key uses one of the appropriate IDs maintained by the transmitter-receiver pair. When unique IDs are available, there can only be at most one winner transmitter but no winner receivers (except for its receiver) within its prohibition range, and at most one winner receiver but no winner transmitter (except for its transmitter) within its prohibition range. As a result, a transmitter will not collide other receptions, while a reception cannot be collided by other transmitters. The rest of proof is similar to that for DPMA and is omitted in this work in progress paper.

Note that overlapping IDs should be avoided among all the competing pairs and groups in the vicinity. However, when the overhead for maintaining uniqueness or the required length for unique IDs cannot be justified, such IDs do not have to be absolutely unique all the time. Since the collision rate for data packets can be reduced and controlled to a probability very close to zero, DPMA/IB can be a collision-controlled MAC protocol.

Due to the characteristics of wireless channels and mobile networks, damage to data packets is still possible in reality so that an appropriate acknowledgement mechanism can be incorporated. However, since DPMA/IB can reduce the collision rate to sufficiently low levels when desired, we may employ ACK mechanisms with lower overhead such as negative/implicit ACK or individualized selective segmented error control. The hybrid, modifications, or other ACK mechanisms may also be used. In DPMA/IB, the inband busytone mechanism is employed as in CSMA/IB. Different from CSMA/IB, the ACK signals can be transmitted at specific time according to its synchronized slots in the control channel. Other aspects for the inband busytone mechanism are very similar to that used in CSMA/IB and the details are omitted in this paper.

### C. Independent Review Comments for Inband Busytone

In what follows I include review comments and evaluation (without any modifications) for my submission entitled “Inband Busytone for Robust Medium Access Control in Pervasive Networking,” which has been accepted for publication in the 4th IEEE International Conference on Pervasive Computer and Communications (PerCom'06). This review was made on Nov. 26, 2005 by an anonymous expert who served as a reviewer for PerCom'06.

Relevance (1-lowest; 6-highest): 5

Technical Quality (1-lowest; 6-highest): 5

Presentation and Organization (1-lowest; 6-highest): 5

Scope for further research (1-lowest; 6-highest): 5

Overall Recommendation (1-lowest; 6-highest: 5.5

Comment on Technical Contribution:

This paper presents two MAC protocols based on inband busytone, which guarantee collision-free transmission without requiring dual transceivers per node and solve the dual channel mismatch problem.

Importance—Do you think the issues considered are significant to the area of research? comment in 1-3 lines:

Collision problems are a major cause of network performance degradation in multihop networks, having significant consequences on QoS, fairness and other network properties. This paper proposes to use inband busytone, which under certain circumstances can be proved to overcome the collision problem. This is an important contribution, as it can be readily applied to large-scale multihop networks.

Strengths and Weaknesses of the paper—Please provide useful comments:

The paper is sound and well written. A section with an example where the proposed protocols would be applied and compared to existing protocols (i.e. IEEE) would further enhance understanding of applicability of the proposed results.

Overall Recommendation—Please justify your rating—Strong Accept (6), Accept, Weak Accept, Unsure, Reject, Definite Reject(1):

Strong accept. Although this is a very technical contribution, I think the audience will benefit from the discussion on the potential of the proposed protocols.

### XXIV. RECEIVER PROHIBITION MULTIPLE ACCESS (RPMA)

### A. RPMA

### A.1 Central Ideas and Unique Features

PRMA employs MACP-type competition between receivers only to select at most one winner within a prohibiting range. The main difference between PRMA and previous MACP protocols is that PRMA employs receiver prohibition, while earlier MACP protocols employ transmitter prohibition (i.e., competition between transmitters only), and other recent MACP protocols employ dual prohibition. In particular, DPMA requires competition between transmitters and receivers, but a transmitter will not prohibit a receiver and vice versa.

In RPMA, intended receivers use transmitter-ID-based competition numbers (CNs) for competition. This is different from DPMA and CSMA/BC, which use link-ID-based CNs and receiver-ID-based CNs, receptively. Such transmitter-ID-based CNs are essential to RPMA since they are needed to trigger intended transmitter to send data after a successful competition. This way the transmitter in a transmitter-receiver pair only needs to inform its receiver the number or rate for data packet transmissions, and the receiver can initiate the competition and then reception on its own. This is different from DPMA, where both the transmitter and receiver in a transmitter-receiver pair has to enter the competition at the same time, thus reducing complexity and overhead in this respect.

In RPMA, intended receivers that just lost a competition can restart a competition after a competition round as long as they do not receive data signals from nearby transmitters. This resolves the prohibition-range exposed terminal problem of CSMA/IC. When RPMA is combined with inband busytone, the waiting period may need to be longer as will be explained in the section for PRMA with inband busytone. But with appropriate modifications, an intended receiver that just lost can in fact join the competition in the very next competition round.

The prohibiting signals of RPMA replace, but retain the functionality of, CTS messages in CSMA/BI. Moreover, prohibiting signals in RPMA do not suffer from collisions since they are still detectable in the presence of multiple prohibiting signals. As a result, RPMA solves the vulnerability problem of virtual carrier sensing in CSMA/BI as well as in other dialogue-based protocols such as IEEE 802.11/11e and BROADEN.

Also, the hidden terminal problem is taken care of naturally in RPMA, without having to augment additional mechanisms such as hidden terminal detection in transmitter prohibition MACP protocols. Moreover, the interference-range hidden terminal problem is resolved naturally in RPMA, since, unlike control messages, prohibiting signals can reach interference ranges easily without requiring any special techniques or increased power level. Power control is also naturally supported in RPMA without requiring on RTS/CTS dialogues, which cannot be done in CSMA/IC or other transmitter prohibition MACA protocols unless dialogues and/or other special mechanisms (such as detached dialogues) are added.

In the following subsections, we present the mechanisms and examples for implementing RPMA.

### A.2 Basic RPMA Operations and Mechanisms

In the RPMA scheme, a node that intends to receive a data packet sends prohibiting signals to other nodes within its prohibiting range (to be elaborated shortly). The purpose for the competition is to elect at most one winner within a prohibiting range in a fully distributed manner. Note, however, that it is not required for the competition to elect a winner for “every” prohibiting range.

We define the maximum interfering range for an intended receiver as the range within which the receiver will receive, from a single interfering node, interference above certain threshold (nonnegligible for the intended data reception). Note that the maximum interfering range for a transmitter-receiver pair depends on the intended reception signal strength as well as other factors associated with interference tolerance and target error rates. For example, when spread spectrum with larger spreading factors are used, the interference tolerance will be higher so that the maximum interfering ranges can be reduced. We also define the maximum interfered range for an intended transmitter as the range within which a nearby node will receive, from the intended transmitter, interference above certain threshold (nonnegligible for the data reception at the nearby node). Note that the maximum interfered range depends on the intended transmission power. Then for dual-channel RPMA without inband busytone, the radius of the prohibiting range for an intended receiver can be anything ranging from the maximum interfering radius of the intended receiver to the sum of the sender-receiver distance plus the maximum interfered range for its intended transmitter (if the latter is larger), plus appropriate safe margin. When the prohibiting range actually used is smaller than the sender-receiver distance plus the maximum interfered range for its intended transmitter, the probability of having hidden terminals during competition is lower so that the chance for canceled trans-mission by winning candidates will be lower. When the prohibiting range actually used is smaller than the sender-receiver distance plus the maximum interfered range for its intended transmitter, an intended transmitter (for a winning intended receiver) may be blocked by other winning intended receivers with higher probability so that more competitions will end up with canceled transmissions, thus wasting radio resource in competition sometimes. However, anything within the legitimate range leads to correct operation of the protocol, and can achieve collision freedom when the CNs are unique locally within a prohibiting range.

Similar to RICK, a CN used for RPMA can be comprised of a priority part, a random number part, and an ID part. The IDs used in RPMA are based on the IDs of the intended transmitters (or the links if such IDs are available and preferred). Note that it is very important for such IDs to be transmitter-oriented or link-oriented for RPMA to work. Otherwise, an additional CTS or invitation message needs to be sent by a winning receiver, making the protocol vulnerable to collision of control messages again as in IEEE 802.11. For an intended transmitter to be invoked by the CN correctly, the IDs should be based on the same set of additive error detectable codes (AEDC). It is also preferred to use AEDC for the random number part to mitigate problem caused by possible occurrence of duplicate IDs (temporarily) or concurrent invitations to the same intended transmitter from multiple intended receivers. As an example, a binary AEDC code is a binary codeword that is guaranteed to be changed to a non-codeword as long as none of its 1-bits are changed to 0 and at least one 0-bit is changed to 1. n-choose-k codes is a possible set of n-bit AEDC and have exactly k 1-bits and n-k 0-bits in any codeword. Typically k can be selected as └n/2┘ or ┌n/2┐. FIG. 23a provides an example for the 6-choose-3 codes in CSMA/BC. Note that there are other possible AEDC coding. For example, the binary 0-count mapping (BZM) codes shown in FIG. 23b (for CSMA/BC) can transform any binary number into an AEDC code by adding an extension with logarithmic length of its original binary number. When BZM coding is employed, the priority part, random number part, and a binary-number ID can be transformed together to obtain a single BZM extension for the AEDC-based CN.

By changing “sender prohibiting bit-slots” to “receiver prohibiting bit-slots” in FIG. 23, and removing receiver slots in FIG. 23, we can get examples for 6-choose-3 codes and BZM codes in RPMA.

By changing “sender prohibiting bit-slots” to “receiver prohibiting bit-slots” in FIG. 23, without removing receiver slots in FIG. 23, we can get examples for 6-choose-3 codes and BZM codes in a variant of RPMA where the last few receiver slots that are not removed can be used by the wining receiver candidate to send prohibition signals at appropriate power levels (to reach its prohibition range). In this way, the power used for receiver prohibiting signals do not need to be proportional to the power level required to reach its prohibition range, and can be more flexible. Nearby intended receivers (and their intended transmitters) that do not receive such prohibition signals can join the competition earlier (e.g., in the 2nd next round or without having to wait for a maximum APP period (or EIFS). One or some of the slots can also be used to “acknowledge” or “invoke” the intended transmitter of the wining receiver candidate to transmit. When this mechanism is supported, an intended receiver does not have to use a transmitter-ID-based CN or link-ID-based CN to invoke it intended transmitter.

Similarly, when such a mechanism is supported in CSMA/BC for an intended transmitter to invoke its intended receiver, the intended transmitter does not have to use a receiver-ID-based CN or link-ID-based CN to invoke it intended receiver.

By changing “sender prohibiting bit-slots” to “receiver prohibiting bit-slots” in FIG. 23, and changing the middle “receiver prohibiting bit-slots” or all “receiver prohibiting bit-slots” to “transmitter prohibiting bit-slots” in FIG. 23, we can get examples for 6-choose-3 codes and BZM codes in receiver-oriented dual prohibition. The intended transmitter can then acknowledge its intended receiver if it is allowed to transmit or not. (The intended transmitter can also use such slots to send prohibiting signals to block nearby intended receivers. Then nearby intended receivers that do not receive such prohibition signals can join the competition in the next round. However, nearby intended receivers can replace the latter mechanism by sensing the data packet transmission signals before rejoining competition or using larger safe margin so that the latter type of slots are not needed in some embodiments.) Similar to the preceding variant for RPMA, the last (few) slot(s) can be used by the winning receiver candidate to send prohibition signals at appropriate power levels (to reach its prohibition range). Then nearby intended receivers that do not receive such prohibition signals can join the competition without having to wait for a maximum APP period (or EIFS). If desired, the slot(s) before the new “transmitter prohibiting bit-slots” can be used by the winning receiver candidate to “invoke” its intended transmitter similar to the preceding variant for RPMA. When this mechanism is supported, an intended receiver does not have to use a transmitter-ID-based CN or link-ID-based CN to invoke it intended transmitter.

The RPMA scheme is a family of protocols that can be implemented in various ways to achieve respective advantages according to their requirements and the options made. In this subsection, we use a simpler version of RPMA protocol, dual-channel time-division RPMA (DT-RPMA) with fixed data packet duration, to illustrate the basic operations and mechanisms of RPMA. In the following subsections, we will introduce more advanced mechanisms and options and explain how to extend to other protocols in the RPMA family.

In the fixed-duration DT-RPMA protocol, all participating nodes are synchronized (e.g., to timing signals from GPS, WLAN APs/MPs, or WiMax/4G+base/relay stations), and start the competition round at the same time. A narrow-band control channel is used for sending prohibiting signals (including acknowledgement and declaration signals), while a data channel is used for transmissions of data packets. Acknowledgement message can be piggybacked in the data channel or transmitted explicitly in the data channel if so desired. It may also be replaced by prohibiting signals during the acknowledgement slot in the control channel (coded with interference-based signaling or transmitted as a small control message). The acknowledgement signals can also include information for rate and power control as well as other control such as spreading factor. An intended transmitter can then retry with higher priority in the next competition round based on the suggested rate and power if they are eligible.

During a competition round, an intended receiver whose CN has value 1 for its i-th bit, i=1, 2, . . . , n, transmits a short prohibiting signal during bit-slot i at power level sufficiently high to be detectable by most other nodes within its prohibitive range during bit-slot i. The received signal strength should be above the minimum required power level or SNR for detection, which is referred to as the prohibiting threshold. On the other hand, a node whose i-th bit is 0 keeps silent and senses whether there is any prohibiting signal that has strength above the prohibiting threshold during bit-slot i. If the silent competing node finds that bit-slot i is not idle (i.e., there is at least one competitor whose i-th bit is 1), then it loses the competition and keeps silent until the end of the current round of competition. Otherwise, it survives and remains in the competition. If a node survives all the n bit-slots, it becomes a candidate for the winner within its prohibiting range.

An active intended transmitter observes the ID part of the current competition for prohibiting signals with strength above its interference threshold, where a competitor sending prohibiting signals with such strengths will be interfered by the transmission of the intended transmitter. If it finds that the heard prohibiting signals correspond to its own ID, then its intended receiver has successfully won the competition. If it also decides that its transmission power will not interfere with current on-going receptions, it can go ahead to transmit its data packet. This is different from CSMA/BC, where additional acknowledgement and declaration signals are required to be transmitter after the partner of a node wins a competition.

If a winning candidate receiver does not hear data packet transmission from its intended transmitter, it backs off before entering another competition again. If a nearby node hears a data packet transmission with strength above an appropriate threshold, it sets it reception-NAV accordingly so that the associated reception can be protected. Note that the threshold is determined by the intended reception signal strength or tolerance to interference for the nearby node. For example, if the received data packet signal is weaker, a nearby node may still be available to receive if it will have sufficiently high reception signal strength. It can thus join competition if needed. This naturally enables power control capability in RPMA, which was not possible in CSMA/IC.

Note that if the winning intended receiver has a hidden node (or hidden nodes) that also wins its competition, its intended transmitter will not send its data packet and thus will not block other intended receivers in the associated region. The reason is that the intended transmitter will have observed a non-codeword for the ID part of the competition due to the prohibiting signals from the hidden node(s). As a result, the hidden terminal problem is naturally resolved in RPMA. Since an intended receiver losing a competition can join the following competition as long as it does not receive any data packet signals or interference above its associated threshold, the prohibiting-range exposed terminal problem can also be mitigated. As mentioned earlier, power control is also naturally supported with the proceeding mechanisms.

B. RPMA with Inband Busytone (RPMA/IB) and Other Variants

RPMA is particularly suitable for combining with inband busytone.

RPMA/IB can be derived in a way similar to the derivation of CSMA/BC with inband busytone (CSMA/BC-IB) or DPMA/IB.

For example, RPMA can be extended to its variable-length variant, and then its prohibiting signals can be replaced by inband busytone. Also, we can augment RPMA competition to CSMA/IB.

The prohibiting signals for competition in MACP can be sent in a separate control channel. In a different type of embodiments, the prohibiting signals can be sent in the same channel as the data packets. The senders of such prohibiting signals have to consider their rights for transmissions. For example, if they may collide other on-going receptions, they are not allowed to send prohibiting signals for competition. Or they have to reduce their transmission power to acceptable levels. An advantage for such inband prohibition is to resolve or mitigate the dual channel mismatch problem.

MACP, including DPMA, CSMA/BC, RPMA, with or without inband busytone, may be synchronized for their competition as in some descriptions in this document.

In a different type of embodiments for MACP, asynchronous competition may be preferred. An additional approach to implement such asynchronous MACP is to allow an intended node to initiate its competition when it has not heard others' prohibiting signals, and it has the right to send them. The QoS differentiation capability for such embodiments may be compromised, but they have practical values since in some environments or contexts, synchronization may not be supported/allowed, affordable, or worth the overhead/complexity/efforts.

In DPMA and some other dual prohibition-based protocols, the same slot may be used by the intended transmitter and receiver in a pair. This is a special case of pairwise group competition. This makes asynchronous DPMA easier to implement. Other ways to implement asynchronous DPMA include using different frequency bands for intended transmitter and intended receivers. This way an intended transmitter can tune to the channel for the prohibiting signals from intended receivers when it has nothing to send or after it finishes its transmissions using position-based prohibition, while an intended receiver can tune to the channel for the prohibiting signals from intended transmitters when it has nothing to send or after it finishes its transmissions using position-based prohibition,

To support inband competition (i.e., using the same frequency band for both prohibiting signals and data packets), a type of embodiments can use multiple ultra-narrow-band (M-UNB) for prohibiting signaling, where several relatively narrow bands within the frequency band used for data packets are employed to transmit prohibiting signals. An advantage for such embodiments is that the interference from prohibiting signals to data packet receptions may be reduced since the total energy for competition (i.e., based on prohibiting signals) may be reduced. These narrow bands can also be selected to fall at frequencies that may generate less problems/interference to data packet receptions.

M-UNB can also use one or several narrow bands outside data channels so that they can be transmitted at higher power without much interference. M-UNB may degenerate and use only one relatively narrow band within the data channel if so desired. M-UNB may be applied to inband busytone if so desired. Such M-UNB inband busytone can still defer other devices using the same protocol, but legacy IEEE 802.11/11e devices may not be deferred as effectively unless the total energy for the inband busytone remains high.

### C. Additional Remarks

There are many flexible ways for embodiments of the general interference/sensing-based signaling approach. In what follows I provide some additional remarks on this issue. The numerical value used in competition can be comprising of the ID of said transmitter, receiver, or link and possibly other parts. An CN or ID can be the ID of an intended receiver or link (i.e., associated with the transmitter-receiver pair). Node can react to such an interference/sensing-based signal according to the protocol it is running. For example, when IEEE 802.11/11e is employed by a legacy node, it can defer by EIFS. The numerical value used for interference/sensing-based signaling can be comprising of a competition number with two bits or digits. It can also be comprising of at least three bits or digits in order to represent ID and reduce collision or even achieve collision freedom when the protocol is appropriately designed. Nodes participating in competition or interference/sensing-based signaling are not required to be synchronized when the protocol is appropriately designed. They can also be synchronized, and possibly transmit signals out of band or inband. They can also be asynchronous and possibly transmit signals out of band or inband, when the protocol is appropriately designed. The AEDC coding technique can be used for representing a numerical value. Its characteristics are that a codeword is changed to a non-codeword when none of its 1-bits are changed to 0 and at least one 0-bit is changed to 1. It can be used in various applications. In particular, it can be used for competition or interference/sensing-based signaling. n-choose-k code, BZM code, and other codes are possible and have their respective advantages. In some embodiments, a node that is not an intended transmitter or intended receiver can be allowed to send a signal or several signals interference/sensing-based signaling. The HTD mechanism is a special case for such usage.

### XXV. CONCLUSIONS

The MAC and PHY standards for wireless networks are evolving. In particular, faster PHY standards such as IEEE 802.11, 11b, 11a, 11g, have been released one after another, while new standards such as IEEE 802.11n are expected to continue appearing. Currently, an extension to the MAC protocol of IEEE 802.11 is being standardized for the supports of real-time applications in future wireless LANs. Other needs and emerging technologies, such as security, sensor networks, directional antenna, UWB, and mesh networks, are destined to further evolve wireless communication technologies.

In 4G wireless systems, mobile ad hoc networks and multihop wireless LANs are expected to become a critical part of the heterogeneous network architecture. IEEE 802.11-based standards are most promising for this sector of wireless technologies. However, extensions to the current MAC protocols and/or appropriate accompanying mechanisms are mandatory for IEEE 802.11-based wireless devices to operate with acceptable quality and efficiency in multihop networking environments under stress conditions. In 5G mobile systems, multihop ad hoc cellular networks are likely to be realized. From the trends of wireless technologies, it can be expected that an integrated but versatile, evolvable, and extensible MAC protocol that is efficient, secure, and can guarantee satisfactory quality in multihop networking environments will be desirable and highly demanded in the years to come.

In multihop wireless networks, a fundamental source of problems for many important issues or requirements, including QoS, fairness, radio and energy efficiency, is interference, complicated by their inherent mobility characteristics. By mitigating or resolving the interference problems in multihop networks, we can achieve reduced collision rate, better quality and fairness, and increased throughput. As a result of such improvements, important applications that were not feasible or ran poorly in ad hoc networks can now be enabled, and have their efficiency increased and communication costs/prices reduced with the maturity of the associated technologies and the networking/MAC/PHY paradigms adopted. This will in turn lead to proliferation of multihop wireless LANs/MANs as well as multihop ad hoc cellular networks in the future. By employing advanced techniques for interference management, more objectives can be achieved. For example, energy consumption can be reduced and coverage and connectivity can be increased due to smaller interference/noise achieved, and maximum transmission rate can be further increased due to larger SNIR, which enables the use of a faster modulation technique.

In this application, we pointed out the heterogeneous hidden/exposed terminal problem, the interference-radius hidden/exposed terminal problem, and the alternate blocking problem, which are not present in single-hop wireless LANs but will considerably degrade the throughout and weaken the QoS provisioning capability of ad hoc networks and multihop wireless LANs. We then disclosed the DDMDD protocol with effective supports for differentiated service and power control. in ad hoc networks. To the best of our knowledge, DDMDD is the first distributed MAC protocol reported in the literature thus far that can solve the HHET, IHET, and alternate blocking problems without relying on busy tone or dual transceivers per wireless device. Our simulation results showed that DDMDD can considerably increase the throughput and reduce the energy consumption as compared to IEEE 802.11e without power control. We also show through simulations that the differentiation capability of DDMDD is considerably stronger than IEEE 802.11e. Due to the improvements achievable by DDMDD, the techniques and mechanisms disclosed for in this application may be applied to obtain an extension to IEEE 802.11e to better support differentiated service and power control in ad hoc networks and multihop wireless LANs.

I provided more details concerning an embodiment of DPMA called RICK. DPMA does not require RTS/CTS messages, and can resolve the hidden and exposed terminal problems without relying on complex group competition or busy tone. DPMA can also support power control and interference control/engineering, which can lead to considerably better spatial reuse and energy efficiency. Due to the improvements achievable by DPMA, CSMA/BC, RPMA, and/or inband tone, the techniques and mechanisms of this invention may be applied to obtain an extension to IEEE 802.11/11e to better support differentiated service, power control, and collision control in ad hoc networks, multihop wireless LANs, as well as WLANs with crowded APs or competing service providers. New protocols may also be designed based on these embodiments for MACP or more generally interference/sensing-based signaling. Some DPMA mechanisms and techniques may also be combined with previous and future mechanisms/techniques for multiple access.

I claim:

1. A collision prevention method for coordinating medium access among a plurality of nodes according to claim 1 of the parent application (i.e., the U.S. patent application Ser. No. 10/881,414 filed on 2004 Jun. 30) wherein option (d) an interference/sensing-based signaling approach is employed, comprising the following steps:
(d.1) a node transmitting intermittent signal(s) in a channel the same as or different from that of associated data;
(d.2) other nearby nodes sensing the channel to understand the conveyed information or instructions according to the pattern of the signals, using information including, but not limited to, the timing, length, and/or power levels of the signals;
(d.3) nodes successfully sensing the signals optionally following the instructions and/or utilizing the conveyed information if there are any and the said nodes know the corresponding instructions and/or information, or simply reacting according to the protocol they are running; thereby achieving desired purposes such as avoiding collision of an associated reception while other nearby nodes are running other coexisting MAC approaches;

2. The method as set forth in claim 1, comprising the following steps: (a) an intended receiver sending a signal or several signals that use the same frequency band as the one used by the associated data/information to be received, or use a frequency band or several frequency bands within the one used by the associated data/information to be received, but are not control messages; (b) a node that receives the said signal(s) but is not the intended transmitter of the said intended receiver deferring from transmitting for at least a predetermined period of time.

3. The method as set forth in claim 1, comprising the following steps: (a) a node sending a signal or several signals corresponding to a numerical value (b) a node that receives the said signal(s) but is not the intended receiver or transmitter associated with the said node deferring from transmitting data/signals above a corresponding power level for at least a predetermined period of time, if the strengths for one or some of the received signals are above corresponding predetermined levels according to said power level of said data/signals and rules set forth by the protocol, and if its own corresponding numerical value is smaller (or larger according to the rules set forth by the protocol) than that of the received said signal(s) by at least a predetermined value (which can be equal to zero) according to the rules set forth by the protocol.

4. The method as set forth in claim 3, wherein the said node sending a signal or several signals is an intended receiver.

5. The method as set forth in claim 3, wherein the said signal or signals are sent using a frequency band or frequency bands different from the one(s) used by the associated data/information.

6. The method as set forth in claim 1, wherein both the transmitter and receiver in an intended transmitter/receiver-pair are involved in transmitting said intermittent signal(s).

7. The method as set forth in claim 6, wherein said intermittent signal(s) sent by the transmitter in an intended transmitter/receiver-pair and the said intermittent signal(s) sent by the receiver in said intended transmitter/receiver-pair are interleaved at least once.

8. The method as set forth in claim 6, wherein said intermittent signal(s) sent by the transmitter and the receiver in an intended transmitter/receiver-pair are not interleaved.

9. The method as set forth in claim 8, wherein said intermittent signal(s) sent by the transmitter in an intended transmitter/receiver-pair precede the said intermittent signal(s) sent by the receiver in the said intended transmitter/receiver-pair.

10. The method as set forth in claim 8, wherein said intermittent signal(s) sent by the receiver in an intended transmitter/receiver-pair precede said intermittent signal(s) sent by the transmitter in said intended transmitter/receiver-pair.

11. The method as set forth in claim 3, wherein said numerical value is comprising of the ID of said transmitter, receiver, or link and possibly other parts.

12. The method as set forth in claim 11, wherein said ID is the ID of said receiver.

13. The method as set forth in claim 11, wherein said ID is the ID of said link (i.e., associated with said transmitter-receiver pair).

14. The method as set forth in claim 1, wherein said node reacting by deferring for at least a predetermined time.

15. The method as set forth in claim 3, wherein said numerical value is comprising of a competition number with at least two bits or digits.

16. The method as set forth in claim 15, wherein said numerical value is comprising of a competition number with at least three bits or digits.

17. The method as set forth in claim 3, wherein said nodes are not synchronized.

18. The method as set forth in claim 5, wherein nodes that sends said signals are synchronized.

19. The method as set forth in claim 5, wherein nodes that sends said signals are not synchronized.

20. A coding technique for representing a numerical value, wherein a codeword is changed to a non-codeword when none of its 1-bits are changed to 0 and at least one 0-bit is changed to 1.

21. The method as set forth in claim 3, wherein said numerical value represented by a code is changed to a non-codeword when none of its 1-bits are changed to 0 and at least one 0-bit is changed to 1.

22. The coding technique as set forth in claim 20, wherein n-choose-k code is used.

23. The coding technique as set forth in claim 20, wherein BZM code is used.

24. The method as set forth in claim 1, wherein a node that is not an intended transmitter or intended receiver is allowed to send a said signal or several said signals.
